(19) United States
(12) Patent Application Publication
(10) Pub. No.: US 2024/0332330 A1
(43) Pub. Date: Oct. 3, 2024

(54) SOLID-STATE IMAGE-CAPTURING ELEMENT AND ELECTRONIC EQUIPMENT

(71) Applicant: SONY SEMICONDUCTOR SOLUTIONS CORPORATION, KANAGAWA (JP)

(72) Inventors: SHUHEI KASUKAWA, KANAGAWA (JP); SHO NISHIDA, KANAGAWA (JP); MICHIKO SAKAMOTO, KANAGAWA (JP)

(21) Appl. No.: 18/694,135

(22) PCT Filed: Mar. 24, 2022
(86) PCT No.: PCT/JP2022/013976

§ 371 Date: Mar. 21, 2024

(30) Foreign Application Priority Data
Sep. 30, 2021 (JP) 2021-160956

(51) Int. Cl. H01L 27/146

(52) U.S. Cl. CPC H01L 27/14627; H01L 27/14645

(57) ABSTRACT

The present disclosure relates to a solid-state image-capturing element and electronic equipment that make it possible to attain more uniform sensitivity characteristics.

The solid-state image-capturing element is configured such that it is provided with an on-chip lens for each 2×2 array of pixels in a same-color pixel group including pixels that receive light of the same color and that are arranged in a 4×4 array. Further, a sensitivity adjustment structure is configured by providing, on the light-incidence-surface side of a semiconductor substrate of predetermined pixels in the same-color pixel group, intra-pixel grooves with various shapes that are formed by digging shallower than an element separating portion for separating a photoelectric converting section in units of the pixels. For example, the present technology can be applied to a CMOS image sensor.

### TECHNICAL FIELD

The present disclosure relates to a solid-state image-capturing element and electronic equipment, and, in particular, relates to a solid-state image-capturing element and electronic equipment that make it possible to attain more uniform sensitivity characteristics.

### BACKGROUND ART

Conventionally, for example, solid-state image-capturing elements such as CMOS (Complementary Metal Oxide Semiconductor) image sensors include Bayer-arrayed pixels to receive red light, pixels to receive green light, and pixels to receive blue light, and can capture color images. In addition, in recent years, solid-state image-capturing elements with structures including Bayer-arrayed pixel groups each including a 4×4 array of pixels to receive light of the same color are under development.

For example, PTL 1 discloses a configuration which includes 4×4 arrays each including pixels to receive light of the same color and in which configuration an on-chip lens is arranged for each pixel, an on-chip lens is arranged for each 2×2 array of pixels, or an on-chip lens is arranged for each 4×4 array of pixels.

### CITATION LIST

### Patent Literature

### [PTL 1]

U.S. Patent Application Publication No. 2021/0144315

### SUMMARY

### Technical Problem

Meanwhile, there is concern that, in a solid-state image-capturing element with a structure including Bayer-arrayed pixel groups including 4×4 arrays each including pixels to receive light of the same color, inter-pixel sensitivity differences are generated in each pixel group. Accordingly, there has been a demand for development of a solid-state image-capturing element that suppresses such sensitivity differences and has more uniform sensitivity characteristics.

The present disclosure has been made in view of such a situation, and makes it possible to attain more uniform sensitivity characteristics.

### Solution to Problem

A solid-state image-capturing element according to an aspect of the present disclosure includes a same-color pixel group including pixels that receive light of the same color and that are arranged in an n×n array (n is an integer which is equal to or greater than two), an on-chip lens provided for each m×m array (m is an integer which is equal to or smaller than n) of pixels in the same-color pixel group, and a sensitivity adjustment structure with a configuration in which a dug portion shallower than an element separating portion for separating a photoelectric converting section in units of the pixels is provided on a light-incidence surface side of a semiconductor substrate at a predetermined pixel in the same-color pixel group.

Electronic equipment according to an aspect of the present disclosure includes a solid-state image-capturing element having a same-color pixel group including pixels that receive light of the same color and that are arranged in an n×n array (n is an integer which is equal to or greater than two), an on-chip lens provided for each m×m array (m is an integer which is equal to or smaller than n) of pixels in the same-color pixel group, and a sensitivity adjustment structure with a configuration in which a dug portion shallower than an element separating portion for separating a photoelectric converting section in units of the pixels is provided on a light-incidence surface side of a semiconductor substrate at a predetermined pixel in the same-color pixel group.

In an aspect of the present disclosure, the on-chip lens is provided for each m×m array (m is an integer which is equal to or smaller than n) of pixels in the same-color pixel group including the pixels that receive light of the same color and that are arranged in the n×n array (n is an integer which is equal to or greater than two). Further, the sensitivity adjustment structure is configured by providing, on the light-incidence-surface side of the semiconductor substrate of the predetermined pixel in the same-color pixel group, the dug portion shallower than the element separating portion for separating the photoelectric converting section in units of the pixels.

### BRIEF DESCRIPTION OF DRAWINGS

FIG. 1 is a figure for explaining the basic configuration of an image-capturing element to which the present technology is applied.

FIG. 2 is a figure for explaining sensitivity differences of each same-color pixel group.

FIG. 3 is a figure depicting a configuration example of a first sensitivity adjustment structure.

FIG. 4 is a figure depicting a configuration example of a second sensitivity adjustment structure.

FIG. 5 is a figure depicting a configuration example of a third sensitivity adjustment structure.

FIG. 6 is a figure depicting a configuration example of a fourth sensitivity adjustment structure.

FIG. 7 is a figure depicting a configuration example of a fifth sensitivity adjustment structure.

FIG. 8 is a figure depicting a configuration example of a sixth sensitivity adjustment structure.

FIG. 9 is a figure depicting a configuration example of a seventh sensitivity adjustment structure.

FIG. 10 is a figure depicting a configuration example of an eighth sensitivity adjustment structure.

FIG. 11 is a figure depicting a configuration example of a ninth sensitivity adjustment structure.

FIG. 12 is a figure depicting a configuration example of a tenth sensitivity adjustment structure.

FIG. 13 is a figure depicting a configuration example of an eleventh sensitivity adjustment structure.

FIG. 14 is a figure depicting a configuration example of a twelfth sensitivity adjustment structure.

FIG. 15 is a figure depicting a configuration example of a thirteenth sensitivity adjustment structure.

FIG. 16 is a figure depicting a configuration example of a fourteenth sensitivity adjustment structure.

FIG. 17 is a figure depicting a configuration example of a fifteenth sensitivity adjustment structure.

FIG. 18 is a figure depicting a configuration example of a sixteenth sensitivity adjustment structure.

FIG. 19 is a figure depicting a configuration example of a seventeenth sensitivity adjustment structure.

FIG. 20 is a figure depicting a configuration example of an eighteenth sensitivity adjustment structure.

FIG. 21 is a figure depicting a configuration example of a nineteenth sensitivity adjustment structure.

FIG. 22 is a figure depicting a configuration example of a twentieth sensitivity adjustment structure.

FIG. 23 is a figure depicting a configuration example of a twenty-first sensitivity adjustment structure.

FIG. 24 is a figure depicting a configuration example of a twenty-second sensitivity adjustment structure.

FIG. 25 is a figure depicting a configuration example of a twenty-third sensitivity adjustment structure.

FIG. 26 is a figure depicting a configuration example of a twenty-fourth sensitivity adjustment structure.

FIG. 27 is a figure depicting a configuration example of a twenty-fifth sensitivity adjustment structure.

FIG. 28 is a figure depicting a configuration example of a twenty-sixth sensitivity adjustment structure.

FIG. 29 is a figure depicting a configuration example of a twenty-seventh sensitivity adjustment structure.

FIG. 30 is a figure depicting a configuration example of a twenty-eighth sensitivity adjustment structure.

FIG. 31 is a figure depicting a configuration example of a twenty-ninth sensitivity adjustment structure.

FIG. 32 is a figure depicting a configuration example of a thirtieth sensitivity adjustment structure.

FIG. 33 is a figure depicting a configuration example of a thirty-first sensitivity adjustment structure.

FIG. 34 is a figure depicting a configuration example of a thirty-second sensitivity adjustment structure.

FIG. 35 is a figure depicting a configuration example of a thirty-third sensitivity adjustment structure.

FIG. 36 is a figure depicting a configuration example of a thirty-fourth sensitivity adjustment structure.

FIG. 37 is a figure depicting a configuration example of a thirty-fifth sensitivity adjustment structure.

FIG. 38 is a figure depicting a configuration example of a thirty-sixth sensitivity adjustment structure.

FIG. 39 is a figure depicting a configuration example of a thirty-seventh sensitivity adjustment structure.

FIG. 40 is a figure depicting a configuration example of a thirty-eighth sensitivity adjustment structure.

FIG. 41 is a figure depicting a configuration example of a thirty-ninth sensitivity adjustment structure.

FIG. 42 is a figure depicting a configuration example of a fortieth sensitivity adjustment structure.

FIG. 43 is a figure depicting a configuration example of a forty-first sensitivity adjustment structure.

FIG. 44 is a figure depicting a configuration example of a forty-second sensitivity adjustment structure.

FIG. 45 is a figure depicting a configuration example of a forty-third sensitivity adjustment structure.

FIG. 46 is a figure depicting a configuration example of a forty-fourth sensitivity adjustment structure.

FIG. 47 is a figure for explaining an arrangement example of the forty-third sensitivity adjustment structure and the forty-fourth sensitivity adjustment structure.

FIG. 48 is a figure depicting a configuration example of a forty-fifth sensitivity adjustment structure.

FIG. 49 is a figure depicting a configuration example of a forty-sixth sensitivity adjustment structure.

FIG. 50 is a figure depicting a configuration example of a forty-seventh sensitivity adjustment structure.

FIG. 51 is a figure depicting a configuration example of a forty-eighth sensitivity adjustment structure.

FIG. 52 is a figure depicting a configuration example of a forty-ninth sensitivity adjustment structure.

FIG. 53 is a figure depicting a configuration example of a fiftieth sensitivity adjustment structure.

FIG. 54 is a figure depicting a configuration example of a fifty-first sensitivity adjustment structure.

FIG. 55 is a figure depicting a configuration example of a fifty-second sensitivity adjustment structure.

FIG. 56 is a figure depicting a configuration example of a fifty-third sensitivity adjustment structure.

FIG. 57 is a figure depicting a configuration example of a fifty-fourth sensitivity adjustment structure.

FIG. 58 is a figure depicting a configuration example of a fifty-fifth sensitivity adjustment structure.

FIG. 59 is a figure depicting a configuration example of a fifty-sixth sensitivity adjustment structure.

FIG. 60 is a figure depicting a configuration example of a fifty-seventh sensitivity adjustment structure.

FIG. 61 is a figure depicting a configuration example of a fifty-eighth sensitivity adjustment structure.

FIG. 62 is a figure depicting a configuration example of a fifty-ninth sensitivity adjustment structure.

FIG. 63 is a figure depicting a configuration example of a sixtieth sensitivity adjustment structure.

FIG. 64 is a figure depicting a configuration example of a sixty-first sensitivity adjustment structure.

FIG. 65 is a figure depicting a configuration example of a sixty-second sensitivity adjustment structure.

FIG. 66 is a figure depicting a configuration example of a first combination layout.

FIG. 67 depicts cross-sectional views of the first combination layout.

FIG. 68 is a figure depicting a configuration example of a second combination layout.

FIG. 69 depicts cross-sectional views of the second combination layout.

FIG. 70 is a figure depicting a configuration example of a third combination layout.

FIG. 71 depicts cross-sectional views of the third combination layout.

FIG. 72 is a figure depicting a configuration example of a fourth combination layout.

FIG. 73 depicts cross-sectional views of the fourth combination layout.

FIG. 74 is a figure depicting a configuration example of a fifth combination layout.

FIG. 75 depicts cross-sectional views of the fifth combination layout.

FIG. 76 is a figure depicting a configuration example of a sixth combination layout.

FIG. 77 depicts cross-sectional views of the sixth combination layout.

FIG. 78 is a figure depicting a configuration example of a seventh combination layout.

FIG. 79 depicts cross-sectional views of the seventh combination layout.

FIG. 80 is a figure depicting a configuration example of an eighth combination layout.

FIG. 81 is a figure depicting a configuration example of a ninth combination layout.

FIG. 82 is a figure depicting a configuration example of a tenth combination layout.

FIG. 83 is a figure depicting a configuration example of an eleventh combination layout.

FIG. 84 is a figure depicting a configuration example of a twelfth combination layout.

FIG. 85 is a figure depicting a configuration example of a thirteenth combination layout.

FIG. 86 is a figure depicting an example of a first 2×1-OCL arrangement pattern.

FIG. 87 depicts cross-sectional views of the first 2×1-OCL arrangement pattern.

FIG. 88 is a figure depicting an example of a second 2×1-OCL arrangement pattern.

FIG. 89 is a figure depicting an example of a third 2×1-OCL arrangement pattern.

FIG. 90 is a figure depicting an example of a fourth 2×1-OCL arrangement pattern.

FIG. 91 is a figure depicting an example of a fifth 2×1-OCL arrangement pattern.

FIG. 92 is a figure depicting an example of a sixth 2×1-OCL arrangement pattern.

FIG. 93 is a figure depicting an example of a seventh 2×1-OCL arrangement pattern.

FIG. 94 is a figure depicting an example of an eighth 2×1-OCL arrangement pattern.

FIG. 95 is a figure depicting an example of a ninth 2×1-OCL arrangement pattern.

FIG. 96 is a figure depicting an example of a tenth 2×1-OCL arrangement pattern.

FIG. 97 is a figure depicting an example of an eleventh 2×1-OCL arrangement pattern.

FIG. 98 is a figure depicting an example of a twelfth 2×1-OCL arrangement pattern.

FIG. 99 is a figure depicting an example of a thirteenth 2×1-OCL arrangement pattern.

FIG. 100 is a figure depicting an example of a fourteenth 2×1-OCL arrangement pattern.

FIG. 101 is a figure depicting an example of a fifteenth 2×1-OCL arrangement pattern.

FIG. 102 is a figure depicting an example of a sixteenth 2×1-OCL arrangement pattern.

FIG. 103 is a figure depicting an example of a seventeenth 2×1-OCL arrangement pattern.

FIG. 104 is a figure depicting an example of an eighteenth 2×1-OCL arrangement pattern.

FIG. 105 is a figure depicting an example of a nineteenth 2×1-OCL arrangement pattern.

FIG. 106 is a figure depicting an example of a twentieth 2×1-OCL arrangement pattern.

FIG. 107 is a figure depicting an example of a twenty-first 2×1-OCL arrangement pattern.

FIG. 108 is a figure depicting an example of a twenty-second 2×1-OCL arrangement pattern.

FIG. 109 is a figure depicting an example of a twenty-third 2×1-OCL arrangement pattern.

FIG. 110 is a figure depicting an example of a twenty-fourth 2×1-OCL arrangement pattern.

FIG. 111 is a figure depicting an example of a twenty-fifth 2×1-OCL arrangement pattern.

FIG. 112 is a figure depicting an example of a twenty-sixth 2×1-OCL arrangement pattern.

FIG. 113 is a figure depicting an example of a twenty-seventh 2×1-OCL arrangement pattern.

FIG. 114 is a figure depicting an example of a twenty-eighth 2×1-OCL arrangement pattern.

FIG. 115 is a figure depicting an example of a twenty-ninth 2×1-OCL arrangement pattern.

FIG. 116 is a figure depicting an example of a thirtieth 2×1-OCL arrangement pattern.

FIG. 117 is a figure depicting an example of a thirty-first 2×1-OCL arrangement pattern.

FIG. 118 is a figure depicting an example of a thirty-second 2×1-OCL arrangement pattern.

FIG. 119 is a figure depicting an example of a thirty-third 2×1-OCL arrangement pattern.

FIG. 120 is a figure depicting an example of a thirty-fourth 2×1-OCL arrangement pattern.

FIG. 121 is a figure depicting an example of a thirty-fifth 2×1-OCL arrangement pattern.

FIG. 122 is a figure depicting an example of a thirty-sixth 2×1-OCL arrangement pattern.

FIG. 123 is a figure depicting an example of a thirty-seventh 2×1-OCL arrangement pattern.

FIG. 124 is a figure depicting an example of a thirty-eighth 2×1-OCL arrangement pattern.

FIG. 125 is a figure depicting an example of a thirty-ninth 2×1-OCL arrangement pattern.

FIG. 126 is a figure depicting a configuration example of a first 5×5-array sensitivity adjustment structure.

FIG. 127 is a figure depicting a configuration example of a second 5×5-array sensitivity adjustment structure.

FIG. 128 is a figure depicting a configuration example of a third 5×5-array sensitivity adjustment structure.

FIG. 129 is a figure depicting a configuration example of a fourth 5×5-array sensitivity adjustment structure.

FIG. 130 is a figure depicting a configuration example of a fifth 5×5-array sensitivity adjustment structure.

FIG. 131 is a figure depicting a configuration example of a sixth 5×5-array sensitivity adjustment structure.

FIG. 132 is a figure depicting a configuration example of a seventh 5×5-array sensitivity adjustment structure.

FIG. 133 is a figure depicting a configuration example of an eighth 5×5-array sensitivity adjustment structure.

FIG. 134 is a figure depicting a configuration example of a ninth 5×5-array sensitivity adjustment structure.

FIG. 135 is a figure depicting a configuration example of a tenth 5×5-array sensitivity adjustment structure.

FIG. 136 is a figure depicting a configuration example of an eleventh 5×5-array sensitivity adjustment structure.

FIG. 137 is a figure depicting a configuration example of a twelfth 5×5-array sensitivity adjustment structure.

FIG. 138 is a figure depicting a configuration example of a thirteenth 5×5-array sensitivity adjustment structure.

FIG. 139 is a figure depicting a configuration example of a fourteenth 5×5-array sensitivity adjustment structure.

FIG. 140 is a figure depicting a configuration example of a fifteenth 5×5-array sensitivity adjustment structure.

FIG. 141 is a figure depicting a configuration example of a sixteenth 5×5-array sensitivity adjustment structure.

FIG. 142 is a figure depicting a configuration example of a seventeenth 5×5-array sensitivity adjustment structure.

FIG. 143 is a figure depicting a configuration example of an eighteenth 5×5-array sensitivity adjustment structure.

FIG. 144 is a figure depicting a configuration example of a nineteenth 5×5-array sensitivity adjustment structure.

FIG. 145 is a figure depicting a configuration example of a twentieth 5×5-array sensitivity adjustment structure.

FIG. 146 is a figure depicting a configuration example of a twenty-first 5×5-array sensitivity adjustment structure.

FIG. 147 is a figure depicting a configuration example of a twenty-second 5×5-array sensitivity adjustment structure.

FIG. 148 is a figure depicting a configuration example of a twenty-third 5×5-array sensitivity adjustment structure.

FIG. 149 is a figure depicting a configuration example of a twenty-fourth 5×5-array sensitivity adjustment structure.

FIG. 150 is a figure depicting a configuration example of a twenty-fifth 5×5-array sensitivity adjustment structure.

FIG. 151 is a figure depicting a configuration example of a twenty-sixth 5×5-array sensitivity adjustment structure.

FIG. 152 is a figure depicting a configuration example of a twenty-seventh 5×5-array sensitivity adjustment structure.

FIG. 153 is a figure depicting a configuration example of a twenty-eighth 5×5-array sensitivity adjustment structure.

FIG. 154 is a figure depicting a configuration example of a twenty-ninth 5×5-array sensitivity adjustment structure.

FIG. 155 is a figure depicting a configuration example of a thirtieth 5×5-array sensitivity adjustment structure.

FIG. 156 is a figure depicting a configuration example of a thirty-first 5×5-array sensitivity adjustment structure.

FIG. 157 is a figure depicting a configuration example of a thirty-second 5×5-array sensitivity adjustment structure.

FIG. 158 is a figure depicting a configuration example of a thirty-third 5×5-array sensitivity adjustment structure.

FIG. 159 is a figure depicting a configuration example of a thirty-fourth 5×5-array sensitivity adjustment structure.

FIG. 160 is a block diagram depicting a configuration example of an image-capturing device.

FIG. 161 is a figure depicting use examples in which an image sensor is used.

### DESCRIPTION OF EMBODIMENT

Hereinbelow, a specific embodiment to which the present technology is applied is explained in detail with reference to the figures.

### <Basic Configuration of Image-Capturing Element>

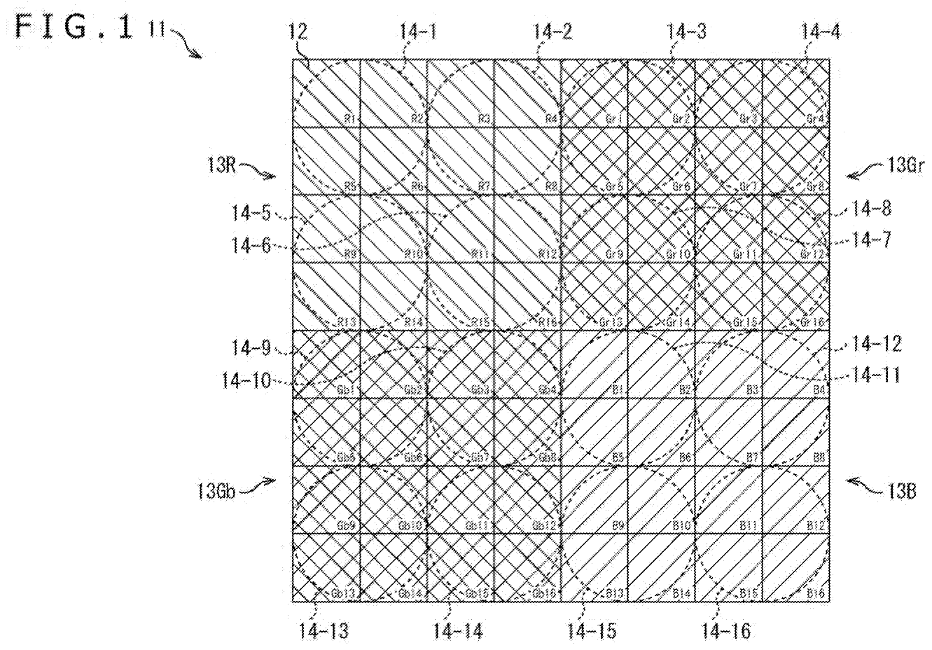

The basic configuration of an image-capturing element to which the present technology is applied is explained with reference to FIG. 1.

An image-capturing element 11 includes multiple pixels 12 arranged in a matrix, and, in FIG. 1, individual squares depicted as forming an 8×8 array represent the pixels 12. In addition, in the present embodiment, a group of pixels 12 to receive light of the same color is referred to as a same-color pixel group 13. Further, the image-capturing element 11 includes a Bayer-arrayed red same-color pixel group 13R, green same-color pixel group 13Gr, green same-color pixel group 13Gb, and blue same-color pixel group 13B.

For example, in the image-capturing element 11 depicted in FIG. 1, a 4×4 array of pixels 12 is included in each same-color pixel group 13. Further, in the 8×8 array of the pixels 12 as the one depicted in the figure, the red same-color pixel group 13R is arranged at the upper left, the green same-color pixel group 13Gr is arranged at the upper right, the green same-color pixel group 13Gb is arranged at the lower left, and the blue same-color pixel group 13B is arranged at the lower right.

The red same-color pixel group 13R includes sixteen pixels 12-R1 to 12-R16 to receive red light which are arranged in a 4×4 array. The green same-color pixel group 13Gr includes sixteen pixels 12-Gr1 to 12-Gr16 to receive green light which are arranged in a 4×4 array. The green same-color pixel group 13Gb includes sixteen pixels 12-Gb1 to 12-Gb16 to receive green light which are arranged in a 4×4 array. The blue same-color pixel group 13B includes sixteen pixels 12-B1 to 12-B16 to receive blue light which are arranged in a 4×4 array.

In addition, for each 2×2 array of pixels 12, an on-chip lens 14 is arranged on the light reception surface of the image-capturing element 11. Accordingly, for the 8×8 array of the pixels 12 as the one depicted in the figure, sixteen on-chip lenses 14-1 to 14-16 are arranged in a 4×4 array.

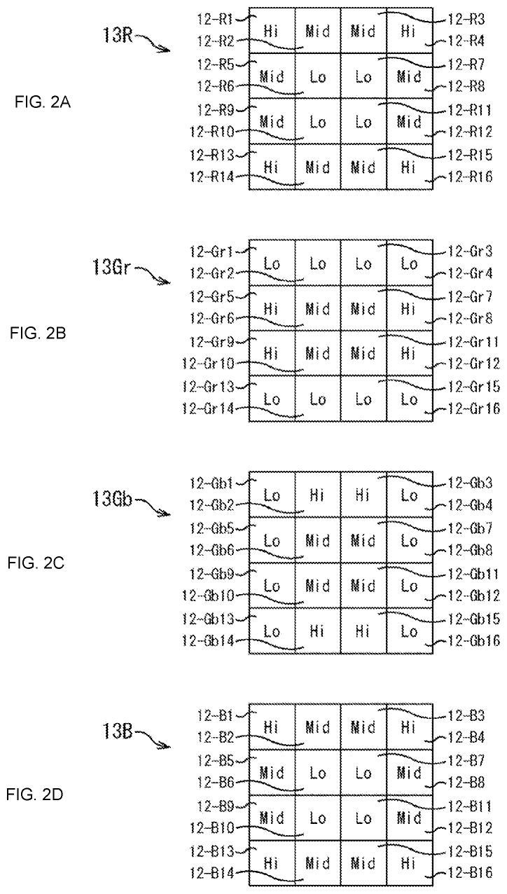

It is known that, in the thus-configured image-capturing element 11, sensitivity differences as the ones depicted in FIG. 2 occur in each same-color pixel group 13. In FIG. 2, pixels 12 that tend to have high sensitivity are represented by “Hi,” pixels 12 that tend to have low sensitivity are represented by “Lo,” and pixels 12 that have intermediate sensitivity between them are represented by “Mid.”

As depicted in A in FIG. 2, in the red same-color pixel group 13R, the pixel 12-R1, the pixel 12-R4, the pixel 12-R13, and the pixel 12-R16 arranged at the four corner locations tend to have high sensitivity. In addition, the pixel 12-R6, the pixel 12-R7, the pixel 12-R10, and the pixel 12-R11 arranged at the four locations in the middle 2×2 array tend to have low sensitivity. In addition, the pixel 12-R2 and the pixel 12-R3 arranged at the two middle locations on the upper side, the pixel 12-R5 and the pixel 12-R9 arranged at the two middle locations on the left side, the pixel 12-R8 and the pixel 12-R12 arranged at the two middle locations on the right side, and the pixel 12-R14 and the pixel 12-R15 arranged at the two middle locations on the lower side have intermediate sensitivity.

As depicted in B in FIG. 2, in the green same-color pixel group 13Gr, the pixel 12-Gr1, the pixel 12-Gr2, the pixel 12-Gr3, and the pixel 12-Gr4 arranged at the four locations on the upper side and the pixel 12-Gr13, the pixel 12-Gr14, the pixel 12-Gr15, and the pixel 12-Gr16 arranged at the four locations on the lower side tend to have low sensitivity. In addition, the pixel 12-Gr5 and the pixel 12-Gr9 arranged at the two middle locations on the left side and the pixel 12-Gr8 and the pixel 12-Gr12 arranged at the two middle locations on the right side tend to have high sensitivity. In addition, the pixel 12-Gr6, the pixel 12-Gr7, the pixel 12-Gr10, and the pixel 12-Gr11 arranged at the four locations in the middle 2×2 array have intermediate sensitivity.

As depicted in C in FIG. 2, in the green same-color pixel group 13Gb, the pixel 12-Gb1, the pixel 12-Gb5, the pixel 12-Gb9, and the pixel 12-Gb13 arranged at the four locations on the left side and the pixel 12-Gb4, the pixel 12-Gb8, the pixel 12-Gb12, and the pixel 12-Gb16 arranged at the four locations on the right side tend to have low sensitivity. In addition, the pixel 12-Gb2 and the pixel 12-Gb3 arranged at the two middle locations on the upper side and the pixel 12-Gb14 and the pixel 12-Gb15 arranged at the two middle locations on the lower side tend to have high sensitivity. In addition, the pixel 12-Gb6, the pixel 12-Gb7, the pixel 12-Gb10, and the pixel 12-Gb11 arranged at the four locations in the middle 2×2 array have intermediate sensitivity.

As depicted in D in FIG. 2, in the blue same-color pixel group 13B, the pixel 12-B1, the pixel 12-B4, the pixel 12-B13, and the pixel 12-B16 arranged at the four corner locations tend to have high sensitivity. In addition, the pixel 12-B6, the pixel 12-B7, the pixel 12-B10, and the pixel 12-B11 arranged at the four locations in the middle 2×2 array tend to have low sensitivity. In addition, the pixel 12-B2 and the pixel 12-B3 arranged at the two middle locations on the upper side, the pixel 12-B5 and the pixel 12-B9 arranged at the two middle locations on the left side, the pixel 12-B8 and the pixel 12-B12 arranged at the two middle locations on the right side, and the pixel 12-B14 and the pixel 12-B15 arranged at the two middle locations on the lower side have intermediate sensitivity.

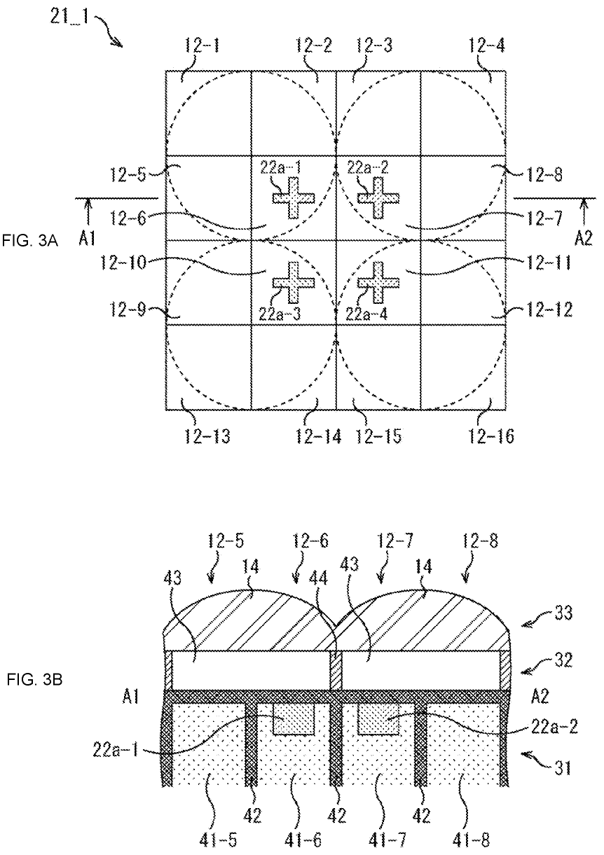

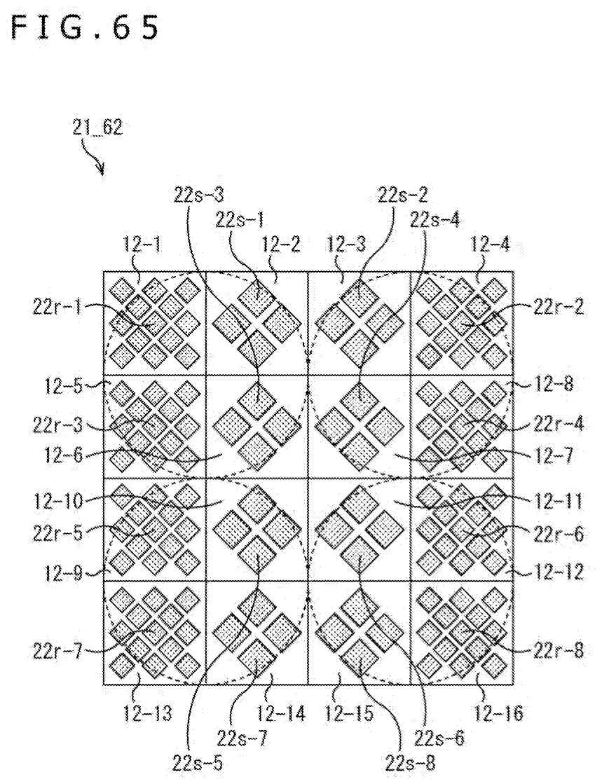

In view of this, the image-capturing element 11 is configured such that it is provided with sensitivity adjustment structures for adjusting the sensitivity of the individual pixels 12 to suppress the occurrence of sensitivity differences in the same-color pixel groups 13, for example. For example, as described later with reference to FIG. 3 to FIG. 65, sensitivity adjustment structures 21 include arrangement patterns in which intra-pixel grooves 22 with various shapes are provided to make it possible to attempt to improve the sensitivity of pixels 12 that tend to have low sensitivity.

### <Configuration Examples of Sensitivity Adjustment Structures>

Configuration examples of the sensitivity adjustment structures are explained with reference to FIG. 3 to FIG. 65.

FIG. 3 is a figure depicting a configuration example of a first sensitivity adjustment structure 21_1. A in FIG. 3 depicts the configuration example of the first sensitivity adjustment structure 21_1 as seen in a plan view of sixteen pixels 12-1 to 12-16 included in a same-color pixel group 13. B in FIG. 3 depicts the configuration example of the first sensitivity adjustment structure 21_1 on a cross-section taken along A1-A2 depicted in A in FIG. 3.

As depicted in A in FIG. 3, the first sensitivity adjustment structure 21_1 uses intra-pixel grooves 22a with a cross shape in which lines extending in the vertical direction and the horizontal direction of a pixel 12 cross each other at the middle. For example, the intra-pixel grooves 22a with the cross shape have a function of significantly improving the sensitivity of pixels 12 provided with the intra-pixel grooves 22a with the cross shape, as a result of being able to more significantly scatter light than intra-pixel grooves with a line shape can and enlarge the optical path lengths. In addition, the intra-pixel grooves 22a with the cross shape have a function of improving the sensitivity of other pixels 12 vertically or horizontally adjacent to the pixels 12 provided with the intra-pixel grooves 22a with the cross shape, as a result of causing the scattered light to be incident on those adjacent pixels 12.

The first sensitivity adjustment structure 21_1 includes an arrangement pattern in which, in a 4×4 array of sixteen pixels 12-1 to 12-16, the intra-pixel grooves 22a with the cross shape are provided to pixels 12 arranged at the four locations in the middle 2×2 array. That is, in the first sensitivity adjustment structure 21_1, an intra-pixel groove 22a-1 with the cross shape is provided to the pixel 12-6, an intra-pixel groove 22a-2 with the cross shape is provided to the pixel 12-7, an intra-pixel groove 22a-3 with the cross shape is provided to the pixel 12-10, and an intra-pixel groove 22a-4 with the cross shape is provided to the pixel 12-11.

As depicted in B in FIG. 3, the image-capturing element 11 includes a semiconductor layer 31, a filter layer 32, and an on-chip lens layer 33 that are stacked one on another.

The semiconductor layer 31 is provided with a photoelectric converting section 41 that photoelectrically converts light, and is provided with an element separating portion 42 for separating the photoelectric converting section 41 in units of pixels 12. The filter layer 32 is provided with color filters 43 that transmit light of respectively corresponding colors, and is provided with light-blocking portions 44 for blocking leakage of light from the side surfaces of the color filters 43. The on-chip lens layer 33 is provided the on-chip lenses 14 that condense light.

For example, the element separating portion 42 is formed by embedding silicon oxide in trenches formed by digging the semiconductor layer 31 deep (or such that the trenches penetrate the semiconductor layer 31). Further, the intra-pixel grooves 22 are formed by embedding silicon oxide in dug portions formed by digging the light-incidence-surface side of the semiconductor layer 31 shallower than the element separating portion 42.

Accordingly, by applying the first sensitivity adjustment structure 21_1 to the red same-color pixel group 13R and the blue same-color pixel group 13B, it is possible to attempt to significantly improve the sensitivity of the pixels 12 that are arranged at the four locations in the middle 2×2 array and that tend to have low sensitivity, since the intra-pixel grooves 22a with the cross shape significantly scatter light in the pixels 12 and, along with this, the optical path lengths are enlarged. In addition, it is possible to attempt to slightly improve the sensitivity of the pixels 12 arranged vertically and horizontally adjacent to the middle 2×2 array, since the light scattered at the intra-pixel grooves 22a with the cross shape is incident on the adjacent pixels 12. As a result, the image-capturing element 11 can suppress inter-pixel-12 sensitivity differences in the red same-color pixel group 13R and the blue same-color pixel group 13B, and attain more uniform sensitivity characteristics.

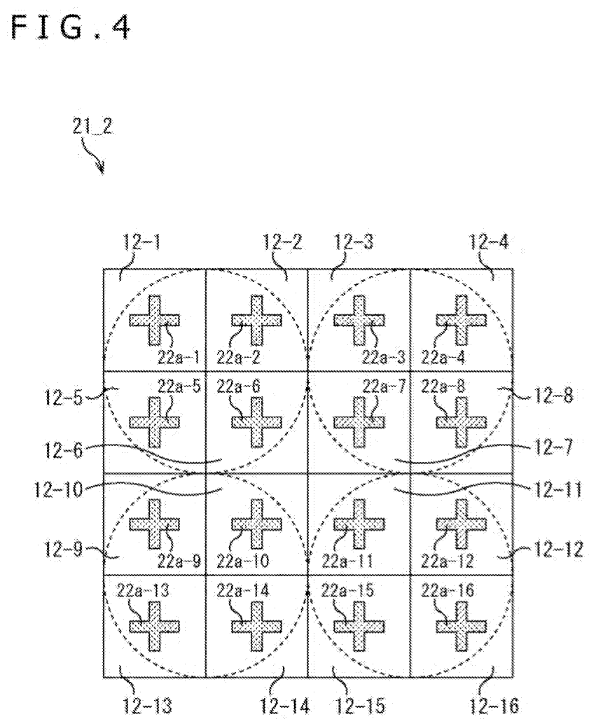

FIG. 4 is a figure depicting a configuration example of a second sensitivity adjustment structure 21_2.

As depicted in FIG. 4, the second sensitivity adjustment structure 21_2 uses the intra-pixel grooves 22a with the cross shape in which lines extending in the vertical direction and the horizontal direction of a pixel 12 cross each other at the middle.

The second sensitivity adjustment structure 21_2 includes an arrangement pattern in which the intra-pixel grooves 22a with the cross shape are provided to all the sixteen pixels 12-1 to 12-16 in the 4×4 array. That is, in the second sensitivity adjustment structure 21_2, intra-pixel grooves 22a-1 to 22a-16 with the cross shape are provided to the pixels 12-1 to 12-16, respectively.

Accordingly, by applying the second sensitivity adjustment structure 21_2 to a same-color pixel group 13, it is possible to attempt to improve the overall sensitivity of the same-color pixel group 13. For example, it is preferable to apply the second sensitivity adjustment structure 21_2 in a case where it is desired to avoid lowering of the sensitivity that accompanies miniaturization of the pixels 12. In particular, by applying the second sensitivity adjustment structure 21_2 to the red same-color pixel group 13R, a significant advantage in terms of sensitivity improvement can be attained since the application can contribute to enlargement of optical path lengths in the photoelectric converting section 41.

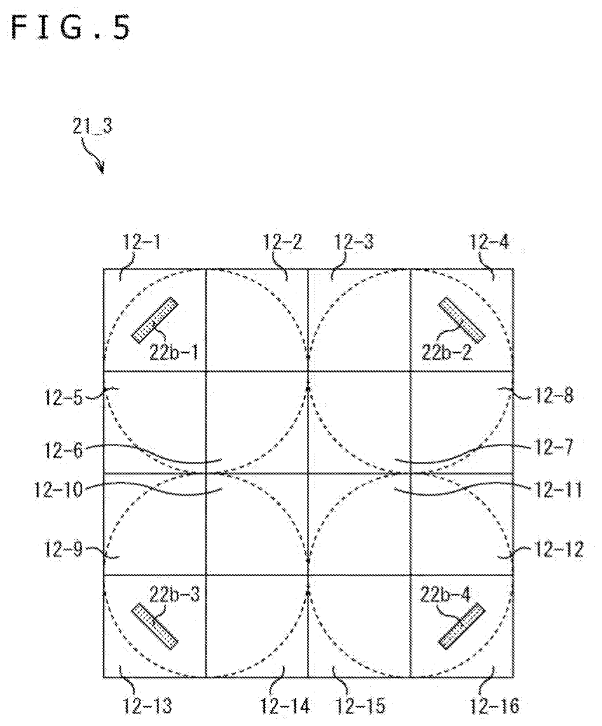

FIG. 5 is a figure depicting a configuration example of a third sensitivity adjustment structure 21_3.

As depicted in FIG. 5, the third sensitivity adjustment structure 21_3 uses intra-pixel grooves 22b with a diagonal line shape extending in a diagonal direction of a pixel 12. For example, the intra-pixel grooves 22b with the diagonal line shape have a function of improving the sensitivity of pixels 12 provided with the intra-pixel grooves 22b with the diagonal line shape, as a result of being able to scatter light and enlarge the optical path lengths. In addition, the intra-pixel grooves 22b with the diagonal line shape have a function of improving, to some extent, the sensitivity of other pixels 12 positioned in directions perpendicular to the longitudinal directions of the intra-pixel grooves 22b with the diagonal line shape, as a result of causing the light scattered by the intra-pixel grooves 22b with the diagonal line shape to be incident on those pixels 12 positioned in the directions perpendicular to the longitudinal directions of the intra-pixel grooves 22b. On the other hand, the intra-pixel grooves 22b with the diagonal line shape can suppress incidence of the light scattered by the intra-pixel grooves 22b with the diagonal line shape on other pixels 12 positioned in directions along the longitudinal directions of the intra-pixel grooves 22b with the diagonal line shape, and suppress the occurrence of color mixing.

The third sensitivity adjustment structure 21_3 includes an arrangement pattern in which, in the 4×4 array of the sixteen pixels 12-1 to 12-16, the intra-pixel grooves 22b with the diagonal line shape are provided to pixels 12 arranged at the four corner locations. The intra-pixel grooves 22b with the diagonal line shape are formed such that side surfaces of the intra-pixel grooves 22b along the longitudinal directions face the middle of the 4×4 array.

That is, in the third sensitivity adjustment structure 21_3, an intra-pixel groove 22b-1 with the diagonal line shape whose longitudinal direction extends from the upper right to the lower left is provided to the pixel 12-1, an intra-pixel groove 22b-2 with the diagonal line shape whose longitudinal direction extends from the upper left to the lower right is provided to the pixel 12-4, an intra-pixel groove 22b-3 with the diagonal line shape whose longitudinal direction extends from the upper left to the lower right is provided to the pixel 12-13, and an intra-pixel groove 22b-4 with the diagonal line shape whose longitudinal direction extends from the upper right to the lower left is provided to the pixel 12-16.

Accordingly, by applying the third sensitivity adjustment structure 21_3 to the red same-color pixel group 13R and the blue same-color pixel group 13B, it is possible to attempt to improve the sensitivity of pixels 12 that are arranged at the four locations in the middle 2×2 array and that tend to have low sensitivity. That is, the sensitivity of the pixels 12 arranged at the four locations in the middle 2×2 array is improved, as a result of scattering of light by the intra-pixel grooves 22b with the diagonal line shape in directions perpendicular to the longitudinal directions of the intra-pixel grooves 22b with the diagonal line shape and causing the scattered light to be incident on the middle pixels 12. As a result, the image-capturing element 11 can suppress inter-pixel-12 sensitivity differences in the red same-color pixel group 13R and the blue same-color pixel group 13B, and attain more uniform sensitivity characteristics.

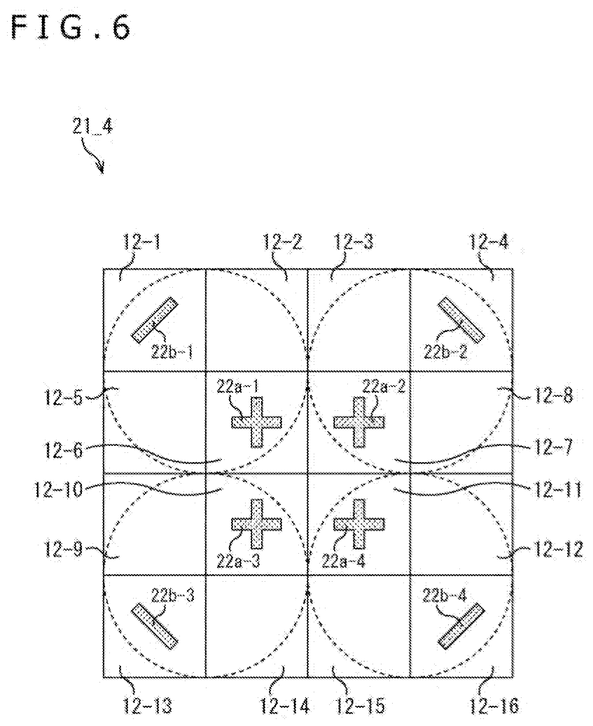

FIG. 6 is a figure depicting a configuration example of a fourth sensitivity adjustment structure 21_4.

As depicted in FIG. 6, the fourth sensitivity adjustment structure 21_4 uses the intra-pixel grooves 22a with the cross shape in which lines extending in the vertical direction and the horizontal direction of a pixel 12 cross each other at the middle, and the intra-pixel grooves 22b with the diagonal line shape extending in a diagonal direction of a pixel 12.

The fourth sensitivity adjustment structure 21_4 includes an arrangement pattern in which, in the 4×4 array of the sixteen pixels 12-1 to 12-16, the intra-pixel grooves 22a with the cross shape are provided to pixels 12 arranged at the four locations in the middle 2×2 array and the intra-pixel grooves 22b with the diagonal line shape are provided to pixels 12 arranged at the four corner locations. That is, in the fourth sensitivity adjustment structure 21_4, the intra-pixel grooves 22a-1 to 22a-4 with the cross shape are provided similarly to the first sensitivity adjustment structure 21_1 in FIG. 3, and the intra-pixel grooves 22b-1 to 22b-4 with the diagonal line shape are provided similarly to the third sensitivity adjustment structure 21_3 in FIG. 5.

Accordingly, by applying the fourth sensitivity adjustment structure 21_4 to the red same-color pixel group 13R and the blue same-color pixel group 13B, an advantage combining those of the first sensitivity adjustment structure 21_1 and the third sensitivity adjustment structure 21_3 can be attained. That is, the image-capturing element 11 can suppress inter-pixel-12 sensitivity differences in the red same-color pixel group 13R and the blue same-color pixel group 13B, and attain more uniform sensitivity characteristics.

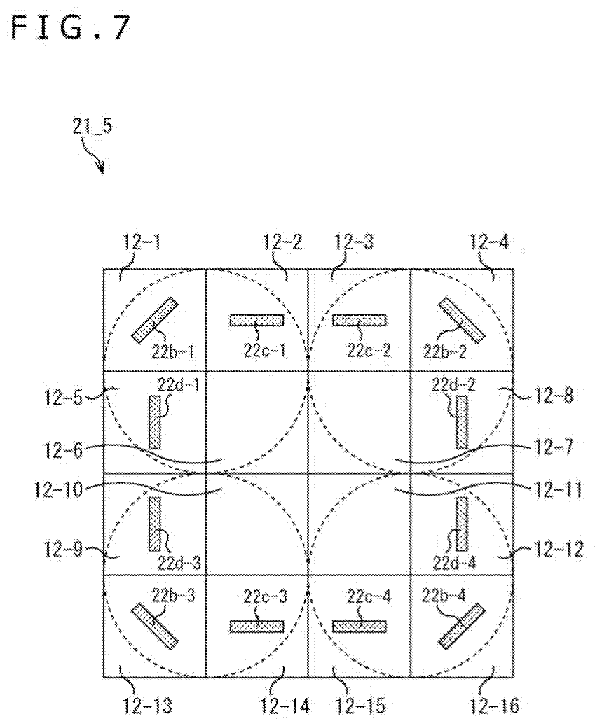

FIG. 7 is a figure depicting a configuration example of a fifth sensitivity adjustment structure 21_5.

As depicted in FIG. 7, the fifth sensitivity adjustment structure 21_5 uses the intra-pixel grooves 22b with the diagonal line shape extending in a diagonal direction of a pixel 12, intra-pixel grooves 22c with a horizontal line shape extending in the horizontal direction of a pixel 12, and intra-pixel grooves 22d with a vertical line shape extending in the vertical direction of a pixel 12.

For example, the intra-pixel grooves 22c with the horizontal line shape have a function of improving the sensitivity of pixels 12 provided with the intra-pixel grooves 22c with the horizontal line shape, as a result of being able to scatter light and enlarge the optical path lengths. In addition, the intra-pixel grooves 22c with the horizontal line shape have a function of improving, to some extent, the sensitivity of other pixels 12 vertically adjacent to the pixels 12 provided with the intra-pixel grooves 22c with the horizontal line shape, as a result of causing the light scattered by the intra-pixel grooves 22c with the horizontal line shape to be incident on those adjacent pixels 12. On the other hand, the intra-pixel grooves 22c with the horizontal line shape can suppress incidence of the light scattered by the intra-pixel grooves 22c with the horizontal line shape on other pixels 12 horizontally adjacent to the pixels 12 provided with the intra-pixel grooves 22c with the horizontal line shape, and suppress the occurrence of color mixing.

For example, the intra-pixel grooves 22d with the vertical line shape have a function of improving the sensitivity of pixels 12 provided with the intra-pixel grooves 22d with the vertical line shape, as a result of being able to scatter light and enlarge the optical path lengths. In addition, the intra-pixel grooves 22d with the vertical line shape have a function of improving, to some extent, the sensitivity of other pixels 12 horizontally adjacent to the pixels 12 provided with the intra-pixel grooves 22d with the vertical line shape, as a result of causing the light scattered by the intra-pixel grooves 22d with the vertical line shape to be incident on those adjacent pixels 12. On the other hand, the intra-pixel grooves 22d with the vertical line shape can suppress incidence of the light scattered by the intra-pixel grooves 22d with the vertical line shape on other pixels 12 vertically adjacent to the pixels 12 provided with the intra-pixel grooves 22d with the vertical line shape, and suppress the occurrence of color mixing.

The fifth sensitivity adjustment structure 21_5 includes an arrangement pattern in which, in the 4×4 array of the sixteen pixels 12-1 to 12-16, the intra-pixel grooves 22b with the diagonal line shape are provided to pixels 12 arranged at the four corner locations, the intra-pixel grooves 22c with the horizontal line shape are provided to pixels 12 arranged at the two middle locations on the upper side and pixels 12 arranged at the two middle locations on the lower side, and the intra-pixel grooves 22d with the vertical line shape are provided to pixels 12 arranged at the two middle locations on the right side and pixels 12 arranged at the two middle locations on the left side. The intra-pixel grooves 22b with the diagonal line shape are formed such that side surfaces of the intra-pixel grooves 22b along the longitudinal directions face the middle of the 4×4 array.

That is, in the fifth sensitivity adjustment structure 21_5, the intra-pixel groove 22b-1 with the diagonal line shape whose longitudinal direction extends from the upper right to the lower left is provided to the pixel 12-1, the intra-pixel groove 22b-2 with the diagonal line shape whose longitudinal direction extends from the upper left to the lower right is provided to the pixel 12-4, the intra-pixel groove 22b-3 with the diagonal line shape whose longitudinal direction extends from the upper left to the lower right is provided to the pixel 12-13, and the intra-pixel groove 22b-4 with the diagonal line shape whose longitudinal direction extends from the upper right to the lower left is provided to the pixel 12-16. Moreover, an intra-pixel groove 22c-1 with the horizontal line shape is provided to the pixel 12-2, an intra-pixel groove 22c-2 with the horizontal line shape is provided to the pixel 12-3, an intra-pixel groove 22c-3 with the horizontal line shape is provided to the pixel 12-14, and an intra-pixel groove 22c-4 with the horizontal line shape is provided to the pixel 12-15. Moreover, an intra-pixel groove 22d-1 with the vertical line shape is provided to the pixel 12-5, an intra-pixel groove 22d-2 with the vertical line shape is provided to the pixel 12-8, an intra-pixel groove 22d-3 with the vertical line shape is provided to the pixel 12-9, and an intra-pixel groove 22d-4 with the vertical line shape is provided to the pixel 12-12.

Accordingly, by applying the fifth sensitivity adjustment structure 21_5 to the red same-color pixel group 13R and the blue same-color pixel group 13B, it is possible to attempt to improve the sensitivity of pixels 12 that are arranged at the four locations in the middle 2×2 array and that tend to have low sensitivity. That is, the sensitivity of the pixels 12 arranged at the four locations in the middle 2×2 array is improved, as a result of scattering of light by the intra-pixel grooves 22b with the diagonal line shape, the intra-pixel grooves 22c with the horizontal line shape, and the intra-pixel grooves 22d with the vertical line shape in directions perpendicular to the longitudinal directions of the intra-pixel grooves 22b with the diagonal line shape, the intra-pixel grooves 22c with the horizontal line shape, and the intra-pixel grooves 22d with the vertical line shape and causing the scattered light to be incident on the middle pixels 12. As a result, the image-capturing element 11 can suppress inter-pixel-12 sensitivity differences in the red same-color pixel group 13R and the blue same-color pixel group 13B, and attain more uniform sensitivity characteristics.

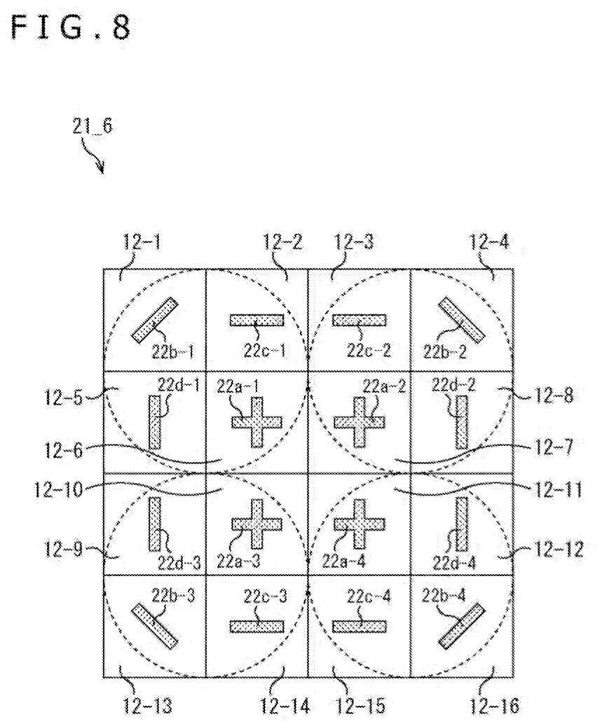

FIG. 8 is a figure depicting a configuration example of a sixth sensitivity adjustment structure 21_6.

As depicted in FIG. 8, the sixth sensitivity adjustment structure 21_6 uses the intra-pixel grooves 22a with the cross shape in which lines extending in the vertical direction and the horizontal direction of a pixel 12 cross each other at the middle, the intra-pixel grooves 22b with the diagonal line shape extending in a diagonal direction of a pixel 12, the intra-pixel grooves 22c with the horizontal line shape extending in the horizontal direction of a pixel 12, and the intra-pixel grooves 22d with the vertical line shape extending in the vertical direction of a pixel 12.

The sixth sensitivity adjustment structure 21_6 includes an arrangement pattern in which, in the 4×4 array of the sixteen pixels 12-1 to 12-16, the intra-pixel grooves 22a with the cross shape are provided to pixels 12 arranged at the four locations in the middle 2×2 array, the intra-pixel grooves 22b with the diagonal line shape are provided to pixels 12 arranged at the four corner locations, the intra-pixel grooves 22c with the horizontal line shape are provided to pixels 12 arranged at the two middle locations on the upper side and pixels 12 arranged at the two middle locations on the lower side, and the intra-pixel grooves 22d with the vertical line shape are provided to pixels 12 arranged at the two middle locations on the right side and pixels 12 arranged at the two middle locations on the left side.

That is, in the sixth sensitivity adjustment structure 21_6, the intra-pixel grooves 22a-1 to 22a-4 with the cross shape are provided similarly to the first sensitivity adjustment structure 21_1 in FIG. 3, and the intra-pixel grooves 22b-1 to 22b-4 with the diagonal line shape, the intra-pixel grooves 22c-1 to 22c-4 with the horizontal line shape, and the intra-pixel grooves 22d-1 to 22d-4 with the vertical line shape are provided similarly to the fifth sensitivity adjustment structure 21_5 in FIG. 7.

Accordingly, by applying the sixth sensitivity adjustment structure 21_6 to the red same-color pixel group 13R and the blue same-color pixel group 13B, an advantage combining those of the first sensitivity adjustment structure 21_1 and the fifth sensitivity adjustment structure 21_5 can be attained. That is, the image-capturing element 11 can suppress inter-pixel-12 sensitivity differences in the red same-color pixel group 13R and the blue same-color pixel group 13B, and attain more uniform sensitivity characteristics.

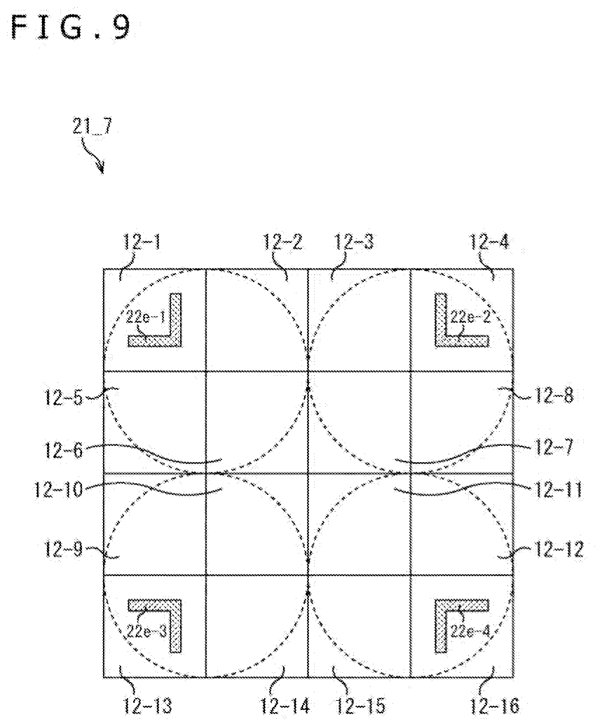

FIG. 9 is a figure depicting a configuration example of a seventh sensitivity adjustment structure 21_7.

As depicted in FIG. 9, the seventh sensitivity adjustment structure 21_7 uses intra-pixel grooves 22e with an L-shape in which lines extending in the vertical direction and the horizontal direction of a pixel 12 are joined with each other at ends thereof. For example, the intra-pixel grooves 22e with the L-shape have a function of improving the sensitivity of pixels 12 provided with the intra-pixel grooves 22e with the L-shape, as a result of being able to scatter light and enlarge the optical path lengths.

In addition, the intra-pixel grooves 22e with the L-shape have a function of improving, to some extent, the sensitivity of other pixels 12 that are adjacent to the pixels 12 provided with the intra-pixel grooves 22e with the L-shape and that are adjacent on a side where the vertical lines are arranged nearby and other pixels 12 that are adjacent to the pixels 12 provided with the intra-pixel grooves 22e with the L-shape and that are adjacent on a side where the horizontal lines are arranged nearby, as a result of making it easier for the light scattered by the intra-pixel grooves 22e with the L-shape to be incident on those adjacent pixels 12. On the other hand, the intra-pixel grooves 22e with the L-shape can suppress the occurrence of color mixing since it becomes more difficult for the light scattered by the intra-pixel grooves 22e with the L-shape to be incident on other pixels 12 that are adjacent to the pixels 12 provided with the intra-pixel grooves 22e with the L-shape and that are adjacent on a side opposite to the side where the vertical lines are arranged nearby, and other pixels 12 that are adjacent to the pixels 12 provided with the intra-pixel grooves 22e with the L-shape and that are adjacent on a side opposite to the side where the horizontal lines are arranged nearby.

The seventh sensitivity adjustment structure 21_7 includes an arrangement pattern in which, in the 4×4 array of the sixteen pixels 12-1 to 12-16, the intra-pixel grooves 22e with the L-shape are provided to pixels 12 arranged at the four corner locations. The intra-pixel grooves 22e with the L-shape are formed such that joined portions of the lines extending in the vertical directions and the horizontal directions are arranged on the middle sides of 4×4 arrays.

That is, in the seventh sensitivity adjustment structure 21_7, an intra-pixel groove 22e-1 with the L-shape having a vertical line that is arranged near the right side and a horizontal line that is arranged near the lower side is provided to the pixel 12-1, an intra-pixel groove 22e-2 with the L-shape having a vertical line that is arranged near the left side and a horizontal line that is arranged near the lower side is provided to the pixel 12-4, an intra-pixel groove 22e-3 with the L-shape having a vertical line that is arranged near the right side and a horizontal line that is arranged near the upper side is provided to the pixel 12-13, and an intra-pixel groove 22e-4 with the L-shape having a vertical line that is arranged near the left side and a horizontal line that is arranged near the upper side is provided to the pixel 12-16.

For example, the intra-pixel groove 22e-1 with the L-shape scatters light in directions perpendicular to the longitudinal directions of the vertical and horizontal lines, and the scattered light is incident on the pixel 12-2, the pixel 12-5, and the pixel 12-6. Similarly, light scattered by the intra-pixel groove 22e-2 with the L-shape is incident on the pixel 12-3, the pixel 12-7, and the pixel 12-8, light scattered by the intra-pixel groove 22e-3 with the L-shape is incident on the pixel 12-9, the pixel 12-10, and the pixel 12-14, and light scattered by the intra-pixel groove 22e-4 with the L-shape is incident on the pixel 12-11, the pixel 12-12, and the pixel 12-15. As a result of the scattering of light in such a manner, the seventh sensitivity adjustment structure 21_7 can suppress inter-pixel-12 sensitivity differences in the red same-color pixel group 13R and the blue same-color pixel group 13B.

Accordingly, by applying the seventh sensitivity adjustment structure 21_7 to the red same-color pixel group 13R and the blue same-color pixel group 13B, more uniform sensitivity characteristics can be attained.

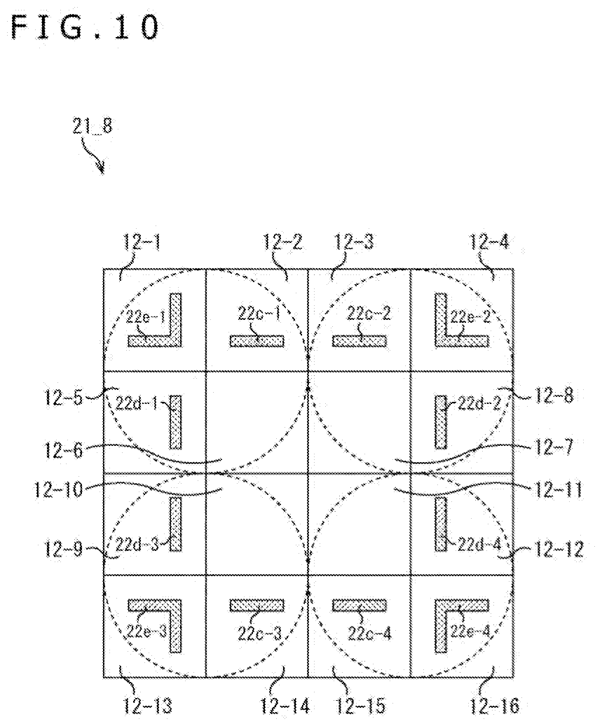

FIG. 10 is a figure depicting a configuration example of an eighth sensitivity adjustment structure 21_8.

As depicted in FIG. 10, the eighth sensitivity adjustment structure 21_8 uses the intra-pixel grooves 22c with the horizontal line shape extending in the horizontal direction of a pixel 12, the intra-pixel grooves 22d with the vertical line shape extending in the vertical direction of a pixel 12, and the intra-pixel grooves 22e with the L-shape in which lines extending in the vertical direction and the horizontal direction of a pixel 12 are joined with each other at ends thereof.

The eighth sensitivity adjustment structure 21_8 includes an arrangement pattern in which, in the 4×4 array of the sixteen pixels 12-1 to 12-16, the intra-pixel grooves 22c with the horizontal line shape are provided to pixels 12 arranged at the two middle locations on the upper side and pixels 12 arranged at the two middle locations on the lower side, the intra-pixel grooves 22d with the vertical line shape are provided to pixels 12 arranged at the two middle locations on the right side and pixels 12 arranged at the two middle locations on the left side, and the intra-pixel grooves 22e with the L-shape are provided to pixels 12 arranged at the four corner locations. The intra-pixel grooves 22e with the L-shape are formed such that joined portions of the lines extending in the vertical directions and the horizontal directions are arranged on the middle sides of 4×4 arrays.

That is, in the eighth sensitivity adjustment structure 21_8, the intra-pixel groove 22c-1 with the horizontal line shape is provided to the pixel 12-2, the intra-pixel groove 22c-2 with the horizontal line shape is provided to the pixel 12-3, the intra-pixel groove 22c-3 with the horizontal line shape is provided to the pixel 12-14, and the intra-pixel groove 22c-4 with the horizontal line shape is provided to the pixel 12-15. Moreover, the intra-pixel groove 22d-1 with the vertical line shape is provided to the pixel 12-5, the intra-pixel groove 22d-2 with the vertical line shape is provided to the pixel 12-8, the intra-pixel groove 22d-3 with the vertical line shape is provided to the pixel 12-9, and the intra-pixel groove 22d-4 with the vertical line shape is provided to the pixel 12-12. Moreover, the intra-pixel groove 22e-1 with the L-shape having a vertical line that is arranged near the right side and a horizontal line that is arranged near the lower side is provided to the pixel 12-1, the intra-pixel groove 22e-2 with the L-shape having a vertical line that is arranged near the left side and a horizontal line that is arranged near the lower side is provided to the pixel 12-4, the intra-pixel groove 22e-3 with the L-shape having a vertical line that is arranged near the right side and a horizontal line that is arranged near the upper side is provided to the pixel 12-13, and the intra-pixel groove 22e-4 with the L-shape having a vertical line that is arranged near the left side and a horizontal line that is arranged near the upper side is provided to the pixel 12-16.

Accordingly, by applying the eighth sensitivity adjustment structure 21_8 to the red same-color pixel group 13R and the blue same-color pixel group 13B, it is possible to attempt to improve the sensitivity of pixels 12 that are arranged at the four locations in the middle 2×2 array and that tend to have low sensitivity. That is, the sensitivity of the pixels 12 arranged at the four locations in the middle 2×2 array is improved, as a result of incidence of light scattered by the intra-pixel grooves 22c with the horizontal line shape, the intra-pixel grooves 22d with the vertical line shape, and the intra-pixel grooves 22e with the L-shape on the middle pixels 12. As a result, the image-capturing element 11 can suppress inter-pixel-12 sensitivity differences in the red same-color pixel group 13R and the blue same-color pixel group 13B, and attain more uniform sensitivity characteristics.

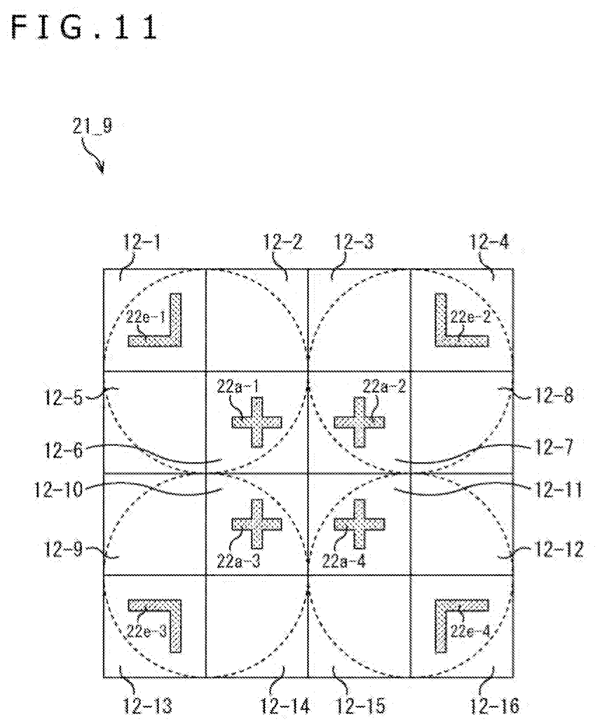

FIG. 11 is a figure depicting a configuration example of a ninth sensitivity adjustment structure 21_9.

As depicted in FIG. 11, the ninth sensitivity adjustment structure 21_9 uses the intra-pixel grooves 22a with the cross shape in which lines extending in the vertical direction and the horizontal direction of a pixel 12 cross each other at the middle, and the intra-pixel grooves 22e with the L-shape in which lines extending in the vertical direction and the horizontal direction of a pixel 12 are joined with each other at ends thereof.

The ninth sensitivity adjustment structure 21_9 includes an arrangement pattern in which, in the 4×4 array of the sixteen pixels 12-1 to 12-16, the intra-pixel grooves 22a with the cross shape are provided to pixels 12 arranged at the four locations in the middle 2×2 array and the intra-pixel grooves 22e with the L-shape are provided to pixels 12 arranged at the four corner locations. That is, in the ninth sensitivity adjustment structure 21_9, the intra-pixel grooves 22a-1 to 22a-4 with the cross shape are provided similarly to the first sensitivity adjustment structure 21_1 in FIG. 3, and the intra-pixel grooves 22e-1 to 22e-4 with the L-shape are provided similarly to the seventh sensitivity adjustment structure 21_7 in FIG. 9.

Accordingly, by applying the ninth sensitivity adjustment structure 21_9 to the red same-color pixel group 13R and the blue same-color pixel group 13B, an advantage combining those of the first sensitivity adjustment structure 21_1 and the seventh sensitivity adjustment structure 21_7 can be attained. That is, the image-capturing element 11 can suppress inter-pixel-12 sensitivity differences in the red same-color pixel group 13R and the blue same-color pixel group 13B, and attain more uniform sensitivity characteristics.

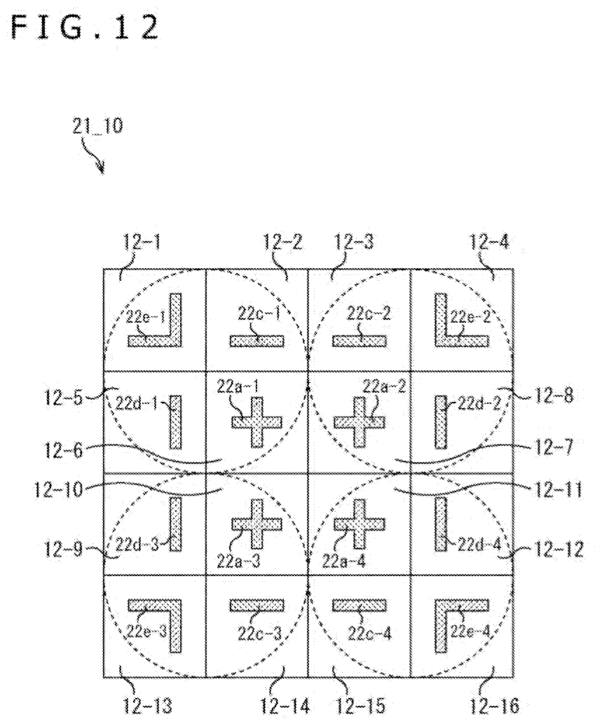

FIG. 12 is a figure depicting a configuration example of a tenth sensitivity adjustment structure 21_10.

As depicted in FIG. 12, the tenth sensitivity adjustment structure 21_10 uses the intra-pixel grooves 22a with the cross shape in which lines extending in the vertical direction and the horizontal direction of a pixel 12 cross each other at the middle, the intra-pixel grooves 22c with the horizontal line shape extending in the horizontal direction of a pixel 12, the intra-pixel grooves 22d with the vertical line shape extending in the vertical direction of a pixel 12, and the intra-pixel grooves 22e with the L-shape in which lines extending in the vertical directions and the horizontal directions are joined with each other at ends thereof.

The tenth sensitivity adjustment structure 21_10 includes an arrangement pattern in which, in the 4×4 array of the sixteen pixels 12-1 to 12-16, the intra-pixel grooves 22a with the cross shape are provided to pixels 12 arranged at the four locations in the middle 2×2 array, the intra-pixel grooves 22c with the horizontal line shape are provided to pixels 12 arranged at the two middle locations on the upper side and pixels 12 arranged at the two middle locations on the lower side, the intra-pixel grooves 22d with the vertical line shape are provided to pixels 12 arranged at the two middle locations on the right side and pixels 12 arranged at the two middle locations on the left side, and the intra-pixel grooves 22e with the L-shape are provided to pixels 12 arranged at the four corner locations.

That is, in the tenth sensitivity adjustment structure 21_10, the intra-pixel grooves 22a-1 to 22a-4 with the cross shape are provided similarly to the first sensitivity adjustment structure 21_1 in FIG. 3, and the intra-pixel grooves 22c-1 to 22c-4 with the horizontal line shape, the intra-pixel grooves 22d-1 to 22d-4 with the vertical line shape, and the intra-pixel grooves 22e-1 to 22e-4 with the L-shape are provided similarly to the eighth sensitivity adjustment structure 21_8 in FIG. 10.

Accordingly, by applying the tenth sensitivity adjustment structure 21_10 to the red same-color pixel group 13R and the blue same-color pixel group 13B, an advantage combining those of the first sensitivity adjustment structure 21_1 and the eighth sensitivity adjustment structure 21_8 can be attained. That is, the image-capturing element 11 can suppress inter-pixel-12 sensitivity differences in the red same-color pixel group 13R and the blue same-color pixel group 13B, and attain more uniform sensitivity characteristics.

Here, the intra-pixel grooves 22 (the intra-pixel grooves 22a with the cross shape, the intra-pixel grooves 22b with the diagonal line shape, the intra-pixel grooves 22c with the horizontal line shape, the intra-pixel grooves 22d with the vertical line shape, and the intra-pixel grooves 22e with the L-shape) depicted in FIG. 3 to FIG. 12 are formed in such sizes that the intra-pixel grooves 22 are provided at middle portions of pixels 12 in a state where ends thereof are separated apart from the element separating portion 42. In contrast to this, the intra-pixel grooves 22 may be formed such that the intra-pixel grooves 22 are provided extending over the widths of pixels 12 in a state where ends thereof are not separated apart from the element separating portion 42. That is, structures in which the sizes of the intra-pixel grooves 22 are enlarged to such an extent that both ends of the intra-pixel grooves 22 are linked with the element separating portion 42 (hereinafter, referred to as enlarged structures) may be adopted.

For example, if the intra-pixel grooves 22a with the cross shape, the intra-pixel grooves 22b with the diagonal line shape, the intra-pixel grooves 22c with the horizontal line shape, the intra-pixel grooves 22d with the vertical line shape, and the intra-pixel grooves 22e with the L-shape are separated apart from the element separating portion 42, the area sizes of light reception increase by amounts corresponding to the separation, and it is possible to attempt to improve amounts Qs of electric charge that can be accumulated. In contrast to this, by adopting the enlarged structures for the intra-pixel grooves 22, a more significant advantage can be attained by scattering of light, contributing to sensitivity improvement.

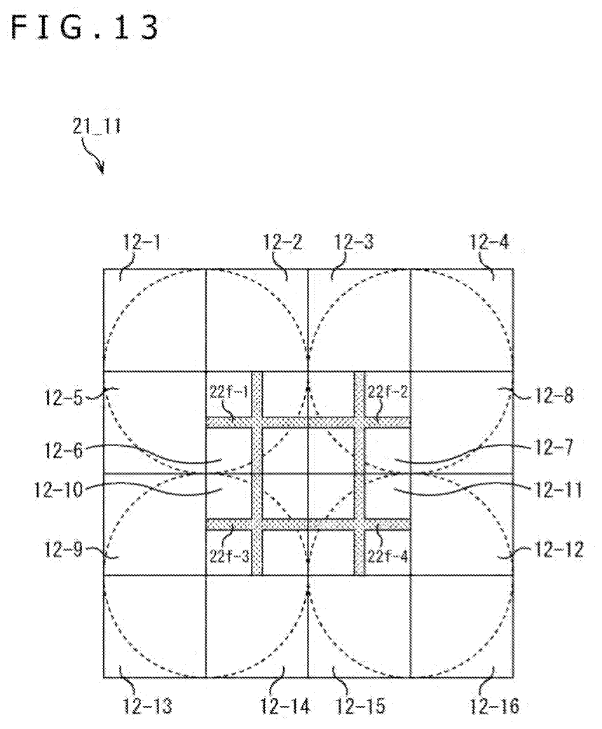

FIG. 13 is a figure depicting a configuration example of an eleventh sensitivity adjustment structure 21_11.

As depicted in FIG. 13, the eleventh sensitivity adjustment structure 21_11 uses intra-pixel grooves 22f with the cross shape and the enlarged structure in which lines extending in the vertical direction and the horizontal direction of a pixel 12 cross each other at the middle. Similarly to the intra-pixel grooves 22a with the cross shape, the intra-pixel grooves 22f with the cross shape and the enlarged structure have a function of more significantly improving the sensitivity of pixels 12 provided with the intra-pixel grooves 22f with the cross shape and the enlarged structure and other pixels 12 that are vertically or horizontally adjacent to the pixels 12 provided with the intra-pixel grooves 22a with the cross shape.

Further, similarly to the first sensitivity adjustment structure 21_1 in FIG. 3, the eleventh sensitivity adjustment structure 21_11 includes an arrangement pattern in which, in the 4×4 array of the sixteen pixels 12-1 to 12-16, the intra-pixel grooves 22f with the cross shape and the enlarged structure are provided to pixels 12 arranged at the four locations in the middle 2×2 array.

Accordingly, similarly to the first sensitivity adjustment structure 21_1, by applying the eleventh sensitivity adjustment structure 21_11 to the red same-color pixel group 13R and the blue same-color pixel group 13B, more uniform sensitivity characteristics can be attained. Moreover, the eleventh sensitivity adjustment structure 21_11 can more significantly contribute to sensitivity improvement owing to the intra-pixel grooves 22f with the cross shape and the enlarged structure.

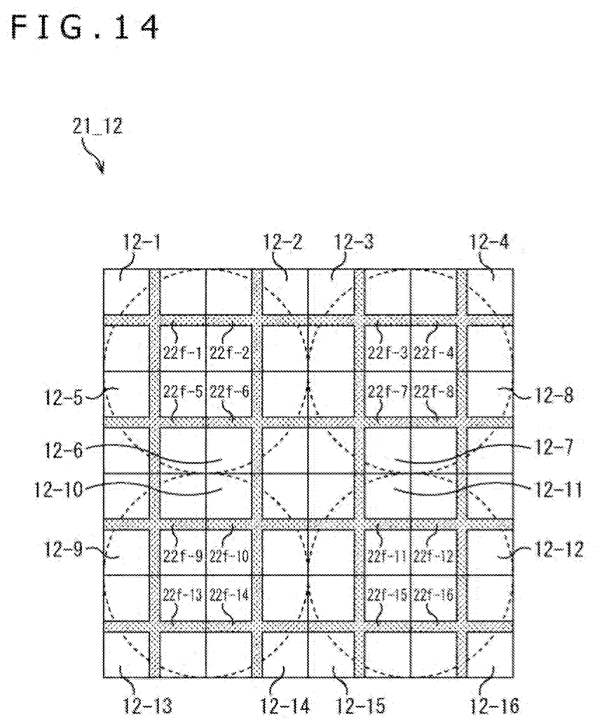

FIG. 14 is a figure depicting a configuration example of a twelfth sensitivity adjustment structure 21_12.

As depicted in FIG. 14, the twelfth sensitivity adjustment structure 21_12 uses the intra-pixel grooves 22f with the cross shape and the enlarged structure in which lines extending in the vertical direction and the horizontal direction of a pixel 12 cross each other at the middle.

Further, similarly to the second sensitivity adjustment structure 21_2 in FIG. 4, the twelfth sensitivity adjustment structure 21_12 includes an arrangement pattern in which the intra-pixel grooves 22f with the cross shape and the enlarged structure are provided to all the sixteen pixels 12-1 to 12-16 in the 4×4 array.

Accordingly, similarly to the second sensitivity adjustment structure 21_2, the twelfth sensitivity adjustment structure 21_12 makes it possible to attempt to improve the overall sensitivity of the same-color pixel groups 13. Moreover, the twelfth sensitivity adjustment structure 21_12 can more significantly contribute to sensitivity improvement owing to the intra-pixel grooves 22f with the cross shape and the enlarged structure.

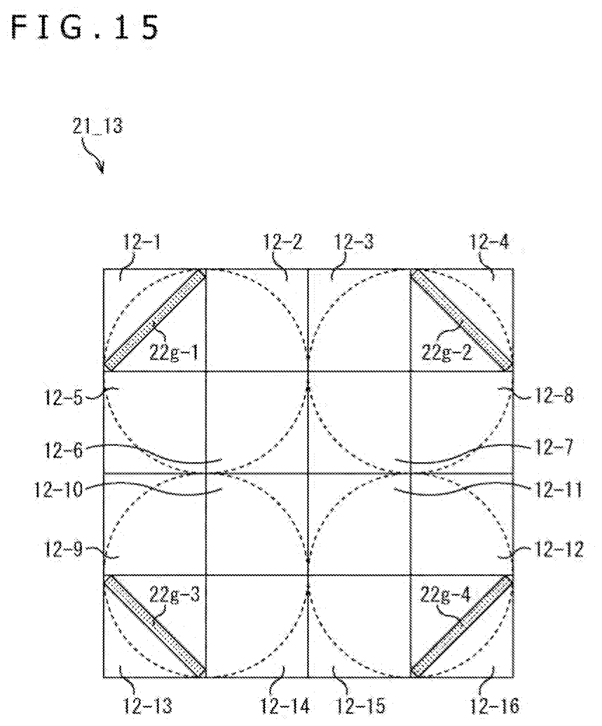

FIG. 15 is a figure depicting a configuration example of a thirteenth sensitivity adjustment structure 21_13.

As depicted in FIG. 15, the thirteenth sensitivity adjustment structure 21_13 uses intra-pixel grooves 22g with the diagonal line shape and the enlarged structure extending in a diagonal direction of a pixel 12. Similarly to the intra-pixel grooves 22b with the diagonal line shape, the intra-pixel grooves 22g with the diagonal line shape and the enlarged structure have a function of more significantly improving the sensitivity of pixels 12 provided with the intra-pixel grooves 22g with the diagonal line shape and the enlarged structure and other pixels 12 positioned in directions perpendicular to the longitudinal directions of the intra-pixel grooves 22g with the diagonal line shape and the enlarged structure.

Further, similarly to the third sensitivity adjustment structure 21_3 in FIG. 5, the thirteenth sensitivity adjustment structure 21_13 includes an arrangement pattern in which, in the 4×4 array of the sixteen pixels 12-1 to 12-16, the intra-pixel grooves 22g with the diagonal line shape and the enlarged structure are provided to pixels 12 arranged at the four corner locations.

Accordingly, similarly to the third sensitivity adjustment structure 21_3, by applying the thirteenth sensitivity adjustment structure 21_13 to the red same-color pixel group 13R and the blue same-color pixel group 13B, more uniform sensitivity characteristics can be attained. Moreover, the thirteenth sensitivity adjustment structure 21_13 can more significantly contribute to sensitivity improvement owing to the intra-pixel grooves 22g with the diagonal line shape and the enlarged structure.

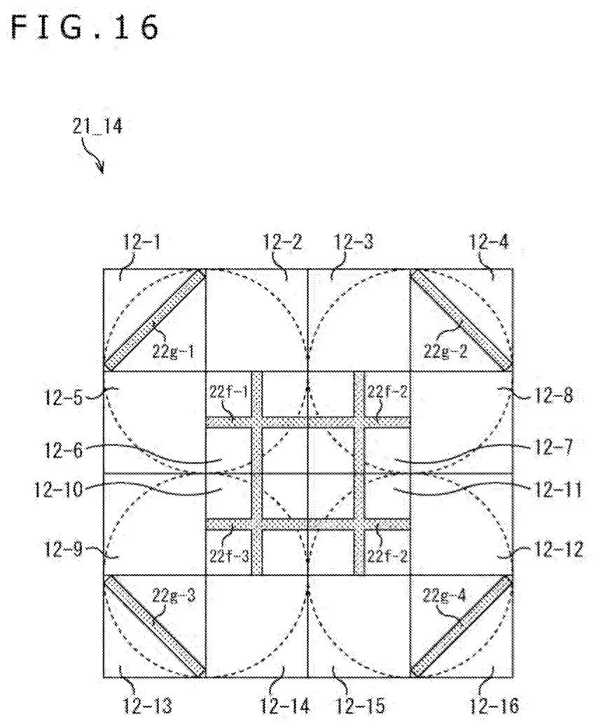

FIG. 16 is a figure depicting a configuration example of a fourteenth sensitivity adjustment structure 21_14.

As depicted in FIG. 16, the fourteenth sensitivity adjustment structure 21_14 uses the intra-pixel grooves 22f with the cross shape and the enlarged structure in which lines extending in the vertical direction and the horizontal direction of a pixel 12 cross each other at the middle, and the intra-pixel grooves 22g with the diagonal line shape and the enlarged structure extending in a diagonal direction of a pixel 12.

Further, similarly to the fourth sensitivity adjustment structure 21_4 in FIG. 6, the fourteenth sensitivity adjustment structure 21_14 includes an arrangement pattern in which, in the 4×4 array of the sixteen pixels 12-1 to 12-16, the intra-pixel grooves 22f with the cross shape and the enlarged structure are provided to pixels 12 arranged at the four locations in the middle 2×2 array and the intra-pixel grooves 22g with the diagonal line shape and the enlarged structure are provided to pixels 12 arranged at the four corner locations.

Accordingly, similarly to the fourth sensitivity adjustment structure 21_4, by applying the fourteenth sensitivity adjustment structure 21_14 to the red same-color pixel group 13R and the blue same-color pixel group 13B, more uniform sensitivity characteristics can be attained. Moreover, the fourteenth sensitivity adjustment structure 21_14 can more significantly contribute to sensitivity improvement owing to the intra-pixel grooves 22f with the cross shape and the enlarged structure and the intra-pixel grooves 22g with the diagonal line shape and the enlarged structure.

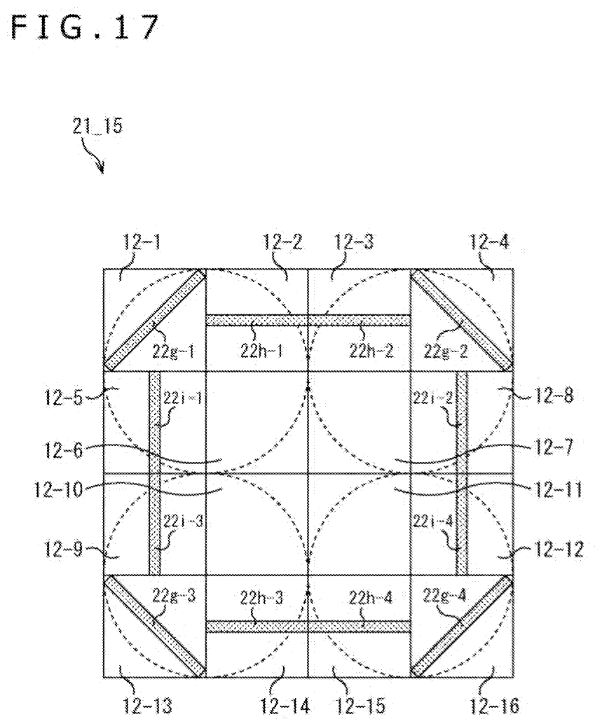

FIG. 17 is a figure depicting a configuration example of a fifteenth sensitivity adjustment structure 21_15.

As depicted in FIG. 17, the fifteenth sensitivity adjustment structure 21_15 uses the intra-pixel grooves 22g with the diagonal line shape and the enlarged structure extending in a diagonal direction of a pixel 12, intra-pixel grooves 22h with the horizontal line shape and the enlarged structure extending in the horizontal direction of a pixel 12, and intra-pixel grooves 22i with the vertical line shape and the enlarged structure extending in the vertical direction of a pixel 12.

For example, similarly to the intra-pixel grooves 22c with the horizontal line shape, the intra-pixel grooves 22h with the horizontal line shape and the enlarged structure have a function of more significantly improving the sensitivity of pixels 12 provided with the intra-pixel grooves 22h with the horizontal line shape and the enlarged structure and other pixels 12 vertically adjacent to the pixels 12 provided with the intra-pixel grooves 22h with the horizontal line shape and the enlarged structure. For example, similarly to the intra-pixel grooves 22d with the vertical line shape, the intra-pixel grooves 22i with the vertical line shape and the enlarged structure have a function of more significantly improving the sensitivity of pixels 12 provided with the intra-pixel grooves 22i with the vertical line shape and the enlarged structure and other pixels 12 horizontally adjacent to the pixels 12 provided with the intra-pixel grooves 22i with the vertical line shape and the enlarged structure.

Further, similarly to the fifth sensitivity adjustment structure 21_5 in FIG. 7, the fifteenth sensitivity adjustment structure 21_15 includes an arrangement pattern in which, in the 4×4 array of the sixteen pixels 12-1 to 12-16, the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the two middle locations on the upper side and pixels 12 arranged at the two middle locations on the lower side, and the intra-pixel grooves 22i with the vertical line shape and the enlarged structure are provided to pixels 12 arranged at the two middle locations on the right side, and pixels 12 arranged at the two middle locations on the left side.

Accordingly, similarly to the fifth sensitivity adjustment structure 21_5, by applying the fifteenth sensitivity adjustment structure 21_15 to the red same-color pixel group 13R and the blue same-color pixel group 13B, more uniform sensitivity characteristics can be attained. Moreover, the fifteenth sensitivity adjustment structure 21_15 can more significantly contribute to sensitivity improvement owing to the intra-pixel grooves 22g with the diagonal line shape and the enlarged structure, the intra-pixel grooves 22h with the horizontal line shape and the enlarged structure, and the intra-pixel grooves 22i with the vertical line shape and the enlarged structure.

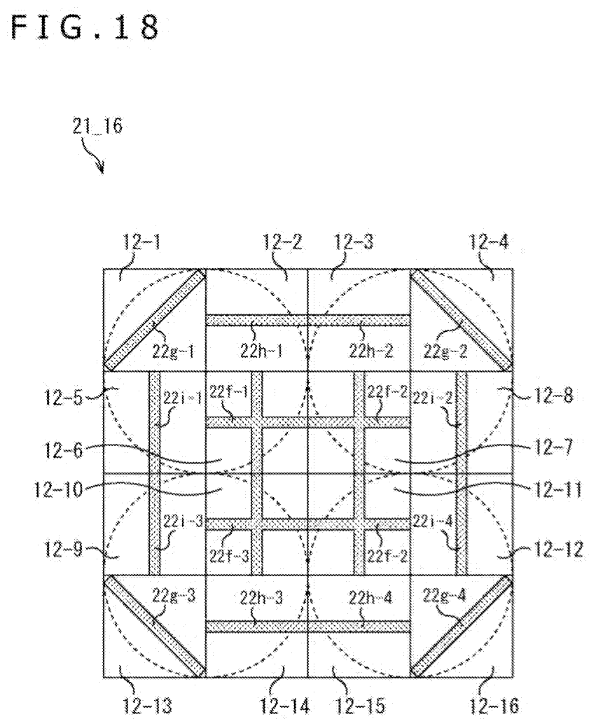

FIG. 18 is a figure depicting a configuration example of a sixteenth sensitivity adjustment structure 21_16.

As depicted in FIG. 18, the sixteenth sensitivity adjustment structure 21_16 uses the intra-pixel grooves 22f with the cross shape and the enlarged structure in which lines extending in the vertical direction and the horizontal direction of a pixel 12 cross each other at the middle, the intra-pixel grooves 22g with the diagonal line shape and the enlarged structure extending in a diagonal direction of a pixel 12, the intra-pixel grooves 22h with the horizontal line shape and the enlarged structure extending in the horizontal direction of a pixel 12, and the intra-pixel grooves 22i with the vertical line shape and the enlarged structure extending in the vertical direction of a pixel 12.

Further, similarly to the sixth sensitivity adjustment structure 21_6 in FIG. 8, the sixteenth sensitivity adjustment structure 21_16 includes an arrangement pattern in which, in the 4×4 array of the sixteen pixels 12-1 to 12-16, the intra-pixel grooves 22f with the cross shape and the enlarged structure are provided to pixels 12 arranged at the four locations in the middle 2×2 array, the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the two middle locations on the upper side and pixels 12 arranged at the two middle locations on the lower side, and the intra-pixel grooves 22i with the vertical line shape and the enlarged structure are provided to pixels 12 arranged at the two middle locations on the right side and pixels 12 arranged at the two middle locations on the left side.

Accordingly, similarly to the sixth sensitivity adjustment structure 21_6, by applying the sixteenth sensitivity adjustment structure 21_16 to the red same-color pixel group 13R and the blue same-color pixel group 13B, more uniform sensitivity characteristics can be attained. Moreover, the sixteenth sensitivity adjustment structure 21_16 can more significantly contribute to sensitivity improvement owing to the intra-pixel grooves 22f with the cross shape and the enlarged structure, the intra-pixel grooves 22g with the diagonal line shape and the enlarged structure, the intra-pixel grooves 22h with the horizontal line shape and the enlarged structure, and the intra-pixel grooves 22i with the vertical line shape and the enlarged structure.

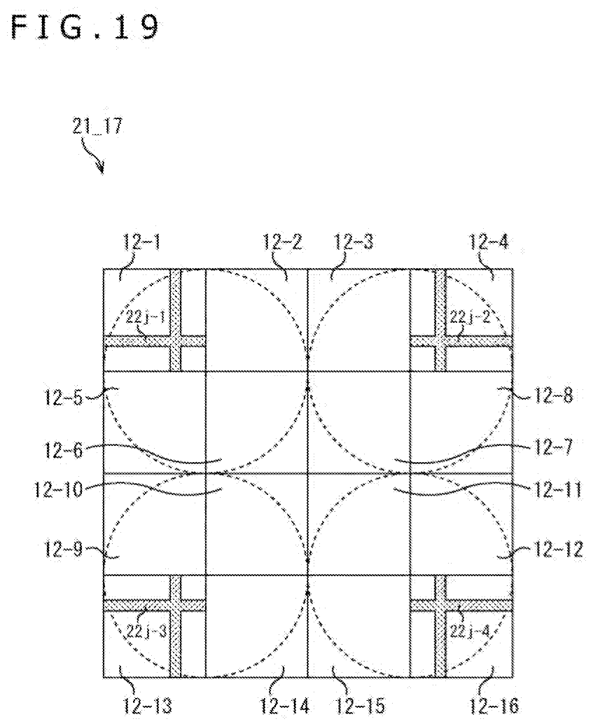

FIG. 19 is a figure depicting a configuration example of a seventeenth sensitivity adjustment structure 21_17.

As depicted in FIG. 19, the seventeenth sensitivity adjustment structure 21_17 uses intra-pixel grooves 22j with the L-shape and an enlarged structure in which lines extending in the vertical directions and the horizontal directions of the intra-pixel grooves 22e with the L-shape are enlarged to pixel ends. Note that the intra-pixel grooves 22j with the L-shape and the enlarged structure have not an L-shape but a shape in which lines extending in the vertical direction and the horizontal direction cross at positions off the centers of the lines. For example, similarly to the intra-pixel grooves 22e with the L-shape, the intra-pixel grooves 22j with the L-shape and the enlarged structure have a function of more significantly improving the sensitivity of pixels 12 provided with the intra-pixel grooves 22j with the L-shape and the enlarged structure, other pixels 12 that are adjacent to the pixels 12 provided with the intra-pixel grooves 22e with the L-shape and that are adjacent on a side where the vertical lines are arranged nearby, and other pixels 12 that are adjacent to the pixels 12 provided with the intra-pixel grooves 22e with the L-shape and that are adjacent on a side where the horizontal lines are arranged nearby.

Further, similarly to the seventh sensitivity adjustment structure 21_7 in FIG. 9, the seventeenth sensitivity adjustment structure 21_17 includes an arrangement pattern in which the intra-pixel grooves 22j with the L-shape and the enlarged structure are provided to pixels 12 arranged at the four corner locations in the 4×4 array of the sixteen pixels 12-1 to 12-16.

Accordingly, similarly to the seventh sensitivity adjustment structure 21_7, by applying the seventeenth sensitivity adjustment structure 21_17 to the red same-color pixel group 13R and the blue same-color pixel group 13B, more uniform sensitivity characteristics can be attained. Moreover, the seventeenth sensitivity adjustment structure 21_17 can more significantly contribute to sensitivity improvement owing to the intra-pixel grooves 22j with the L-shape and the enlarged structure.

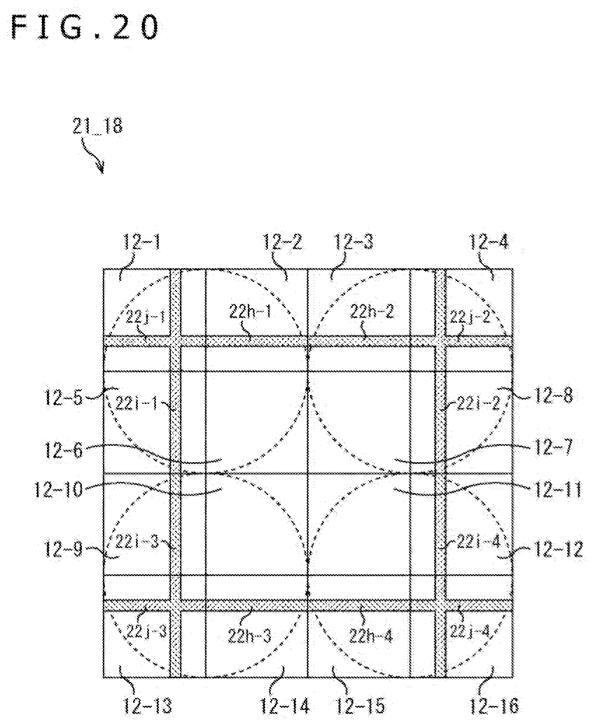

FIG. 20 is a figure depicting a configuration example of an eighteenth sensitivity adjustment structure 21_18.

As depicted in FIG. 20, the eighteenth sensitivity adjustment structure 21_18 uses the intra-pixel grooves 22h with the horizontal line shape and the enlarged structure extending in the horizontal direction of a pixel 12, the intra-pixel grooves 22i with the vertical line shape and the enlarged structure extending in the vertical direction of a pixel 12, and the intra-pixel grooves 22j with the L-shape and the enlarged structure in which lines extending in the vertical directions and the horizontal directions of the intra-pixel grooves 22e with the L-shape are enlarged to pixel ends.

Further, similarly to the eighth sensitivity adjustment structure 21_8 in FIG. 10, the eighteenth sensitivity adjustment structure 21_18 includes an arrangement pattern in which, in the 4×4 array of the sixteen pixels 12-1 to 12-16, the intra-pixel grooves 22h with the horizontal line shape and the enlarged structure are provided to pixels 12 arranged at the two middle locations on the upper side and pixels 12 arranged at the two middle locations on the lower side, the intra-pixel grooves 22i with the vertical line shape and the enlarged structure are provided to pixels 12 arranged at the two middle locations on the right side and pixels 12 arranged at the two middle locations on the left side, and the intra-pixel grooves 22j with the L-shape and the enlarged structure are provided to pixels 12 arranged at the four corner locations.

Accordingly, similarly to the eighth sensitivity adjustment structure 21_8, by applying the eighteenth sensitivity adjustment structure 21_18 to the red same-color pixel group 13R and the blue same-color pixel group 13B, more uniform sensitivity characteristics can be attained. Moreover, the eighteenth sensitivity adjustment structure 21_18 can more significantly contribute to sensitivity improvement owing to the intra-pixel grooves 22h with the horizontal line shape and the enlarged structure, the intra-pixel grooves 22i with the vertical line shape and the enlarged structure, and the intra-pixel grooves 22j with the L-shape and the enlarged structure.

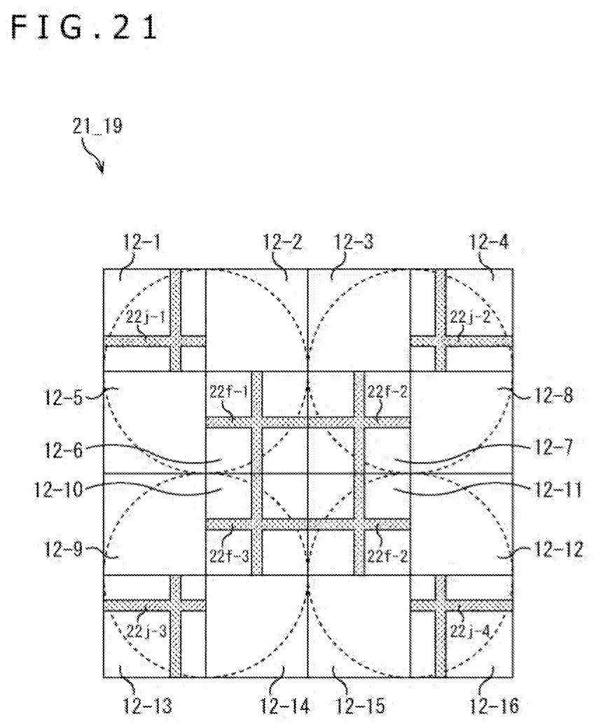

FIG. 21 is a figure depicting a configuration example of a nineteenth sensitivity adjustment structure 21_19.

As depicted in FIG. 21, the nineteenth sensitivity adjustment structure 21_19 uses the intra-pixel grooves 22f with the cross shape and the enlarged structure in which lines extending in the vertical direction and the horizontal direction of a pixel 12 cross each other at the middle, and the intra-pixel grooves 22j with the L-shape and the enlarged structure in which lines extending in the vertical directions and the horizontal directions of the intra-pixel grooves 22e with the L-shape are enlarged to pixel ends.

Further, similarly to the ninth sensitivity adjustment structure 21_9 in FIG. 11, the nineteenth sensitivity adjustment structure 21_19 includes an arrangement pattern in which, in the 4×4 array of the sixteen pixels 12-1 to 12-16, the intra-pixel grooves 22f with the cross shape and the enlarged structure are provided to pixels 12 arranged at the four locations in the middle 2×2 array and the intra-pixel grooves 22j with the L-shape and the enlarged structure are provided to pixels 12 arranged at the four corner locations.

Accordingly, similarly to the ninth sensitivity adjustment structure 21_9, by applying the nineteenth sensitivity adjustment structure 21_19 to the red same-color pixel group 13R and the blue same-color pixel group 13B, more uniform sensitivity characteristics can be attained. Moreover, the nineteenth sensitivity adjustment structure 21_19 can more significantly contribute to sensitivity improvement owing to the intra-pixel grooves 22f with the cross shape and the enlarged structure and the intra-pixel grooves 22j with the L-shape and the enlarged structure.

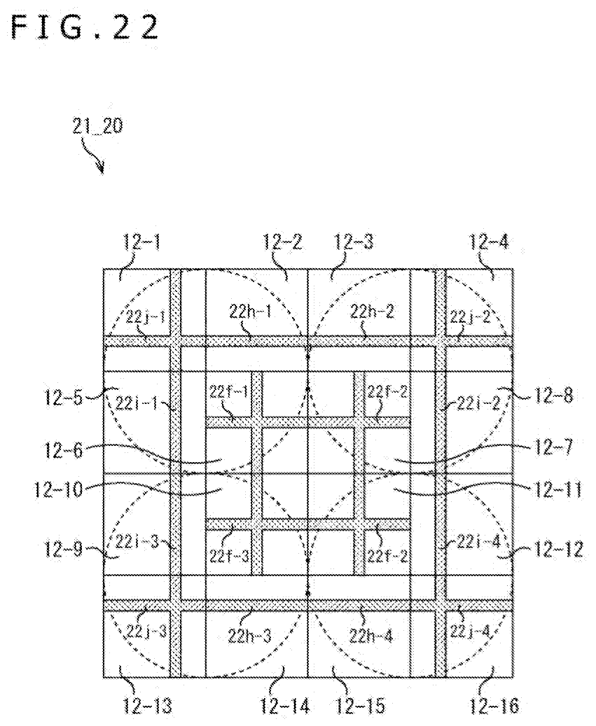

FIG. 22 is a figure depicting a configuration example of a twentieth sensitivity adjustment structure 21_20.

As depicted in FIG. 22, the twentieth sensitivity adjustment structure 21_20 uses the intra-pixel grooves 22f with the cross shape and the enlarged structure in which lines extending in the vertical direction and the horizontal direction of a pixel 12 cross each other at the middle, the intra-pixel grooves 22h with the horizontal line shape and the enlarged structure extending in the horizontal direction of a pixel 12, the intra-pixel grooves 22i with the vertical line shape and the enlarged structure extending in the vertical direction of a pixel 12, and the intra-pixel grooves 22j with the L-shape and the enlarged structure in which lines extending in the vertical directions and the horizontal directions of the intra-pixel grooves 22e with the L-shape are enlarged to pixel ends.

Further, similarly to the tenth sensitivity adjustment structure 21_10 in FIG. 12, the twentieth sensitivity adjustment structure 21_20 includes an arrangement pattern in which, in the 4×4 array of the sixteen pixels 12-1 to 12-16, the intra-pixel grooves 22f with the cross shape and the enlarged structure are provided to pixels 12 arranged at the four locations in the middle 2×2 array, the intra-pixel grooves 22h with the horizontal line shape and the enlarged structure are provided to pixels 12 arranged at the two middle locations on the upper side and pixels 12 arranged at the two middle locations on the lower side, the intra-pixel grooves 22i with the vertical line shape and the enlarged structure are provided to pixels 12 arranged at the two middle locations on the right side and pixels 12 arranged at the two middle locations on the left side, and the intra-pixel grooves 22j with the L-shape and the enlarged structure are provided to pixels 12 arranged at the four corner locations.

Accordingly, similarly to the tenth sensitivity adjustment structure 21_10, by applying the twentieth sensitivity adjustment structure 21_20 to the red same-color pixel group 13R and the blue same-color pixel group 13B, more uniform sensitivity characteristics can be attained. Moreover, the twentieth sensitivity adjustment structure 21_20 can more significantly contribute to sensitivity improvement owing to the intra-pixel grooves 22f with the cross shape and the enlarged structure, the intra-pixel grooves 22h with the horizontal line shape and the enlarged structure, the intra-pixel grooves 22i with the vertical line shape and the enlarged structure, and the intra-pixel grooves 22j with the L-shape and the enlarged structure.

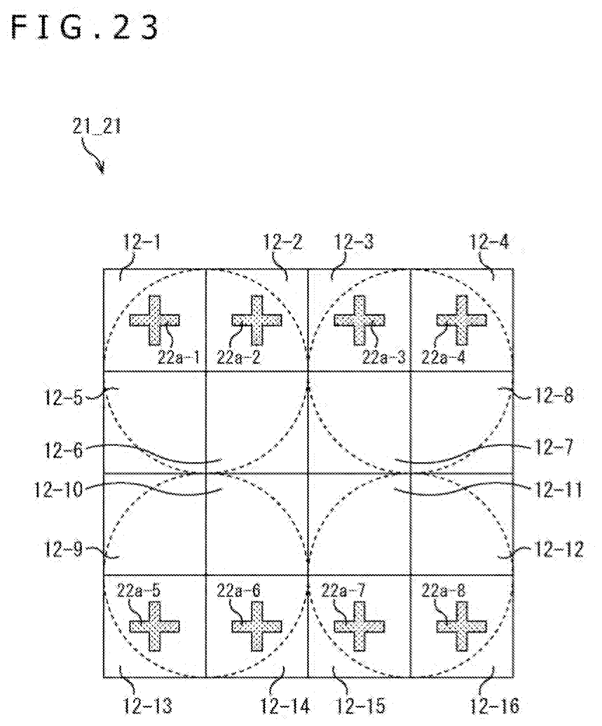

FIG. 23 is a figure depicting a configuration example of a twenty-first sensitivity adjustment structure 21_21.

As depicted in FIG. 23, the twenty-first sensitivity adjustment structure 21_21 uses the intra-pixel grooves 22a with the cross shape in which lines extending in the vertical direction and the horizontal direction of a pixel 12 cross each other at the middle.

The twenty-first sensitivity adjustment structure 21_21 includes an arrangement pattern in which, in the 4×4 array of the sixteen pixels 12-1 to 12-16, the intra-pixel grooves 22a with the cross shape are provided to pixels 12 arranged at the four locations on the upper side and pixels 12 arranged at the four locations on the lower side. That is, in the twenty-first sensitivity adjustment structure 21_21, the intra-pixel grooves 22a-1 to 22a-4 with the cross shape are provided to the pixels 12-1 to 12-4, respectively, and the intra-pixel grooves 22a-5 to 22a-8 with the cross shape are provided to the pixels 12-13 to 12-16, respectively.

Accordingly, by applying the twenty-first sensitivity adjustment structure 21_21 to the green same-color pixel group 13Gr, it is possible to attempt to significantly improve the sensitivity of the pixels 12 that are arranged at the four locations on the upper side and that tend to have low sensitivity and the pixels 12 that are arranged at the four locations on the lower side and that tend to have low sensitivity, since the intra-pixel grooves 22a with the cross shape scatter intense light in the pixels 12 and, along with this, the optical path lengths are enlarged. As a result, the image-capturing element 11 can suppress inter-pixel-12 sensitivity differences in the green same-color pixel group 13Gr, and attain more uniform sensitivity characteristics.

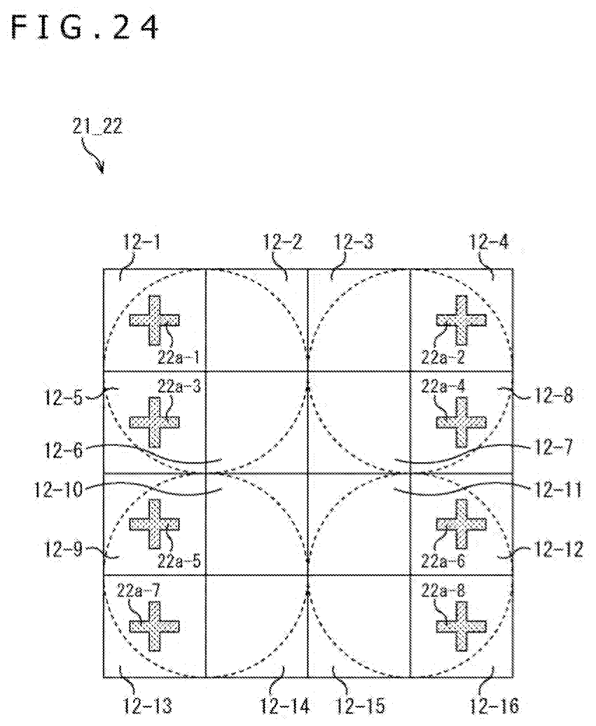

FIG. 24 is a figure depicting a configuration example of a twenty-second sensitivity adjustment structure 21_22.

As depicted in FIG. 24, the twenty-second sensitivity adjustment structure 21_22 uses the intra-pixel grooves 22a with the cross shape in which lines extending in the vertical direction and the horizontal direction of a pixel 12 cross each other at the middle.

The twenty-second sensitivity adjustment structure 21_22 includes an arrangement pattern in which, in the 4×4 array of the sixteen pixels 12-1 to 12-16, the intra-pixel grooves 22a with the cross shape are provided to pixels 12 arranged at the four locations on the left side and pixels 12 arranged at the four locations on the right side. That is, in the twenty-second sensitivity adjustment structure 21_22, the intra-pixel groove 22a-1 with the cross shape is provided to the pixel 12-1, the intra-pixel groove 22a-2 with the cross shape is provided to the pixel 12-4, the intra-pixel groove 22a-3 with the cross shape is provided to the pixel 12-5, and the intra-pixel groove 22a-4 with the cross shape is provided to the pixel 12-8. Moreover, the intra-pixel groove 22a-5 with the cross shape is provided to the pixel 12-9, the intra-pixel groove 22a-6 with the cross shape is provided to the pixel 12-12, the intra-pixel groove 22a-7 with the cross shape is provided to the pixel 12-13, and the intra-pixel groove 22a-8 with the cross shape is provided to the pixel 12-16.

Accordingly, by applying the twenty-second sensitivity adjustment structure 21_22 to the green same-color pixel group 13Gb, it is possible to attempt to significantly improve the sensitivity of the pixels 12 that are arranged at the four locations on the left side and that tend to have low sensitivity and the pixels 12 that are arranged at the four locations on the right side and that tend to have low sensitivity, since the intra-pixel grooves 22a with the cross shape scatter intense light in the pixels 12 and, along with this, the optical path lengths are enlarged. As a result, the image-capturing element 11 can suppress inter-pixel-12 sensitivity differences in the green same-color pixel group 13Gb, and attain more uniform sensitivity characteristics.

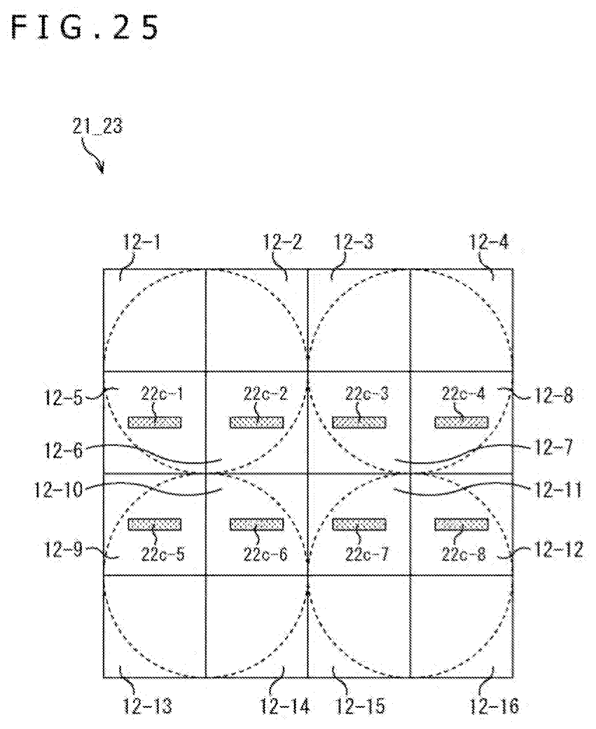

FIG. 25 is a figure depicting a configuration example of a twenty-third sensitivity adjustment structure 21_23.

As depicted in FIG. 25, the twenty-third sensitivity adjustment structure 21_23 uses the intra-pixel grooves 22c with the horizontal line shape extending in the horizontal direction of a pixel 12.

The twenty-third sensitivity adjustment structure 21_23 includes an arrangement pattern in which, in the 4×4 array of the sixteen pixels 12-1 to 12-16, the intra-pixel grooves 22c with the horizontal line shape are provided to pixels 12 arranged at the eight locations in the two middle rows. That is, in the twenty-third sensitivity adjustment structure 21_23, the intra-pixel grooves 22c-1 to 22c-4 with the horizontal line shape are provided to the pixels 12-5 to 12-8, respectively, and intra-pixel grooves 22c-5 to 22c-8 with the horizontal line shape are provided to the pixels 12-9 to 12-12, respectively.

Accordingly, by applying the twenty-third sensitivity adjustment structure 21_23 to the green same-color pixel group 13Gr, it is possible to attempt to improve the sensitivity of pixels 12 that are arranged at the four locations on the upper side and that tend to have low sensitivity and pixels 12 that are arranged at the four locations on the lower side and that tend to have low sensitivity. That is, the sensitivity of the pixels 12 arranged at the four locations on the upper side and the pixels 12 arranged at the four locations on the lower side is improved, as a result of scattering of light by the intra-pixel grooves 22c in directions perpendicular to the longitudinal directions of the intra-pixel grooves 22c with the horizontal line shape and causing the scattered light to be incident on the pixels 12 on the upper side and the lower side. As a result, the image-capturing element 11 can suppress inter-pixel-12 sensitivity differences in the green same-color pixel group 13Gr, and attain more uniform sensitivity characteristics.

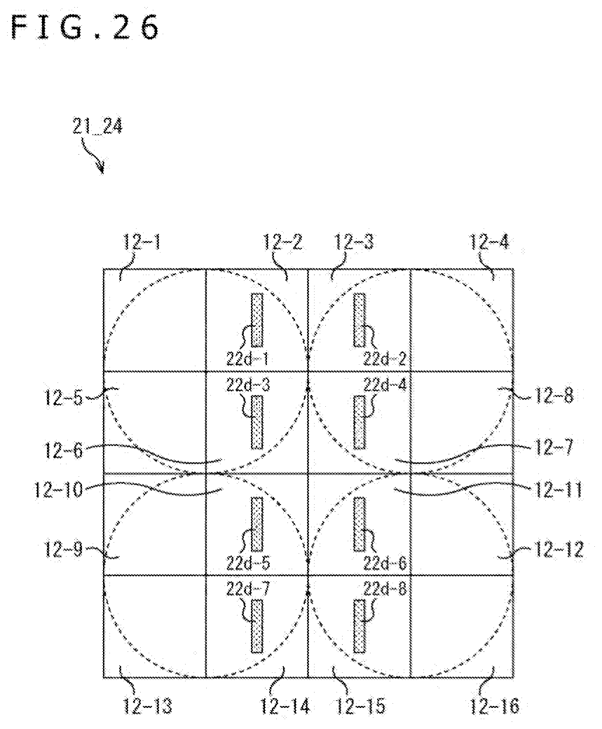

FIG. 26 is a figure depicting a configuration example of a twenty-fourth sensitivity adjustment structure 21_24.

As depicted in FIG. 26, the twenty-fourth sensitivity adjustment structure 21_24 uses the intra-pixel grooves 22d with the vertical line shape extending in the vertical direction of a pixel 12.

The twenty-fourth sensitivity adjustment structure 21_24 includes an arrangement pattern in which, in the 4×4 array of the sixteen pixels 12-1 to 12-16, the intra-pixel grooves 22d with the vertical line shape are provided to pixels 12 arranged at the eight locations in the two middle columns. That is, in the twenty-fourth sensitivity adjustment structure 21_24, the intra-pixel groove 22d-1 with the vertical line shape is provided to the pixel 12-2, the intra-pixel groove 22d-2 with the vertical line shape is provided to the pixel 12-3, the intra-pixel groove 22d-3 with the vertical line shape is provided to the pixel 12-6, and the intra-pixel groove 22d-4 with the vertical line shape is provided to the pixel 12-7. Moreover, an intra-pixel groove 22d-5 with the vertical line shape is provided to the pixel 12-10, an intra-pixel groove 22d-6 with the vertical line shape is provided to the pixel 12-11, an intra-pixel groove 22d-7 with the vertical line shape is provided to the pixel 12-14, and an intra-pixel groove 22d-8 with the vertical line shape is provided to the pixel 12-15.

Accordingly, by applying the twenty-fourth sensitivity adjustment structure 21_24 to the green same-color pixel group 13Gb, it is possible to attempt to improve the sensitivity of pixels 12 that are arranged at the four locations on the left side and that tend to have low sensitivity and pixels 12 that are arranged at the four locations on the right side and that tend to have low sensitivity. That is, the sensitivity of the pixels 12 arranged at the four locations on the left side and the pixels 12 arranged at the four locations on the right side is improved, as a result of scattering of light by the intra-pixel grooves 22d with the vertical line shape in directions perpendicular to the longitudinal directions of the intra-pixel grooves 22d with the vertical line shape and causing the scattered light to be incident on the pixels 12 on the left side and the right side. As a result, the image-capturing element 11 can suppress inter-pixel-12 sensitivity differences in the green same-color pixel group 13Gb, and attain more uniform sensitivity characteristics.

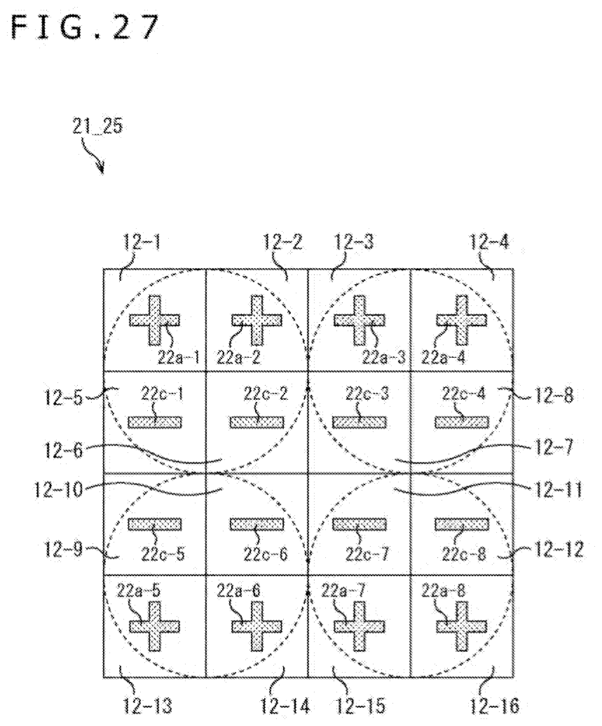

FIG. 27 is a figure depicting a configuration example of a twenty-fifth sensitivity adjustment structure 21_25.

As depicted in FIG. 27, the twenty-fifth sensitivity adjustment structure 21_25 uses the intra-pixel grooves 22a with the cross shape in which lines extending in the vertical direction and the horizontal direction of a pixel 12 cross each other at the middle, and the intra-pixel grooves 22c with the horizontal line shape extending in the horizontal direction of a pixel 12.

The twenty-fifth sensitivity adjustment structure 21_25 includes an arrangement pattern in which, in the 4×4 array of the sixteen pixels 12-1 to 12-16, the intra-pixel grooves 22a with the cross shape are provided to pixels 12 arranged at the four locations on the upper side and pixels 12 arranged at the four locations on the lower side and the intra-pixel grooves 22c with the horizontal line shape are provided to pixels 12 arranged at the eight locations in the two middle rows. That is, in the twenty-fifth sensitivity adjustment structure 21_25, the intra-pixel grooves 22a-1 to 22a-8 with the cross shape are provided similarly to the twenty-first sensitivity adjustment structure 21_21 in FIG. 23, and the intra-pixel grooves 22c-1 to 22c-8 with the horizontal line shape are provided similarly to the twenty-third sensitivity adjustment structure 21_23 in FIG. 25.

Accordingly, by applying the twenty-first sensitivity adjustment structure 21_21 to the green same-color pixel group 13Gr, an advantage combining those of the twenty-first sensitivity adjustment structure 21_21 and the twenty-third sensitivity adjustment structure 21_23 can be attained. That is, the image-capturing element 11 can suppress inter-pixel-12 sensitivity differences in the green same-color pixel group 13Gr, and attain more uniform sensitivity characteristics.

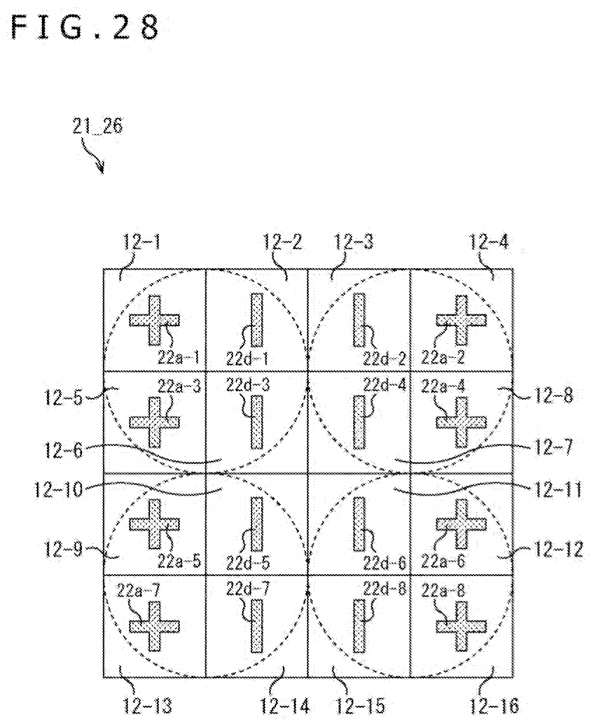

FIG. 28 is a figure depicting a configuration example of a twenty-sixth sensitivity adjustment structure 21_26.

As depicted in FIG. 28, the twenty-sixth sensitivity adjustment structure 21_26 uses the intra-pixel grooves 22a with the cross shape in which lines extending in the vertical direction and the horizontal direction of a pixel 12 cross each other at the middle and the intra-pixel grooves 22d with the vertical line shape extending in the vertical direction of a pixel 12.

The twenty-sixth sensitivity adjustment structure 21_26 includes an arrangement pattern in which, in the 4×4 array of the sixteen pixels 12-1 to 12-16, the intra-pixel grooves 22a with the cross shape are provided to pixels 12 arranged at the four locations on the left side and pixels 12 arranged at the four locations on the right side and the intra-pixel grooves 22d with the vertical line shape are provided to pixels 12 arranged at the eight locations in the two middle columns. That is, in the twenty-sixth sensitivity adjustment structure 21_26, the intra-pixel grooves 22a-1 to 22a-8 with the cross shape are provided similarly to the twenty-second sensitivity adjustment structure 21_22 in FIG. 24, and the intra-pixel grooves 22d-1 to 22d-8 with the vertical line shape are provided similarly to the twenty-fourth sensitivity adjustment structure 21_24 in FIG. 26.

Accordingly, by applying the twenty-second sensitivity adjustment structure 21_22 to the green same-color pixel group 13Gb, an advantage combining those of the twenty-second sensitivity adjustment structure 21_22 and the twenty-fourth sensitivity adjustment structure 21_24 can be attained. That is, the image-capturing element 11 can suppress inter-pixel-12 sensitivity differences in the green same-color pixel group 13Gb, and attain more uniform sensitivity characteristics.

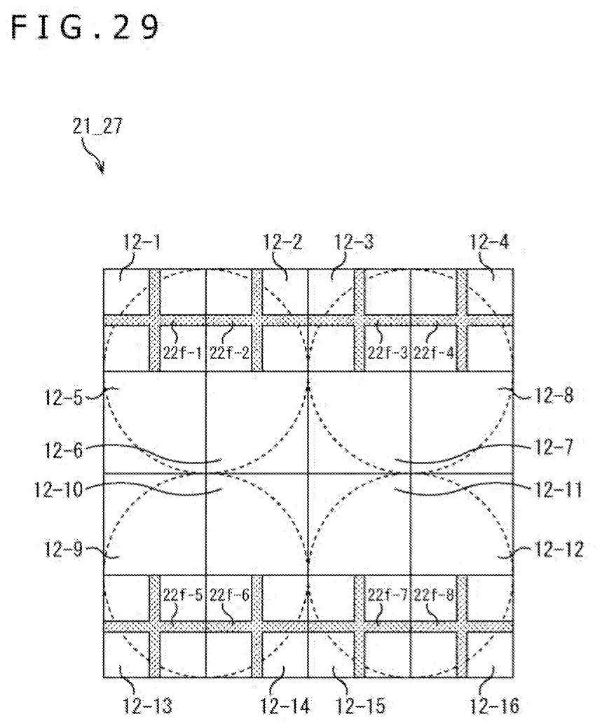

FIG. 29 is a figure depicting a configuration example of a twenty-seventh sensitivity adjustment structure 21_27.

As depicted in FIG. 29, the twenty-seventh sensitivity adjustment structure 21_27 uses the intra-pixel grooves 22f with the cross shape and the enlarged structure in which lines extending in the vertical direction and the horizontal direction of a pixel 12 cross each other at the middle.

Further, similarly to the twenty-first sensitivity adjustment structure 21_21 in FIG. 23, the twenty-seventh sensitivity adjustment structure 21_27 includes an arrangement pattern in which, in the 4×4 array of the sixteen pixels 12-1 to 12-16, the intra-pixel grooves 22f with the cross shape and the enlarged structure are provided to pixels 12 arranged at the four locations on the upper side and pixels 12 arranged at the four locations on the lower side.

Accordingly, similarly to the twenty-first sensitivity adjustment structure 21_21, by applying the twenty-seventh sensitivity adjustment structure 21_27 to the green same-color pixel group 13Gr, more uniform sensitivity characteristics can be attained. Moreover, the twenty-seventh sensitivity adjustment structure 21_27 can more significantly contribute to sensitivity improvement owing to the intra-pixel grooves 22f with the cross shape and the enlarged structure.

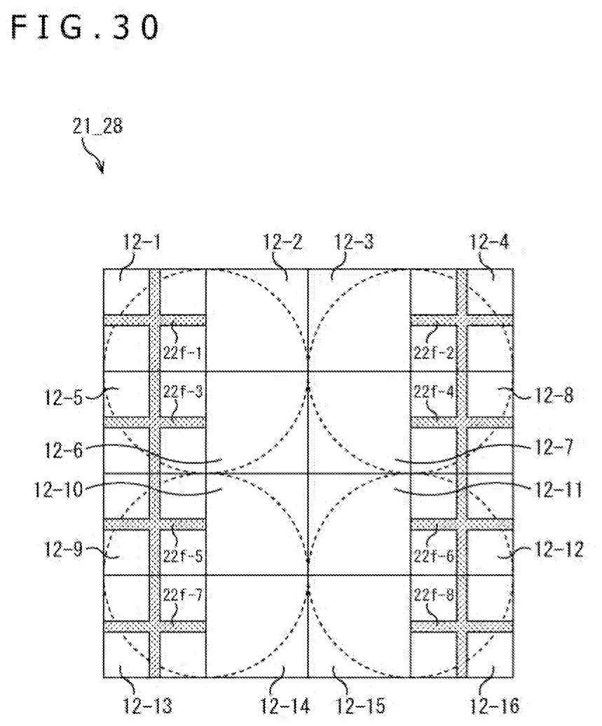

FIG. 30 is a figure depicting a configuration example of a twenty-eighth sensitivity adjustment structure 21_28.

As depicted in FIG. 30, the twenty-eighth sensitivity adjustment structure 21_28 uses the intra-pixel grooves 22f with the cross shape and the enlarged structure in which lines extending in the vertical direction and the horizontal direction of a pixel 12 cross each other at the middle.

Further, similarly to the twenty-second sensitivity adjustment structure 21_22 in FIG. 24, the twenty-eighth sensitivity adjustment structure 21_28 includes an arrangement pattern in which, in the 4×4 array of the sixteen pixels 12-1 to 12-16, the intra-pixel grooves 22f with the cross shape and the enlarged structure are provided to pixels 12 arranged at the four locations on the left side and pixels 12 arranged at the four locations on the right side.

Accordingly, similarly to the twenty-second sensitivity adjustment structure 21_22, by applying the twenty-eighth sensitivity adjustment structure 21_28 to the green same-color pixel group 13Gb, more uniform sensitivity characteristics can be attained. Moreover, the twenty-eighth sensitivity adjustment structure 21_28 can more significantly contribute to sensitivity improvement owing to the intra-pixel grooves 22f with the cross shape and the enlarged structure.

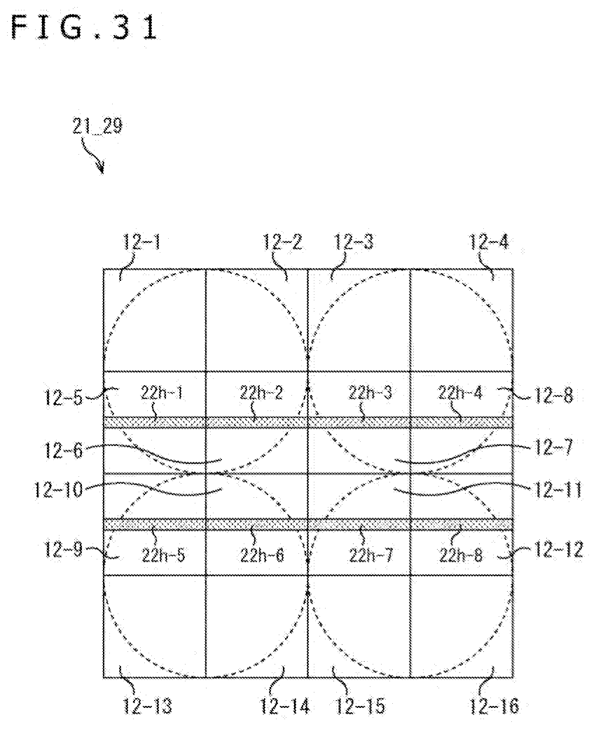

FIG. 31 is a figure depicting a configuration example of a twenty-ninth sensitivity adjustment structure 21_29.

As depicted in FIG. 31, the twenty-ninth sensitivity adjustment structure 21_29 uses the intra-pixel grooves 22h with the horizontal line shape and the enlarged structure extending in the horizontal direction of a pixel 12.

Further, similarly to the twenty-third sensitivity adjustment structure 21_23 in FIG. 25, the twenty-ninth sensitivity adjustment structure 21_29 includes an arrangement pattern in which, in the 4×4 array of the sixteen pixels 12-1 to 12-16, the intra-pixel grooves 22h with the horizontal line shape and the enlarged structure are provided to pixels 12 arranged at the eight locations in the two middle rows.

Accordingly, similarly to the twenty-third sensitivity adjustment structure 21_23, by applying the twenty-ninth sensitivity adjustment structure 21_29 to the green same-color pixel group 13Gr, more uniform sensitivity characteristics can be attained. Moreover, the twenty-ninth sensitivity adjustment structure 21_29 can more significantly contribute to sensitivity improvement owing to the intra-pixel grooves 22h with the horizontal line shape and the enlarged structure.

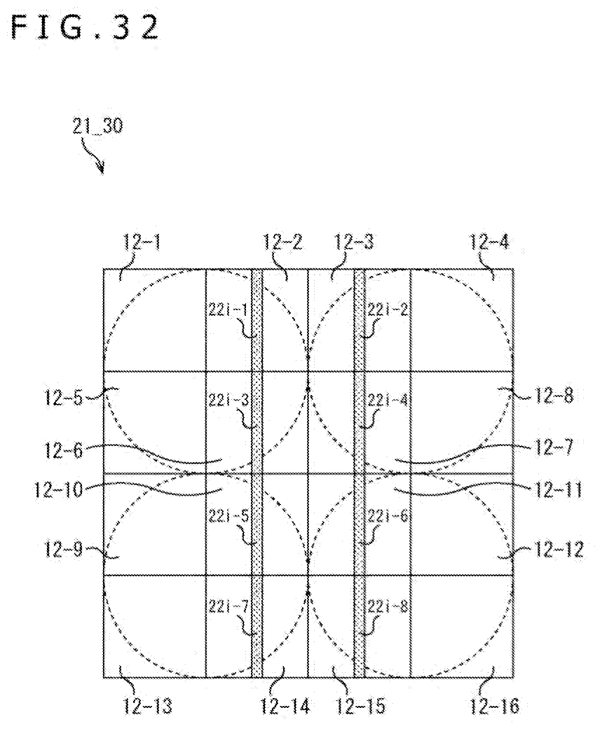

FIG. 32 is a figure depicting a configuration example of a thirtieth sensitivity adjustment structure 21_30.

As depicted in FIG. 32, the thirtieth sensitivity adjustment structure 21_30 uses the intra-pixel grooves 22i with the vertical line shape and the enlarged structure extending in the vertical direction of a pixel 12.

Further, similarly to the twenty-fourth sensitivity adjustment structure 21_24 in FIG. 26, the thirtieth sensitivity adjustment structure 21_30 includes an arrangement pattern in which, in the 4×4 array of the sixteen pixels 12-1 to 12-16, the intra-pixel grooves 22i with the vertical line shape and the enlarged structure are provided to pixels 12 arranged at the eight locations in the two middle columns.

Accordingly, similarly to the twenty-fourth sensitivity adjustment structure 21_24, by applying the thirtieth sensitivity adjustment structure 21_30 to the green same-color pixel group 13Gb, more uniform sensitivity characteristics can be attained. Moreover, the thirtieth sensitivity adjustment structure 21_30 can more significantly contribute to sensitivity improvement owing to the intra-pixel grooves 22h with the horizontal line shape and the enlarged structure.

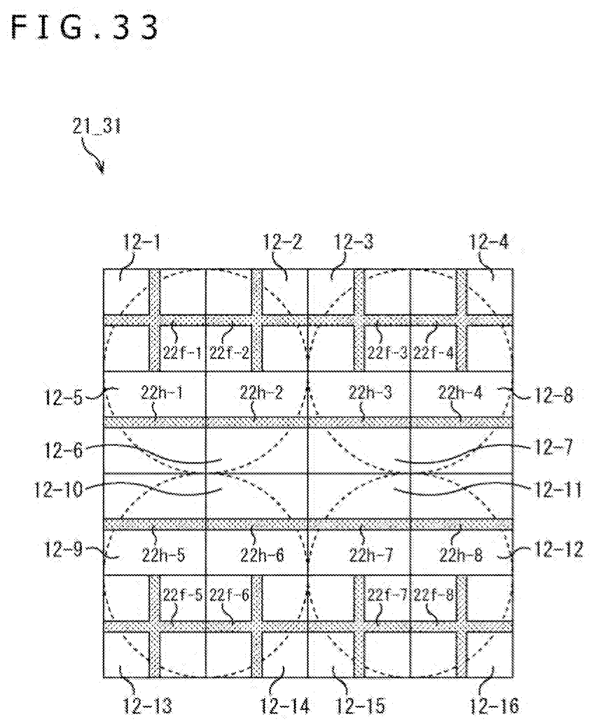

FIG. 33 is a figure depicting a configuration example of a thirty-first sensitivity adjustment structure 21_31.

As depicted in FIG. 33, the thirty-first sensitivity adjustment structure 21_31 uses the intra-pixel grooves 22f with the cross shape and the enlarged structure in which lines extending in the vertical direction and the horizontal direction of a pixel 12 cross each other at the middle, and the intra-pixel grooves 22h with the horizontal line shape and the enlarged structure extending in the horizontal direction of a pixel 12.

Further, similarly to the twenty-fifth sensitivity adjustment structure 21_25 in FIG. 27, the thirty-first sensitivity adjustment structure 21_31 includes an arrangement pattern in which, in the 4×4 array of the sixteen pixels 12-1 to 12-16, the intra-pixel grooves 22f with the cross shape and the enlarged structure are provided to pixels 12 arranged at the four locations on the upper side and pixels 12 arranged at the four locations on the lower side and the intra-pixel grooves 22h with the horizontal line shape and the enlarged structure are provided to pixels 12 arranged at the eight locations in the two middle rows.

Accordingly, similarly to the twenty-fifth sensitivity adjustment structure 21_25, by applying the thirty-first sensitivity adjustment structure 21_31 to the green same-color pixel group 13Gr, more uniform sensitivity characteristics can be attained. Moreover, the thirty-first sensitivity adjustment structure 21_31 can contribute to sensitivity improvement owing to the intra-pixel grooves 22f with the cross shape and the enlarged structure and the intra-pixel grooves 22h with the horizontal line shape and the enlarged structure.

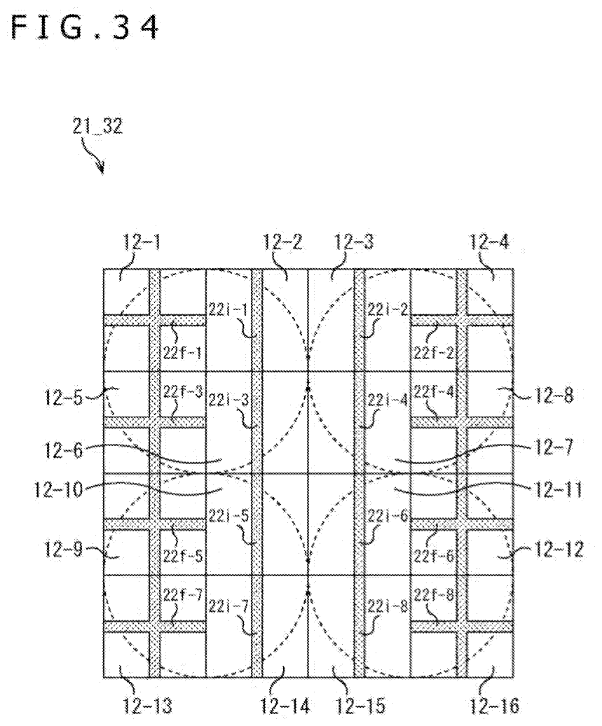

FIG. 34 is a figure depicting a configuration example of a thirty-second sensitivity adjustment structure 21_32.

As depicted in FIG. 34, the thirty-second sensitivity adjustment structure 21_32 uses the intra-pixel grooves 22f with the cross shape and the enlarged structure in which lines extending in the vertical direction and the horizontal direction of a pixel 12 cross each other at the middle, and the intra-pixel grooves 22i with the vertical line shape and the enlarged structure extending in the vertical direction of a pixel 12.

Further, similarly to the twenty-sixth sensitivity adjustment structure 21_26 in FIG. 28, the thirty-second sensitivity adjustment structure 21_32 includes an arrangement pattern in which, in the 4×4 array of the sixteen pixels 12-1 to 12-16, the intra-pixel grooves 22f with the cross shape and the enlarged structure are provided to pixels 12 arranged at the four locations on the left side and pixels 12 arranged at the four locations on the right side and the intra-pixel grooves 22i with the vertical line shape and the enlarged structure are provided to pixels 12 arranged at the eight locations in the two middle columns.

Accordingly, similarly to the twenty-sixth sensitivity adjustment structure 21_26, by applying the thirty-second sensitivity adjustment structure 21_32 to the green same-color pixel group 13Gb, more uniform sensitivity characteristics can be attained. Moreover, the thirty-second sensitivity adjustment structure 21_32 can contribute to sensitivity improvement owing to the intra-pixel grooves 22f with the cross shape and the enlarged structure and the intra-pixel grooves 22i with the vertical line shape and the enlarged structure.

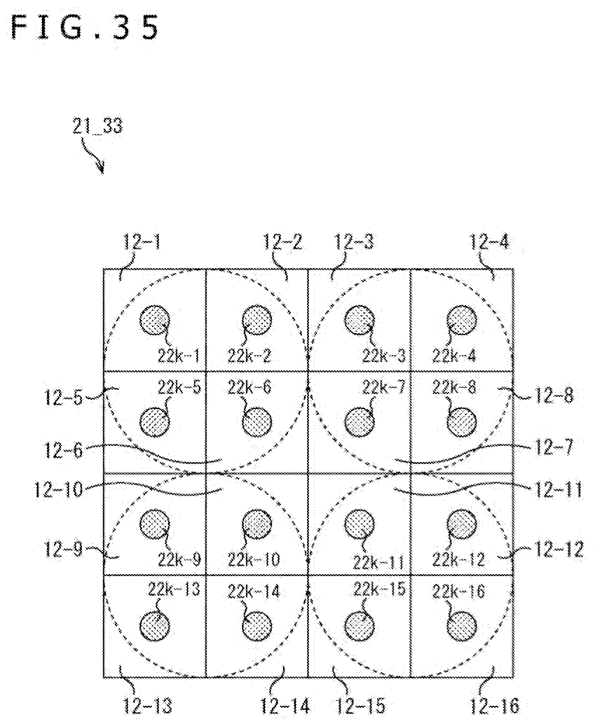

FIG. 35 is a figure depicting a configuration example of a thirty-third sensitivity adjustment structure 21_33.

As depicted in FIG. 35, the thirty-third sensitivity adjustment structure 21_33 uses intra-pixel grooves 22k with an approximately circular dot shape. For example, the intra-pixel grooves 22k with the dot shape have a function of significantly improving the sensitivity of pixels 12 provided with the intra-pixel grooves 22k with the dot shape, as a result of being able to more significantly scatter light and enlarge the optical path lengths. In addition, the intra-pixel grooves 22k with the dot shape have a function of improving the sensitivity of other pixels 12 vertically, horizontally, and obliquely adjacent to the pixels 12 provided with the intra-pixel grooves 22k with the dot shape, as a result of incidence of the scattered light on those adjacent pixels 12, and can solve stepwise differences of the sensitivity of the pixels 12 provided with the intra-pixel grooves 22k with the dot shape from the sensitivity of those adjacent pixels 12.

The thirty-third sensitivity adjustment structure 21_33 includes an arrangement pattern in which the intra-pixel grooves 22k with the dot shape are provided to all the sixteen pixels 12-1 to 12-16 in the 4×4 array at approximately middle positions of the pixels 12. That is, in the thirty-third sensitivity adjustment structure 21_33, intra-pixel grooves 22k-1 to 22k-16 with the dot shape are provided at respective approximately middle positions of the pixels 12-1 to 12-16.

Accordingly, by applying the thirty-third sensitivity adjustment structure 21_33 to a same-color pixel group 13, it is possible to attempt to improve the overall sensitivity of the same-color pixel group 13.

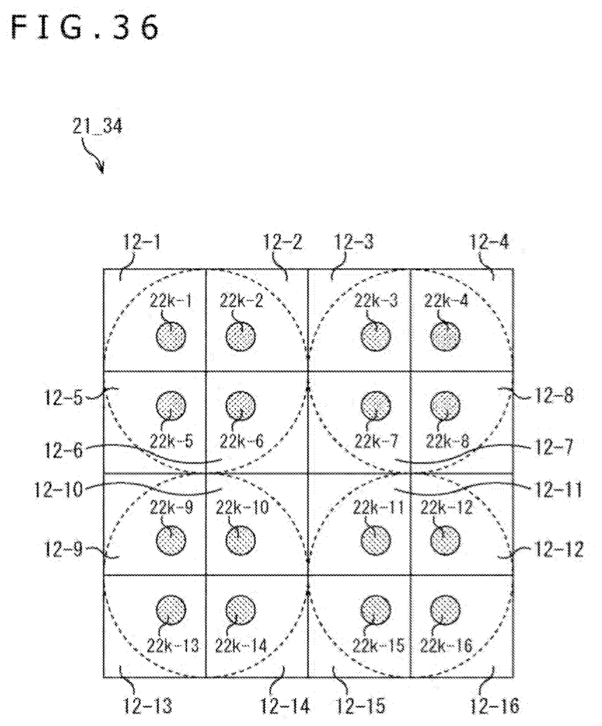

FIG. 36 is a figure depicting a configuration example of a thirty-fourth sensitivity adjustment structure 21_34.

As depicted in FIG. 36, the thirty-fourth sensitivity adjustment structure 21_34 uses the intra-pixel grooves 22k with the approximately circular dot shape.

The thirty-fourth sensitivity adjustment structure 21_34 includes an arrangement pattern in which the intra-pixel grooves 22k with the dot shape are provided to all the sixteen pixels 12-1 to 12-16 in the 4×4 array at positions shifted in directions from the middles of the pixels 12 toward the central axes of the on-chip lenses 14. That is, in the thirty-fourth sensitivity adjustment structure 21_34, the intra-pixel grooves 22k-1 to 22k-16 with the dot shape are provided at the positions shifted in the directions from the respective middles of the pixels 12-1 to 12-16 toward the central axes of the respectively corresponding on-chip lenses 14.

For example, in the pixel 21-1 arranged on the upper left side of the on-chip lens 14, the intra-pixel groove 22k-1 with the dot shape is provided at a position shifted in the lower right direction from the middle of the pixel 21-1 toward the central axis of the on-chip lens 14. Similarly, in the pixel 21-2 arranged on the upper right side of the on-chip lens 14, the intra-pixel groove 22k-2 with the dot shape is provided at a position shifted in the lower left direction from the middle of the pixel 21-2 toward the central axis of the on-chip lens 14. In addition, in the pixel 21-5 arranged on the lower left side of the on-chip lens 14, the intra-pixel groove 22k-5 with the dot shape is provided at a position shifted in the upper right direction from the middle of the pixel 21-5 toward the central axis of the on-chip lens 14. Similarly, in the pixel 21-6 arranged on the lower right side of the on-chip lens 14, the intra-pixel groove 22k-6 with the dot shape is provided at a position shifted in the upper left direction from the middle of the pixel 21-6 toward the central axis of the on-chip lens 14.

Accordingly, by applying the thirty-fourth sensitivity adjustment structure 21_34 to a same-color pixel group 13, it is possible to attempt to improve the overall sensitivity of the same-color pixel group 13. In particular, the thirty-fourth sensitivity adjustment structure 21_34 can scatter light efficiently and improve the sensitivity by arranging the intra-pixel grooves 22k with the dot shape at the positions shifted in the directions from the middles of the pixels 21 toward the central axes of the on-chip lenses 14.

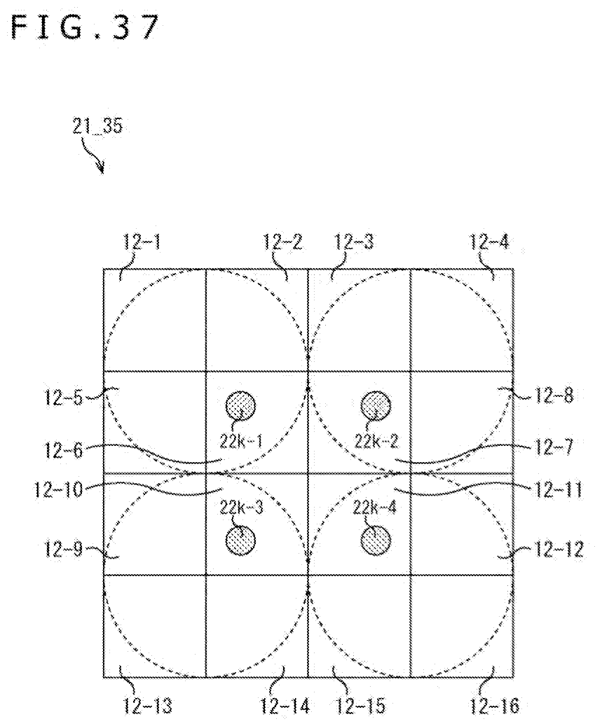

FIG. 37 is a figure depicting a configuration example of a thirty-fifth sensitivity adjustment structure 21_35.

As depicted in FIG. 37, the thirty-fifth sensitivity adjustment structure 21_35 uses the intra-pixel grooves 22k with the approximately circular dot shape.

The thirty-fifth sensitivity adjustment structure 21_35 includes an arrangement pattern in which, in the 4×4 array of the sixteen pixels 12-1 to 12-16, the intra-pixel grooves 22k with the dot shape are provided to pixels 12 arranged at the four locations in the middle 2×2 array, at positions shifted in directions from the middles of the pixels 12 toward the central axes of the on-chip lenses 14.

That is, in the thirty-fifth sensitivity adjustment structure 21_35, the intra-pixel groove 22k-1 with the dot shape is provided at a position shifted in the upper left direction from the middle of the pixel 21-6 toward the central axis of the on-chip lens 14, and the intra-pixel groove 22k-2 with the dot shape is provided at a position shifted in the upper right direction from the middle of the pixel 12-7 toward the central axis of the on-chip lens 14. Moreover, the intra-pixel groove 22k-3 with the dot shape is provided at a position shifted in the lower left direction from the middle of the pixel 12-10 toward the central axis of the on-chip lens 14, and the intra-pixel groove 22k-4 with the dot shape is provided at a position shifted in the lower right direction from the middle of the pixel 12-11 toward the central axis of the on-chip lens 14.

Accordingly, by applying the thirty-fifth sensitivity adjustment structure 21_35 to the red same-color pixel group 13R and the blue same-color pixel group 13B, it is possible to attempt to improve the sensitivity of the pixels 12 that are arranged at the four locations in the middle 2×2 array and that tend to have low sensitivity. As a result, the image-capturing element 11 can suppress inter-pixel-12 sensitivity differences in the red same-color pixel group 13R and the blue same-color pixel group 13B, and attain more uniform sensitivity characteristics.

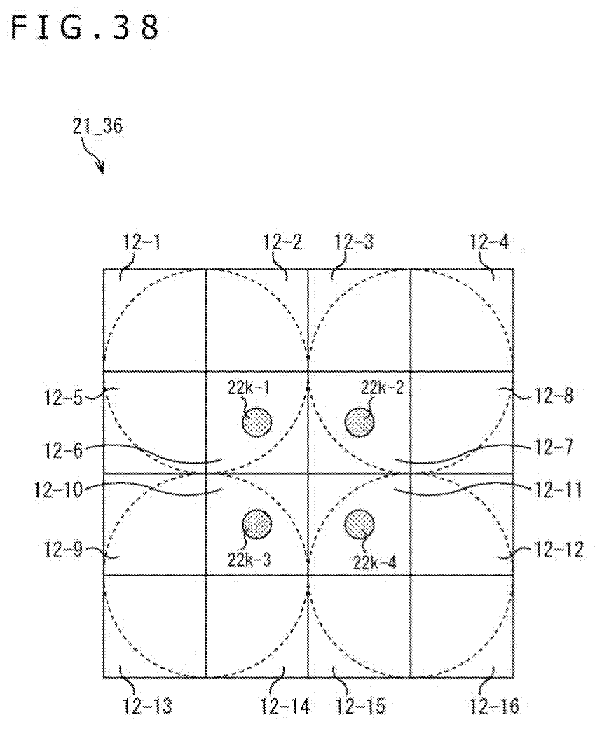

FIG. 38 is a figure depicting a configuration example of a thirty-sixth sensitivity adjustment structure 21_36. As depicted in FIG. 38, the thirty-sixth sensitivity adjustment structure 21_36 uses the intra-pixel grooves 22k with the approximately circular dot shape.

The thirty-sixth sensitivity adjustment structure 21_36 includes an arrangement pattern in which, in the 4×4 array of the sixteen pixels 12-1 to 12-16, the intra-pixel grooves 22k with the dot shape are provided to pixels 12 arranged at the four locations in the middle 2×2 array, at approximately middle positions of the pixels 12. That is, in the thirty-sixth sensitivity adjustment structure 21_36, the intra-pixel groove 22k-1 with the dot shape is provided at an approximately middle position of the pixel 21-6, the intra-pixel groove 22k-2 with the dot shape is provided at an approximately middle position of the pixel 12-7, the intra-pixel groove 22k-3 with the dot shape is provided at an approximately middle position of the pixel 12-10, and the intra-pixel groove 22k-4 with the dot shape is provided at an approximately middle position of the pixel 12-11.

Accordingly, by applying the thirty-sixth sensitivity adjustment structure 21_36 to the red same-color pixel group 13R and the blue same-color pixel group 13B, it is possible to attempt to improve the sensitivity of the pixels 12 that are arranged at the four locations in the middle 2×2 array and that tend to have low sensitivity. As a result, the image-capturing element 11 can suppress inter-pixel-12 sensitivity differences in the red same-color pixel group 13R and the blue same-color pixel group 13B, and attain more uniform sensitivity characteristics.

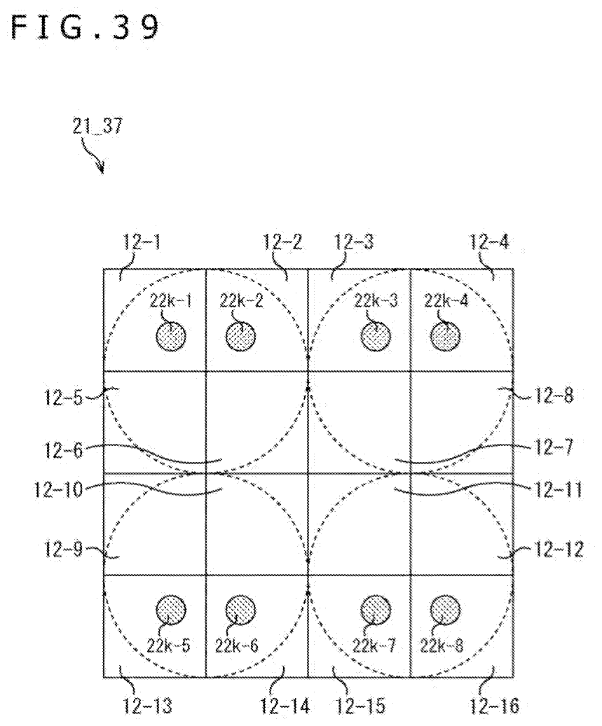

FIG. 39 is a figure depicting a configuration example of a thirty-seventh sensitivity adjustment structure 21_37.

As depicted in FIG. 39, the thirty-seventh sensitivity adjustment structure 21_37 uses the intra-pixel grooves 22k with the approximately circular dot shape.

The thirty-seventh sensitivity adjustment structure 21_37 includes an arrangement pattern in which, in the 4×4 array of the sixteen pixels 12-1 to 12-16, the intra-pixel grooves 22k with the dot shape are provided to pixels 12 arranged at the four locations on the upper side and pixels 12 arranged at the four locations on the lower side, at positions shifted in directions from the middles of the pixels 12 toward the central axes of the on-chip lenses 14.

That is, in the thirty-seventh sensitivity adjustment structure 21_37, the intra-pixel groove 22k-1 with the dot shape is provided at a position shifted in the lower right direction from the middle of the pixel 21-1 toward the central axis of the on-chip lens 14, and the intra-pixel groove 22k-2 with the dot shape is provided at a position shifted in the lower left direction from the middle of the pixel 21-2 toward the central axis of the on-chip lens 14. Moreover, the intra-pixel groove 22k-3 with the dot shape is provided at a position shifted in the lower right direction from the middle of the pixel 21-3 toward the central axis of the on-chip lens 14, and the intra-pixel groove 22k-4 with the dot shape is provided at a position shifted in the lower left direction from the middle of the pixel 21-4 toward the central axis of the on-chip lens 14. Moreover, the intra-pixel groove 22k-5 with the dot shape is provided at a position shifted in the upper right direction from the middle of the pixel 21-13 toward the central axis of the on-chip lens 14, and the intra-pixel groove 22k-6 with the dot shape is provided at a position shifted in the upper left direction from the middle of the pixel 21-14 toward the central axis of the on-chip lens 14. Moreover, the intra-pixel groove 22k-7 with the dot shape is provided at a position shifted in the upper right direction from the middle of the pixel 21-15 toward the central axis of the on-chip lens 14, and the intra-pixel groove 22k-8 with the dot shape is provided at a position shifted in the upper left direction from the middle of the pixel 21-16 toward the central axis of the on-chip lens 14.

Accordingly, by applying the thirty-seventh sensitivity adjustment structure 21_37 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. As a result, the image-capturing element 11 can suppress inter-pixel-12 sensitivity differences in the green same-color pixel group 13Gr, and attain more uniform sensitivity characteristics.

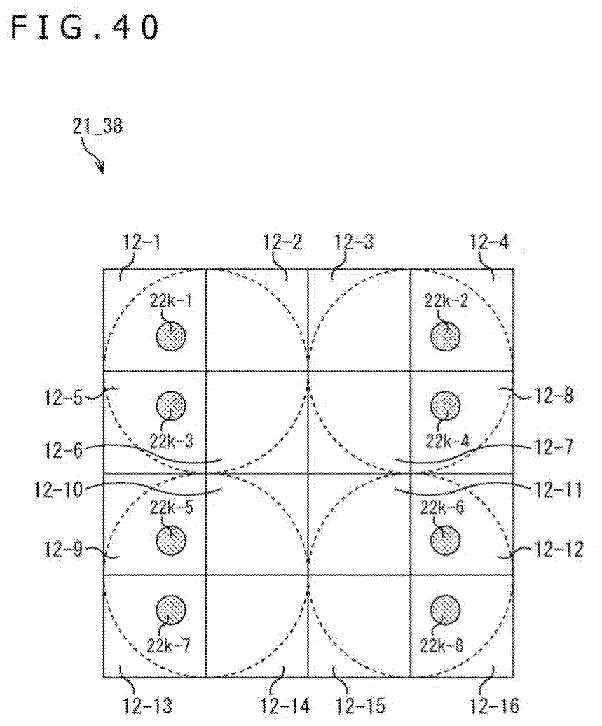

FIG. 40 is a figure depicting a configuration example of a thirty-eighth sensitivity adjustment structure 21_38.

As depicted in FIG. 40, the thirty-eighth sensitivity adjustment structure 21_38 uses the intra-pixel grooves 22k with the approximately circular dot shape.

The thirty-eighth sensitivity adjustment structure 21_38 includes an arrangement pattern in which, in the 4×4 array of the sixteen pixels 12-1 to 12-16, the intra-pixel grooves 22k with the dot shape are provided to pixels 12 arranged at the four locations on the left side and pixels 12 arranged at the four locations on the right side, at positions shifted in directions from the middles of the pixels 12 toward the central axes of the on-chip lenses 14.

That is, in the thirty-eighth sensitivity adjustment structure 21_38, the intra-pixel groove 22k-1 with the dot shape is provided at a position shifted in the lower right direction from the middle of the pixel 21-1 toward the central axis of the on-chip lens 14, and the intra-pixel groove 22k-2 with the dot shape is provided at a position shifted in the lower left direction from the middle of the pixel 21-4 toward the central axis of the on-chip lens 14. Moreover, the intra-pixel groove 22k-3 with the dot shape is provided at a position shifted in the upper right direction from the middle of the pixel 21-5 toward the central axis of the on-chip lens 14, and the intra-pixel groove 22k-4 with the dot shape is provided at a position shifted in the upper left direction from the middle of the pixel 21-8 toward the central axis of the on-chip lens 14. Moreover, the intra-pixel groove 22k-5 with the dot shape is provided at a position shifted in the lower right direction from the middle of the pixel 21-9 toward the central axis of the on-chip lens 14, and the intra-pixel groove 22k-6 with the dot shape is provided at a position shifted in the lower left direction from the middle of the pixel 21-12 toward the central axis of the on-chip lens 14. Moreover, the intra-pixel groove 22k-7 with the dot shape is provided at a position shifted in the upper right direction from the middle of the pixel 21-13 toward the central axis of the on-chip lens 14, and the intra-pixel groove 22k-8 with the dot shape is provided at a position shifted in the upper left direction from the middle of the pixel 21-16 toward the central axis of the on-chip lens 14.

Accordingly, by applying the thirty-eighth sensitivity adjustment structure 21_38 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. As a result, the image-capturing element 11 can suppress inter-pixel-12 sensitivity differences in the green same-color pixel group 13Gb, and attain more uniform sensitivity characteristics.

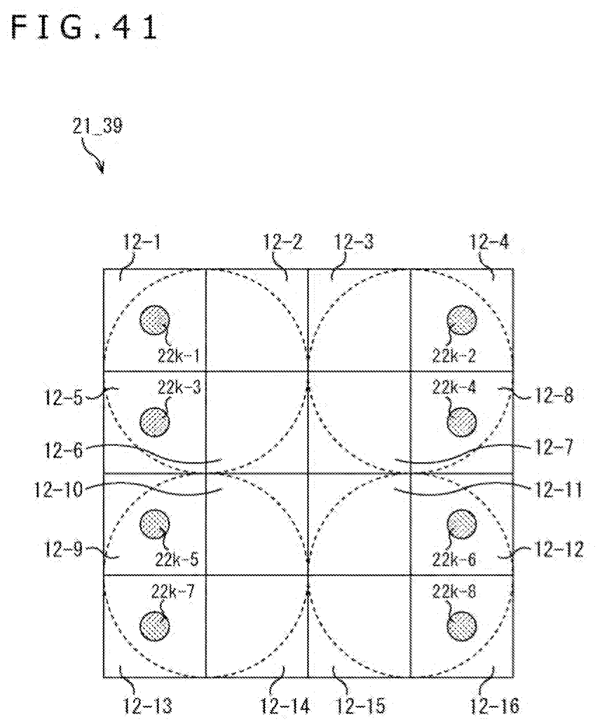

FIG. 41 is a figure depicting a configuration example of a thirty-ninth sensitivity adjustment structure 21_39.

As depicted in FIG. 41, the thirty-ninth sensitivity adjustment structure 21_39 uses the intra-pixel grooves 22k with the approximately circular dot shape.

The thirty-ninth sensitivity adjustment structure 21_39 includes an arrangement pattern in which, in the 4×4 array of the sixteen pixels 12-1 to 12-16, the intra-pixel grooves 22k with the dot shape are provided to pixels 12 arranged at the four locations on the left side and pixels 12 arranged at the four locations on the right side, at approximately middle positions of the pixels 12.

That is, in the thirty-ninth sensitivity adjustment structure 21_39, the intra-pixel groove 22k-1 with the dot shape is provided at an approximately middle position of the pixel 21-1, and the intra-pixel groove 22k-2 with the dot shape is provided at an approximately middle position of the pixel 21-4. Moreover, the intra-pixel groove 22k-3 with the dot shape is provided at an approximately middle position of the pixel 21-5, and the intra-pixel groove 22k-4 with the dot shape is provided at an approximately middle position of the pixel 21-8. Moreover, the intra-pixel groove 22k-5 with the dot shape is provided at an approximately middle position of the pixel 21-9, and the intra-pixel groove 22k-6 with the dot shape is provided at an approximately middle position of the pixel 21-12. Moreover, the intra-pixel groove 22k-7 with the dot shape is provided at an approximately middle position of the pixel 21-13, and the intra-pixel groove 22k-8 with the dot shape is provided at an approximately middle position of the pixel 21-16.

Accordingly, by applying the thirty-ninth sensitivity adjustment structure 21_39 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. As a result, the image-capturing element 11 can suppress inter-pixel-12 sensitivity differences in the green same-color pixel group 13Gb, and attain more uniform sensitivity characteristics.

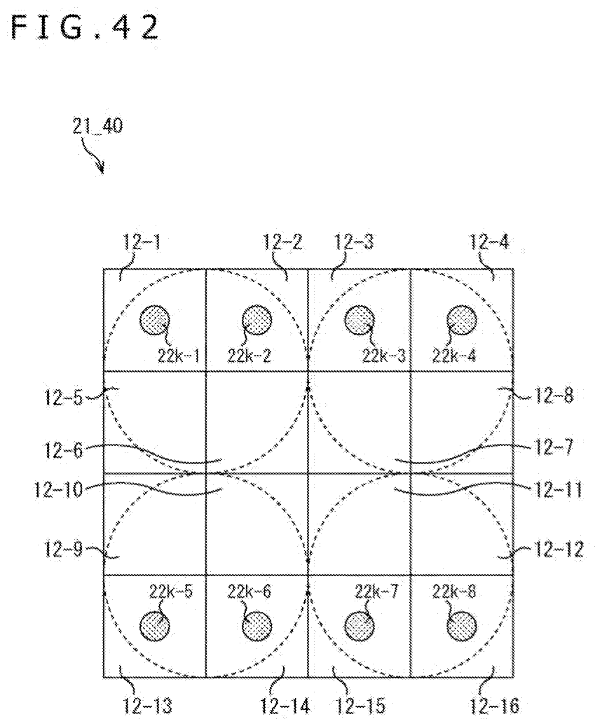

FIG. 42 is a figure depicting a configuration example of a fortieth sensitivity adjustment structure 21_40.

As depicted in FIG. 42, the fortieth sensitivity adjustment structure 21_40 uses the intra-pixel grooves 22k with the approximately circular dot shape.

The fortieth sensitivity adjustment structure 21_40 includes an arrangement pattern in which, in the 4×4 array of the sixteen pixels 12-1 to 12-16, the intra-pixel grooves 22k with the dot shape are provided to pixels 12 arranged at the four locations on the upper side and pixels 12 arranged at the four locations on the lower side, at approximately middle positions of the pixels 12. That is, in the fortieth sensitivity adjustment structure 21_40, the intra-pixel grooves 22k-1 to 22k-4 with the dot shape are provided to the pixels 12-1 to 12-4, respectively, and the intra-pixel grooves 22k-5 to 22k-8 with the dot shape are provided to the pixels 12-13 to 12-16, respectively.

Accordingly, by applying the fortieth sensitivity adjustment structure 21_40 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. As a result, the image-capturing element 11 can suppress inter-pixel-12 sensitivity differences in the green same-color pixel group 13Gr, and attain more uniform sensitivity characteristics.

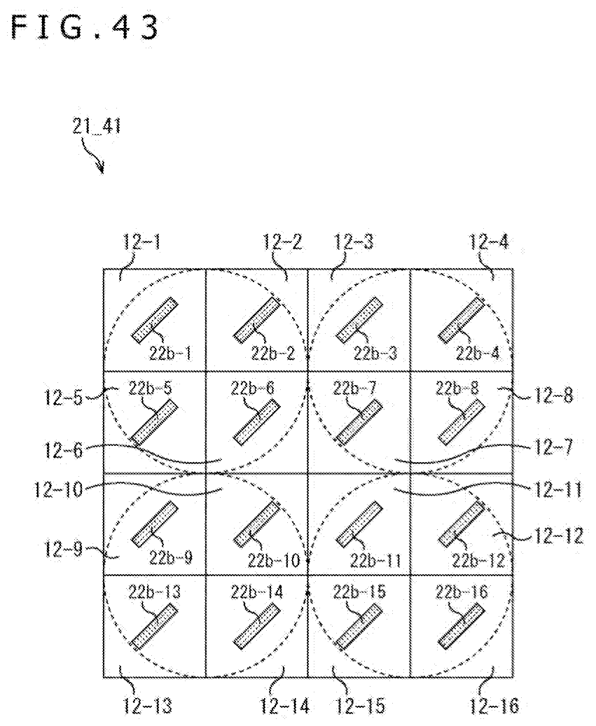

FIG. 43 is a figure depicting a configuration example of a forty-first sensitivity adjustment structure 21_41.

As depicted in FIG. 43, the forty-first sensitivity adjustment structure 21_41 uses the intra-pixel grooves 22b with the diagonal line shape extending in a diagonal direction of a pixel 12.

In the forty-first sensitivity adjustment structure 21_41, intra-pixel grooves 22b-1 to 22b-16 with the diagonal line shape whose longitudinal directions extend from the upper right to the lower left are provided to all the sixteen pixels 12-1 to 12-16 in the 4×4 array.

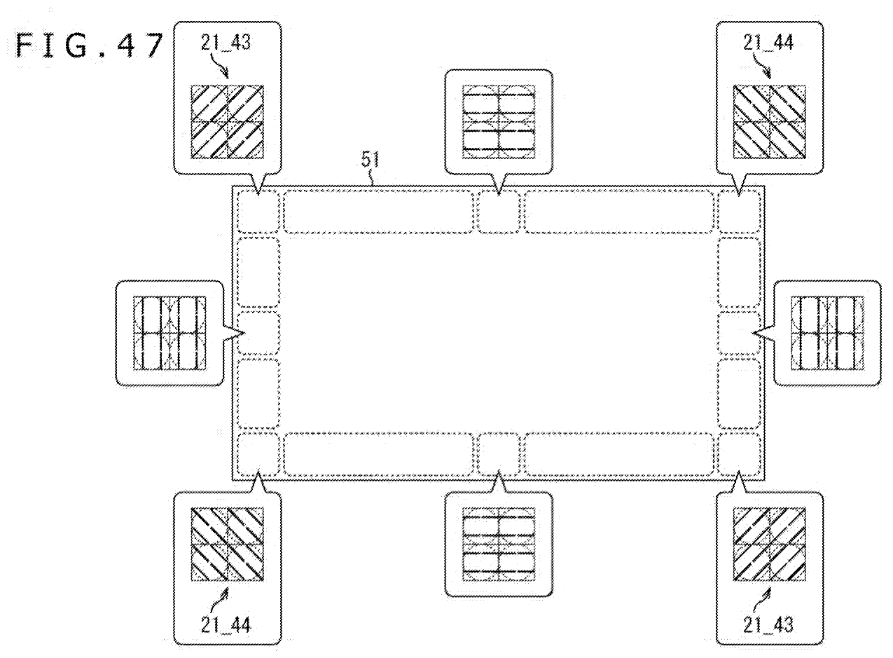

Accordingly, by applying the forty-first sensitivity adjustment structure 21_41 to the same-color pixel groups 13, the intra-pixel grooves 22b-1 to 22b-16 with the diagonal line shape scatter light in directions perpendicular to the longitudinal directions, and the scattered light is incident on pixels 12 arranged on the upper left sides or the lower right sides. As a result, for example, as explained with reference to FIG. 47 described later, variations of the overall sensitivity of a sensor surface 51 can be suppressed.

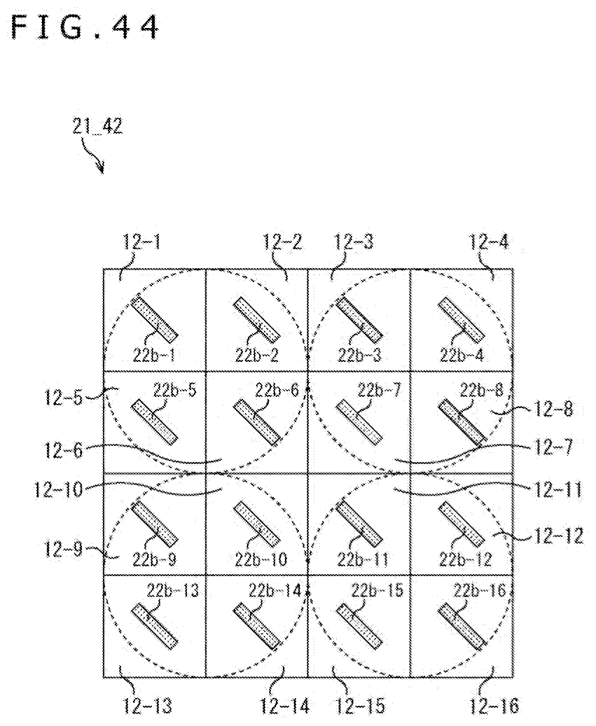

FIG. 44 is a figure depicting a configuration example of a forty-second sensitivity adjustment structure 21_42.

As depicted in FIG. 44, the forty-second sensitivity adjustment structure 21_42 uses the intra-pixel grooves 22b with the diagonal line shape extending in a diagonal direction of a pixel 12.

In the forty-second sensitivity adjustment structure 21_42, the intra-pixel grooves 22b-1 to 22b-16 with the diagonal line shape whose longitudinal directions extend from the upper left to the lower right are provided to all the sixteen pixels 12-1 to 12-16 in the 4×4 array.

Accordingly, by applying the forty-second sensitivity adjustment structure 21_42 to the same-color pixel groups 13, the intra-pixel grooves 22b-1 to 22b-16 with the diagonal line shape scatter light in directions perpendicular to the longitudinal directions, and the scattered light is incident on pixels 12 arranged on the upper right sides or the lower left sides. As a result, for example, as explained with reference to FIG. 47 described later, variations of the overall sensitivity of the sensor surface 51 can be suppressed.

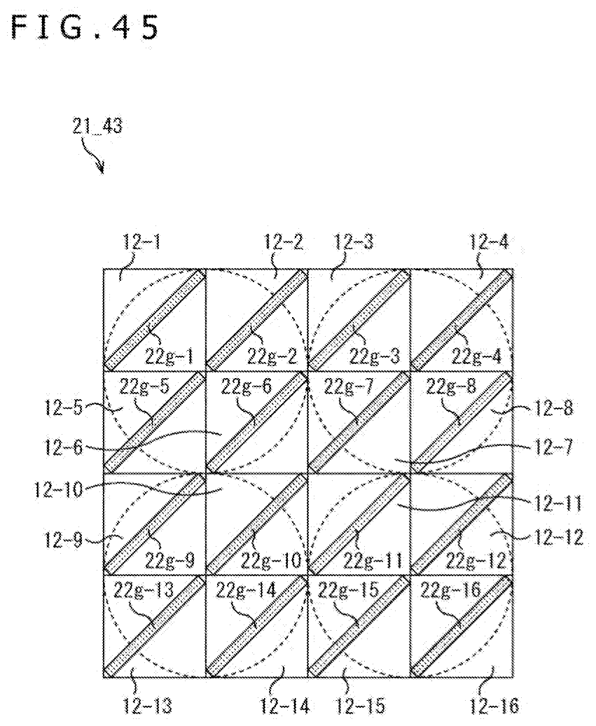

FIG. 45 is a figure depicting a configuration example of a forty-third sensitivity adjustment structure 21_43.

As depicted in FIG. 45, the forty-third sensitivity adjustment structure 21_43 uses the intra-pixel grooves 22g with the diagonal line shape and the enlarged structure extending in a diagonal direction of a pixel 12.

In the forty-third sensitivity adjustment structure 21_43, intra-pixel grooves 22g-1 to 22g-16 with the diagonal line shape and the enlarged structure whose longitudinal directions extend from the upper right to the lower left are provided to all the sixteen pixels 12-1 to 12-16 in the 4×4 array.

Accordingly, by applying the forty-third sensitivity adjustment structure 21_43 to the same-color pixel groups 13, the intra-pixel grooves 22g-1 to 22g-16 with the diagonal line shape and the enlarged structure scatter light in directions perpendicular to the longitudinal directions, and the scattered light is incident on pixels 12 arranged on the upper left sides or the lower right sides. As a result, for example, as explained with reference to FIG. 47 described later, variations of the overall sensitivity of the sensor surface 51 can be suppressed.

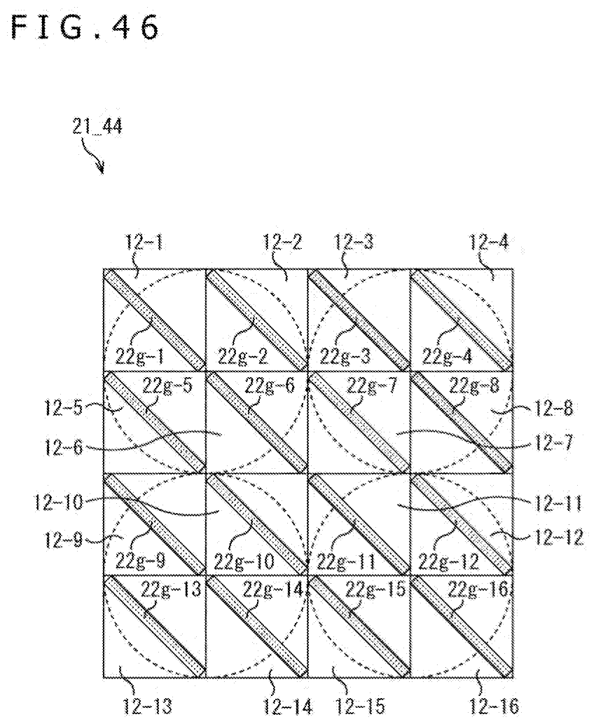

FIG. 46 is a figure depicting a configuration example of a forty-fourth sensitivity adjustment structure 21_44.

As depicted in FIG. 46, the forty-fourth sensitivity adjustment structure 21_44 uses the intra-pixel grooves 22g with the diagonal line shape and the enlarged structure extending in a diagonal direction of a pixel 12.

In the forty-fourth sensitivity adjustment structure 21_44, the intra-pixel grooves 22g-1 to 22g-16 with the diagonal line shape and the enlarged structure whose longitudinal directions extend from the upper left to the lower right are provided to all the sixteen pixels 12-1 to 12-16 in the 4×4 array.

Accordingly, by applying the forty-fourth sensitivity adjustment structure 21_44 to the same-color pixel groups 13, the intra-pixel grooves 22g-1 to 22g-16 with the diagonal line shape and the enlarged structure scatter light in directions perpendicular to the longitudinal directions, and the scattered light is incident on pixels 12 arranged on the upper right sides or the lower left sides. As a result, for example, as explained with reference to FIG. 47 described later, variations of the overall sensitivity of the sensor surface 51 can be suppressed.

Here, with reference to FIG. 47, an arrangement example of the forty-third sensitivity adjustment structure 21_43 and the forty-fourth sensitivity adjustment structure 21_44 is explained. Note that the forty-first sensitivity adjustment structure 21_41 and the forty-second sensitivity adjustment structure 21_42 also are arranged similarly.

On the sensor surface 51 as the one depicted in FIG. 47, the forty-third sensitivity adjustment structure 21_43 is arranged in an upper left corner area and a lower right corner area, and the forty-fourth sensitivity adjustment structure 21_44 is arranged in an upper right corner area and a lower left corner area.

In addition, in an area near the middle on the upper side of the sensor surface 51, the sensitivity adjustment structure 21 with the arrangement pattern in which intra-pixel grooves 22h-1 to 22h-16 with the horizontal line shape and the enlarged structure extending in the horizontal directions of the pixels 12 are provided to all the sixteen pixels 12-1 to 12-16 in the 4×4 array is arranged. Further, the sensitivity adjustment structures 21 in which the inclinations of the lines of the intra-pixel grooves 22 are adjusted such that the inclinations gradually become inclinations as those of the forty-third sensitivity adjustment structure 21_43 from the upper right to the lower left as the sensitivity adjustment structures 21 get closer to the upper left corner area of the sensor surface 51 from the area near the middle on the upper side are arranged. Similarly, the sensitivity adjustment structures 21 in which the inclinations of the lines of the intra-pixel grooves 22 are adjusted such that the inclinations gradually become inclinations as those of the forty-fourth sensitivity adjustment structure 21_44 from the upper left to the lower right as the sensitivity adjustment structures 21 get closer to the upper right corner area of the sensor surface 51 from the area near the middle on the upper side are arranged. Note that, as for the lower side of the sensor surface 51 also, the sensitivity adjustment structures 21 provided with the intra-pixel grooves 22 in which the inclinations of the lines are adjusted are arranged, similarly to the upper side of the sensor surface 51.

In addition, in an area near the middle on the left side of the sensor surface 51, same-color pixel groups 13 with arrangement patterns in which intra-pixel grooves 22i-1 to 22i-16 with the vertical line shape and the enlarged structure extending in the vertical directions of the pixels 12 are provided to all the sixteen pixels 12-1 to 12-16 in the 4×4 array are arranged. Further, the sensitivity adjustment structures 21 in which the inclinations of the lines of the intra-pixel grooves 22 are adjusted such that the inclinations gradually become inclinations as those of the forty-third sensitivity adjustment structure 21_43 from the upper right to the lower left as the sensitivity adjustment structures 21 get closer to the upper left corner area of the sensor surface 51 from the area near the middle on the left side are arranged. Similarly, the sensitivity adjustment structures 21 in which the inclinations of the lines of the intra-pixel grooves 22 are adjusted such that the inclinations gradually become inclinations as those of the forty-fourth sensitivity adjustment structure 21_44 from the upper left to the lower right as the sensitivity adjustment structures 21 get closer to the lower left corner area of the sensor surface 51 from the area near the middle on the left side are arranged. Note that, as for the right side of the sensor surface 51 also, the sensitivity adjustment structures 21 provided with the intra-pixel grooves 22 in which the inclinations of the lines are adjusted are arranged, similarly to the left side of the sensor surface 51.

By adjusting the inclinations of the lines of the intra-pixel grooves 22 according to image heights of the sensor surface 51 in such a manner, it is possible to make uniform the directionalities of projections entering at any angles of view, for incident light incident on the sensor surface 51. As a result, it is possible to suppress non-uniformity of scattering on the sensor surface 51 seen as a whole, and it is possible to suppress variations of the sensitivity of the sensor surface 51 seen as a whole.

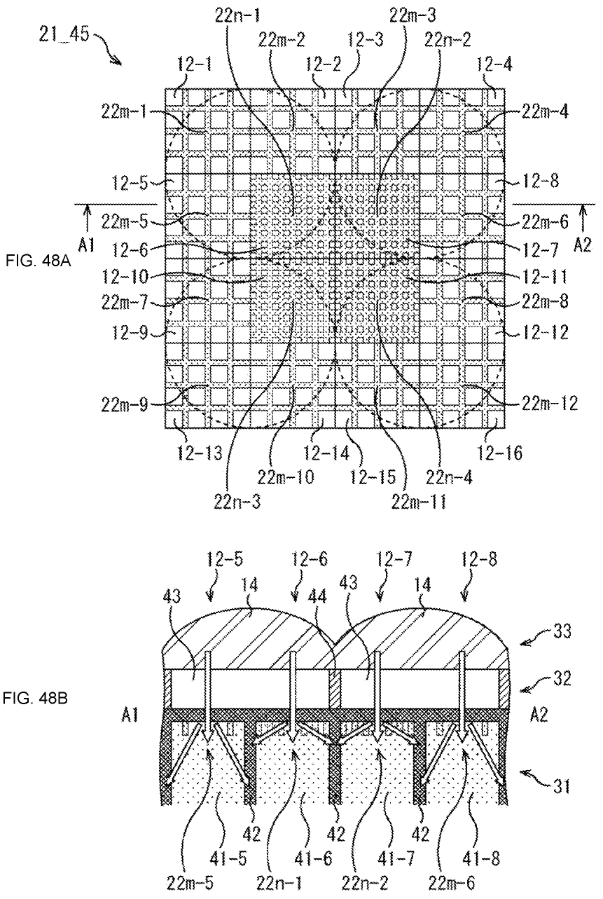

FIG. 48 is a figure depicting a configuration example of a forty-fifth sensitivity adjustment structure 21_45. A in FIG. 48 depicts the configuration example of the forty-fifth sensitivity adjustment structure 21_45 as seen in a plan view of the sixteen pixels 12-1 to 12-16 included in a same-color pixel group 13. B in FIG. 48 depicts the configuration example of the forty-fifth sensitivity adjustment structure 21_45 on a cross-section taken along A1-A2 depicted in A in FIG. 48.

As depicted in A in FIG. 48, the forty-fifth sensitivity adjustment structure 21_45 uses intra-pixel grooves 22m with a lattice shape in which multiple lines extending in the vertical direction and the horizontal direction of a pixel 12 are provided at a wide pitch, and intra-pixel grooves 22n with a lattice shape in which multiple lines extending in the vertical direction and the horizontal direction of a pixel 12 are provided at a narrow pitch.

For example, the intra-pixel grooves 22m with the lattice shape with the wide pitch and the intra-pixel grooves 22n with the lattice shape with the narrow pitch have a function of significantly improving the sensitivity of pixels 12 provided with the intra-pixel grooves 22m with the lattice shape with the wide pitch and the intra-pixel grooves 22n with the lattice shape with the narrow pitch, as a result of being able to more significantly scatter light and enlarge the optical path lengths. In addition, the intra-pixel grooves 22m with the lattice shape with the wide pitch and the intra-pixel grooves 22n with the lattice shape with the narrow pitch have a function of improving the sensitivity of other pixels 12 vertically and horizontally adjacent to the pixels 12 provided with the intra-pixel grooves 22m with the lattice shape with the wide pitch and the intra-pixel grooves 22n with the lattice shape with the narrow pitch, as a result of incidence of the light scattered by the intra-pixel grooves 22m with the lattice shape with the wide pitch and the intra-pixel grooves 22n with the lattice shape with the narrow pitch on those adjacent pixels 12.

In addition, the angle θ at which the light having been incident on the intra-pixel grooves 22m with the lattice shape with the wide pitch is scattered, and the angle θ at which the light having been incident on the intra-pixel grooves 22n with the lattice shape with the narrow pitch is scattered are represented as sin θ=mA/d, using the pitches d of the lattices, the wavelength λ of light, and an integer m. Accordingly, as represented by outline arrows in B in FIG. 48, the angle θ at which the light having been incident on the intra-pixel grooves 22m with the lattice shape with the wide pitch is scattered becomes smaller than the angle θ at which the light having been incident on the intra-pixel grooves 22n with the lattice shape with the narrow pitch is scattered.

The forty-fifth sensitivity adjustment structure 21_45 includes an arrangement pattern in which, in the 4×4 array of the sixteen pixels 12-1 to 12-16, the intra-pixel grooves 22m with the lattice shape with the wide pitch are arranged in pixels 12 arranged at the twelve peripheral locations and the intra-pixel grooves 22n with the lattice shape with the narrow pitch are provided to pixels 12 arranged at the four locations in the middle 2×2 array.

That is, in the forty-fifth sensitivity adjustment structure 21_45, intra-pixel grooves 22m-1 to 22m-5 with the lattice shape with the wide pitch are provided to the pixels 12-1 to 12-5, respectively, an intra-pixel groove 22m-6 with the lattice shape with the wide pitch is provided to the pixel 12-8, an intra-pixel groove 22m-7 with the lattice shape with the wide pitch is provided to the pixel 12-9, and intra-pixel grooves 22m-8 to 22m-12 with the lattice shape with the wide pitch are provided to the pixels 12-12 to 12-16, respectively. Moreover, an intra-pixel groove 22n-1 with the lattice shape with the narrow pitch is provided to the pixel 12-6, an intra-pixel groove 22n-2 with the lattice shape with the narrow pitch is provided to the pixel 12-7, an intra-pixel groove 22n-3 with the lattice shape with the narrow pitch is provided to the pixel 12-10, and an intra-pixel groove 22n-4 with the lattice shape with the narrow pitch is provided to the pixel 12-11.

Accordingly, by applying the forty-fifth sensitivity adjustment structure 21_45 to the red same-color pixel group 13R and the blue same-color pixel group 13B, it is possible to attempt to improve the sensitivity of the pixels 12 that are arranged at the four locations in the middle 2×2 array and that tend to have low sensitivity. That is, the intra-pixel grooves 22n with the lattice shape with the narrow pitch can improve the sensitivity of the pixels 12 arranged at the four locations in the middle 2×2 array, by scattering the light that has been incident on the pixels 12 and enlarging the optical path lengths of the light. As a result, the image-capturing element 11 can suppress inter-pixel-12 sensitivity differences in the red same-color pixel group 13R and the blue same-color pixel group 13B, and attain more uniform sensitivity characteristics. Note that it is possible to suppress color mixing by providing, at the peripheral locations, the intra-pixel grooves 22m with the lattice shape with the wide pitch that scatters the light at the small angle θ.

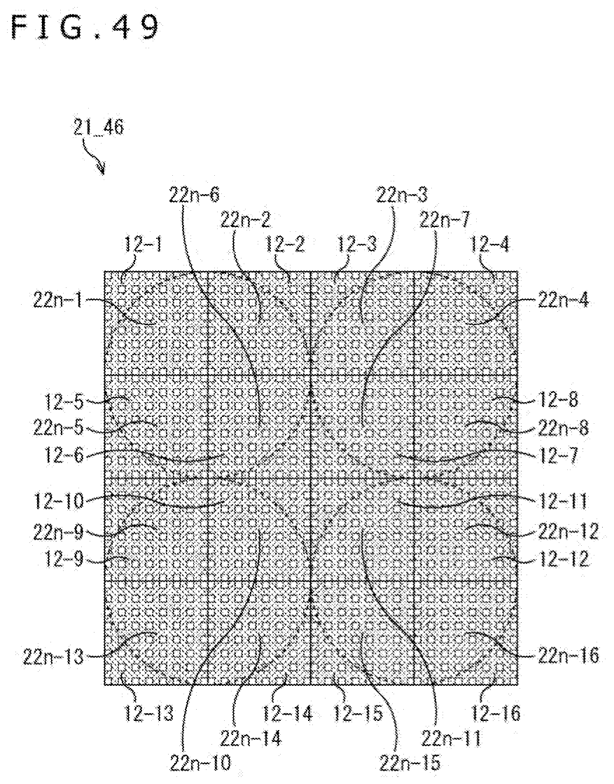

FIG. 49 is a figure depicting a configuration example of a forty-sixth sensitivity adjustment structure 21_46.

As depicted in FIG. 49, the forty-sixth sensitivity adjustment structure 21_46 uses the intra-pixel grooves 22n with the lattice shape with the narrow pitch.

The forty-sixth sensitivity adjustment structure 21_46 includes an arrangement pattern in which the intra-pixel grooves 22n with the lattice shape with the narrow pitch are provided to all the sixteen pixels 12-1 to 12-16 in the 4×4 array. That is, in the forty-sixth sensitivity adjustment structure 21_46, intra-pixel grooves 22n-1 to 22n-16 with the lattice shape with the narrow pitch are provided to the pixels 12-1 to 12-16, respectively.

Accordingly, by applying the forty-sixth sensitivity adjustment structure 21_46 to a same-color pixel group 13, it is possible to attempt to improve the overall sensitivity of the same-color pixel group 13.

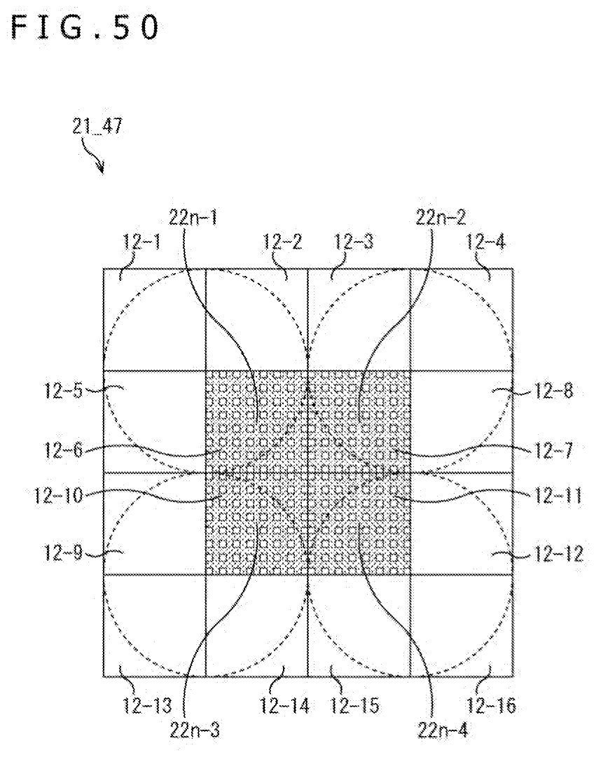

As depicted in FIG. 50, a forty-seventh sensitivity adjustment structure 21_47 uses the intra-pixel grooves 22n with the lattice shape with the narrow pitch.

The forty-seventh sensitivity adjustment structure 21_47 includes an arrangement pattern in which, in the 4×4 array of the sixteen pixels 12-1 to 12-16, the intra-pixel grooves 22n with the lattice shape with the narrow pitch are provided to pixels 12 arranged at the four locations in the middle 2×2 array. That is, in the forty-seventh sensitivity adjustment structure 21_47, the intra-pixel groove 22n-1 with the lattice shape with the narrow pitch is provided to the pixel 12-6, the intra-pixel groove 22n-2 with the lattice shape with the narrow pitch is provided to the pixel 12-7, the intra-pixel groove 22n-3 with the lattice shape with the narrow pitch is provided to the pixel 12-10, and the intra-pixel groove 22n-4 with the lattice shape with the narrow pitch is provided to the pixel 12-11.

Accordingly, by applying the forty-seventh sensitivity adjustment structure 21_47 to the red same-color pixel group 13R and the blue same-color pixel group 13B, it is possible to attempt to improve the sensitivity of the pixels 12 that are arranged at the four locations in the middle 2×2 array and that tend to have low sensitivity. That is, the intra-pixel grooves 22n with the lattice shape with the narrow pitch can improve the sensitivity of the pixels 12 arranged at the four locations in the middle 2×2 array, by scattering the light that has been incident on the pixels 12 and enlarging the optical path lengths of the light. As a result, the image-capturing element 11 can suppress inter-pixel-12 sensitivity differences in the red same-color pixel group 13R and the blue same-color pixel group 13B, and attain more uniform sensitivity characteristics.

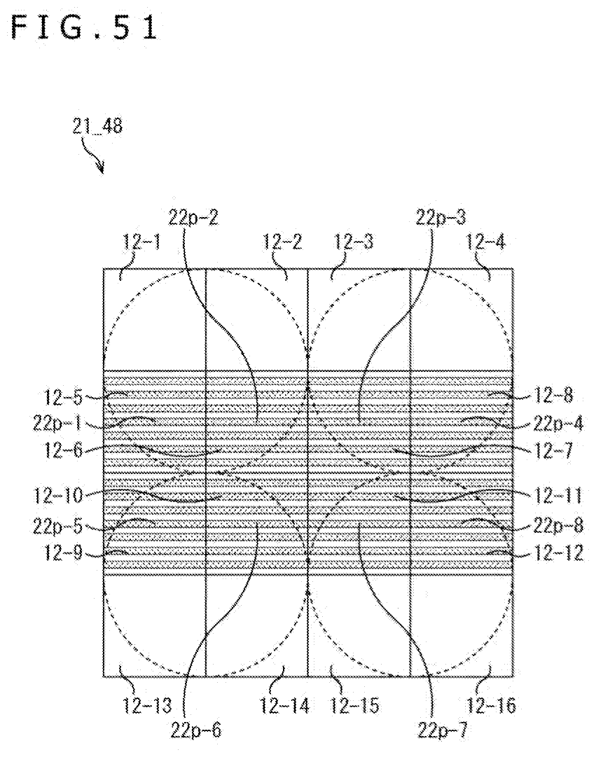

FIG. 51 is a figure depicting a configuration example of a forty-eighth sensitivity adjustment structure 21_48.

As depicted in FIG. 51, the forty-eighth sensitivity adjustment structure 21_48 uses intra-pixel grooves 22p with horizontal stripes in which multiple lines extending in the horizontal direction of a pixel 12 are provided. For example, the intra-pixel grooves 22p with the horizontal stripes have a function of improving the sensitivity of pixels 12 provided with the intra-pixel grooves 22p with the horizontal stripes, as a result of being able to more significantly scatter light and enlarge the optical path lengths. In addition, the intra-pixel grooves 22p with the horizontal stripes have a function of improving, to some extent, the sensitivity of other pixels 12 vertically adjacent to the pixels 12 provided with the intra-pixel grooves 22p with the horizontal stripes, as a result of causing the light scattered by the intra-pixel grooves 22p with the horizontal stripes to be incident on those adjacent pixels 12.

The forty-eighth sensitivity adjustment structure 21_48 includes an arrangement pattern in which, in the 4×4 array of the sixteen pixels 12-1 to 12-16, the intra-pixel grooves 22p with the horizontal stripes are provided to pixels 12 arranged at the eight locations in the two middle rows. That is, in the forty-eighth sensitivity adjustment structure 21_48, intra-pixel grooves 22p-1 to 22p-4 with the horizontal stripes are provided to the pixels 12-5 to 12-8, respectively, and intra-pixel grooves 22p-5 to 22p-8 with the horizontal stripes are provided to the pixels 12-9 to 12-12, respectively.

Accordingly, by applying the forty-eighth sensitivity adjustment structure 21_48 to the green same-color pixel group 13Gr, it is possible to attempt to improve the sensitivity of pixels 12 that are arranged at the four locations on the upper side and that tend to have low sensitivity and pixels 12 that are arranged at the four locations on the lower side and that tend to have low sensitivity. That is, the intra-pixel grooves 22p with the horizontal stripes can improve the sensitivity of the pixels 12 arranged at the four locations on the upper side and the pixels 12 arranged at the four locations on the lower side, owing to the vertical scattering of the light having been incident on the pixels 12 arranged at the eight locations in the two middle rows and incidence of the scattered light on the pixels 12 arranged at the four locations on the upper side and the pixels 12 arranged at the four locations on the lower side. As a result, the image-capturing element 11 can suppress inter-pixel-12 sensitivity differences in the green same-color pixel group 13Gr, and attain more uniform sensitivity characteristics.

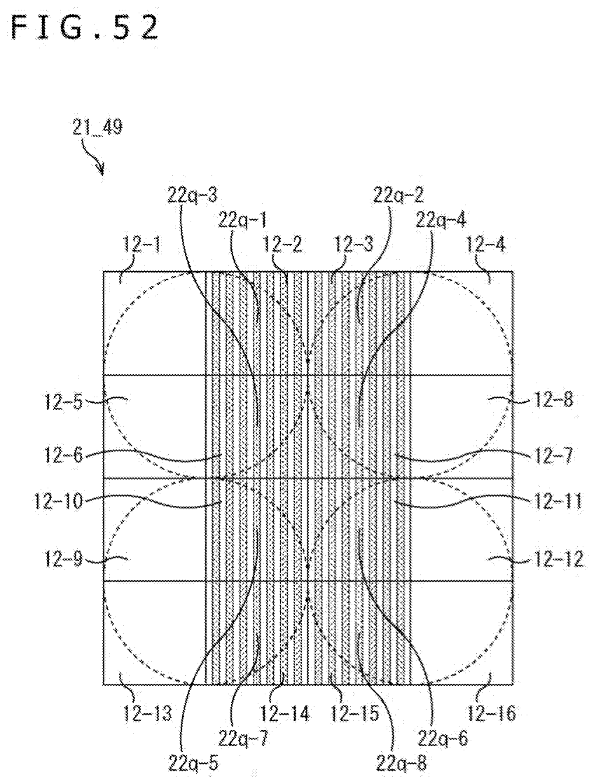

FIG. 52 is a figure depicting a configuration example of a forty-ninth sensitivity adjustment structure 21_49.

As depicted in FIG. 52, the forty-ninth sensitivity adjustment structure 21_49 uses intra-pixel grooves 22q with vertical stripes in which multiple lines extending in the vertical direction of a pixel 12 are provided. For example, the intra-pixel grooves 22q with the vertical stripes have a function of improving the sensitivity of pixels 12 provided with the intra-pixel grooves 22q with the vertical stripes, as a result of being able to scatter light and enlarge the optical path lengths. In addition, the intra-pixel grooves 22q with the vertical stripes have a function of improving, to some extent, the sensitivity of other pixels 12 horizontally adjacent to the pixels 12 provided with the intra-pixel grooves 22q with the vertical stripes, as a result of causing the light scattered by the intra-pixel grooves 22q with the vertical stripes to be incident on those adjacent pixels 12.

The forty-ninth sensitivity adjustment structure 21_49 includes an arrangement pattern in which, in the 4×4 array of the sixteen pixels 12-1 to 12-16, the intra-pixel grooves 22q with the vertical stripes are provided to pixels 12 arranged at the eight locations in the two middle columns. That is, in the forty-ninth sensitivity adjustment structure 21_49, an intra-pixel groove 22q-1 with the vertical stripes is provided to the pixel 12-2, an intra-pixel groove 22q-2 with the vertical stripes is provided to the pixel 12-3, an intra-pixel groove 22q-3 with the vertical stripes is provided to the pixel 12-6, and an intra-pixel groove 22q-4 with the vertical stripes is provided to the pixel 12-7. Moreover, an intra-pixel groove 22q-5 with the vertical stripes is provided to the pixel 12-10, an intra-pixel groove 22q-6 with the vertical stripes is provided to the pixel 12-11, an intra-pixel groove 22q-7 with the vertical stripes is provided to the pixel 12-14, and an intra-pixel groove 22q-8 with the vertical stripes is provided to the pixel 12-15.

Accordingly, by applying the forty-ninth sensitivity adjustment structure 21_49 to the green same-color pixel group 13Gb, it is possible to attempt to improve the sensitivity of pixels 12 that are arranged at the four locations on the left side and that tend to have low sensitivity and pixels 12 that are arranged at the four locations on the right side and that tend to have low sensitivity. That is, the intra-pixel grooves 22q with the vertical stripes can improve the sensitivity of the pixels 12 arranged at the four locations on the left side and the pixels 12 arranged at the four locations on the right side, owing to the horizontal scattering of the light having been incident on the pixels 12 arranged at the eight locations in the two middle columns and incidence of the scattered light on the pixels 12 arranged at the four locations on the left side and the pixels 12 arranged at the four locations on the right side. As a result, the image-capturing element 11 can suppress inter-pixel-12 sensitivity differences in the green same-color pixel group 13Gb, and attain more uniform sensitivity characteristics.

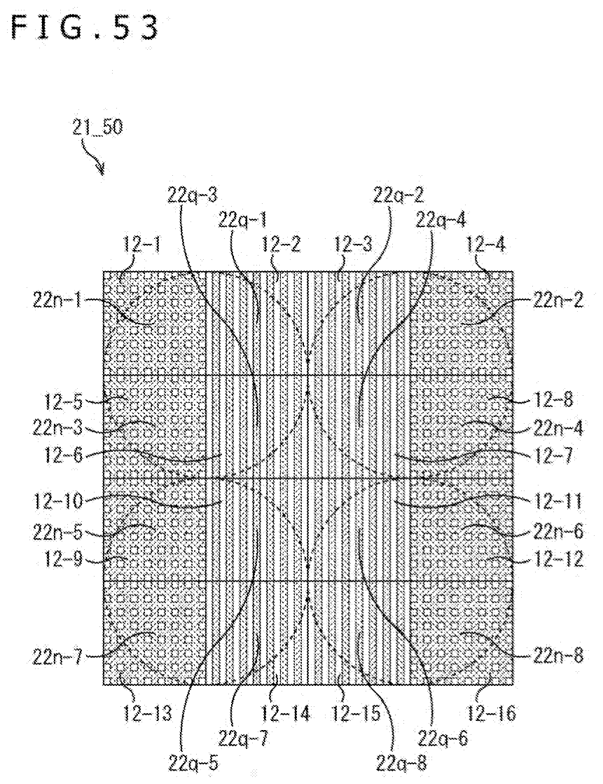

FIG. 53 is a figure depicting a configuration example of a fiftieth sensitivity adjustment structure 21_50.

As depicted in FIG. 53, the fiftieth sensitivity adjustment structure 21_50 uses the intra-pixel grooves 22n with the lattice shape in which multiple lines extending in the vertical direction and the horizontal direction of a pixel 12 are provided at a narrow pitch, and the intra-pixel grooves 22q with the vertical stripes in which multiple lines extending in the vertical direction of a pixel 12 are provided.

The fiftieth sensitivity adjustment structure 21_50 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the left side and pixels 12 arranged at the four locations on the right side and the intra-pixel grooves 22q with the vertical stripes are provided to pixels 12 arranged at the eight locations in the two middle columns.

That is, in the fiftieth sensitivity adjustment structure 21_50, the intra-pixel groove 22n-1 with the lattice shape with the narrow pitch is provided to the pixel 21-1, the intra-pixel groove 22n-2 with the lattice shape with the narrow pitch is provided to the pixel 21-4, the intra-pixel groove 22n-3 with the lattice shape with the narrow pitch is provided to the pixel 21-5, and the intra-pixel groove 22n-4 with the lattice shape with the narrow pitch is provided to the pixel 21-8. Moreover, the intra-pixel groove 22n-5 with the lattice shape with the narrow pitch is provided to the pixel 21-9, the intra-pixel groove 22n-6 with the lattice shape with the narrow pitch is provided to the pixel 21-12, the intra-pixel groove 22n-7 with the lattice shape with the narrow pitch is provided to the pixel 21-13, and the intra-pixel groove 22n-8 with the lattice shape with the narrow pitch is provided to the pixel 21-16. Moreover, the intra-pixel groove 22q-1 with the vertical stripes is provided to the pixel 12-2, the intra-pixel groove 22q-2 with the vertical stripes is provided to the pixel 12-3, the intra-pixel groove 22q-3 with the vertical stripes is provided to the pixel 12-6, and the intra-pixel groove 22q-4 with the vertical stripes is provided to the pixel 12-7. Moreover, the intra-pixel groove 22q-5 with the vertical stripes is provided to the pixel 12-10, the intra-pixel groove 22q-6 with the vertical stripes is provided to the pixel 12-11, the intra-pixel groove 22q-7 with the vertical stripes is provided to the pixel 12-14, and the intra-pixel groove 22q-8 with the vertical stripes is provided to the pixel 12-15.

Accordingly, by applying the fiftieth sensitivity adjustment structure 21_50 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. That is, the intra-pixel grooves 22q with the vertical stripes can improve the sensitivity of the pixels 12 arranged at the four locations on the left side and the pixels 12 arranged at the four locations on the right side, owing to the horizontal scattering of the light having been incident on the pixels 12 arranged at the eight locations in the two middle columns and incidence of the scattered light on the pixels 12 arranged at the four locations on the left side and the pixels 12 arranged at the four locations on the right side. Moreover, the intra-pixel grooves 22n with the lattice shape with the narrow pitch can improve the sensitivity of the pixels 12 arranged at the four locations on the left side and the pixels 12 arranged at the four locations on the right side, by scattering the light that has been incident on the pixels 12 and enlarging the optical path lengths of the light. As a result, the image-capturing element 11 can suppress inter-pixel-12 sensitivity differences in the green same-color pixel group 13Gb, and attain more uniform sensitivity characteristics.

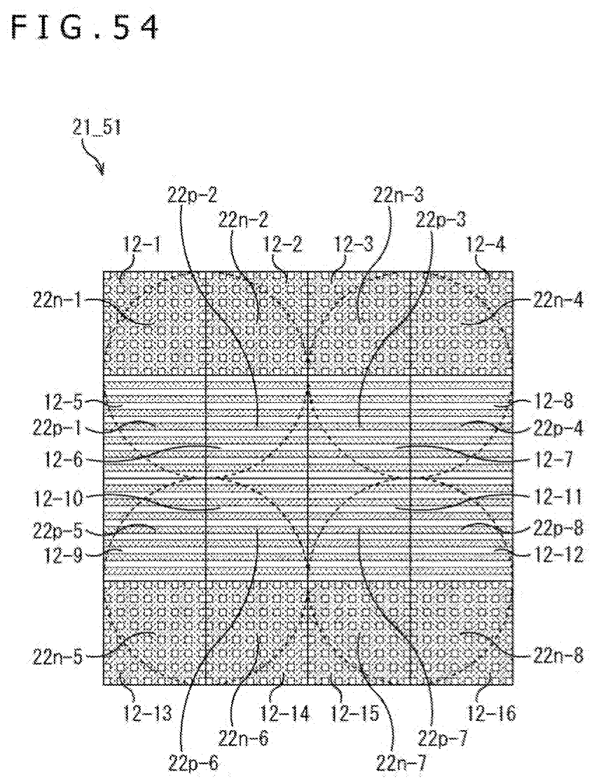

FIG. 54 is a figure depicting a configuration example of a fifty-first sensitivity adjustment structure 21_51.

As depicted in FIG. 54, the fifty-first sensitivity adjustment structure 21_51 uses the intra-pixel grooves 22n with the lattice shape in which multiple lines extending in the vertical direction and the horizontal direction of a pixel 12 are provided at a narrow pitch, and the intra-pixel grooves 22p with the horizontal stripes in which multiple lines extending in the horizontal direction of a pixel 12 are provided.

The fifty-first sensitivity adjustment structure 21_51 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the upper side and pixels 12 arranged at the four locations on the lower side and the intra-pixel grooves 22p with the horizontal stripes are provided to pixels 12 arranged at the eight locations in the two middle rows.

That is, in the fifty-first sensitivity adjustment structure 21_51, the intra-pixel grooves 22n-1 to 22n-4 with the lattice shape with the narrow pitch are provided to the pixels 12-1 to 12-4, respectively, and the intra-pixel grooves 22n-5 to 22n-8 with the lattice shape with the narrow pitch are provided to the pixels 12-13 to 12-16, respectively. Moreover, the intra-pixel grooves 22p-1 to 22p-4 with the horizontal stripes are provided to the pixels 12-5 to 12-8, respectively, and the intra-pixel grooves 22p-5 to 22p-8 with the horizontal stripes are provided to the pixels 12-9 to 12-12, respectively.

Accordingly, by applying the fifty-first sensitivity adjustment structure 21_51 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. That is, the intra-pixel grooves 22p with the horizontal stripes can improve the sensitivity of the pixels 12 arranged at the four locations on the upper side and the pixels 12 arranged at the four locations on the lower side, owing to the vertical scattering of the light having been incident on the pixels 12 arranged at the eight locations in the two middle rows and incidence of the scattered light on the pixels 12 arranged at the four locations on the upper side and the pixels 12 arranged at the four locations on the lower side. Moreover, the intra-pixel grooves 22n with the lattice shape with the narrow pitch can improve the sensitivity of the pixels 12 arranged at the four locations on the upper side and the pixels 12 arranged at the four locations on the lower side, by scattering the light that has been incident on the pixels 12 and enlarging the optical path lengths of the light. As a result, the image-capturing element 11 can suppress inter-pixel-12 sensitivity differences in the green same-color pixel group 13Gr, and attain more uniform sensitivity characteristics.

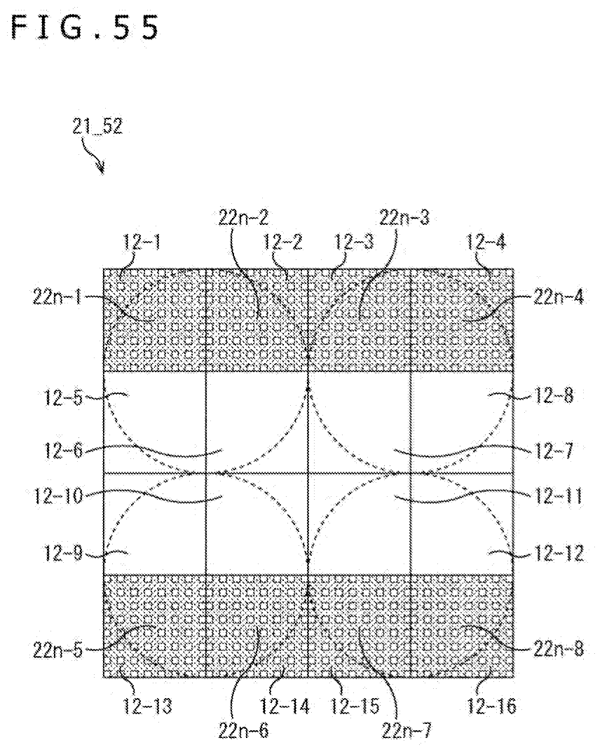

FIG. 55 is a figure depicting a configuration example of a fifty-second sensitivity adjustment structure 21_52.

As depicted in FIG. 55, the fifty-second sensitivity adjustment structure 21_52 uses the intra-pixel grooves 22n with the lattice shape in which multiple lines extending in the vertical direction and the horizontal direction of a pixel 12 are provided at a narrow pitch.

The fifty-second sensitivity adjustment structure 21_52 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the upper side and pixels 12 arranged at the four locations on the lower side.

That is, in the fifty-second sensitivity adjustment structure 21_52, the intra-pixel grooves 22n-1 to 22n-4 with the lattice shape with the narrow pitch are provided to the pixels 12-1 to 12-4, respectively, and the intra-pixel grooves 22n-5 to 22n-8 with the lattice shape with the narrow pitch are provided to the pixels 12-13 to 12-16, respectively.

Accordingly, by applying the fifty-second sensitivity adjustment structure 21_52 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. That is, the intra-pixel grooves 22n with the lattice shape with the narrow pitch can improve the sensitivity of the pixels 12 arranged at the four locations on the upper side and the pixels 12 arranged at the four locations on the lower side, by scattering the light that has been incident on the pixels 12 and enlarging the optical path lengths of the light. As a result, the image-capturing element 11 can suppress inter-pixel-12 sensitivity differences in the green same-color pixel group 13Gr, and attain more uniform sensitivity characteristics.

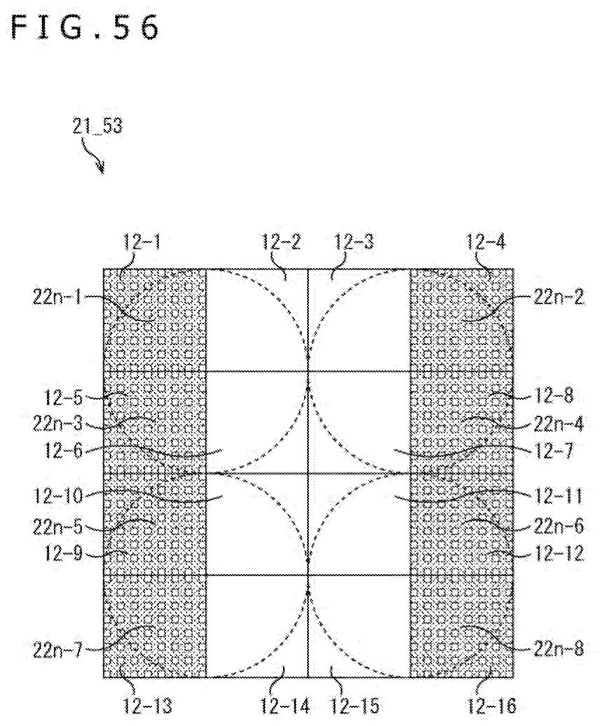

FIG. 56 is a figure depicting a configuration example of a fifty-third sensitivity adjustment structure 21_53.

As depicted in FIG. 56, the fifty-third sensitivity adjustment structure 21_53 uses the intra-pixel grooves 22n with the lattice shape in which multiple lines extending in the vertical direction and the horizontal direction of a pixel 12 are provided at a narrow pitch.

The fifty-third sensitivity adjustment structure 21_53 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the left side and pixels 12 arranged at the four locations on the right side.

That is, in the fifty-third sensitivity adjustment structure 21_53, the intra-pixel groove 22n-1 with the lattice shape with the narrow pitch is provided to the pixel 21-1, the intra-pixel groove 22n-2 with the lattice shape with the narrow pitch is provided to the pixel 21-4, the intra-pixel groove 22n-3 with the lattice shape with the narrow pitch is provided to the pixel 21-5, and the intra-pixel groove 22n-4 with the lattice shape with the narrow pitch is provided to the pixel 21-8. Moreover, the intra-pixel groove 22n-5 with the lattice shape with the narrow pitch is provided to the pixel 21-10, the intra-pixel groove 22n-6 with the lattice shape with the narrow pitch is provided to the pixel 21-12, the intra-pixel groove 22n-7 with the lattice shape with the narrow pitch is provided to the pixel 21-13, and the intra-pixel groove 22n-8 with the lattice shape with the narrow pitch is provided to the pixel 21-16.

Accordingly, by applying the fiftieth sensitivity adjustment structure 21_50 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. That is, the intra-pixel grooves 22n with the lattice shape with the narrow pitch can improve the sensitivity of the pixels 12 arranged at the four locations on the left side and the pixels 12 arranged at the four locations on the right side, by scattering the light that has been incident on the pixels 12 and enlarging the optical path lengths of the light. As a result, the image-capturing element 11 can suppress inter-pixel-12 sensitivity differences in the green same-color pixel group 13Gb, and attain more uniform sensitivity characteristics.

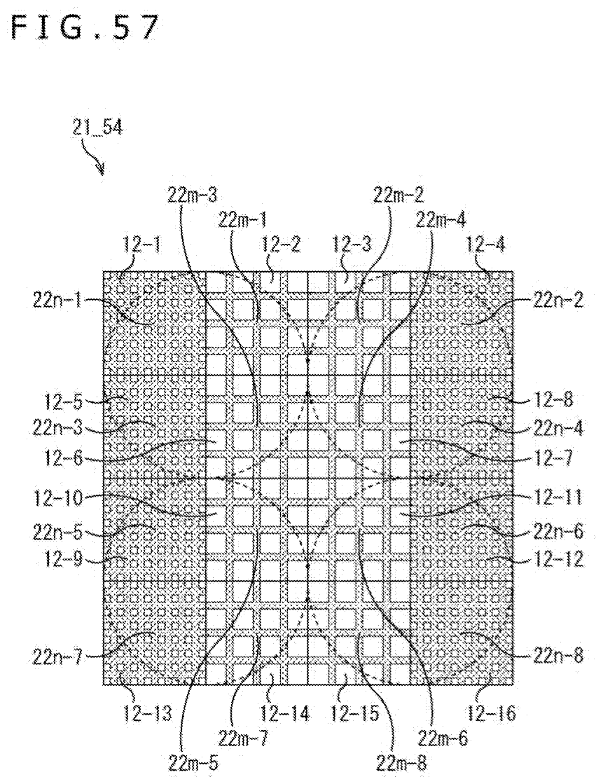

FIG. 57 is a figure depicting a configuration example of a fifty-fourth sensitivity adjustment structure 21_54.

As depicted in FIG. 57, the fifty-fourth sensitivity adjustment structure 21_54 uses the intra-pixel grooves 22m with the lattice shape in which multiple lines extending in the vertical direction and the horizontal direction of a pixel 12 are provided at a wide pitch, and the intra-pixel grooves 22n with the lattice shape in which multiple lines extending in the vertical direction and the horizontal direction of a pixel 12 are provided at a narrow pitch.

The fifty-fourth sensitivity adjustment structure 21_54 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the left side and pixels 12 arranged at the four locations on the right side and the intra-pixel grooves 22m with the lattice shape with the wide pitch are provided to pixels 12 arranged at the eight locations in the two middle columns.

That is, in the fifty-fourth sensitivity adjustment structure 21_54, the intra-pixel groove 22n-1 with the lattice shape with the narrow pitch is provided to the pixel 21-1, the intra-pixel groove 22n-2 with the lattice shape with the narrow pitch is provided to the pixel 21-4, the intra-pixel groove 22n-3 with the lattice shape with the narrow pitch is provided to the pixel 21-5, and the intra-pixel groove 22n-4 with the lattice shape with the narrow pitch is provided to the pixel 21-8. Moreover, the intra-pixel groove 22n-5 with the lattice shape with the narrow pitch is provided to the pixel 21-9, the intra-pixel groove 22n-6 with the lattice shape with the narrow pitch is provided to the pixel 21-12, the intra-pixel groove 22n-7 with the lattice shape with the narrow pitch is provided to the pixel 21-13, and the intra-pixel groove 22n-8 with the lattice shape with the narrow pitch is provided to the pixel 21-16. Moreover, the intra-pixel groove 22m-1 with the lattice shape with the wide pitch is provided to the pixel 12-2, the intra-pixel groove 22m-2 with the lattice shape with the wide pitch is provided to the pixel 12-3, the intra-pixel groove 22m-3 with the lattice shape with the wide pitch is provided to the pixel 12-6, and the intra-pixel groove 22m-4 with the lattice shape with the wide pitch is provided to the pixel 12-7. Moreover, the intra-pixel groove 22m-5 with the lattice shape with the wide pitch is provided to the pixel 12-10, the intra-pixel groove 22m-6 with the lattice shape with the wide pitch is provided to the pixel 12-11, the intra-pixel groove 22m-7 with the lattice shape with the wide pitch is provided to the pixel 12-14, and the intra-pixel groove 22m-8 with the lattice shape with the wide pitch is provided to the pixel 12-15.

Accordingly, by applying the fifty-fourth sensitivity adjustment structure 21_54 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. That is, it is possible with the intra-pixel grooves 22n with the lattice shape with the narrow pitch to significantly improve the sensitivity of the pixels 12 arranged at the four locations on the left side and the pixels 12 arranged at the four locations on the right side, and it is possible with the intra-pixel grooves 22m with the lattice shape with the wide pitch to attempt to intermediately improve the sensitivity of the pixels 12 arranged at the eight locations in the two middle columns. As a result, the image-capturing element 11 can suppress inter-pixel-12 sensitivity differences in the green same-color pixel group 13Gb, and attain more uniform sensitivity characteristics.

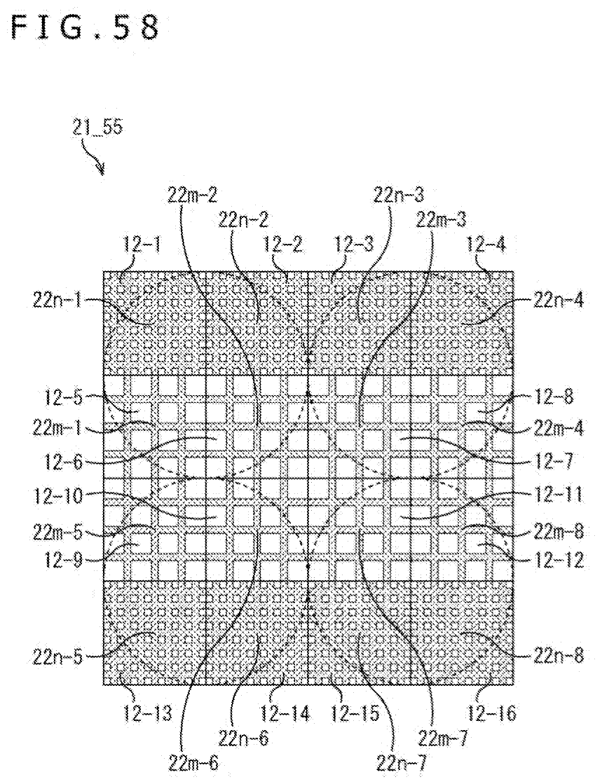

FIG. 58 is a figure depicting a configuration example of a fifty-fifth sensitivity adjustment structure 21_55.

As depicted in FIG. 58, the fifty-fifth sensitivity adjustment structure 21_55 uses the intra-pixel grooves 22m with the lattice shape in which multiple lines extending in the vertical direction and the horizontal direction of a pixel 12 are provided at a wide pitch, and the intra-pixel grooves 22n with the lattice shape in which multiple lines extending in the vertical direction and the horizontal direction of a pixel 12 are provided at a narrow pitch.

The fifty-fifth sensitivity adjustment structure 21_55 includes an arrangement pattern in which, in the 4×4 array of the sixteen pixels 12-1 to 12-16, the intra-pixel grooves 22n with the lattice shape with the narrow pitch are provided to pixels 12 arranged at the four locations on the upper side and pixels 12 arranged at the four locations on the lower side and the intra-pixel grooves 22m with the lattice shape with the wide pitch are provided to pixels 12 arranged at the eight locations in the two middle rows.

That is, in the fifty-fifth sensitivity adjustment structure 21_55, the intra-pixel grooves 22n-1 to 22n-4 with the lattice shape with the narrow pitch are provided to the pixels 12-1 to 12-4, respectively, and the intra-pixel grooves 22n-5 to 22n-8 with the lattice shape with the narrow pitch are provided to the pixels 12-13 to 12-16, respectively. Moreover, the intra-pixel grooves 22m-1 to 22m-4 with the lattice shape with the wide pitch are provided to the pixels 12-5 to 12-8, respectively, and the intra-pixel grooves 22m-5 to 22m-8 with the lattice shape with the wide pitch are provided to the pixels 12-9 to 12-12, respectively.

Accordingly, by applying the fifty-fifth sensitivity adjustment structure 21_55 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. That is, it is possible with the intra-pixel grooves 22n with the lattice shape with the narrow pitch to significantly improve the sensitivity of the pixels 12 arranged at the four locations on the upper side and the pixels 12 arranged at the four locations on the lower side, and it is possible with the intra-pixel grooves 22m with the lattice shape with the wide pitch to attempt to intermediately improve the sensitivity of the pixels 12 arranged at the eight locations in the two middle rows. As a result, the image-capturing element 11 can suppress inter-pixel-12 sensitivity differences in the green same-color pixel group 13Gr, and attain more uniform sensitivity characteristics.

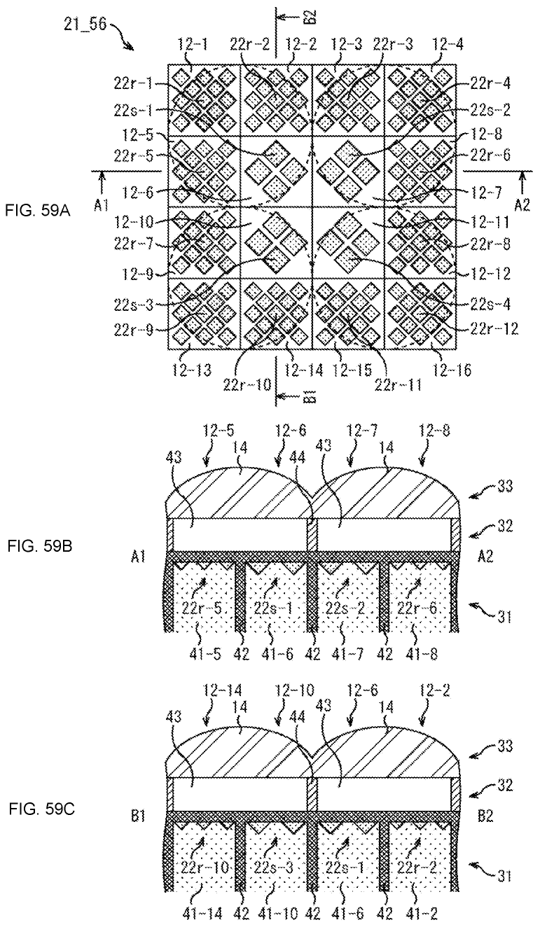

FIG. 59 is a figure depicting a configuration example of a fifty-sixth sensitivity adjustment structure 21_56. A in FIG. 59 depicts the configuration example of the fifty-sixth sensitivity adjustment structure 21_56 as seen in a plan view of the sixteen pixels 12-1 to 12-16 included in a same-color pixel group 13. B in FIG. 59 depicts a configuration example of the fifty-sixth sensitivity adjustment structure 21_56 on a cross-section taken along A1-A2 depicted in A in FIG. 59, and C in FIG. 59 depicts a configuration example of the fifty-sixth sensitivity adjustment structure 21_56 on a cross-section taken along B1-B2 depicted in

A in FIG. 59.

As depicted in FIG. 59, the fifty-sixth sensitivity adjustment structure 21_56 uses intra-pixel grooves 22r with a multi-recess shape in which a plurality of recesses are provided at a narrow pitch, and intra-pixel grooves 22s with a multi-recess shape in which multiple recesses are provided at a wide pitch. For example, multiple inverted-pyramid-shaped recesses can be formed using the regularity of crystal by performing anisotropic etching on a monocrystalline silicon.

For example, the intra-pixel grooves 22r with the multi-recess shape with the narrow pitch and the intra-pixel grooves 22s with the multi-recess shape with the wide pitch have a function of significantly improving the sensitivity of pixels 12 provided with the intra-pixel grooves 22r with the multi-recess shape with the narrow pitch and the intra-pixel grooves 22s with the multi-recess shape with the wide pitch, as a result of being able to scatter light and enlarge the optical path lengths. In addition, the intra-pixel grooves 22r with the multi-recess shape with the narrow pitch and the intra-pixel grooves 22s with the multi-recess shape with the wide pitch have a function of improving the sensitivity of other pixels 12 vertically and horizontally adjacent to the pixels 12 provided with the intra-pixel grooves 22r with the multi-recess shape with the narrow pitch and the intra-pixel grooves 22s with the multi-recess shape with the wide pitch, as a result of incidence of the light scattered by the intra-pixel grooves 22r with the multi-recess shape with the narrow pitch and the intra-pixel grooves 22s with the multi-recess shape with the wide pitch on those adjacent pixels 12.

The fifty-sixth sensitivity adjustment structure 21_56 includes an arrangement pattern in which, in the 4×4 array of the sixteen pixels 12-1 to 12-16, the intra-pixel grooves 22r with the multi-recess shape with the narrow pitch are arranged in pixels 12 arranged at the twelve peripheral locations and the intra-pixel grooves 22s with the multi-recess shape with the wide pitch are provided to pixels 12 arranged at the four locations in the middle 2×2 array.

That is, in the fifty-sixth sensitivity adjustment structure 21_56, intra-pixel grooves 22r-1 to 22r-5 with the multi-recess shape with the narrow pitch are provided to the pixels 12-1 to 12-5, respectively, an intra-pixel groove 22r-6 with the multi-recess shape with the narrow pitch is provided to the pixel 12-8, an intra-pixel groove 22r-7 with the multi-recess shape with the narrow pitch is provided to the pixel 12-9, and intra-pixel grooves 22r-8 to 22r-12 with the multi-recess shape with the narrow pitch are provided to the pixels 12-12 to 12-16, respectively. Moreover, an intra-pixel groove 22s-1 with the multi-recess shape with the wide pitch is provided to the pixel 12-6, an intra-pixel groove 22s-2 with the multi-recess shape with the wide pitch is provided to the pixel 12-7, an intra-pixel groove 22s-3 with the multi-recess shape with the wide pitch is provided to the pixel 12-10, and an intra-pixel groove 22s-4 with the multi-recess shape with the wide pitch is provided to the pixel 12-11.

Accordingly, by applying the fifty-sixth sensitivity adjustment structure 21_56 to the red same-color pixel group 13R and the blue same-color pixel group 13B, it is possible to attempt to improve the sensitivity of the pixels 12 that are arranged at the four locations in the middle 2×2 array and that tend to have low sensitivity. That is, it is possible with the intra-pixel grooves 22s with the multi-recess shape with the wide pitch to significantly improve the sensitivity of the pixels 12 arranged at the four locations in the middle 2×2 array, and it is possible with the intra-pixel grooves 22r with the multi-recess shape with the narrow pitch to attempt to intermediately improve the sensitivity of pixels 12 arranged at the twelve peripheral locations. As a result, the image-capturing element 11 can suppress inter-pixel-12 sensitivity differences in the red same-color pixel group 13R and the blue same-color pixel group 13B, and attain more uniform sensitivity characteristics.

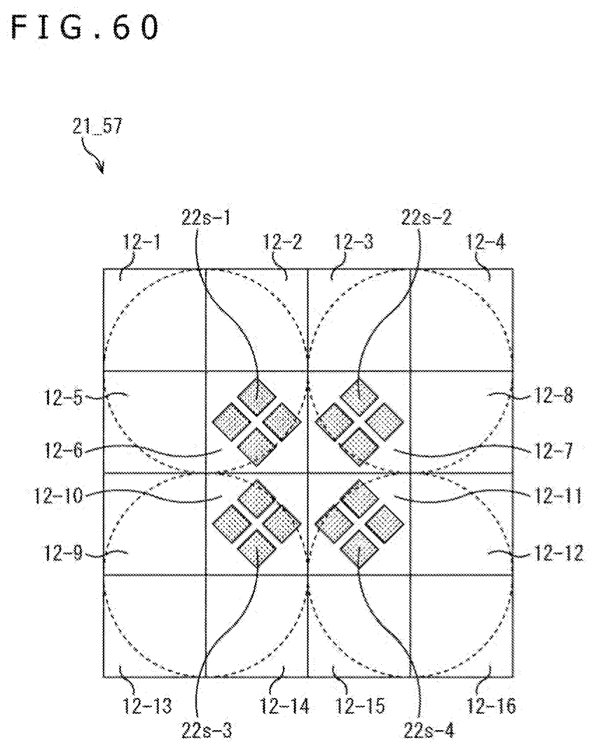

FIG. 60 is a figure depicting a configuration example of a fifty-seventh sensitivity adjustment structure 21_57.

As depicted in FIG. 60, the fifty-seventh sensitivity adjustment structure 21_57 uses the intra-pixel grooves 22s with the multi-recess shape in which multiple recesses are provided at a wide pitch.

The fifty-seventh sensitivity adjustment structure 21_57 includes an arrangement pattern in which, in the 4×4 array of the sixteen pixels 12-1 to 12-16, the intra-pixel grooves 22s with the multi-recess shape with the wide pitch are provided to pixels 12 arranged at the four locations in the middle 2×2 array. That is, in the fifty-seventh sensitivity adjustment structure 21_57, the intra-pixel groove 22s-1 with the multi-recess shape with the wide pitch is provided to the pixel 12-6, the intra-pixel groove 22s-2 with the multi-recess shape with the wide pitch is provided to the pixel 12-7, the intra-pixel groove 22s-3 with the multi-recess shape with the wide pitch is provided to the pixel 12-10, and the intra-pixel groove 22s-4 with the multi-recess shape with the wide pitch is provided to the pixel 12-11.

Accordingly, by applying the fifty-seventh sensitivity adjustment structure 21_57 to the red same-color pixel group 13R and the blue same-color pixel group 13B, it is possible to attempt to improve the sensitivity of the pixels 12 that are arranged at the four locations in the middle 2×2 array and that tend to have low sensitivity. That is, the intra-pixel grooves 22s with the multi-recess shape with the wide pitch can significantly improve the sensitivity of the pixels 12 arranged at the four locations in the middle 2×2 array. As a result, the image-capturing element 11 can suppress inter-pixel-12 sensitivity differences in the red same-color pixel group 13R and the blue same-color pixel group 13B, and attain more uniform sensitivity characteristics.

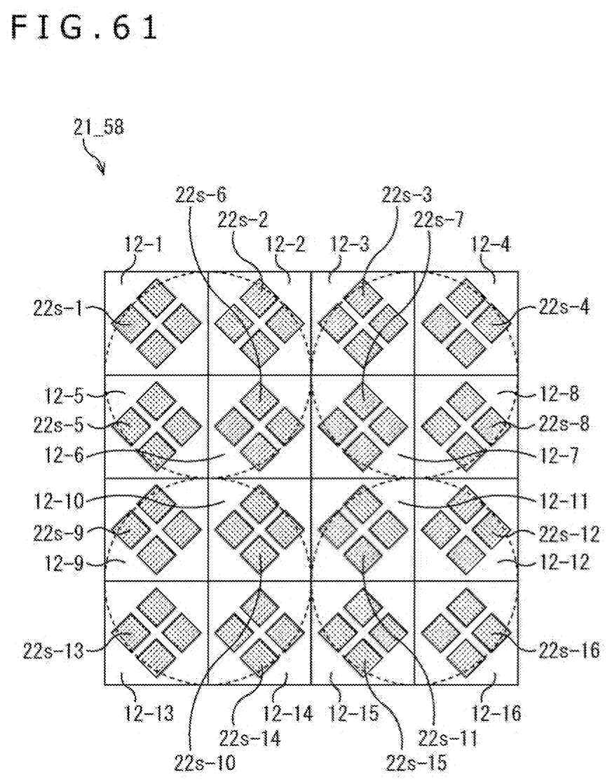

FIG. 61 is a figure depicting a configuration example of a fifty-eighth sensitivity adjustment structure 21_58.

As depicted in FIG. 61, the fifty-eighth sensitivity adjustment structure 21_58 uses the intra-pixel grooves 22s with the multi-recess shape in which multiple recesses are provided at a wide pitch.

The fifty-eighth sensitivity adjustment structure 21_58 includes an arrangement pattern in which the intra-pixel grooves 22s with the multi-recess shape with the wide pitch are provided to all the sixteen pixels 12-1 to 12-16 in the 4×4 array. That is, in the second sensitivity adjustment structure 21_2, intra-pixel grooves 22s-1 to 22s-16 with the multi-recess shape with the wide pitch are provided to the pixels 12-1 to 12-16, respectively.

Accordingly, by applying the fifty-eighth sensitivity adjustment structure 21_58 to a same-color pixel group 13, it is possible to attempt to improve the overall sensitivity of the same-color pixel group 13.

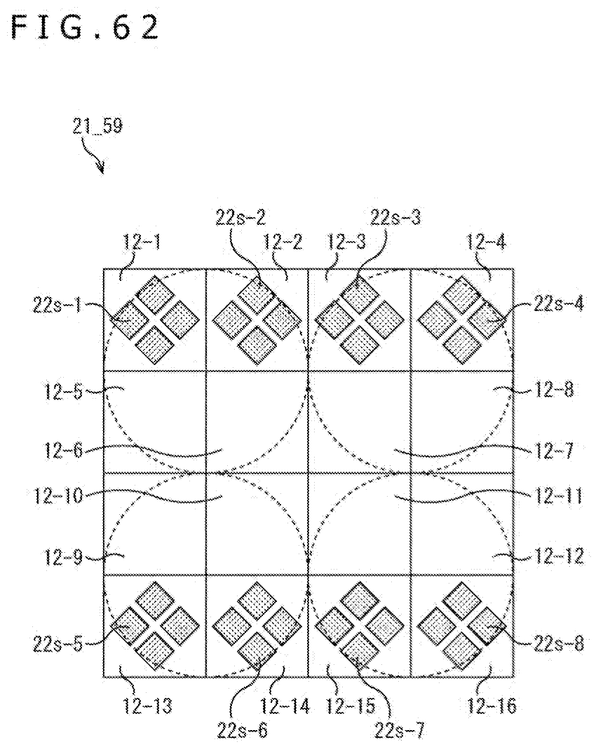

FIG. 62 is a figure depicting a configuration example of a fifty-ninth sensitivity adjustment structure 21_59.

As depicted in FIG. 62, the fifty-ninth sensitivity adjustment structure 21_59 uses the intra-pixel grooves 22s with the multi-recess shape in which multiple recesses are provided at a wide pitch.

The fifty-ninth sensitivity adjustment structure 21_59 includes an arrangement pattern in which, in the 4×4 array of the sixteen pixels 12-1 to 12-16, the intra-pixel grooves 22s with the multi-recess shape with the wide pitch are provided to pixels 12 arranged at the four locations on the upper side and pixels 12 arranged at the four locations on the lower side.

That is, in the fifty-ninth sensitivity adjustment structure 21_59, the intra-pixel grooves 22s-1 to 22s-4 with the multi-recess shape with the wide pitch are provided to the pixels 12-1 to 12-4, respectively, and the intra-pixel grooves 22s-5 to 22s-8 with the multi-recess shape with the wide pitch are provided to the pixels 12-13 to 12-16, respectively.

Accordingly, by applying the fifty-ninth sensitivity adjustment structure 21_59 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. That is, the intra-pixel grooves 22s with the multi-recess shape with the wide pitch can improve the sensitivity of the pixels 12 arranged at the four locations on the upper side and the pixels 12 arranged at the four locations on the lower side, by scattering the light that has been incident on the pixels 12 and enlarging the optical path lengths of the light. As a result, the image-capturing element 11 can suppress inter-pixel-12 sensitivity differences in the green same-color pixel group 13Gr, and attain more uniform sensitivity characteristics.

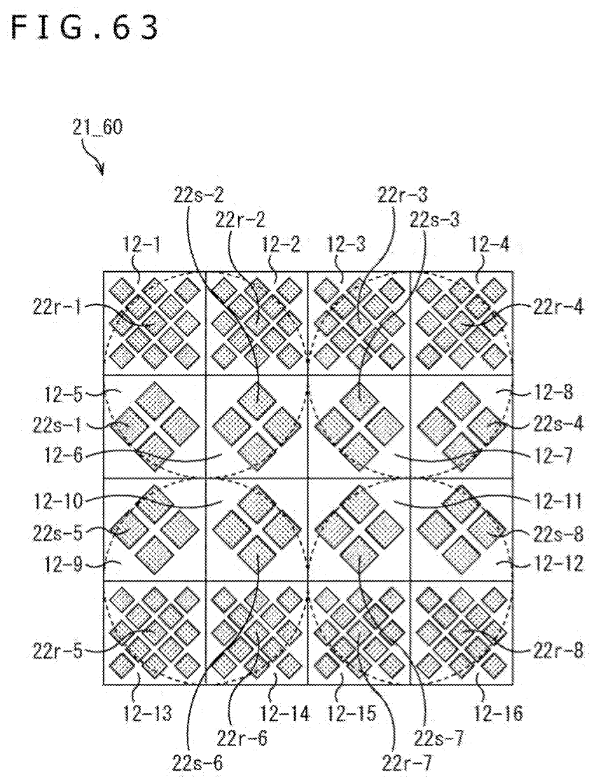

FIG. 63 is a figure depicting a configuration example of a sixtieth sensitivity adjustment structure 21_60.

As depicted in FIG. 63, the sixtieth sensitivity adjustment structure 21_60 uses the intra-pixel grooves 22r with the multi-recess shape in which multiple recesses are provided at a narrow pitch and the intra-pixel grooves 22s with the multi-recess shape in which multiple recesses are provided at a wide pitch.

The sixtieth sensitivity adjustment structure 21_60 includes an arrangement pattern in which, in the 4×4 array of the sixteen pixels 12-1 to 12-16, the intra-pixel grooves 22r with the multi-recess shape with the narrow pitch are provided to pixels 12 arranged at the four locations on the upper side and pixels 12 arranged at the four locations on the lower side and the intra-pixel grooves 22s with the multi-recess shape with the wide pitch are provided to pixels 12 arranged at the eight locations in the two middle rows.

That is, in the sixtieth sensitivity adjustment structure 21_60, the intra-pixel grooves 22r-1 to 22r-4 with the multi-recess shape with the narrow pitch are provided to the pixels 12-1 to 12-4, respectively, and the intra-pixel grooves 22r-5 to 22r-8 with the multi-recess shape with the narrow pitch are provided to the pixels 12-13 to 12-16, respectively. Moreover, the intra-pixel grooves 22s-1 to 22s-4 with the multi-recess shape with the wide pitch are provided to the pixels 12-5 to 12-8, respectively, and the intra-pixel grooves 22s-5 to 22s-8 with the multi-recess shape with the wide pitch are provided to the pixels 12-9 to 12-12, respectively.

Accordingly, by applying the sixtieth sensitivity adjustment structure 21_60 to the green same-color pixel group 13Gr, it is possible to attempt to improve the sensitivity of the pixels 12 that are arranged at the four locations on the upper side and that tend to have low sensitivity and the pixels 12 that are arranged at the four locations on the lower side and that tend to have low sensitivity. That is, it is possible with the intra-pixel grooves 22r with the multi-recess shape with the narrow pitch to significantly improve the sensitivity of the pixels 12 arranged at the four locations on the upper side and the pixels 12 arranged at the four locations on the lower side, and it is possible with the intra-pixel grooves 22s with the multi-recess shape with the wide pitch to attempt to intermediately improve the sensitivity of the pixels 12 arranged at the eight locations in the two middle rows. As a result, the image-capturing element 11 can suppress inter-pixel-12 sensitivity differences in the green same-color pixel group 13Gr, and attain more uniform sensitivity characteristics.

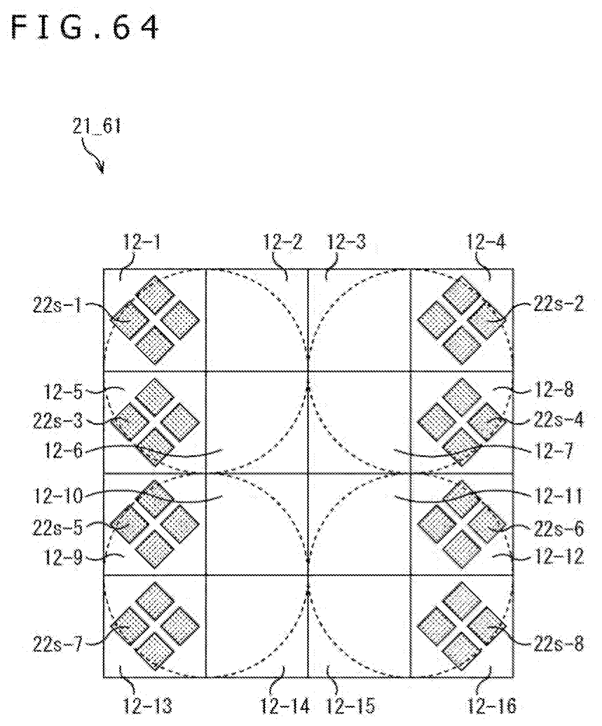

As depicted in FIG. 64, a sixty-first sensitivity adjustment structure 21_61 uses the intra-pixel grooves 22s with the multi-recess shape in which multiple recesses are provided at a wide pitch.

The sixty-first sensitivity adjustment structure 21_61 includes an arrangement pattern in which, in the 4×4 array of the sixteen pixels 12-1 to 12-16, the intra-pixel grooves 22s with the multi-recess shape with the wide pitch are provided to pixels 12 arranged at the four locations on the left side and pixels 12 arranged at the four locations on the right side.

That is, in the sixty-first sensitivity adjustment structure 21_61, the intra-pixel groove 22s-1 with the multi-recess shape with the wide pitch is provided to the pixel 21-1, the intra-pixel groove 22s-2 with the multi-recess shape with the wide pitch is provided to the pixel 21-4, the intra-pixel groove 22s-3 with the multi-recess shape with the wide pitch is provided to the pixel 21-5, and the intra-pixel groove 22s-4 with the multi-recess shape with the wide pitch is provided to the pixel 21-8. Moreover, the intra-pixel groove 22s-5 with the multi-recess shape with the wide pitch is provided to the pixel 21-10, the intra-pixel groove 22s-6 with the multi-recess shape with the wide pitch is provided to the pixel 21-12, the intra-pixel groove 22s-7 with the multi-recess shape with the wide pitch is provided to the pixel 21-13, and the intra-pixel groove 22s-8 with the multi-recess shape with the wide pitch is provided to the pixel 21-16.

Accordingly, by applying the sixty-first sensitivity adjustment structure 21_61 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. That is, the intra-pixel grooves 22s with the multi-recess shape with the wide pitch can improve the sensitivity of the pixels 12 arranged at the four locations on the left side and the pixels 12 arranged at the four locations on the right side, by scattering the light that has been incident on the pixels 12 and enlarging the optical path lengths of the light. As a result, the image-capturing element 11 can suppress inter-pixel-12 sensitivity differences in the green same-color pixel group 13Gb, and attain more uniform sensitivity characteristics.

FIG. 65 is a figure depicting a configuration example of a sixty-second sensitivity adjustment structure 21_62.

As depicted in FIG. 65, the sixty-second sensitivity adjustment structure 21_62 uses the intra-pixel grooves 22r with the multi-recess shape in which multiple recesses are provided at a narrow pitch and the intra-pixel grooves 22s with the multi-recess shape in which multiple recesses are provided at a wide pitch.

The sixty-second sensitivity adjustment structure 21_62 includes an arrangement pattern in which, in the 4×4 array of the sixteen pixels 12-1 to 12-16, the intra-pixel grooves 22r with the multi-recess shape with the narrow pitch are provided to pixels 12 arranged at the four locations on the left side and pixels 12 arranged at the four locations on the right side and the intra-pixel grooves 22s with the multi-recess shape with the wide pitch are provided to pixels 12 arranged at the eight locations in the two middle columns.

That is, in the sixty-second sensitivity adjustment structure 21_62, the intra-pixel groove 22r-1 with the multi-recess shape with the narrow pitch is provided to the pixel 21-1, the intra-pixel groove 22r-2 with the multi-recess shape with the narrow pitch is provided to the pixel 21-4, the intra-pixel groove 22r-3 with the multi-recess shape with the narrow pitch is provided to the pixel 21-5, and the intra-pixel groove 22r-4 with the multi-recess shape with the narrow pitch is provided to the pixel 21-8. Moreover, the intra-pixel groove 22r-5 with the multi-recess shape with the narrow pitch is provided to the pixel 21-9, the intra-pixel groove 22r-6 with the multi-recess shape with the narrow pitch is provided to the pixel 21-12, the intra-pixel groove 22r-7 with the multi-recess shape with the narrow pitch is provided to the pixel 21-13, and the intra-pixel groove 22r-8 with the multi-recess shape with the narrow pitch is provided to the pixel 21-16. Moreover, the intra-pixel groove 22s-1 with the multi-recess shape with the wide pitch is provided to the pixel 12-2, the intra-pixel groove 22s-2 with the multi-recess shape with the wide pitch is provided to the pixel 12-3, the intra-pixel groove 22s-3 with the multi-recess shape with the wide pitch is provided to the pixel 12-6, and the intra-pixel groove 22s-4 with the multi-recess shape with the wide pitch is provided to the pixel 12-7. Moreover, the intra-pixel groove 22s-5 with the multi-recess shape with the wide pitch is provided to the pixel 12-10, the intra-pixel groove 22s-6 with the multi-recess shape with the wide pitch is provided to the pixel 12-11, the intra-pixel groove 22s-7 with the multi-recess shape with the wide pitch is provided to the pixel 12-14, and the intra-pixel groove 22s-8 with the multi-recess shape with the wide pitch is provided to the pixel 12-15.

Accordingly, by applying the sixty-second sensitivity adjustment structure 21_62 to the green same-color pixel group 13Gb, it is possible to attempt to improve the sensitivity of the pixels 12 that are arranged at the four locations on the left side and that tend to have low sensitivity and the pixels 12 that are arranged at the four locations on the right side and that tend to have low sensitivity. That is, it is possible with the intra-pixel grooves 22r with the multi-recess shape with the narrow pitch to significantly improve the sensitivity of the pixels 12 arranged at the four locations on the left side and the pixels 12 arranged at the four locations on the right side, and it is possible with the intra-pixel grooves 22s with the multi-recess shape with the wide pitch to attempt to intermediately improve the sensitivity of the pixels 12 arranged at the eight locations in the two middle columns. As a result, the image-capturing element 11 can suppress inter-pixel-12 sensitivity differences in the green same-color pixel group 13Gb, and attain more uniform sensitivity characteristics.

Note that the configuration examples of the sensitivity adjustment structures 21 adopting the arrangement patterns of the intra-pixel grooves 22 with various shapes as the ones described above are not the sole examples, and sensitivity adjustment structures 21 of various arrangement patterns may be adopted as long as those sensitivity adjustment structures 21 can contribute to suppression of inter-pixel-12 sensitivity differences in a same-color pixel group 13.

### <Combination Examples of Sensitivity Adjustment Structures>

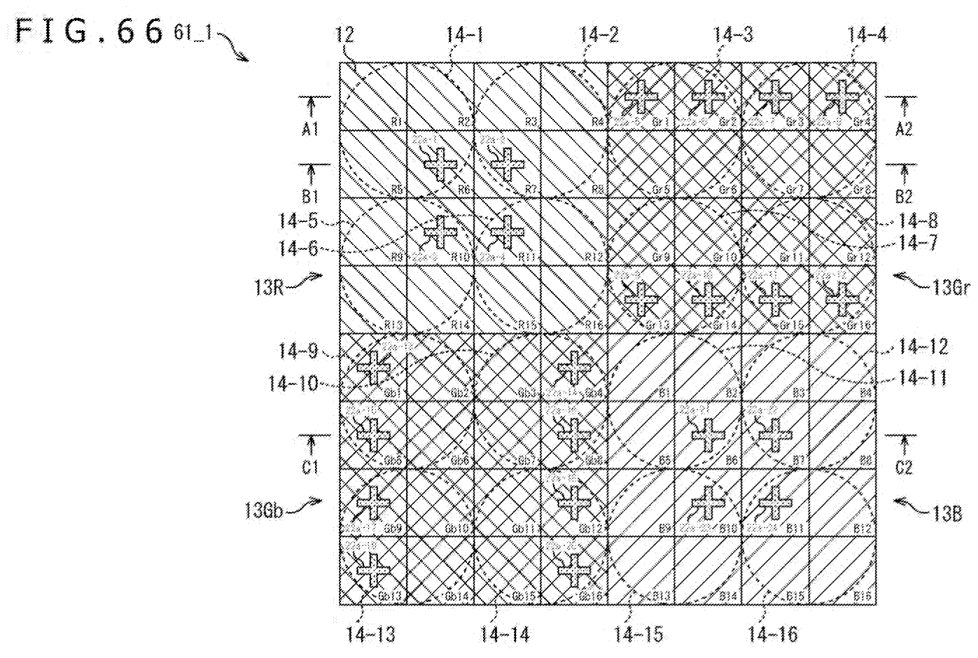

Combination examples of sensitivity adjustment structures are explained with reference to FIG. 66 to FIG. 85.

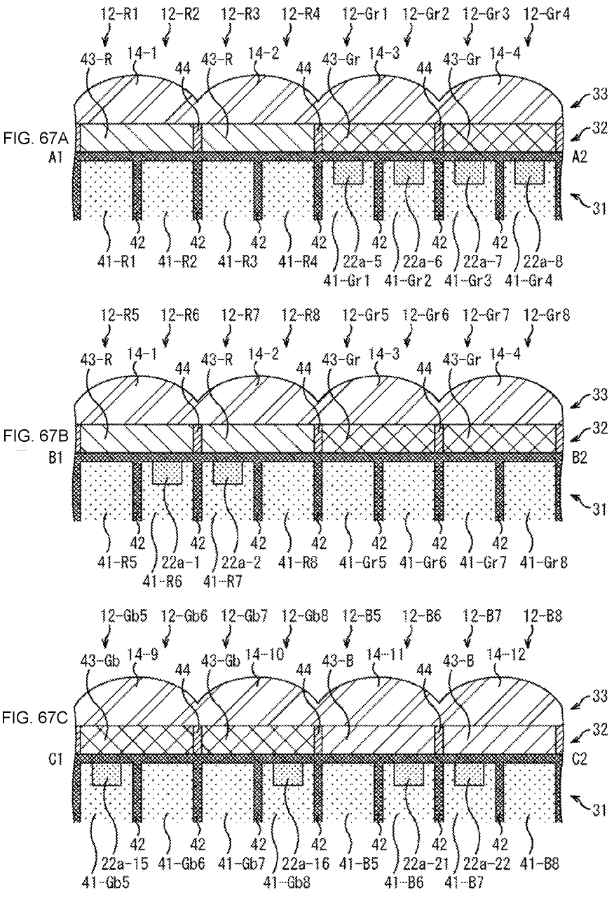

FIG. 66 and FIG. 67 are figures depicting a configuration example of a first combination layout 61_1. FIG. 66 depicts the configuration example of the first combination layout 61_1 as seen in a plan view of the red same-color pixel group 13R, the green same-color pixel group 13Gr, the green same-color pixel group 13Gb, and the blue same-color pixel group 13B. A in FIG. 67 depicts the configuration example of the first combination layout 61_1 on a cross-section taken along A1-A2 depicted in FIG. 66, B in FIG. 67 depicts the configuration example of the first combination layout 61_1 on a cross-section taken along B1-B2 depicted in FIG. 66, and C in FIG. 67 depicts the configuration example of the first combination layout 61_1 on a cross-section taken along C1-C2 depicted in FIG. 66.

As depicted in FIG. 66, similarly to the first sensitivity adjustment structure 21_1 in FIG. 3, in the red same-color pixel group 13R, it is possible with the first combination layout 61_1 to attempt to improve the sensitivity of pixels 12 that are arranged at the four locations in the middle 2×2 array and that tend to have low sensitivity, by providing the intra-pixel grooves 22a-1 to 22a-4 with the cross shape to those pixels 12. Moreover, similarly to the twenty-first sensitivity adjustment structure 21_21 in FIG. 23, in the green same-color pixel group 13Gr, it is possible to attempt to improve the sensitivity of pixels 12 that are arranged at the four locations on the upper side and that tend to have low sensitivity and pixels 12 that are arranged at the four locations on the lower side and that tend to have low sensitivity, by providing the intra-pixel grooves 22a-5 to 22a-12 with the cross shape to those pixels 12.

Moreover, similarly to the twenty-second sensitivity adjustment structure 21_22 in FIG. 24, in the green same-color pixel group 13Gb, it is possible to attempt to improve the sensitivity of pixels 12 that are arranged at the four locations on the left side and that tend to have low sensitivity and pixels 12 that are arranged at the four locations on the right side and that tend to have low sensitivity, by providing intra-pixel grooves 22a-13 to 22a-20 with the cross shape to those pixels 12. Moreover, similarly to the first sensitivity adjustment structure 21_1 in FIG. 3, in the blue same-color pixel group 13B, it is possible to attempt to improve the sensitivity of pixels 12 that are arranged at the four locations in the middle 2×2 array and that tend to have low sensitivity, by providing intra-pixel grooves 22a-21 to 22a-24 with the cross shape to those pixels 12.

Accordingly, by using such sensitivity adjustment structures 21 in combination, the first combination layout 61_1 can suppress inter-pixel-12 sensitivity differences, and attain more uniform sensitivity characteristics.

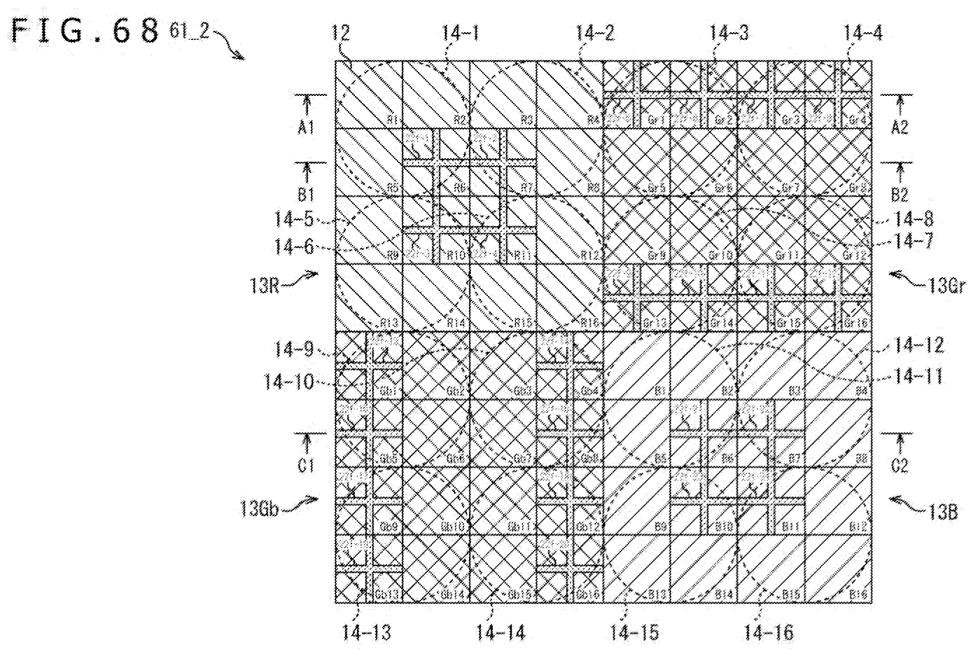

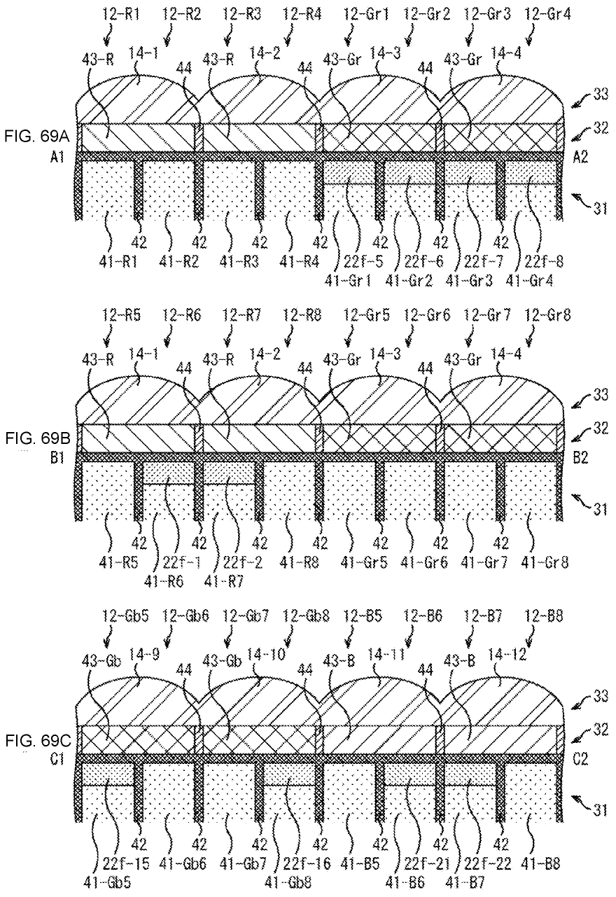

FIG. 68 and FIG. 69 are figures depicting a configuration example of a second combination layout 61_2. FIG. 68 depicts the configuration example of the second combination layout 61_2 as seen in a plan view of the red same-color pixel group 13R, the green same-color pixel group 13Gr, the green same-color pixel group 13Gb, and the blue same-color pixel group 13B. A in FIG. 69 depicts the configuration example of the second combination layout 61_2 on a cross-section taken along A1-A2 depicted in FIG. 68, B in FIG. 69 depicts the configuration example of the second combination layout 61_2 on a cross-section taken along B1-B2 depicted in FIG. 68, and C in FIG. 69 depicts the configuration example of the second combination layout 61_2 on a cross-section taken along C1-C2 depicted in FIG. 68.

As depicted in FIG. 68, similarly to the eleventh sensitivity adjustment structure 21_11 in FIG. 13, in the red same-color pixel group 13R, it is possible with the second combination layout 61_2 to attempt to more significantly improve the sensitivity of pixels 12 that are arranged at the four locations in the middle 2×2 array and that tend to have low sensitivity, by providing intra-pixel grooves 22f-1 to 22f-4 with the cross shape and the enlarged structure to those pixels 12. Moreover, similarly to the twenty-seventh sensitivity adjustment structure 21_27 in FIG. 29, in the green same-color pixel group 13Gr, it is possible to attempt to more significantly improve the sensitivity of pixels 12 that are arranged at the four locations on the upper side and that tend to have low sensitivity and pixels 12 that are arranged at the four locations on the lower side and that tend to have low sensitivity, by providing intra-pixel grooves 22f-5 to 22f-12 with the cross shape and the enlarged structure to those pixels 12.

Moreover, similarly to the twenty-eighth sensitivity adjustment structure 21_28 in FIG. 30, in the green same-color pixel group 13Gb, it is possible to attempt to more significantly improve the sensitivity of pixels 12 that are arranged at the four locations on the left side and that tend to have low sensitivity and pixels 12 that are arranged at the four locations on the right side and that tend to have low sensitivity, by providing intra-pixel grooves 22f-13 to 22f-20 with the cross shape and the enlarged structure to those pixels 12. Moreover, similarly to the eleventh sensitivity adjustment structure 21_11 in FIG. 13, in the blue same-color pixel group 13B, it is possible to attempt to more significantly improve the sensitivity of pixels 12 that are arranged at the four locations in the middle 2×2 array and that tend to have low sensitivity, by providing intra-pixel grooves 22f-21 to 22f-24 with the cross shape and the enlarged structure to those pixels 12.

Accordingly, by using such sensitivity adjustment structures 21 in combination, the second combination layout 61_2 can suppress inter-pixel-12 sensitivity differences, and attain more uniform sensitivity characteristics.

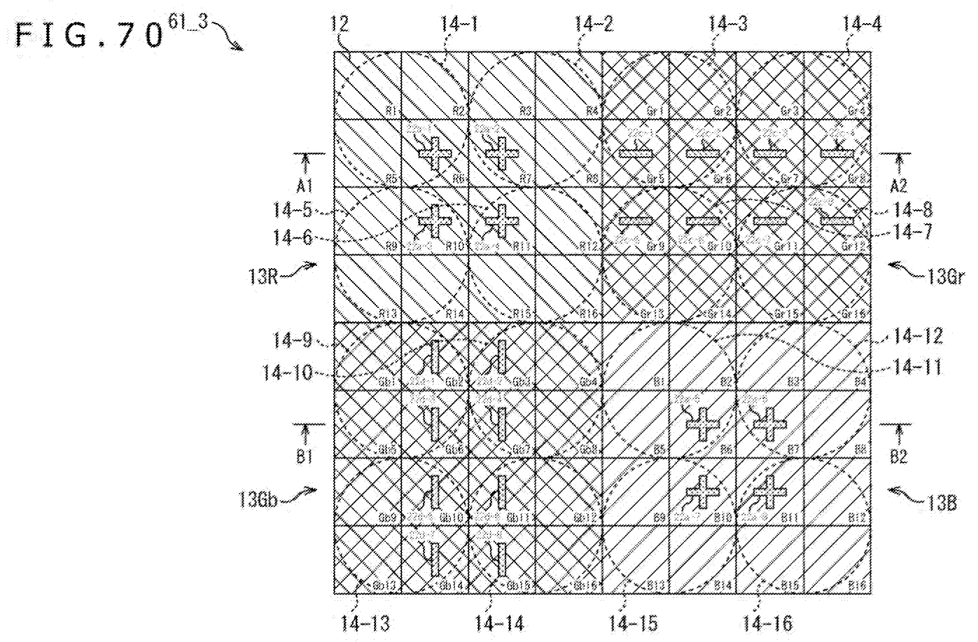

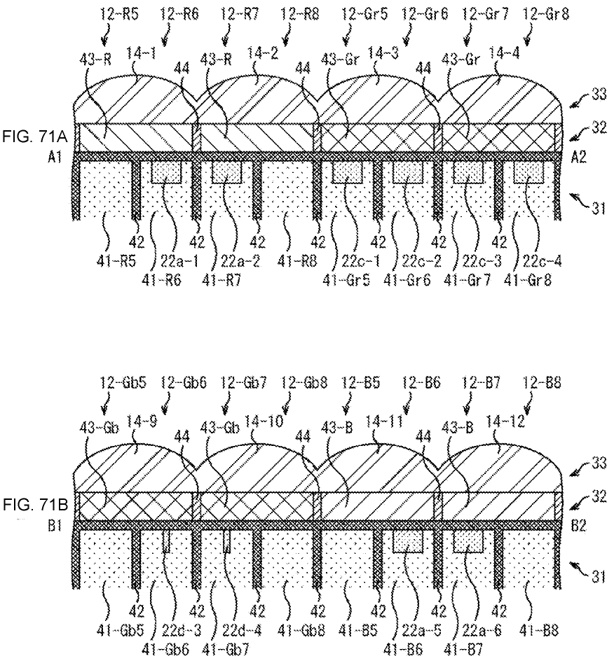

FIG. 70 and FIG. 71 are figures depicting a configuration example of a third combination layout 61_3. FIG. 70 depicts the configuration example of the third combination layout 61_3 as seen in a plan view of the red same-color pixel group 13R, the green same-color pixel group 13Gr, the green same-color pixel group 13Gb, and the blue same-color pixel group 13B. A in FIG. 71 depicts the configuration example of the third combination layout 61_3 on a cross-section taken along A1-A2 depicted in FIG. 70, and B in FIG. 71 depicts the configuration example of the third combination layout 61_3 on a cross-section taken along B1-B2 depicted in FIG. 70.

As depicted in FIG. 70, similarly to the first sensitivity adjustment structure 21_1 in FIG. 3, in the red same-color pixel group 13R, it is possible with the third combination layout 61_3 to attempt to improve the sensitivity of pixels 12 that are arranged at the four locations in the middle 2×2 array, and tend to have low sensitivity, by providing the intra-pixel grooves 22a-1 to 22a-4 with the cross shape to those pixels 12. Moreover, similarly to the twenty-third sensitivity adjustment structure 21_23 in FIG. 25, in the green same-color pixel group 13Gr, it is possible to attempt to scatter light in directions perpendicular to the longitudinal directions of pixels 12 arranged at the eight locations in the two middle rows, by providing the intra-pixel grooves 22c-1 to 22c-8 with the horizontal line shape to those pixels 12, and improve the sensitivity of pixels 12 that are arranged at the four locations on the upper side and that tend to have low sensitivity and pixels 12 that are arranged at the four locations on the lower side and that tend to have low sensitivity.

Moreover, similarly to the twenty-fourth sensitivity adjustment structure 21_24 in FIG. 26, in the green same-color pixel group 13Gb, it is possible to attempt to scatter light in directions perpendicular to the longitudinal directions of pixels 12 arranged at the eight locations in the two middle columns, by providing the intra-pixel grooves 22d-1 to 22d-8 with the vertical line shape to those pixels 12, and improve the sensitivity of pixels 12 that are arranged at the four locations on the left side and that tend to have low sensitivity and pixels 12 that are arranged at the four locations on the right side and that tend to have low sensitivity. Moreover, similarly to the first sensitivity adjustment structure 21_1 in FIG. 3, in the blue same-color pixel group 13B, it is possible to attempt to improve the sensitivity of pixels 12 that are arranged at the four locations in the middle 2×2 array and that tend to have low sensitivity, by providing the intra-pixel grooves 22a-5 to 22a-8 with the cross shape to those pixels 12.

Accordingly, by using such sensitivity adjustment structures 21 in combination, the third combination layout 61_3 can suppress inter-pixel-12 sensitivity differences, and attain more uniform sensitivity characteristics.

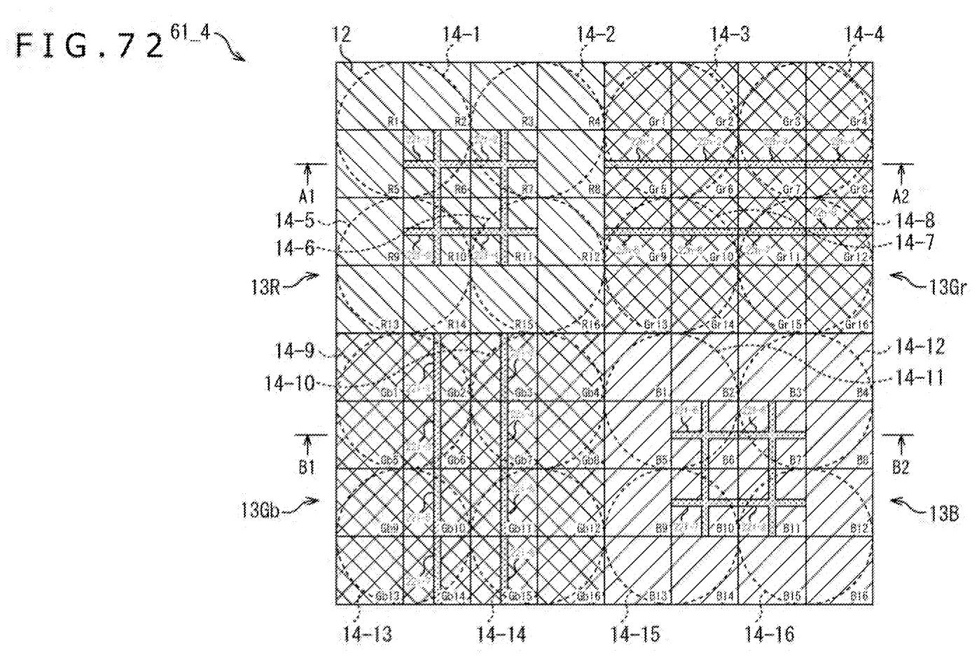

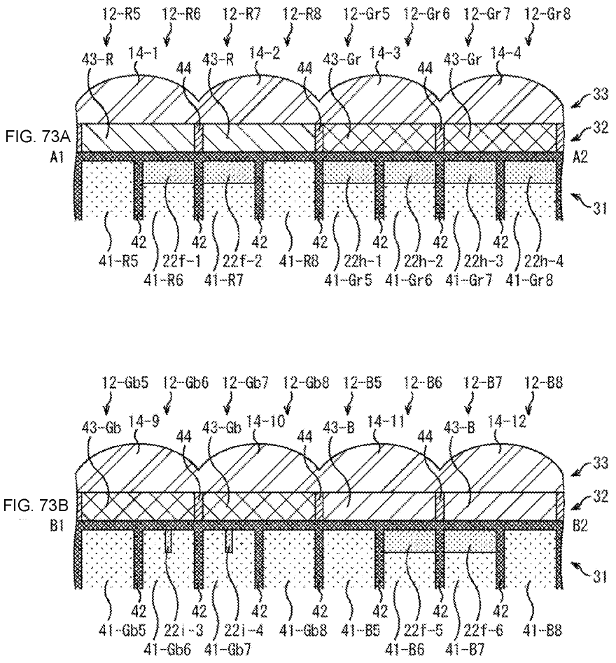

FIG. 72 and FIG. 73 are figures depicting a configuration example of a fourth combination layout 61_4. FIG. 72 depicts the configuration example of the fourth combination layout 61_4 as seen in a plan view of the red same-color pixel group 13R, the green same-color pixel group 13Gr, the green same-color pixel group 13Gb, and the blue same-color pixel group 13B. A in FIG. 73 depicts the configuration example of the fourth combination layout 61_4 on a cross-section taken along A1-A2 depicted in FIG. 72, and B in FIG. 73 depicts the configuration example of the fourth combination layout 61_4 on a cross-section taken along B1-B2 depicted in FIG. 72.

As depicted in FIG. 72, similarly to the eleventh sensitivity adjustment structure 21_11 in FIG. 13, in the red same-color pixel group 13R, it is possible with the fourth combination layout 61_4 to attempt to more significantly improve the sensitivity of pixels 12 that are arranged at the four locations in the middle 2×2 array and that tend to have low sensitivity, by providing the intra-pixel grooves 22f-1 to 22f-4 with the cross shape and the enlarged structure to those pixels 12. Moreover, similarly to the twenty-ninth sensitivity adjustment structure 21_29 in FIG. 31, in the green same-color pixel group 13Gr, it is possible to attempt to scatter light in directions perpendicular to the longitudinal directions of pixels 12 arranged at the eight locations in the two middle rows, by providing the intra-pixel grooves 22h-1 to 22h-8 with the horizontal line shape and the enlarged structure to those pixels 12, and more significantly improve the sensitivity of pixels 12 that are arranged at the four locations on the upper side and that tend to have low sensitivity and pixels 12 that are arranged at the four locations on the lower side and that tend to have low sensitivity.

Moreover, similarly to the thirtieth sensitivity adjustment structure 21_30 in FIG. 32, in the green same-color pixel group 13Gb, it is possible to attempt to scatter light in directions perpendicular to the longitudinal directions of pixels 12 arranged at the eight locations in the two middle columns, by providing the intra-pixel grooves 22i-1 to 22i-8 with the vertical line shape and the enlarged structure to those pixels 12, and more significantly improve the sensitivity of pixels 12 that are arranged at the four locations on the left side and that tend to have low sensitivity and pixels 12 that are arranged at the four locations on the right side and that tend to have low sensitivity. Moreover, similarly to the eleventh sensitivity adjustment structure 21_11 in FIG. 13, in the blue same-color pixel group 13B, it is possible to attempt to more significantly improve the sensitivity of pixels 12 that are arranged at the four locations in the middle 2×2 array and that tend to have low sensitivity, by providing the intra-pixel grooves 22f-5 to 22f-8 with the cross shape and the enlarged structure to those pixels 12.

Accordingly, by using such sensitivity adjustment structures 21 in combination, the fourth combination layout 61_4 can suppress inter-pixel-12 sensitivity differences, and attain more uniform sensitivity characteristics.

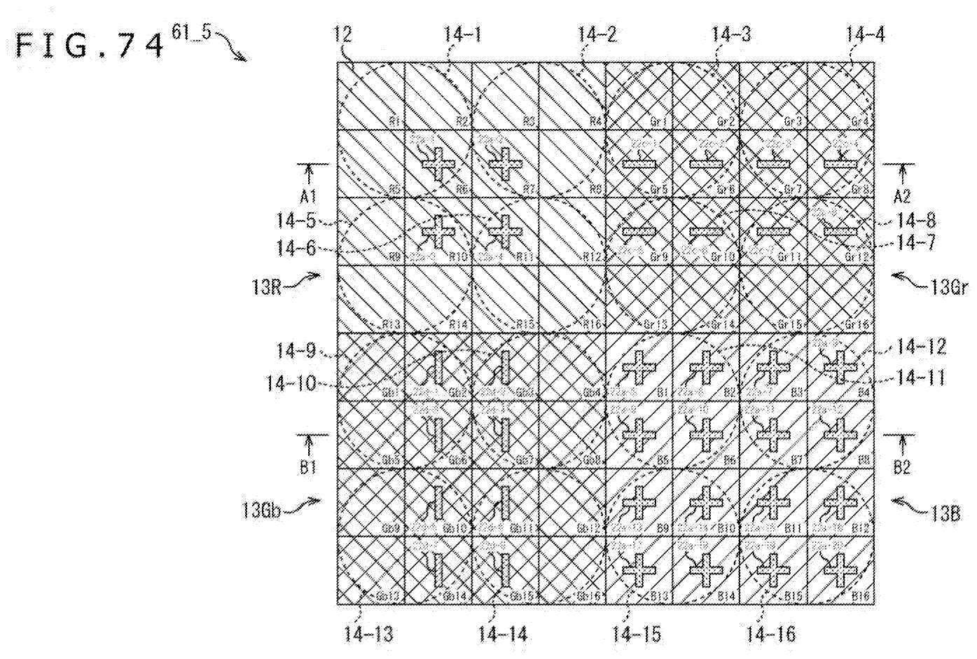

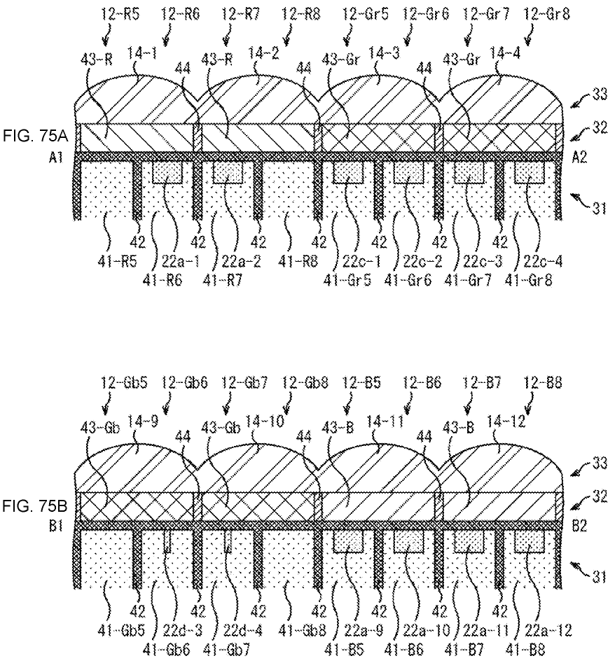

FIG. 74 and FIG. 75 are figures depicting a configuration example of a fifth combination layout 61_5. FIG. 74 depicts the configuration example of the fifth combination layout 61_5 as seen in a plan view of the red same-color pixel group 13R, the green same-color pixel group 13Gr, the green same-color pixel group 13Gb, and the blue same-color pixel group 13B. A in FIG. 75 depicts the configuration example of the fifth combination layout 61_5 on a cross-section taken along A1-A2 depicted in FIG. 74, and B in FIG. 75 depicts the configuration example of the fifth combination layout 61_5 on a cross-section taken along B1-B2 depicted in FIG. 74.

As depicted in FIG. 74, similarly to the third combination layout 61_3 in FIG. 70, in the red same-color pixel group 13R, the green same-color pixel group 13Gr, and the green same-color pixel group 13Gb, it is attempted with the fifth combination layout 61_5 to improve the sensitivity of pixels 12.

Moreover, similarly to the second sensitivity adjustment structure 21_2 in FIG. 4, in the blue same-color pixel group 13B, it is possible to attempt to improve the overall sensitivity of all the sixteen pixels 12 in the 4×4 array by providing the intra-pixel grooves 22a-1 to 22a-16 with the cross shape to those pixels 12. Moreover, it is possible to attempt to improve the sensitivity of pixels 12 that are arranged at the four locations on the lower side in the green same-color pixel group 13Gr arranged above the blue same-color pixel group 13B and that tend to have low sensitivity and pixels 12 that are arranged at the four locations on the upper side in the green same-color pixel group 13Gr arranged below the blue same-color pixel group 13B and that tend to have low sensitivity, since light scattered by the intra-pixel grooves 22a with the cross shape is incident on those pixels 12. Similarly, it is possible to attempt to improve the sensitivity of pixels 12 that are arranged at the four locations on the right side in the green same-color pixel group 13Gb arranged to the left of the blue same-color pixel group 13B and that tend to have low sensitivity and pixels 12 that are arranged at the four locations on the left side in the green same-color pixel group 13Gb arranged to the right of the blue same-color pixel group 13B and that tend to have low sensitivity, since light scattered by the intra-pixel grooves 22a with the cross shape is incident on those pixels 12.

Accordingly, by using such sensitivity adjustment structures 21 in combination, the fifth combination layout 61_5 can suppress inter-pixel-12 sensitivity differences, and attain more uniform sensitivity characteristics.

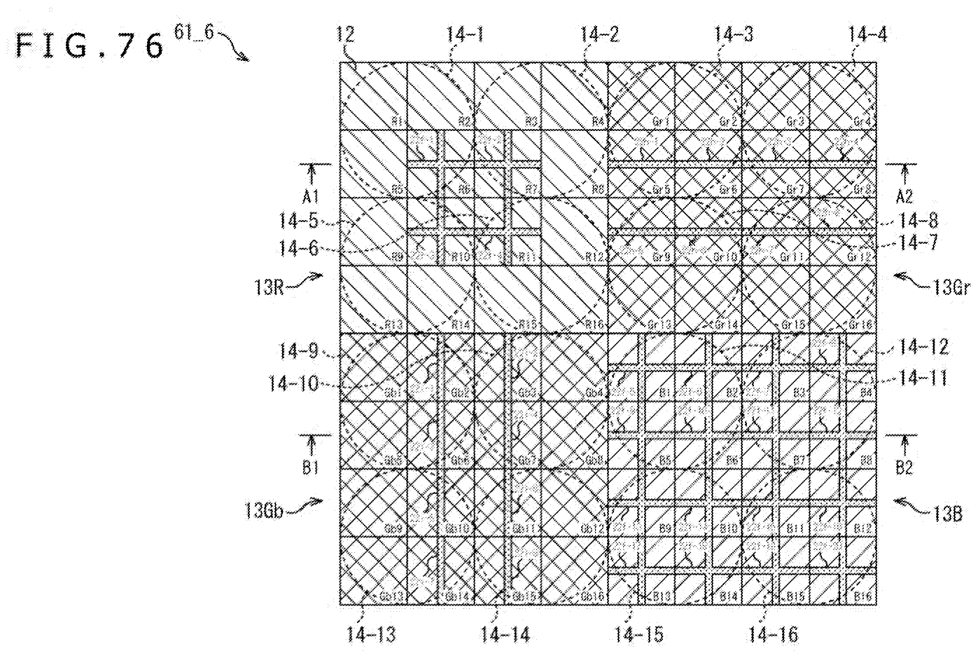

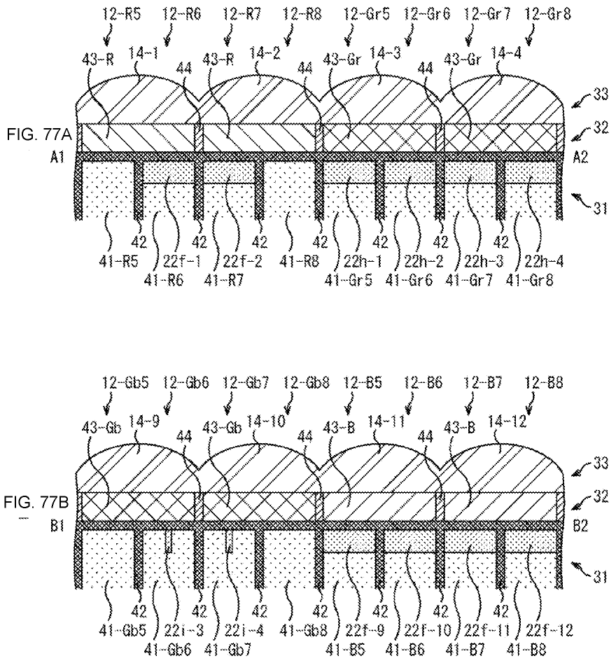

FIG. 76 and FIG. 77 are figures depicting a configuration example of a sixth combination layout 61_6. FIG. 76 depicts the configuration example of the sixth combination layout 61_6 as seen in a plan view of the red same-color pixel group 13R, the green same-color pixel group 13Gr, the green same-color pixel group 13Gb, and the blue same-color pixel group 13B. A in FIG. 77 depicts the configuration example of the sixth combination layout 61_6 on a cross-section taken along A1-A2 depicted in FIG. 76, and B in FIG. 77 depicts the configuration example of the sixth combination layout 61_6 on a cross-section taken along B1-B2 depicted in FIG. 76.

As depicted in FIG. 76, similarly to the fourth combination layout 61_4 in FIG. 72, in the red same-color pixel group 13R, the green same-color pixel group 13Gr, and the green same-color pixel group 13Gb, it is attempted with the sixth combination layout 61_6 to improve the sensitivity of pixels 12.

Moreover, similarly to the twelfth sensitivity adjustment structure 21_12 in FIG. 14, in the blue same-color pixel group 13B, it is possible to attempt to improve the overall sensitivity of all the sixteen pixels 12 in the 4×4 array by providing the intra-pixel grooves 22f-1 to 22f-16 with the cross shape and the enlarged structure to those pixels 12. Moreover, it is possible to attempt to improve the sensitivity of pixels 12 that are arranged at the four locations on the lower side in the green same-color pixel group 13Gr arranged above the blue same-color pixel group 13B and that tend to have low sensitivity and pixels 12 that are arranged at the four locations on the upper side in the green same-color pixel group 13Gr arranged below the blue same-color pixel group 13B and that tend to have low sensitivity, since light scattered by the intra-pixel grooves 22f with the cross shape and the enlarged structure is incident on those pixels 12. Similarly, it is possible to attempt to improve the sensitivity of pixels 12 that are arranged at the four locations on the right side in the green same-color pixel group 13Gb arranged to the left of the blue same-color pixel group 13B and that tend to have low sensitivity and pixels 12 that are arranged at the four locations on the left side in the green same-color pixel group 13Gb arranged to the right of the blue same-color pixel group 13B and that tend to have low sensitivity, since light scattered by the intra-pixel grooves 22f with the cross shape and the enlarged structure is incident on those pixels 12.

Accordingly, by using such sensitivity adjustment structures 21 in combination, the sixth combination layout 61_6 can suppress inter-pixel-12 sensitivity differences, and attain more uniform sensitivity characteristics.

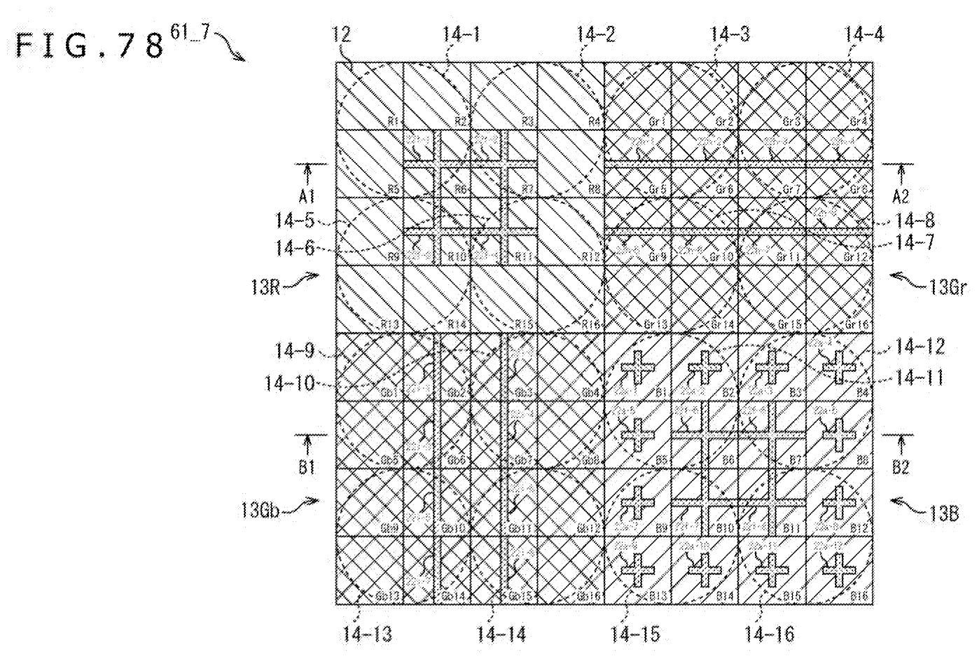

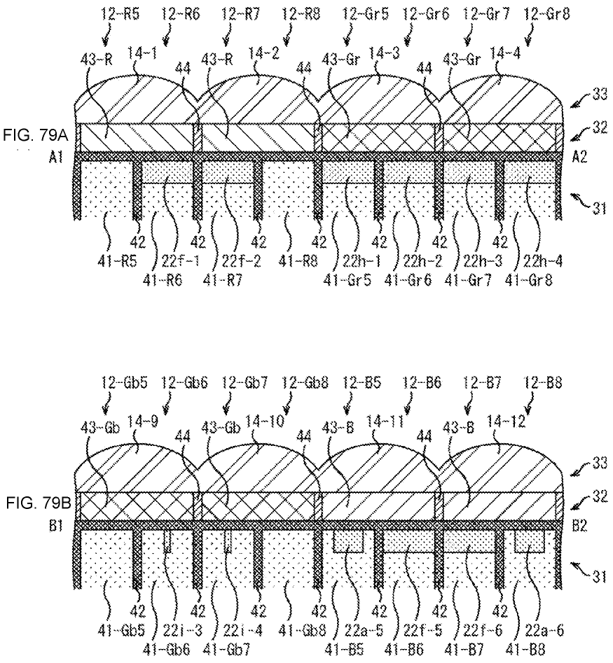

FIG. 78 and FIG. 79 are figures depicting a configuration example of a seventh combination layout 61_7. FIG. 78 depicts the configuration example of the seventh combination layout 61_7 as seen in a plan view of the red same-color pixel group 13R, the green same-color pixel group 13Gr, the green same-color pixel group 13Gb, and the blue same-color pixel group 13B. A in FIG. 79 depicts the configuration example of the seventh combination layout 61_7 on a cross-section taken along A1-A2 depicted in FIG. 78, and B in FIG. 79 depicts the configuration example of the seventh combination layout 61_7 on a cross-section taken along B1-B2 depicted in FIG. 78.

As depicted in FIG. 78, similarly to the fourth combination layout 61_4 in FIG. 72, in the red same-color pixel group 13R, the green same-color pixel group 13Gr, and the green same-color pixel group 13Gb, it is attempted with the seventh combination layout 61_7 to improve the sensitivity of pixels 12.

Moreover, in the blue same-color pixel group 13B, it is possible to attempt to more significantly improve the sensitivity of pixels 12 that are arranged at the four locations in the middle 2×2 array and that tend to have low sensitivity, by providing the intra-pixel grooves 22f-5 to 22f-8 with the cross shape and the enlarged structure to those pixels 12. Moreover, in the blue same-color pixel group 13B, it is possible to attempt to improve the sensitivity of pixels 12 arranged at the twelve peripheral locations, to a degree lower than that of the improvement at the middle, by providing the intra-pixel grooves 22a-1 to 22a-12 with the cross shape to those pixels 12.

In addition, it is possible to attempt to improve the sensitivity of pixels 12 that are arranged at the four locations on the lower side in the green same-color pixel group 13Gr arranged above the blue same-color pixel group 13B and that tend to have low sensitivity and pixels 12 that are arranged at the four locations on the upper side in the green same-color pixel group 13Gr arranged below the blue same-color pixel group 13B and that tend to have low sensitivity, since light scattered by the intra-pixel grooves 22a with the cross shape is incident on those pixels 12. Similarly, it is possible to attempt to improve the sensitivity of pixels 12 that are arranged at the four locations on the right side in the green same-color pixel group 13Gb arranged to the left of the blue same-color pixel group 13B and that tend to have low sensitivity and pixels 12 that are arranged at the four locations on the left side in the green same-color pixel group 13Gb arranged to the right of the blue same-color pixel group 13B and that tend to have low sensitivity, since light scattered by the intra-pixel grooves 22a with the cross shape is incident on those pixels 12. Accordingly, by using such sensitivity adjustment structures 21 in combination, the seventh combination layout 61_7 can suppress inter-pixel-12 sensitivity differences, and attain more uniform sensitivity characteristics.

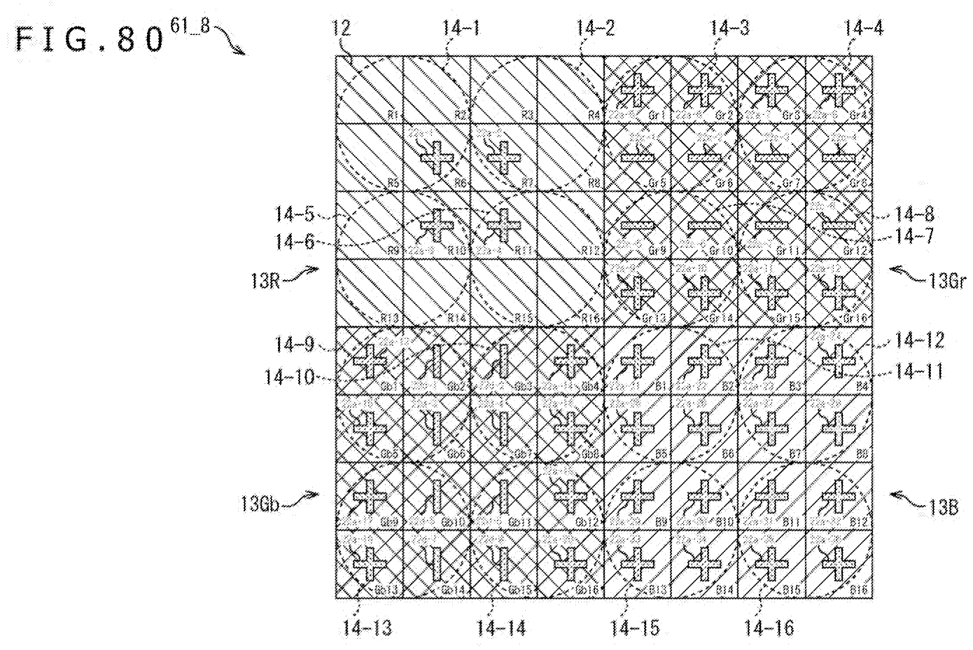

FIG. 80 is a figure depicting a configuration example of an eighth combination layout 61_8.

As depicted in FIG. 80, similarly to the first sensitivity adjustment structure 21_1 in FIG. 3, in the red same-color pixel group 13R, it is possible with the eighth combination layout 61_8 to attempt to improve the sensitivity of pixels 12 that are arranged at the four locations in the middle 2×2 array and that tend to have low sensitivity, by providing the intra-pixel grooves 22a-1 to 22a-4 with the cross shape to those pixels 12.

Moreover, similarly to the twenty-fifth sensitivity adjustment structure 21_25 in FIG. 27, in the green same-color pixel group 13Gr, it is possible to attempt to improve the sensitivity of pixels 12 that are arranged at the four locations on the upper side and that tend to have low sensitivity and pixels 12 that are arranged at the four locations on the lower side and that tend to have low sensitivity, by providing the intra-pixel grooves 22a-5 to 22a-12 with the cross shape to the pixels 12 that are arranged at the four locations on the upper side and that tend to have low sensitivity and the pixels 12 that are arranged at the four locations on the lower side and that tend to have low sensitivity, and also providing the intra-pixel grooves 22c-1 to 22c-8 with the horizontal line shape to pixels 12 arranged at the eight locations in the two middle rows. Moreover, similarly to the twenty-sixth sensitivity adjustment structure 21_26 in FIG. 28, in the green same-color pixel group 13Gb, it is possible to attempt to improve the sensitivity of pixels 12 that are arranged at the four locations on the left side and that tend to have low sensitivity and pixels 12 that are arranged at the four locations on the right side and that tend to have low sensitivity, by providing the intra-pixel grooves 22a-13 to 22a-20 with the cross shape to the pixels 12 that are arranged at the four locations on the left side and that tend to have low sensitivity and the pixels 12 that are arranged at the four locations on the right side and that tend to have low sensitivity, and also providing the intra-pixel grooves 22d-1 to 22d-8 with the vertical line shape to pixels 12 arranged at the eight locations in the two middle columns.

Moreover, similarly to the second sensitivity adjustment structure 21_2 in FIG. 4, in the blue same-color pixel group 13B, it is possible to attempt to improve the overall sensitivity of all the sixteen pixels 12 in the 4×4 array by providing the intra-pixel grooves 22a-1 to 22a-16 with the cross shape to those pixels 12, and also it is possible to suppress sensitivity differences in the green same-color pixel groups 13Gr arranged above and below the blue same-color pixel group 13B and the green same-color pixel groups 13Gb arranged to the left and the right of the blue same-color pixel group 13B.

Accordingly, by using such sensitivity adjustment structures 21 in combination, the seventh combination layout 61_7 can suppress inter-pixel-12 sensitivity differences, and attain more uniform sensitivity characteristics.

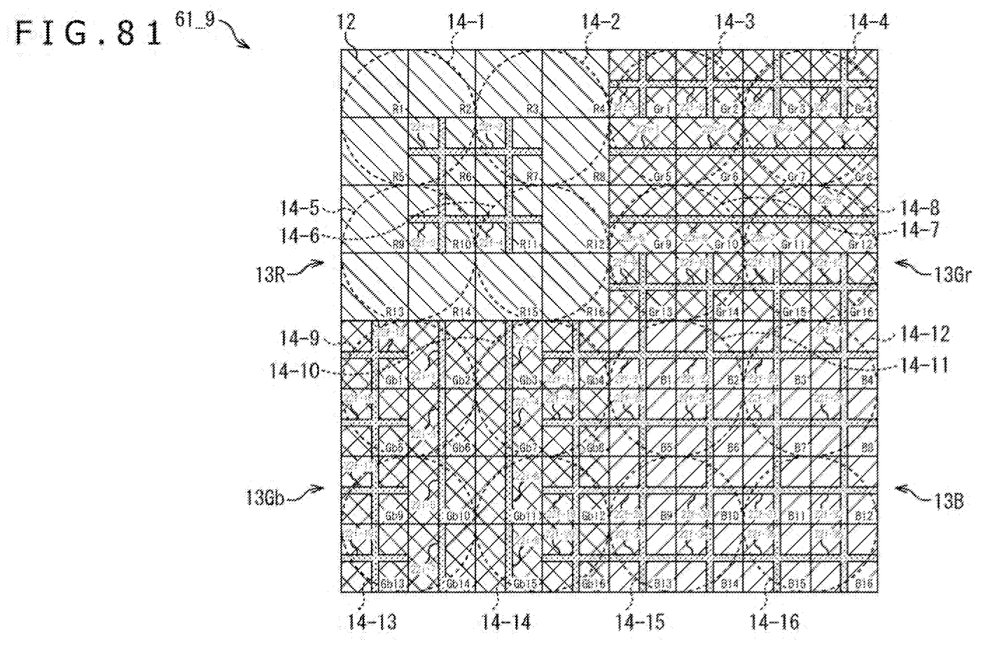

FIG. 81 is a figure depicting a configuration example of a ninth combination layout 61_9.

As depicted in FIG. 81, similarly to the eleventh sensitivity adjustment structure 21_11 in FIG. 13, in the red same-color pixel group 13R, it is possible with the ninth combination layout 61_9 to attempt to more significantly improve the sensitivity of pixels 12 that are arranged at the four locations in the middle 2×2 array and that tend to have low sensitivity, by providing the intra-pixel grooves 22f-1 to 22f-4 with the cross shape and the enlarged structure to those pixels 12.

Moreover, similarly to the thirty-first sensitivity adjustment structure 21_31 in FIG. 33, in the green same-color pixel group 13Gr, it is possible to attempt to improve the sensitivity of pixels 12 that are arranged at the four locations on the upper side and that tend to have low sensitivity and pixels 12 that are arranged at the four locations on the lower side and that tend to have low sensitivity, by providing the intra-pixel grooves 22f-5 to 22f-12 with the cross shape and the enlarged structure to the pixels 12 that are arranged at the four locations on the upper side and that tend to have low sensitivity and the pixels 12 that are arranged at the four locations on the lower side and that tend to have low sensitivity, and also providing the intra-pixel grooves 22h-1 to 22h-8 with the horizontal line shape and the enlarged structure to pixels 12 arranged at the eight locations in the two middle rows. Moreover, similarly to the thirty-second sensitivity adjustment structure 21_32 in FIG. 34, in the green same-color pixel group 13Gb, it is possible to attempt to improve the sensitivity of pixels 12 that are arranged at the four locations on the left side and that tend to have low sensitivity and pixels 12 that are arranged at the four locations on the right side and that tend to have low sensitivity, by providing the intra-pixel grooves 22f-13 to 22f-20 with the cross shape and the enlarged structure to the pixels 12 that are arranged at the four locations on the left side and that tend to have low sensitivity and the pixels 12 that are arranged at the four locations on the right side and that tend to have low sensitivity, and also providing the intra-pixel grooves 22i-1 to 22i-8 with the vertical line shape and the enlarged structure to pixels 12 arranged at the eight locations in the two middle columns.

Moreover, similarly to the twelfth sensitivity adjustment structure 21_12 in FIG. 14, in the blue same-color pixel group 13B, it is possible to attempt to improve the overall sensitivity of all the sixteen pixels 12 in the 4×4 array by providing intra-pixel grooves 22f-21 to 22f-36 with the cross shape and the enlarged structure to those pixels 12, and also it is possible to suppress sensitivity differences in the green same-color pixel groups 13Gr arranged above and below the blue same-color pixel group 13B and the green same-color pixel groups 13Gb arranged to the left and the right of the blue same-color pixel group 13B.

Accordingly, by using such sensitivity adjustment structures 21 in combination, the ninth combination layout 61_9 can suppress inter-pixel-12 sensitivity differences, and attain more uniform sensitivity characteristics.

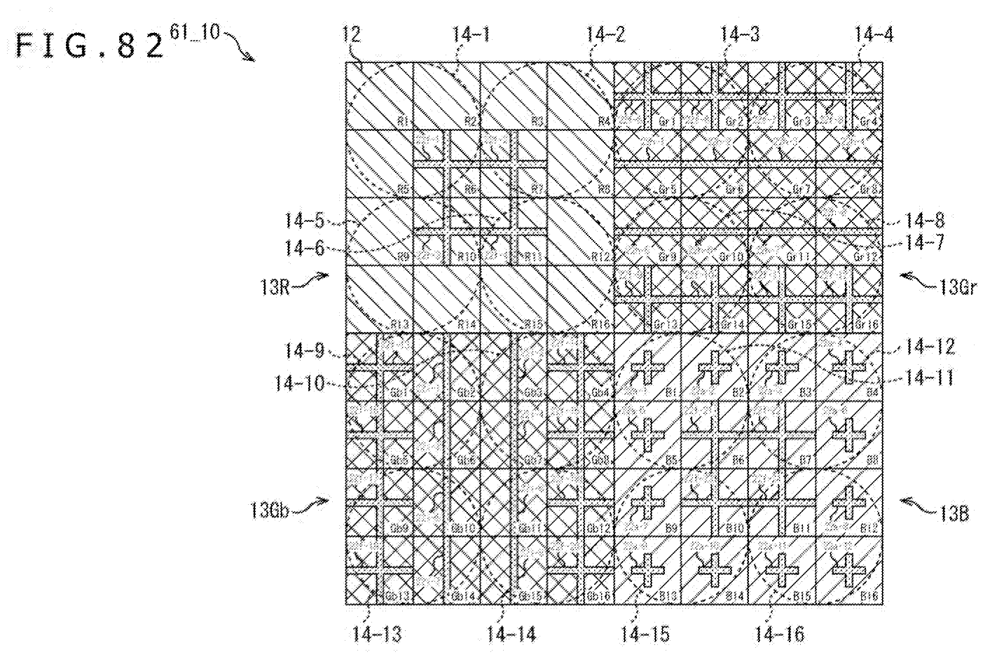

FIG. 82 is a figure depicting a configuration example of a tenth combination layout 61_10.

As depicted in FIG. 82, similarly to the ninth combination layout 61_9 in FIG. 81, in the red same-color pixel group 13R, the green same-color pixel group 13Gr, and the green same-color pixel group 13Gb, it is attempted with the tenth combination layout 61_10 to improve the sensitivity of pixels 12.

Moreover, in the blue same-color pixel group 13B, it is possible to attempt to more significantly improve the sensitivity of pixels 12 that are arranged at the four locations in the middle 2×2 array and that tend to have low sensitivity, by providing the intra-pixel grooves 22f-5 to 22f-8 with the cross shape and the enlarged structure to those pixels 12. Moreover, in the blue same-color pixel group 13B, it is possible to attempt to improve the sensitivity of pixels 12 arranged at the twelve peripheral locations, to a degree lower than that of the improvement at the middle, by providing the intra-pixel grooves 22a-1 to 22a-12 with the cross shape to those pixels 12.

Moreover, it is possible to suppress sensitivity differences in the green same-color pixel groups 13Gr arranged above and below the blue same-color pixel group 13B and the green same-color pixel groups 13Gb arranged to the left and the right of the blue same-color pixel group 13B.

Accordingly, by using such sensitivity adjustment structures 21 in combination, the tenth combination layout 61_10 can suppress inter-pixel-12 sensitivity differences, and attain more uniform sensitivity characteristics.

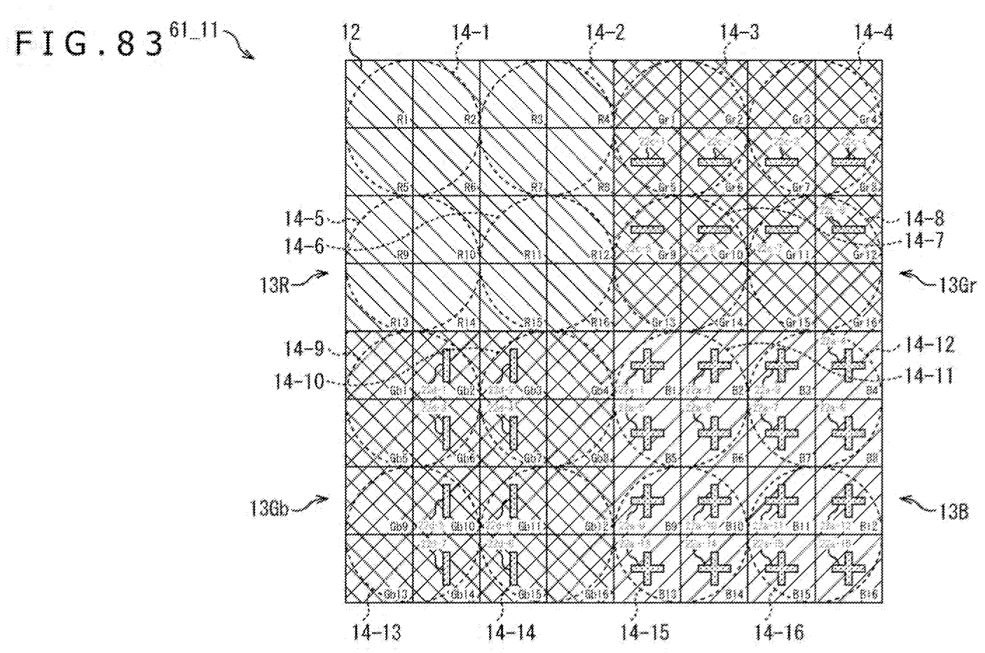

FIG. 83 is a figure depicting a configuration example of an eleventh combination layout 61_11.

As depicted in FIG. 83, similarly to the fifth combination layout 61_5 in FIG. 74, in the green same-color pixel group 13Gr, the green same-color pixel group 13Gb, and the blue same-color pixel group 13B, it is attempted with the eleventh combination layout 61_11 to improve the sensitivity of pixels 12. Note that intra-pixel grooves 22 are not provided in the red same-color pixel group 13R in order to avoid an increase of the degree of color mixing to different colors when light is scattered.

Accordingly, by using such sensitivity adjustment structures 21 in combination, the eleventh combination layout 61_11 can attain more uniform sensitivity characteristics in the green same-color pixel group 13Gr, the green same-color pixel group 13Gb, and the blue same-color pixel group 13B.

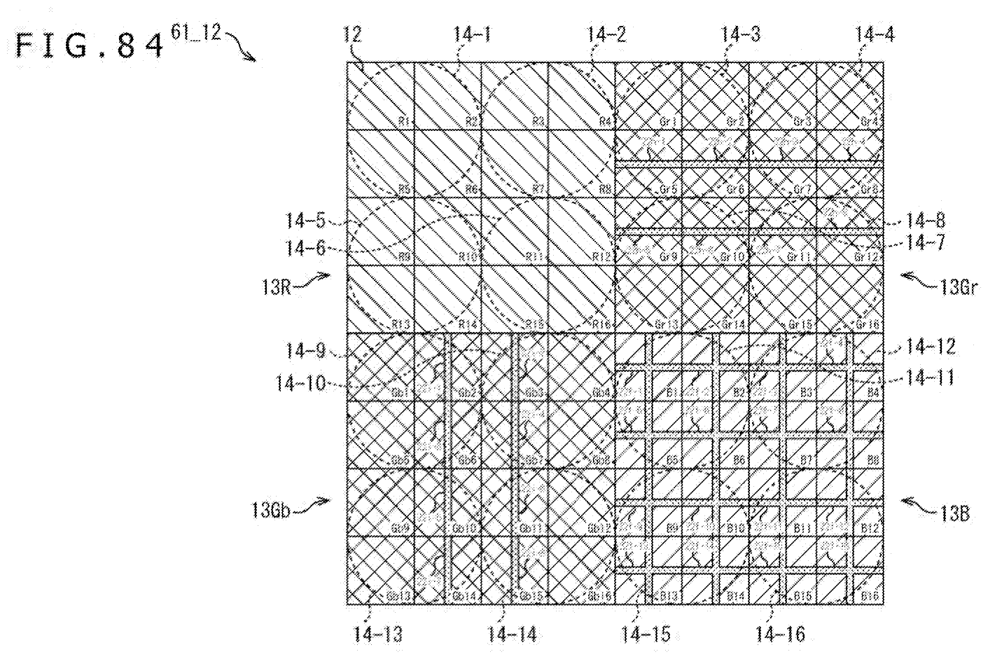

FIG. 84 is a figure depicting a configuration example of a twelfth combination layout 61_12.

As depicted in FIG. 84, similarly to the sixth combination layout 61_6 in FIG. 76, in the green same-color pixel group 13Gr, the green same-color pixel group 13Gb, and the blue same-color pixel group 13B, it is attempted with the twelfth combination layout 61_12 to improve the sensitivity of pixels 12. Note that intra-pixel grooves 22 are not provided in the red same-color pixel group 13R in order to avoid an increase of the degree of color mixing to different colors when light is scattered.

Accordingly, by using such sensitivity adjustment structures 21 in combination, the twelfth combination layout 61_12 can attain more uniform sensitivity characteristics in the green same-color pixel group 13Gr, the green same-color pixel group 13Gb, and the blue same-color pixel group 13B.

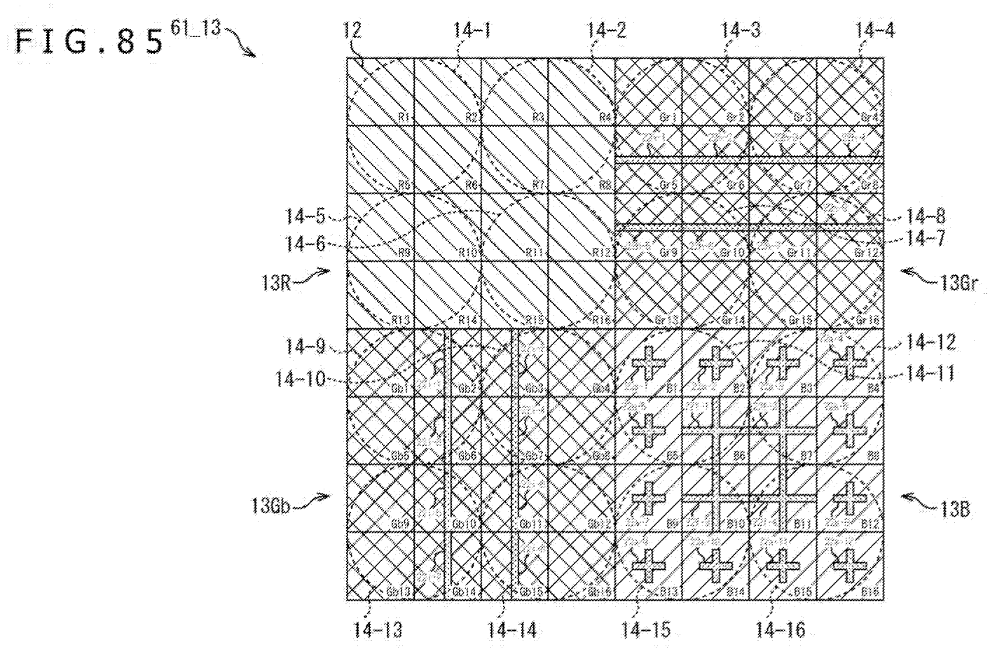

FIG. 85 is a figure depicting a configuration example of a thirteenth combination layout 61_13.

As depicted in FIG. 85, similarly to the seventh combination layout 61_7 in FIG. 78, in the green same-color pixel group 13Gr, the green same-color pixel group 13Gb, and the blue same-color pixel group 13B, it is attempted with the thirteenth combination layout 61_13 to improve the sensitivity of pixels 12. Note that intra-pixel grooves 22 are not provided in the red same-color pixel group 13R in order to avoid an increase of the degree of color mixing to different colors when light is scattered.

Accordingly, by using such sensitivity adjustment structures 21 in combination, the thirteenth combination layout 61_13 can attain more uniform sensitivity characteristics in the green same-color pixel group 13Gr, the green same-color pixel group 13Gb, and the blue same-color pixel group 13B.

Note that the configuration examples of the combination layouts 61 as the ones described above are not the sole examples, and sensitivity adjustment structures 21 of various combinations may be applied to the red same-color pixel group 13R, the green same-color pixel group 13Gr, the green same-color pixel group 13Gb, and the blue same-color pixel group 13B as long as more uniform sensitivity characteristics can be attained.

### Configuration Examples of 2×1-OCL Arrangement Patterns

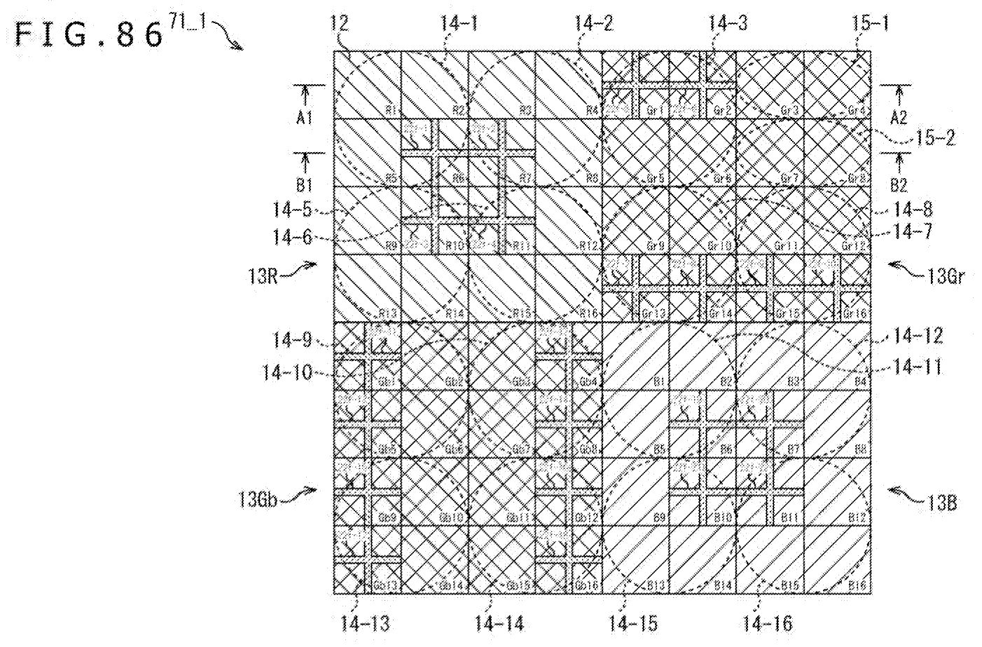

Configuration examples of 2×1-OCL arrangement patterns are explained with reference to FIG. 86 to FIG. 125.

Whereas an on-chip lens 14 is arranged for each 2×2 array of pixels 12 in the configuration explained in the embodiment described above, for example, one on-chip lens is arranged for each pair of horizontally or vertically adjacent pixels 12 for detecting an image surface phase difference, in another possible manner of the configuration. An on-chip lens arranged for a pair of pixels 12 in such a manner is referred to as a 2×1-OCL 15.

For example, 2×1-OCLs 15 tend to be arranged for green pixels 12-Gr or pixels 12-Gb. This is because, in the Bayer array, the number of green pixels 12-Gr or pixels 12-Gb is greater than the numbers of red pixels 12-R and blue pixels 12-B and, even if some green pixels 12-Gr or pixels 12-Gb are used for detection of an image surface phase difference, there are many green pixels 12-Gr or pixels 12-Gb to be used for generation of an image. In addition, it is possible with a configuration in which many 2×1-OCLs 15 are provided to attempt to improve the phase-difference detection precision or detection speed. In addition, it is possible with a configuration in which few 2×1-OCLs 15 are provided to attempt to improve the sensitivity of normal pixels 12 to be used for generation of an image.

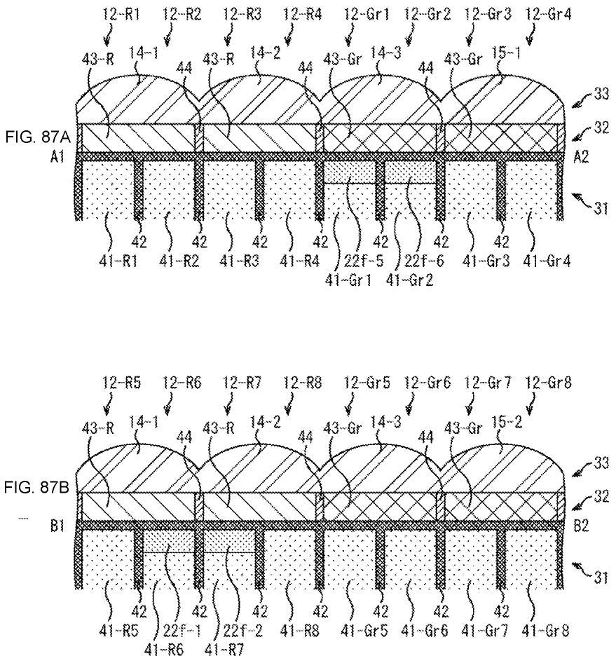

FIG. 86 is a figure depicting an example of a first 2×1-OCL arrangement pattern 71_1. A in FIG. 87 depicts the configuration example of the first 2×1-OCL arrangement pattern 71_1 on a cross-section taken along A1-A2 depicted in FIG. 86, and B in FIG. 87 depicts the configuration example of the first 2×1-OCL arrangement pattern 71_1 on a cross-section taken along B1-B2 depicted in FIG. 86.

As depicted in FIG. 86, in the first 2×1-OCL arrangement pattern 71_1, a 2×1-OCL 15-1 is arranged for the pixels 12-Gr3 and 12-Gr4, and a 2×1-OCL 15-2 is arranged for the pixels 12-Gr7 and 12-Gr8.

Further, the pixels 12 provided with the 2×1-OCLs 15 are not provided with intra-pixel grooves 22 in this configuration. That is, intra-pixel grooves 22 are provided to pixels 12 other than the pixels 12 provided with the 2×1-OCLs 15. This is because the pixels 12 for acquiring an image surface phase difference are provided with inter-pixel light-blocking films below the 2×1-OCLs 15 and, if intra-pixel grooves 22 are provided to the pixels 12, light hits the inter-pixel light-blocking films and is scattered undesirably. As a result, the separation ratio of the pairs of pixels 12 for phase difference detection lowers, and the phase-difference detection precision lowers undesirably. Accordingly, the pixels 12 provided with the 2×1-OCLs 15, that is, the pairs of pixels 12 for phase difference detection, are not provided with intra-pixel grooves 22 in a suitable configuration.

Note that, in 2×1-OCL arrangement patterns 71 to be explained below, each pixel 12 other than pixels 12 provided with 2×1-OCLs 15 may be provided with an on-chip lens 14, or each 2×2 array of four pixels 12 other than pixels 12 provided with 2×1-OCLs 15 may be provided with an on-chip lens 14.

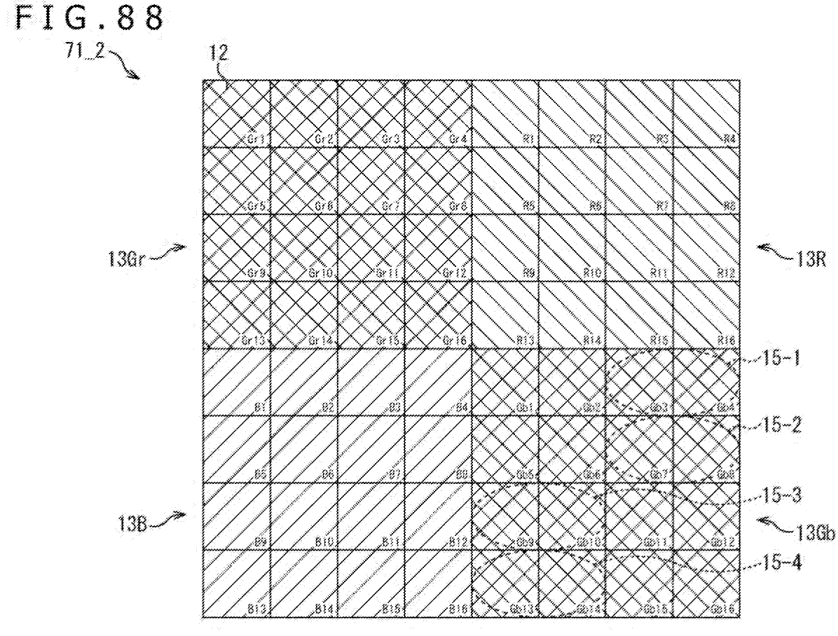

FIG. 88 is a figure depicting an example of a second 2×1-OCL arrangement pattern 71_2.

As depicted in FIG. 88, in the second 2×1-OCL arrangement pattern 71_2, the 2×1-OCL 15-1 is arranged for the pixels 12-Gb3 and 12-Gb4, the 2×1-OCL 15-2 is arranged for the pixels 12-Gb7 and 12-Gb8, a 2×1-OCL 15-3 is arranged for the pixels 12-Gb9 and 12-Gb10, and a 2×1-OCL 15-4 is arranged for the pixels 12-Gb13 and 12-Gb14.

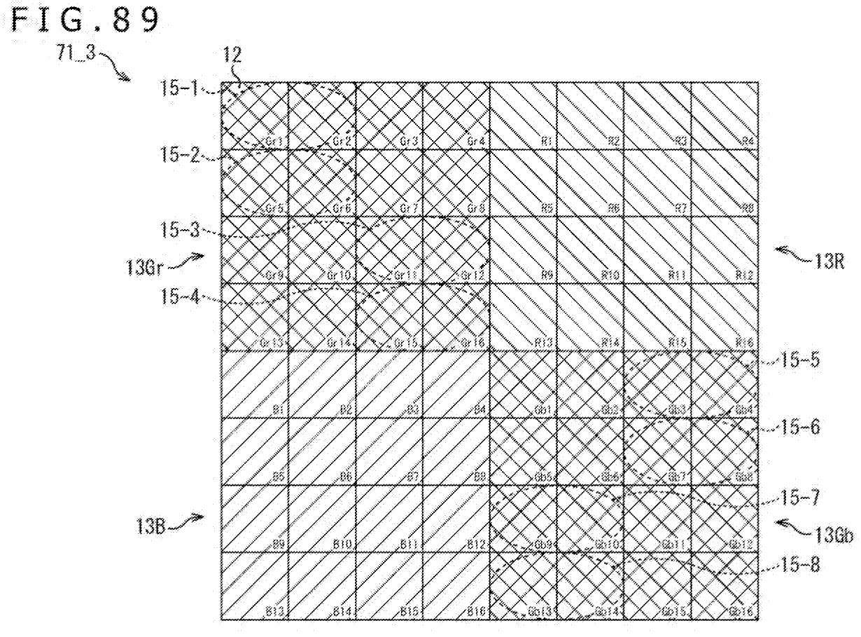

FIG. 89 is a figure depicting an example of a third 2×1-OCL arrangement pattern 71_3.

As depicted in FIG. 89, in the third 2×1-OCL arrangement pattern 71_3, the 2×1-OCL 15-1 is arranged for the pixels 12-Gr1 and 12-Gr2, the 2×1-OCL 15-2 is arranged for the pixels 12-Gr5 and 12-Gr6, the 2×1-OCL 15-3 is arranged for the pixels 12-Gr11 and 12-Gr12, and the 2×1-OCL 15-4 is arranged for the pixels 12-Gr15 and 12-Gr16. Moreover, a 2×1-OCL 15-5 is arranged for the pixels 12-Gb3 and 12-Gb4, a 2×1-OCL 15-6 is arranged for the pixels 12-Gb7 and 12-Gb8, a 2×1-OCL 15-7 is arranged for the pixels 12-Gb9 and 12-Gb10, and a 2×1-OCL 15-8 is arranged for the pixels 12-Gb13 and 12-Gb14.

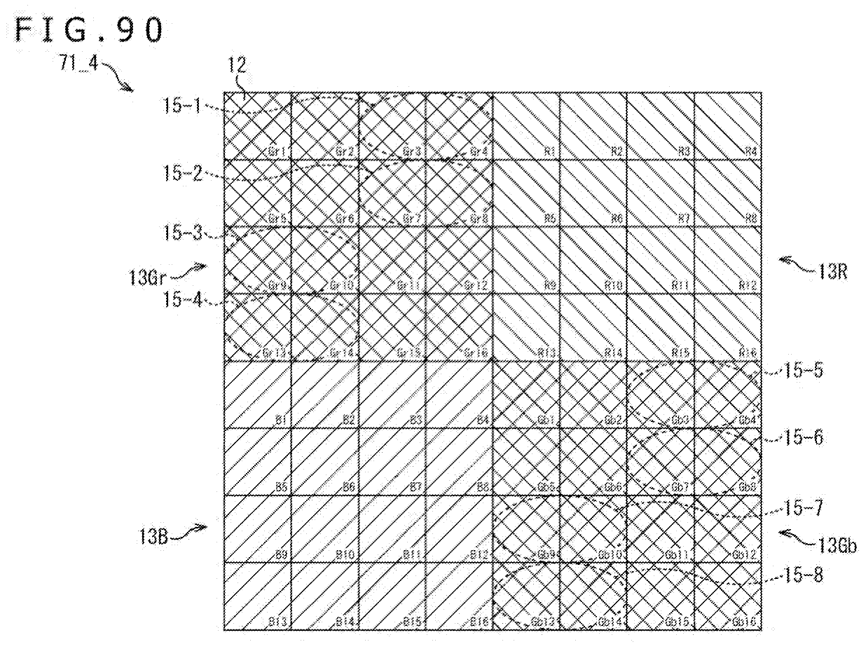

FIG. 90 is a figure depicting an example of a fourth 2×1-OCL arrangement pattern 71_4.

As depicted in FIG. 90, in the fourth 2×1-OCL arrangement pattern 71_4, the 2×1-OCL 15-1 is arranged for the pixels 12-Gr3 and 12-Gr4, the 2×1-OCL 15-2 is arranged for the pixels 12-Gr7 and 12-Gr8, the 2×1-OCL 15-3 is arranged for the pixels 12-Gr9 and 12-Gr10, and the 2×1-OCL 15-4 is arranged for the pixels 12-Gr13 and 12-Gr14. Moreover, the 2×1-OCL 15-5 is arranged for the pixels 12-Gb3 and 12-Gb4, the 2×1-OCL 15-6 is arranged for the pixels 12-Gb7 and 12-Gb8, the 2×1-OCL 15-7 is arranged for the pixels 12-Gb9 and 12-Gb10, and the 2×1-OCL 15-8 is arranged for the pixels 12-Gb13 and 12-Gb14.

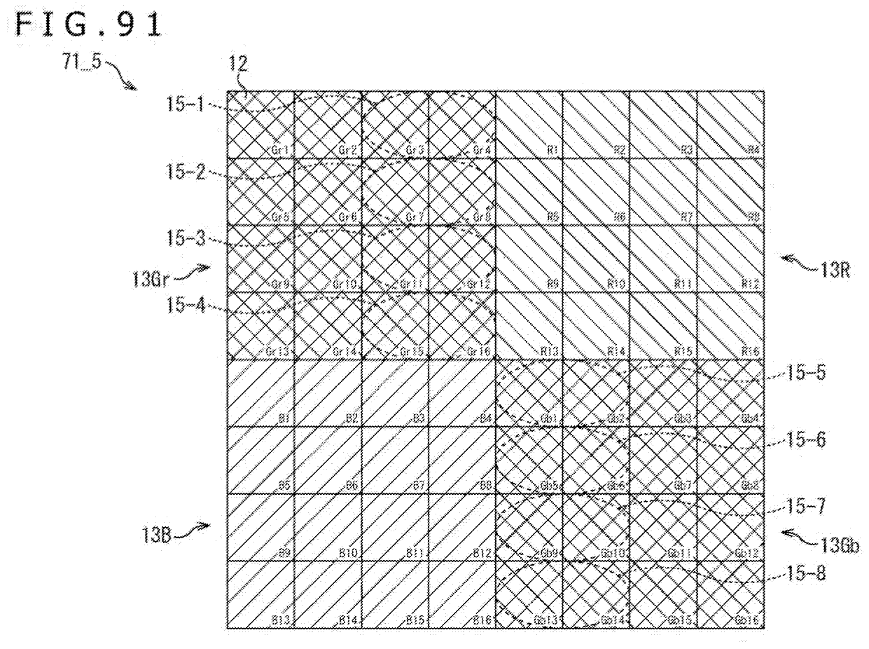

FIG. 91 is a figure depicting an example of a fifth 2×1-OCL arrangement pattern 71_5.

As depicted in FIG. 91, in the fifth 2×1-OCL arrangement pattern 71_5, the 2×1-OCL 15-1 is arranged for the pixels 12-Gr3 and 12-Gr4, the 2×1-OCL 15-2 is arranged for the pixels 12-Gr7 and 12-Gr8, the 2×1-OCL 15-3 is arranged for the pixels 12-Gr11 and 12-Gr12, and the 2×1-OCL 15-4 is arranged for the pixels 12-Gr15 and 12-Gr16. Moreover, the 2×1-OCL 15-5 is arranged for the pixels 12-Gb1 and 12-Gb2, the 2×1-OCL 15-6 is arranged for the pixels 12-Gb5 and 12-Gb6, the 2×1-OCL 15-7 is arranged for the pixels 12-Gb9 and 12-Gb10, and the 2×1-OCL 15-8 is arranged for the pixels 12-Gb13 and 12-Gb14.

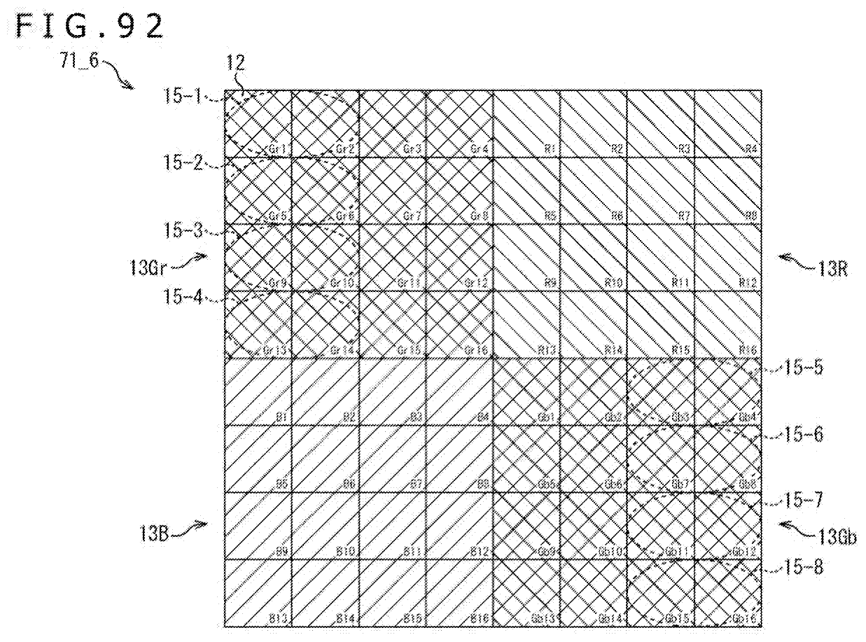

FIG. 92 is a figure depicting an example of a sixth 2×1-OCL arrangement pattern 71_6.

As depicted in FIG. 92, in the sixth 2×1-OCL arrangement pattern 71_6, the 2×1-OCL 15-1 is arranged for the pixels 12-Gr1 and 12-Gr2, the 2×1-OCL 15-2 is arranged for the pixels 12-Gr5 and 12-Gr6, the 2×1-OCL 15-3 is arranged for the pixels 12-Gr9 and 12-Gr10, and the 2×1-OCL 15-4 is arranged for the pixels 12-Gr13 and 12-Gr14. Moreover, the 2×1-OCL 15-5 is arranged for the pixels 12-Gb3 and 12-Gb4, the 2×1-OCL 15-6 is arranged for the pixels 12-Gb7 and 12-Gb8, the 2×1-OCL 15-7 is arranged for the pixels 12-Gb11 and 12-Gb12, and the 2×1-OCL 15-8 is arranged for the pixels 12-Gb15 and 12-Gb16.

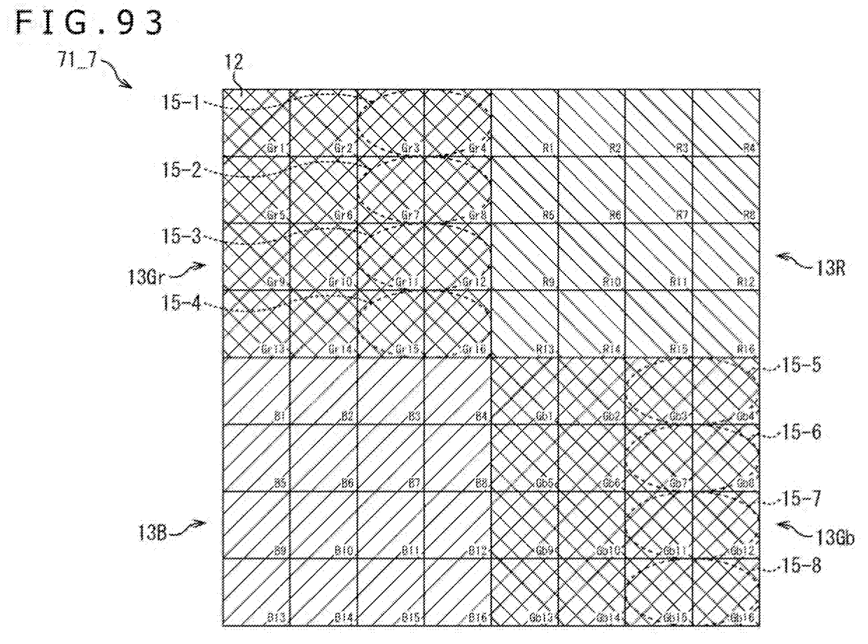

FIG. 93 is a figure depicting an example of a seventh 2×1-OCL arrangement pattern 71_7.

As depicted in FIG. 93, in the seventh 2×1-OCL arrangement pattern 71_7, the 2×1-OCL 15-1 is arranged for the pixels 12-Gr3 and 12-Gr4, the 2×1-OCL 15-2 is arranged for the pixels 12-Gr7 and 12-Gr8, the 2×1-OCL 15-3 is arranged for the pixels 12-Gr11 and 12-Gr12, and the 2×1-OCL 15-4 is arranged for the pixels 12-Gr15 and 12-Gr16. Moreover, the 2×1-OCL 15-5 is arranged for the pixels 12-Gb3 and 12-Gb4, the 2×1-OCL 15-6 is arranged for the pixels 12-Gb7 and 12-Gb8, the 2×1-OCL 15-7 is arranged for the pixels 12-Gb11 and 12-Gb12, and the 2×1-OCL 15-8 is arranged for the pixels 12-Gb15 and 12-Gb16.

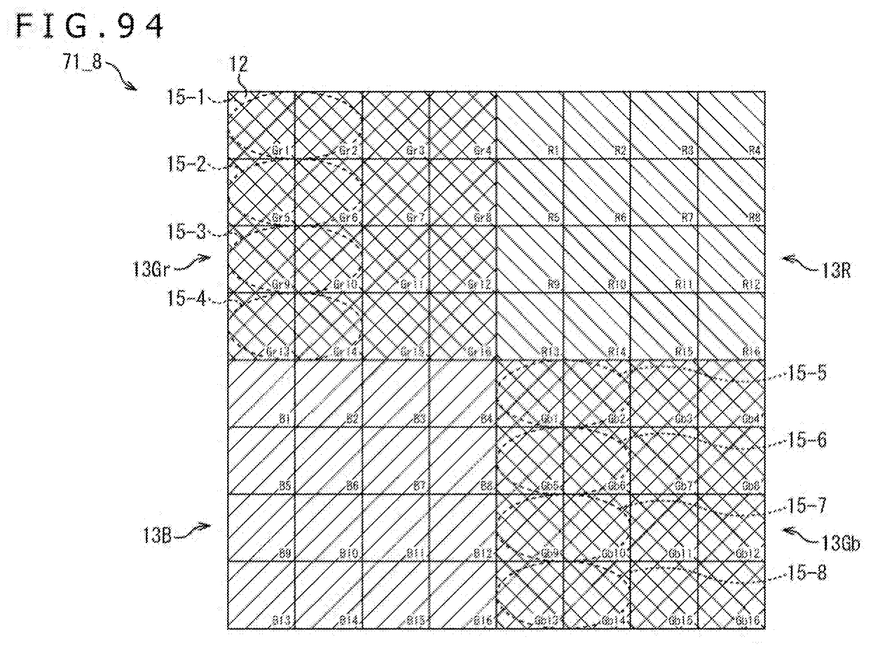

FIG. 94 is a figure depicting an example of an eighth 2×1-OCL arrangement pattern 71_8.

As depicted in FIG. 94, in the eighth 2×1-OCL arrangement pattern 71_8, the 2×1-OCL 15-1 is arranged for the pixels 12-Gr1 and 12-Gr2, the 2×1-OCL 15-2 is arranged for the pixels 12-Gr5 and 12-Gr6, the 2×1-OCL 15-3 is arranged for the pixels 12-Gr9 and 12-Gr10, and the 2×1-OCL 15-4 is arranged for the pixels 12-Gr13 and 12-Gr14. Moreover, the 2×1-OCL 15-5 is arranged for the pixels 12-Gb1 and 12-Gb2, the 2×1-OCL 15-6 is arranged for the pixels 12-Gb5 and 12-Gb6, the 2×1-OCL 15-7 is arranged for the pixels 12-Gb9 and 12-Gb10, and the 2×1-OCL 15-8 is arranged for the pixels 12-Gb13 and 12-Gb14.

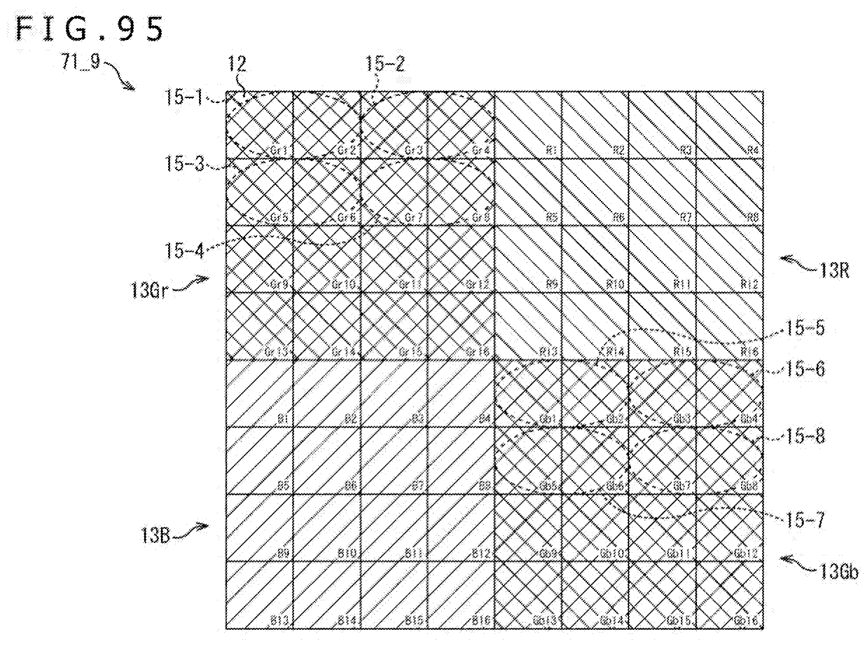

FIG. 95 is a figure depicting an example of a ninth 2×1-OCL arrangement pattern 71_9.

As depicted in FIG. 95, in the ninth 2×1-OCL arrangement pattern 71_9, the 2×1-OCL 15-1 is arranged for the pixels 12-Gr1 and 12-Gr2, the 2×1-OCL 15-2 is arranged for the pixels 12-Gr3 and 12-Gr4, the 2×1-OCL 15-3 is arranged for the pixels 12-Gr5 and 12-Gr6, and the 2×1-OCL 15-4 is arranged for the pixels 12-Gr7 and 12-Gr8. Moreover, the 2×1-OCL 15-5 is arranged for the pixels 12-Gb1 and 12-Gb2, the 2×1-OCL 15-6 is arranged for the pixels 12-Gb3 and 12-Gb4, the 2×1-OCL 15-7 is arranged for the pixels 12-Gb5 and 12-Gb6, and the 2×1-OCL 15-8 is arranged for the pixels 12-Gb7 and 12-Gb8.

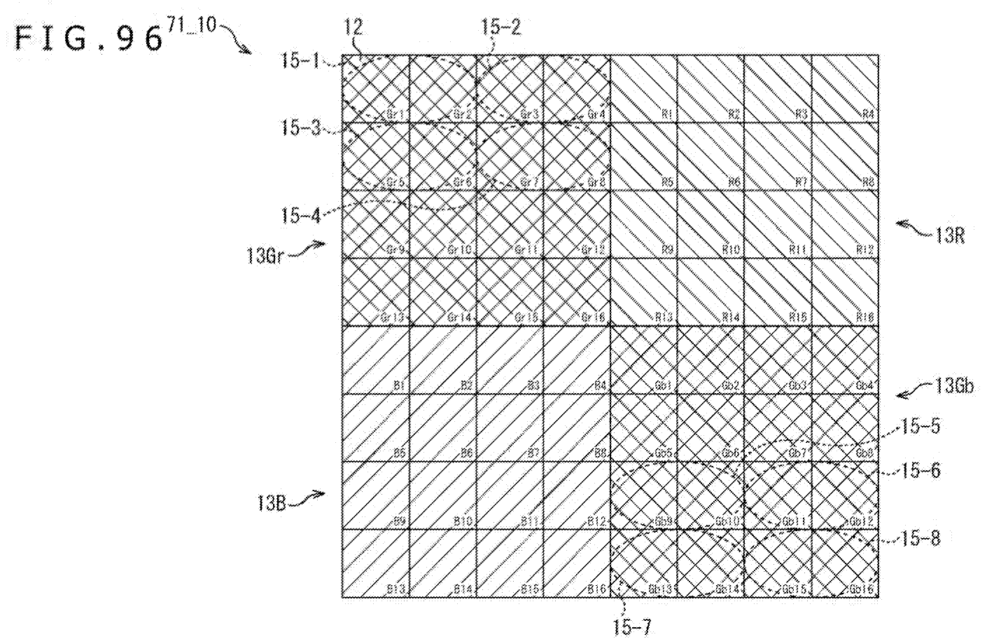

FIG. 96 is a figure depicting an example of a tenth 2×1-OCL arrangement pattern 71_10.

As depicted in FIG. 96, in the tenth 2×1-OCL arrangement pattern 71_10, the 2×1-OCL 15-1 is arranged for the pixels 12-Gr1 and 12-Gr2, the 2×1-OCL 15-2 is arranged for the pixels 12-Gr3 and 12-Gr4, the 2×1-OCL 15-3 is arranged for the pixels 12-Gr5 and 12-Gr6, and the 2×1-OCL 15-4 is arranged for the pixels 12-Gr7 and 12-Gr8. Moreover, the 2×1-OCL 15-5 is arranged for the pixels 12-Gb9 and 12-Gb10, the 2×1-OCL 15-6 is arranged for the pixels 12-Gb11 and 12-Gb12, the 2×1-OCL 15-7 is arranged for the pixels 12-Gb13 and 12-Gb14, and the 2×1-OCL 15-8 is arranged for the pixels 12-Gb15 and 12-Gb16.

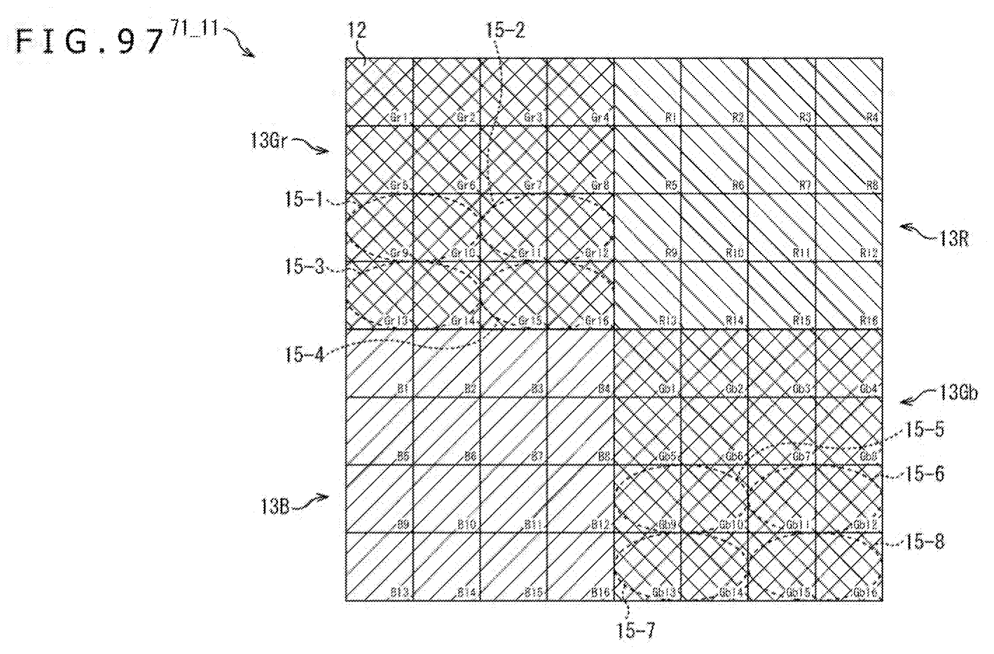

FIG. 97 is a figure depicting an example of an eleventh 2×1-OCL arrangement pattern 71_11.

As depicted in FIG. 97, in the eleventh 2×1-OCL arrangement pattern 71_11, the 2×1-OCL 15-1 is arranged for the pixels 12-Gr9 and 12-Gr10, the 2×1-OCL 15-2 is arranged for the pixels 12-Gr11 and 12-Gr12, the 2×1-OCL 15-3 is arranged for the pixels 12-Gr13 and 12-Gr14, and the 2×1-OCL 15-4 is arranged for the pixels 12-Gr15 and 12-Gr16. Moreover, the 2×1-OCL 15-5 is arranged for the pixels 12-Gb9 and 12-Gb10, the 2×1-OCL 15-6 is arranged for the pixels 12-Gb11 and 12-Gb12, the 2×1-OCL 15-7 is arranged for the pixels 12-Gb13 and 12-Gb14, and the 2×1-OCL 15-8 is arranged for the pixels 12-Gb15 and 12-Gb16.

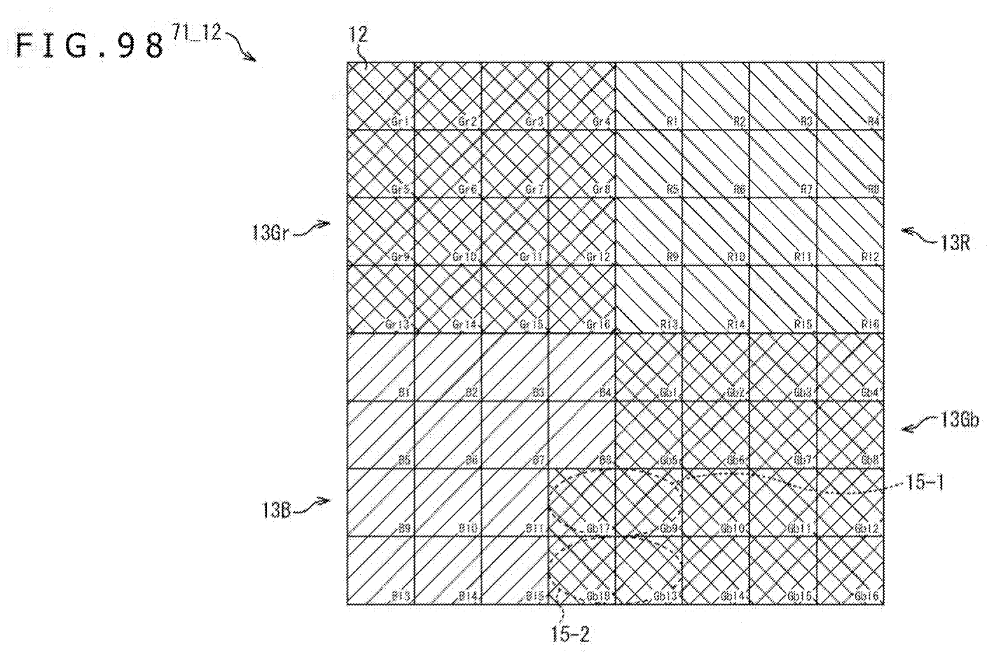

FIG. 98 is a figure depicting an example of a twelfth 2×1-OCL arrangement pattern 71_12.

Here, in the twelfth 2×1-OCL arrangement pattern 71_12, the blue pixel 12-B12 is replaced with a green pixel 12-Gb17, and the blue pixel 12-B16 is replaced with a green pixel 12-Gb18. That is, in this arrangement of the color filters 43, the green same-color pixel group 13Gb partially protrudes into the blue same-color pixel group 13B.

Further, in the twelfth 2×1-OCL arrangement pattern 71_12, the 2×1-OCL 15-1 is arranged for the pixels 12-Gb9 and 12-Gb17, and the 2×1-OCL 15-2 is arranged for the pixels 12-Gb13 and 12-Gb18.

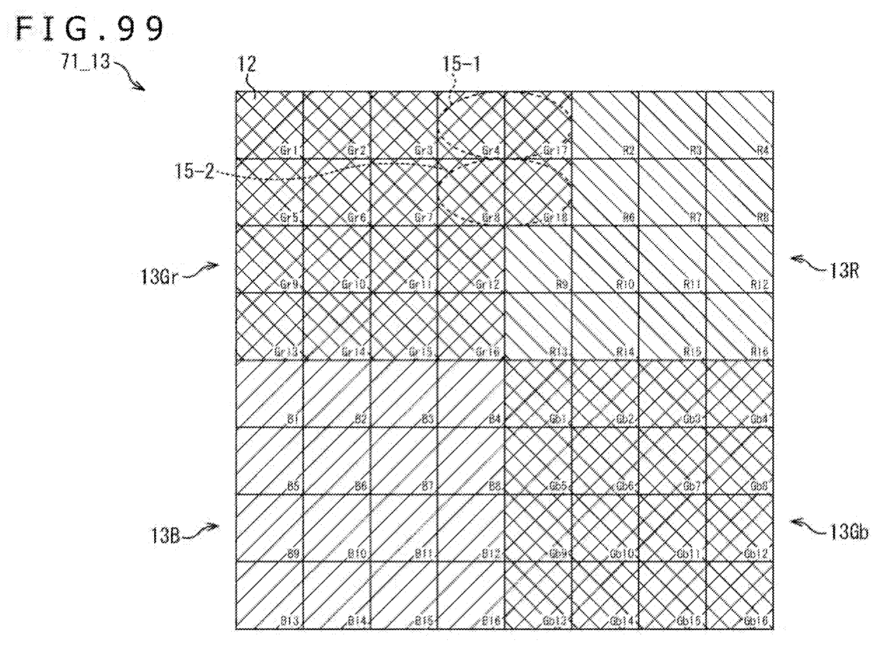

FIG. 99 is a figure depicting an example of a thirteenth 2×1-OCL arrangement pattern 71_13.

Here, in the thirteenth 2×1-OCL arrangement pattern 71_13, the red pixel 12-R1 is replaced with a green pixel 12-Gr17, and the red pixel 12-R5 is replaced with a green pixel 12-Gr18. That is, in this arrangement of the color filters 43, the green same-color pixel group 13Gr partially protrudes into the red same-color pixel group 13R.

Further, in the thirteenth 2×1-OCL arrangement pattern 71_13, the 2×1-OCL 15-1 is arranged for the pixels 12-Gr4 and 12-Gr17, and the 2×1-OCL 15-2 is arranged for the pixels 12-Gr8 and 12-Gr18.

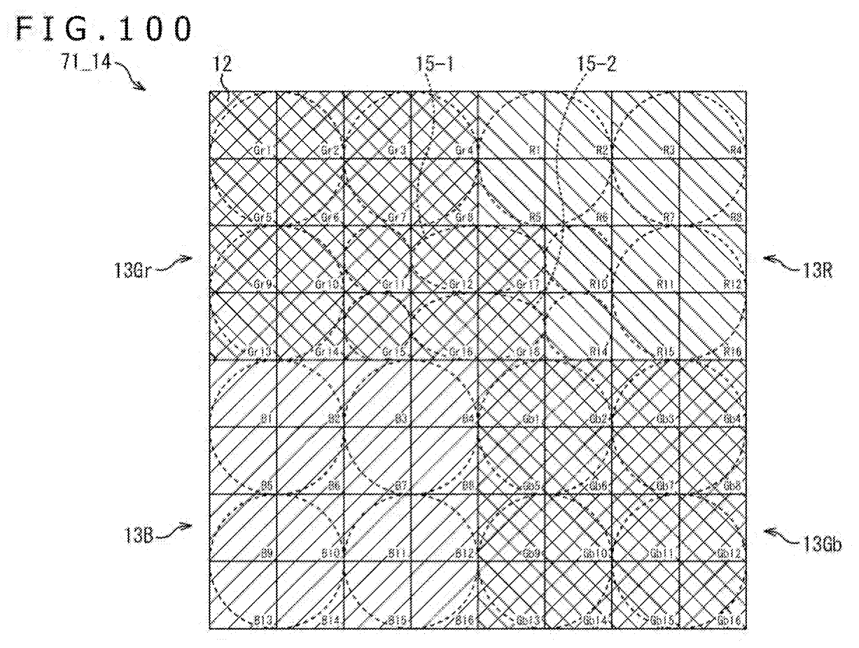

FIG. 100 is a figure depicting an example of a fourteenth 2×1-OCL arrangement pattern 71_14.

Here, in the fourteenth 2×1-OCL arrangement pattern 71_14, the red pixel 12-R9 is replaced with the green pixel 12-Gr17, and the red pixel 12-R13 is replaced with the green pixel 12-Gr18. That is, in this arrangement of the color filters 43, the green same-color pixel group 13Gr partially protrudes into the red same-color pixel group 13R.

Further, in the fourteenth 2×1-OCL arrangement pattern 71_14, the 2×1-OCL 15-1 is arranged for the pixels 12-Gr12 and 12-Gr17, and the 2×1-OCL 15-2 is arranged for the pixels 12-Gr16 and 12-Gr18.

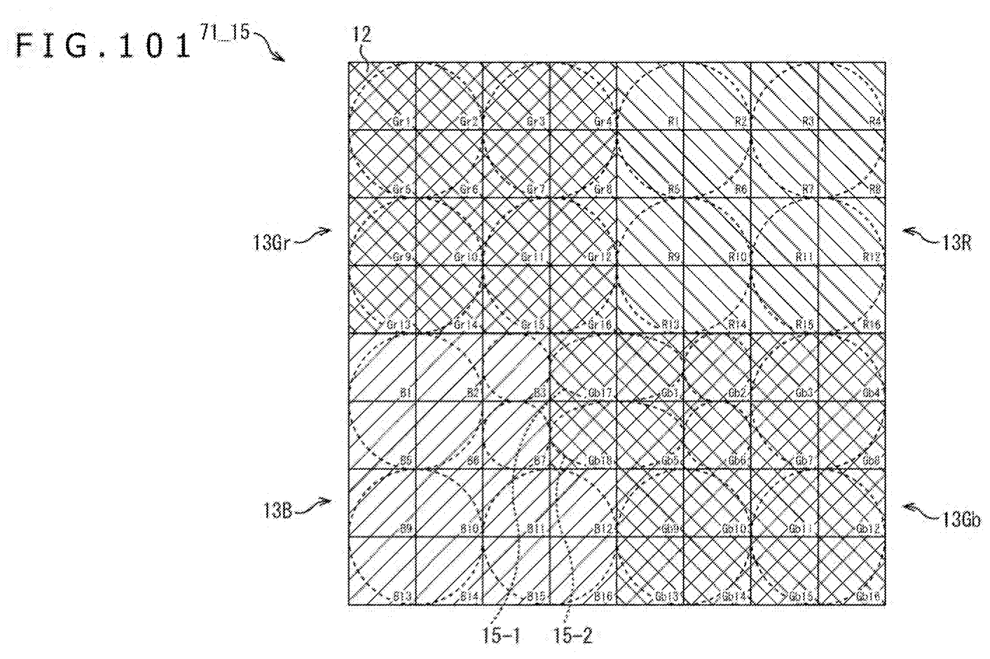

FIG. 101 is a figure depicting an example of a fifteenth 2×1-OCL arrangement pattern 71_15.

Here, in the fifteenth 2×1-OCL arrangement pattern 71_15, the blue pixel 12-B4 is replaced with the green pixel 12-Gb17, and the blue pixel 12-B8 is replaced with the green pixel 12-Gb18. That is, in this arrangement of the color filters 43, the green same-color pixel group 13Gb partially protrudes into the blue same-color pixel group 13B.

Further, in the fifteenth 2×1-OCL arrangement pattern 71_15, the 2×1-OCL 15-1 is arranged for the pixels 12-Gb1 and 12-Gb17, and the 2×1-OCL 15-2 is arranged for the pixels 12-Gb5 and 12-Gb18.

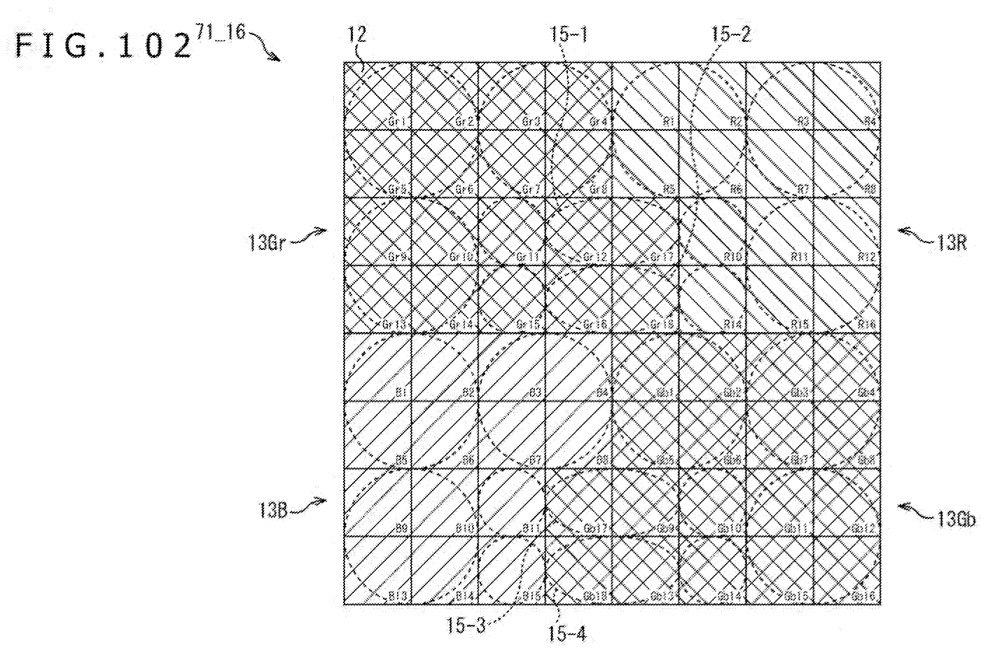

FIG. 102 is a figure depicting an example of a sixteenth 2×1-OCL arrangement pattern 71_16.

Here, in the sixteenth 2×1-OCL arrangement pattern 71_16, the red pixel 12-R9 is replaced with the green pixel 12-Gr17, and the red pixel 12-R13 is replaced with the green pixel 12-Gr18. That is, in this arrangement of the color filters 43, the green same-color pixel group 13Gr partially protrudes into the red same-color pixel group 13R. Moreover, the blue pixel 12-B12 is replaced with the green pixel 12-Gb17, and the blue pixel 12-B16 is replaced with the green pixel 12-Gb18. That is, in this arrangement of the color filters 43, the green same-color pixel group 13Gb partially protrudes into the blue same-color pixel group 13B.

Further, in the sixteenth 2×1-OCL arrangement pattern 71_16, the 2×1-OCL 15-1 is arranged for the pixels 12-Gr12 and 12-Gr17, and the 2×1-OCL 15-2 is arranged for the pixels 12-Gr16 and 12-Gr18. Moreover, the 2×1-OCL 15-3 is arranged for the pixels 12-Gb9 and 12-Gb17, and the 2×1-OCL 15-4 is arranged for the pixels 12-Gb13 and 12-Gb18.

Here, whereas on-chip lenses 14 other than the 2×1-OCLs 15 are illustrated with broken lines in FIG. 100 to FIG. 102, such arrangement of on-chip lenses 14 is not the sole example. For example, an on-chip lens 14 may be arranged for each pixel 12 of all pixels 12 other than the pixels 12 for which the 2×1-OCLs 15 are arranged, in another possible manner of the configuration.

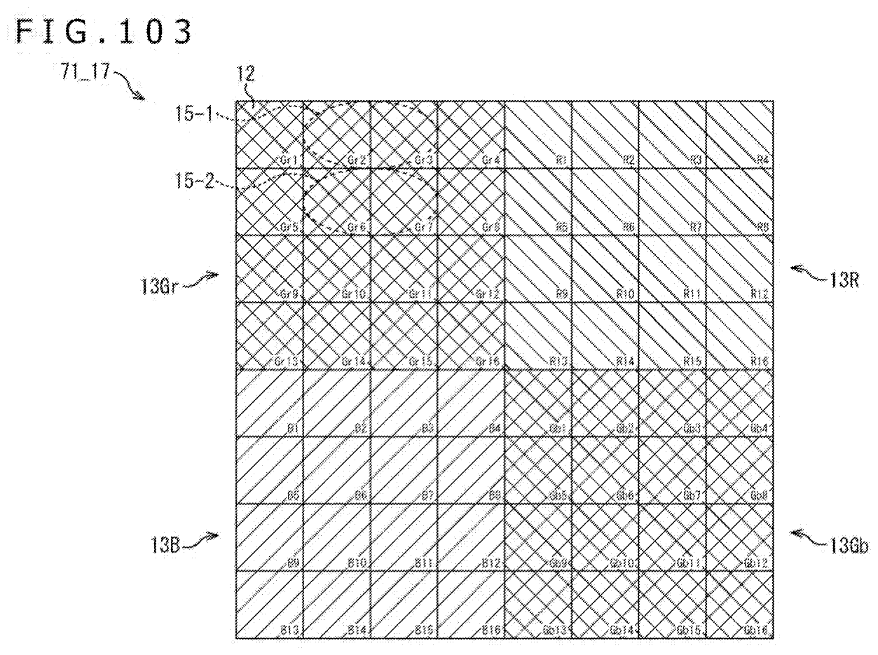

FIG. 103 is a figure depicting an example of a seventeenth 2×1-OCL arrangement pattern 71_17.

As depicted in FIG. 103, in the seventeenth 2×1-OCL arrangement pattern 71_17, the 2×1-OCL 15-1 is arranged for the pixels 12-Gr2 and 12-Gr3, and the 2×1-OCL 15-2 is arranged for the pixels 12-Gr6 and 12-Gr7.

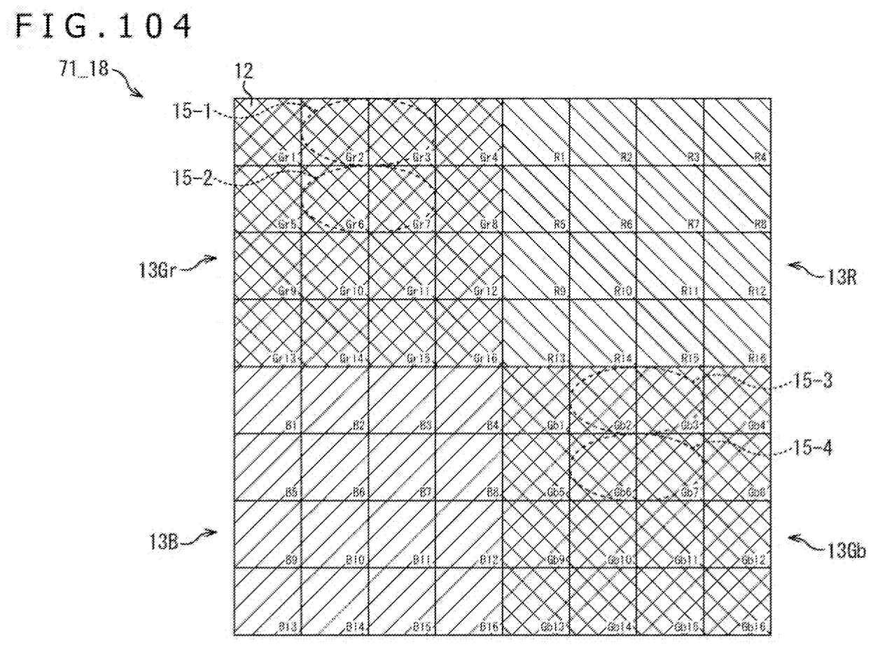

FIG. 104 is a figure depicting an example of an eighteenth 2×1-OCL arrangement pattern 71_18.

As depicted in FIG. 104, in the eighteenth 2×1-OCL arrangement pattern 71_18, the 2×1-OCL 15-1 is arranged for the pixels 12-Gr2 and 12-Gr3, the 2×1-OCL 15-2 is arranged for the pixels 12-Gr6 and 12-Gr7, the 2×1-OCL 15-3 is arranged for the pixels 12-Gb2 and 12-Gb3, and the 2×1-OCL 15-4 is arranged for the pixels 12-Gb6 and 12-Gb7.

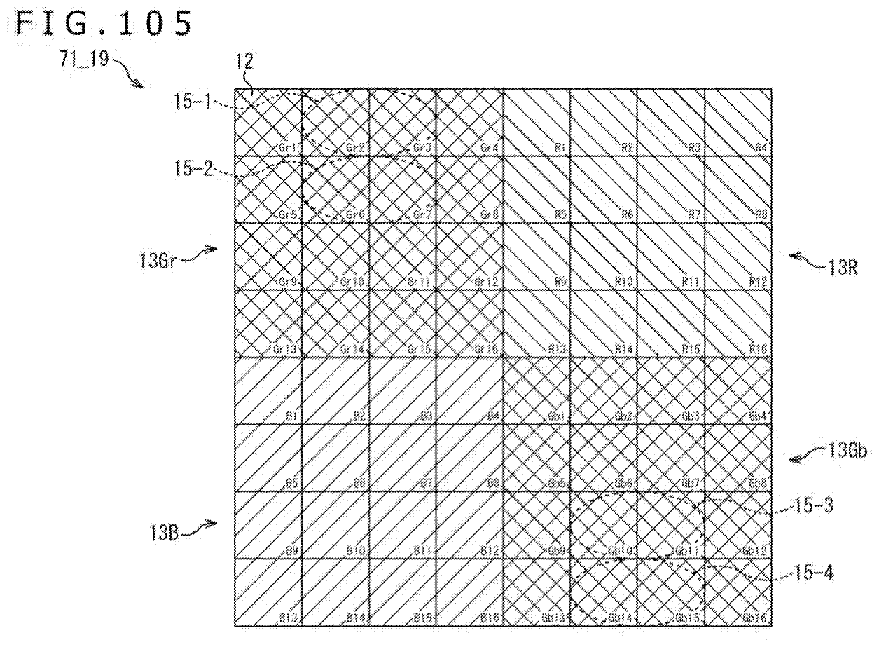

FIG. 105 is a figure depicting an example of a nineteenth 2×1-OCL arrangement pattern 71_19.

As depicted in FIG. 105, in the nineteenth 2×1-OCL arrangement pattern 71_19, the 2×1-OCL 15-1 is arranged for the pixels 12-Gr2 and 12-Gr3, the 2×1-OCL 15-2 is arranged for the pixels 12-Gr6 and 12-Gr7, the 2×1-OCL 15-3 is arranged for the pixels 12-Gb10 and 12-Gb11, and the 2×1-OCL 15-4 is arranged for the pixels 12-Gb14 and 12-Gb15.

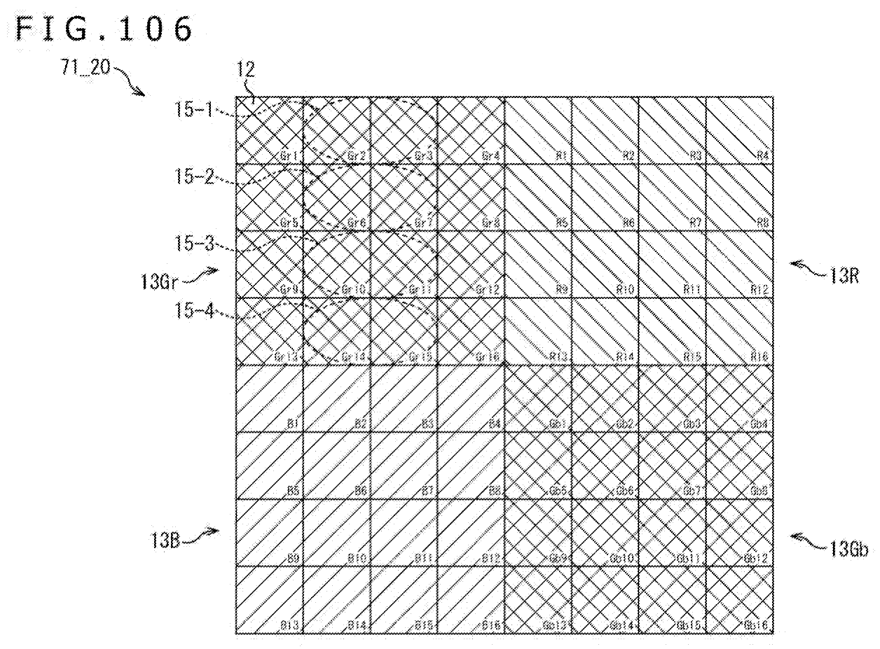

FIG. 106 is a figure depicting an example of a twentieth 2×1-OCL arrangement pattern 71_20.

As depicted in FIG. 106, in the twentieth 2×1-OCL arrangement pattern 71_20, the 2×1-OCL 15-1 is arranged for the pixels 12-Gr2 and 12-Gr3, the 2×1-OCL 15-2 is arranged for the pixels 12-Gr6 and 12-Gr7, the 2×1-OCL 15-3 is arranged for the pixels 12-Gr10 and 12-Gr11, and the 2×1-OCL 15-4 is arranged for the pixels 12-Gr14 and 12-Gr15.

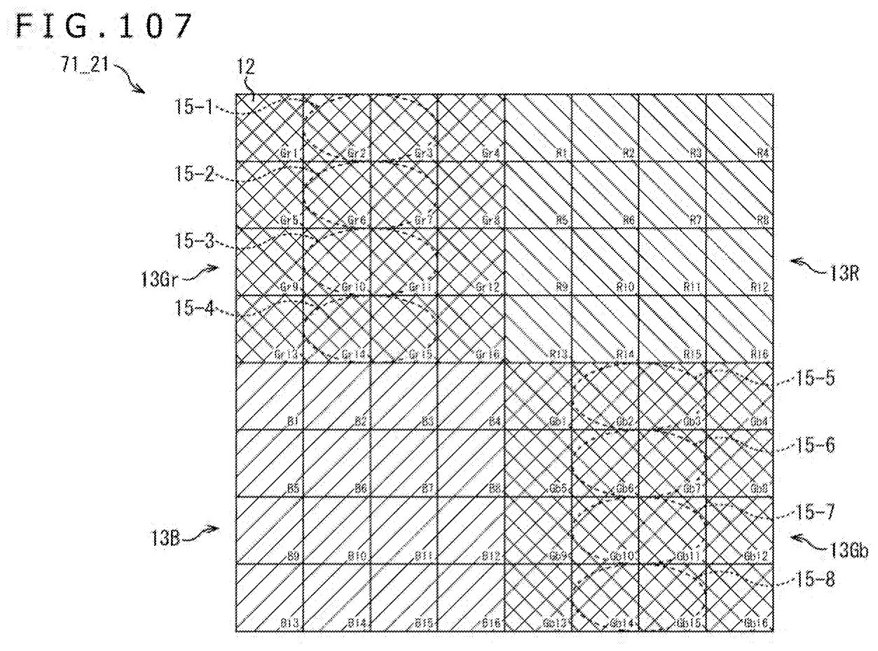

FIG. 107 is a figure depicting an example of a twenty-first 2×1-OCL arrangement pattern 71_21.

As depicted in FIG. 107, in the twenty-first 2×1-OCL arrangement pattern 71_21, the 2×1-OCL 15-1 is arranged for the pixels 12-Gr2 and 12-Gr3, the 2×1-OCL 15-2 is arranged for the pixels 12-Gr6 and 12-Gr7, the 2×1-OCL 15-3 is arranged for the pixels 12-Gr10 and 12-Gr11, and the 2×1-OCL 15-4 is arranged for the pixels 12-Gr14 and 12-Gr15. Moreover, the 2×1-OCL 15-5 is arranged for the pixels 12-Gb2 and 12-Gb3, the 2×1-OCL 15-6 is arranged for the pixels 12-Gb6 and 12-Gb7, the 2×1-OCL 15-7 is arranged for the pixels 12-Gb10 and 12-Gb11, and the 2×1-OCL 15-8 is arranged for the pixels 12-Gb14 and 12-Gb15.

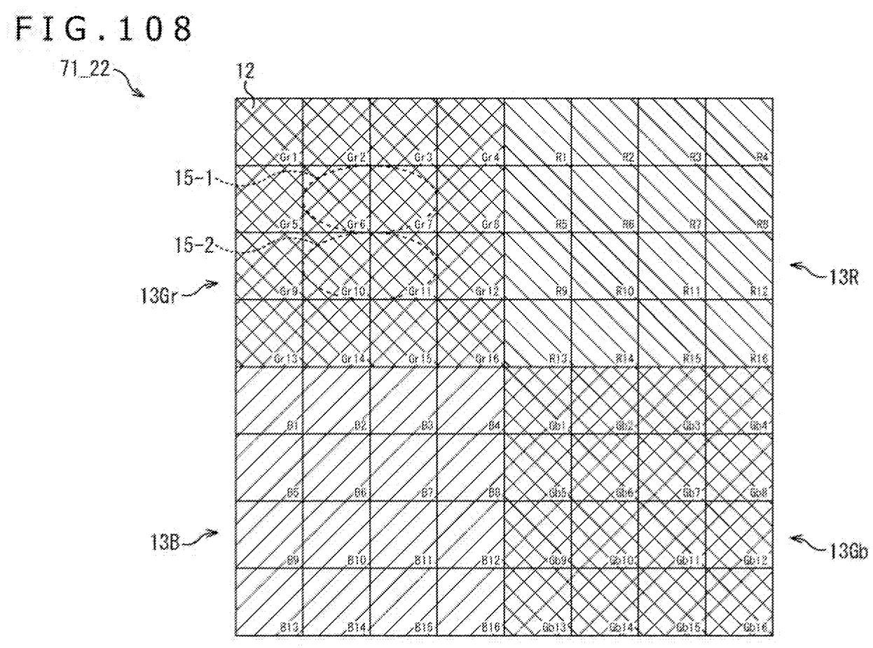

FIG. 108 is a figure depicting an example of a twenty-second 2×1-OCL arrangement pattern 71_22.

As depicted in FIG. 108, in the twenty-second 2×1-OCL arrangement pattern 71_22, the 2×1-OCL 15-1 is arranged for the pixels 12-Gr6 and 12-Gr7, and the 2×1-OCL 15-2 is arranged for the pixels 12-Gr10 and 12-Gr11.

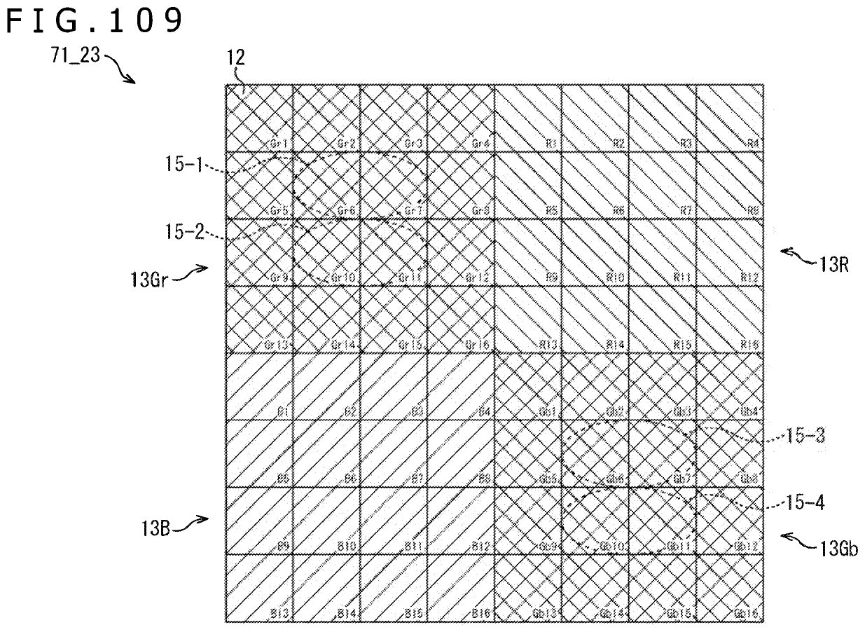

FIG. 109 is a figure depicting an example of a twenty-third 2×1-OCL arrangement pattern 71_23.

As depicted in FIG. 109, in the twenty-third 2×1-OCL arrangement pattern 71_23, the 2×1-OCL 15-1 is arranged for the pixels 12-Gr6 and 12-Gr7, the 2×1-OCL 15-2 is arranged for the pixels 12-Gr10 and 12-Gr11, the 2×1-OCL 15-3 is arranged for the pixels 12-Gb6 and 12-Gb7, and the 2×1-OCL 15-4 is arranged for the pixels 12-Gb10 and 12-Gb11.

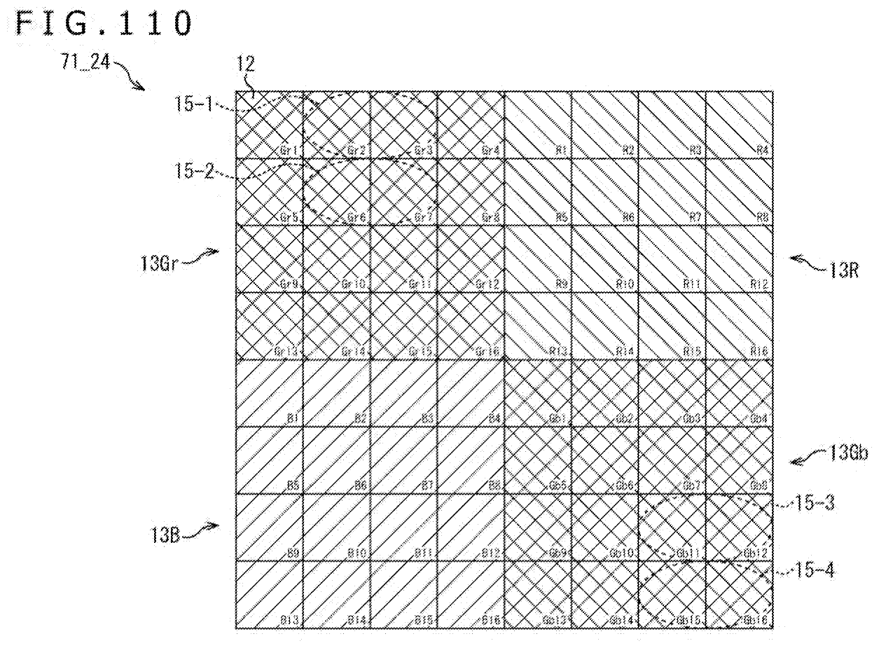

In the manner described above, preferably, 2×1-OCLs 15 are arranged in the two middle columns of a 4×4 array. For example, 2×1-OCLs 15 tend to cause color mixing in the longer-side directions, and, by arranging 2×1-OCLs 15 in the two middle columns of a 4×4 array, it is possible to suppress the occurrence of color mixing between different colors. Needless to say, as depicted in the next FIG. 110, a configuration in which 2×1-OCLs 15 are arranged in the two middle columns of a 4×4 array and a configuration in which 2×1-OCLs 15 are arranged in the two columns at ends of a 4×4 array may be combined.

FIG. 110 is a figure depicting an example of a twenty-fourth 2×1-OCL arrangement pattern 71_24.

As depicted in FIG. 110, in the twenty-fourth 2×1-OCL arrangement pattern 71_24, the 2×1-OCL 15-1 is arranged for the pixels 12-Gr2 and 12-Gr3, the 2×1-OCL 15-2 is arranged for the pixels 12-Gr6 and 12-Gr7, the 2×1-OCL 15-3 is arranged for the pixels 12-Gb11 and 12-Gb12, and the 2×1-OCL 15-4 is arranged for the pixels 12-Gb15 and 12-Gb16.

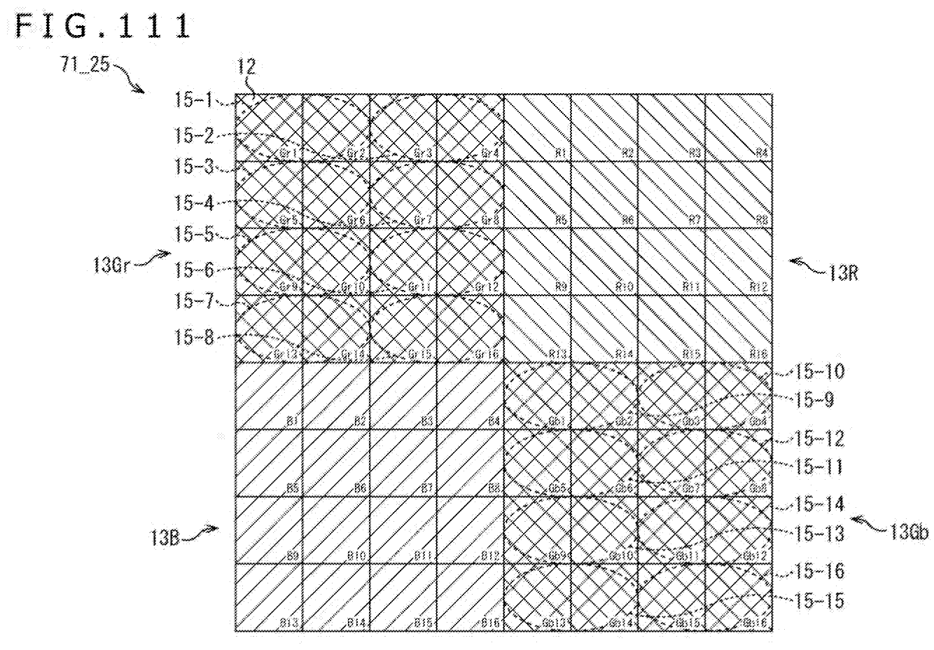

FIG. 111 is a figure depicting an example of a twenty-fifth 2×1-OCL arrangement pattern 71_25.

As depicted in FIG. 111, in the twenty-fifth 2×1-OCL arrangement pattern 71_25, the 2×1-OCL 15-1 is arranged for the pixels 12-Gr1 and 12-Gr2, the 2×1-OCL 15-2 is arranged for the pixels 12-Gr3 and 12-Gr4, the 2×1-OCL 15-3 is arranged for the pixels 12-Gr5 and 12-Gr6, and the 2×1-OCL 15-4 is arranged for the pixels 12-Gr7 and 12-Gr8. Moreover, the 2×1-OCL 15-5 is arranged for the pixels 12-Gr9 and 12-Gr10, the 2×1-OCL 15-6 is arranged for the pixels 12-Gr11 and 12-Gr12, the 2×1-OCL 15-7 is arranged for the pixels 12-Gr13 and 12-Gr14, and the 2×1-OCL 15-8 is arranged for the pixels 12-Gr15 and 12-Gr16.

Moreover, a 2×1-OCL 15-9 is arranged for the pixels 12-Gb1 and 12-Gb2, a 2×1-OCL 15-10 is arranged for the pixels 12-Gb3 and 12-Gb4, a 2×1-OCL 15-11 is arranged for the pixels 12-Gb5 and 12-Gb6, and a 2×1-OCL 15-12 is arranged for the pixels 12-Gb7 and 12-Gb8. Moreover, a 2×1-OCL 15-13 is arranged for the pixels 12-Gb9 and 12-Gb10, a 2×1-OCL 15-14 is arranged for the pixels 12-Gb11 and 12-Gb12, a 2×1-OCL 15-15 is arranged for the pixels 12-Gb13 and 12-Gb14, and a 2×1-OCL 15-16 is arranged for the pixels 12-Gb15 and 12-Gb16.

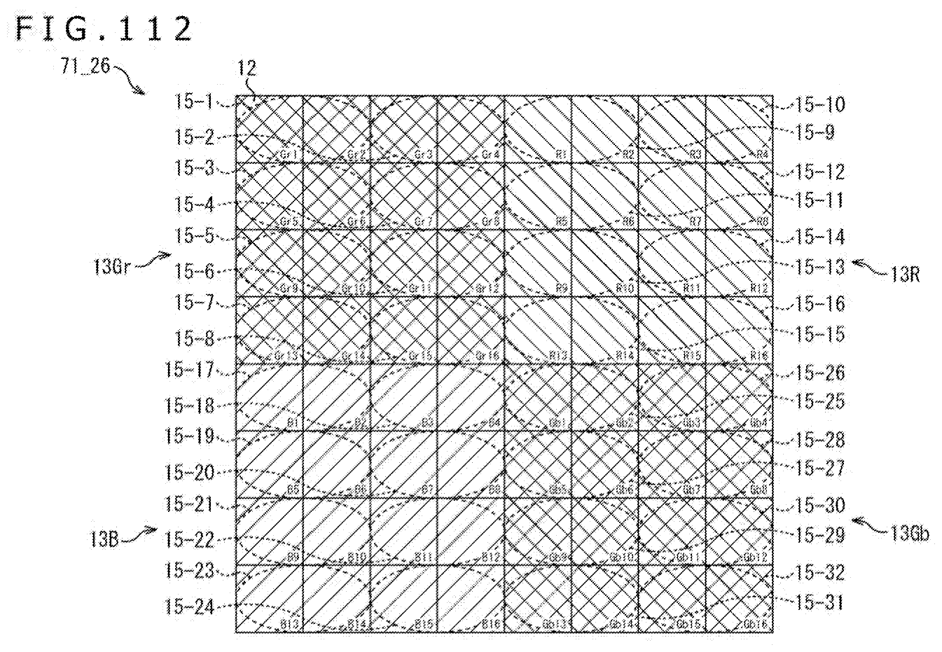

FIG. 112 is a figure depicting an example of a twenty-sixth 2×1-OCL arrangement pattern 71_26.

As depicted in FIG. 112, in the twenty-sixth 2×1-OCL arrangement pattern 71_26, the 2×1-OCL 15-1 is arranged for the pixels 12-Gr1 and 12-Gr2, the 2×1-OCL 15-2 is arranged for the pixels 12-Gr3 and 12-Gr4, the 2×1-OCL 15-3 is arranged for the pixels 12-Gr5 and 12-Gr6, and the 2×1-OCL 15-4 is arranged for the pixels 12-Gr7 and 12-Gr8. Moreover, the 2×1-OCL 15-5 is arranged for the pixels 12-Gr9 and 12-Gr10, the 2×1-OCL 15-6 is arranged for the pixels 12-Gr11 and 12-Gr12, the 2×1-OCL 15-7 is arranged for the pixels 12-Gr13 and 12-Gr14, and the 2×1-OCL 15-8 is arranged for the pixels 12-Gr15 and 12-Gr16. Moreover, the 2×1-OCL 15-9 is arranged for the pixels 12-R1 and 12-R2, the 2×1-OCL 15-10 is arranged for the pixels 12-R3 and 12-R4, the 2×1-OCL 15-11 is arranged for the pixels 12-R5 and 12-R6, and the 2×1-OCL 15-12 is arranged for the pixels 12-R7 and 12-R8. Moreover, the 2×1-OCL 15-13 is arranged for the pixels 12-R9 and 12-R10, the 2×1-OCL 15-14 is arranged for the pixels 12-R11 and 12-R12, the 2×1-OCL 15-15 is arranged for the pixels 12-R13 and 12-R14, and the 2×1-OCL 15-16 is arranged for the pixels 12-R15 and 12-R16.

Moreover, a 2×1-OCL 15-17 is arranged for the pixels 12-B1 and 12-B2, a 2×1-OCL 15-18 is arranged for the pixels 12-B3 and 12-B4, a 2×1-OCL 15-19 is arranged for the pixels 12-B5 and 12-B6, and a 2×1-OCL 15-20 is arranged for the pixels 12-B7 and 12-B8. Moreover, a 2×1-OCL 15-21 is arranged for the pixels 12-B9 and 12-B10, a 2×1-OCL 15-22 is arranged for the pixels 12-B11 and 12-B12, a 2×1-OCL 15-23 is arranged for the pixels 12-B13 and 12-B14, and a 2×1-OCL 15-24 is arranged for the pixels 12-B15 and 12-B16. Moreover, a 2×1-OCL 15-25 is arranged for the pixels 12-Gb1 and 12-Gb2, a 2×1-OCL 15-26 is arranged for the pixels 12-Gb3 and 12-Gb4, a 2×1-OCL 15-27 is arranged for the pixels 12-Gb5 and 12-Gb6, and a 2×1-OCL 15-28 is arranged for the pixels 12-Gb7 and 12-Gb8. Moreover, a 2×1-OCL 15-29 is arranged for the pixels 12-Gb9 and 12-Gb10, a 2×1-OCL 15-30 is arranged for the pixels 12-Gb11 and 12-Gb12, a 2×1-OCL 15-31 is arranged for the pixels 12-Gb13 and 12-Gb14, and a 2×1-OCL 15-32 is arranged for the pixels 12-Gb15 and 12-Gb16.

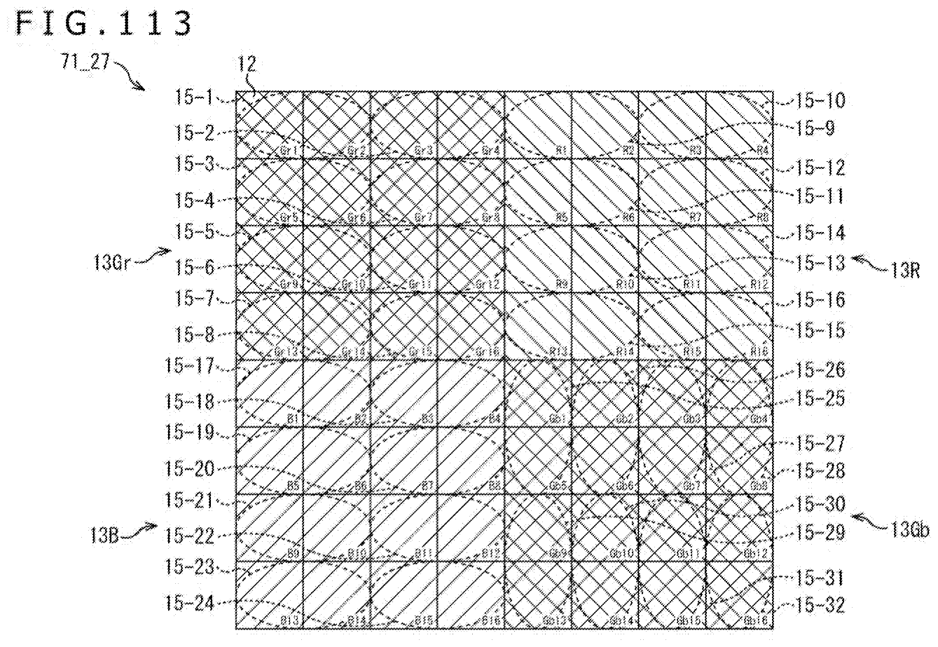

FIG. 113 is a figure depicting an example of a twenty-seventh 2×1-OCL arrangement pattern 71_27.

As depicted in FIG. 113, in the twenty-seventh 2×1-OCL arrangement pattern 71_27, the 2×1-OCLs 15-1 to 15-24 are arranged similarly to the twenty-sixth 2×1-OCL arrangement pattern 71_26 in FIG. 112. Moreover, the 2×1-OCL 15-25 is arranged for the pixels 12-Gb1 and 12-Gb5, the 2×1-OCL 15-26 is arranged for the pixels 12-Gb2 and 12-Gb6, the 2×1-OCL 15-27 is arranged for the pixels 12-Gb3 and 12-Gb7, the 2×1-OCL 15-28 is arranged for the pixels 12-Gb4 and 12-Gb8, the 2×1-OCL 15-29 is arranged for the pixels 12-Gb9 and 12-Gb13, the 2×1-OCL 15-30 is arranged for the pixels 12-Gb10 and 12-Gb14, the 2×1-OCL 15-31 is arranged for the pixels 12-Gb11 and 12-Gb15, and the 2×1-OCL 15-32 is arranged for the pixels 12-Gb12 and 12-Gb16.

As depicted in FIG. 112 and FIG. 113, 2×1-OCLs 15 may be arranged for all the pixels 12 in another possible manner of the configuration. Alternatively, as depicted in FIG. 111, 2×1-OCLs 15 may be arranged for all the green pixels 12-Gr or pixels 12-Gb in another possible manner of the configuration. In addition, it is possible to attempt to improve the autofocus performance in the horizontal direction and the vertical direction by arranging 2×1-OCLs 15 for horizontally adjacent pixels 12 and also arranging 2×1-OCLs 15 for vertically adjacent pixels 12.

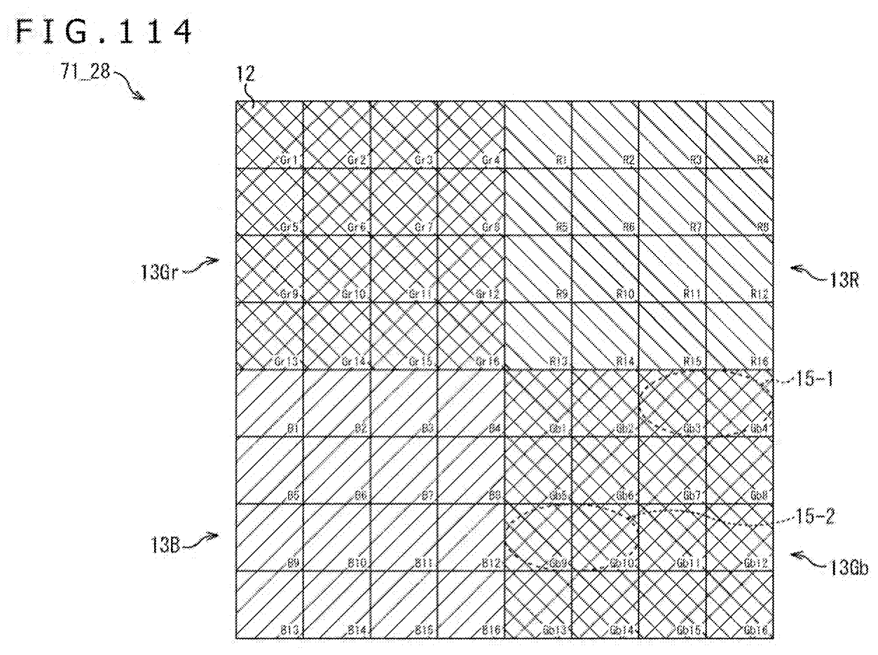

FIG. 114 is a figure depicting an example of a twenty-eighth 2×1-OCL arrangement pattern 71_28.

As depicted in FIG. 114, in the twenty-eighth 2×1-OCL arrangement pattern 71_28, the 2×1-OCL 15-1 is arranged for the pixels 12-Gb3 and 12-Gb4, and the 2×1-OCL 15-2 is arranged for the pixels 12-Gb9 and 12-Gb10.

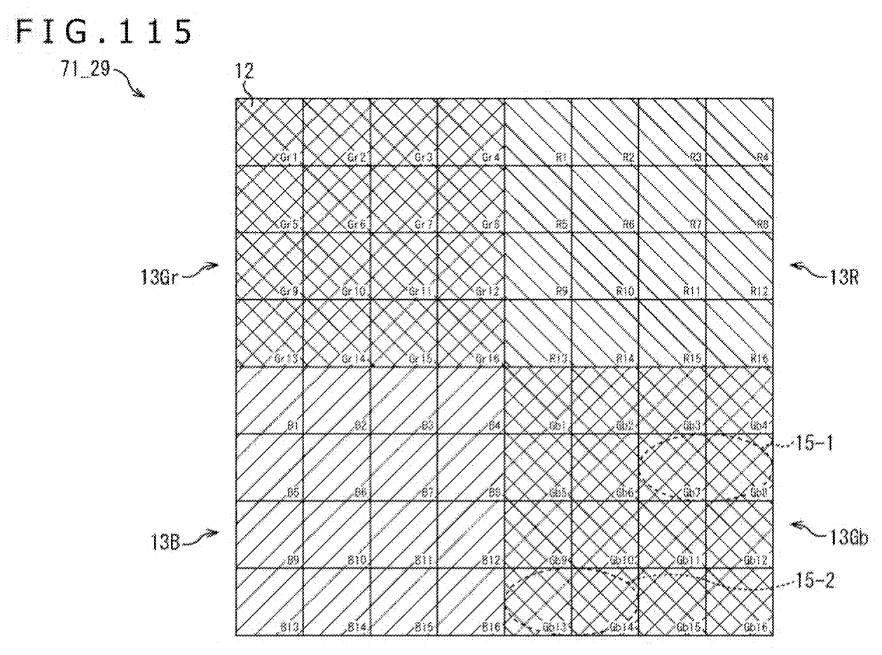

FIG. 115 is a figure depicting an example of a twenty-ninth 2×1-OCL arrangement pattern 71_29.

As depicted in FIG. 115, in the twenty-ninth 2×1-OCL arrangement pattern 71_29, the 2×1-OCL 15-1 is arranged for the pixels 12-Gb7 and 12-Gb8, and the 2×1-OCL 15-2 is arranged for the pixels 12-Gb13 and 12-Gb14.

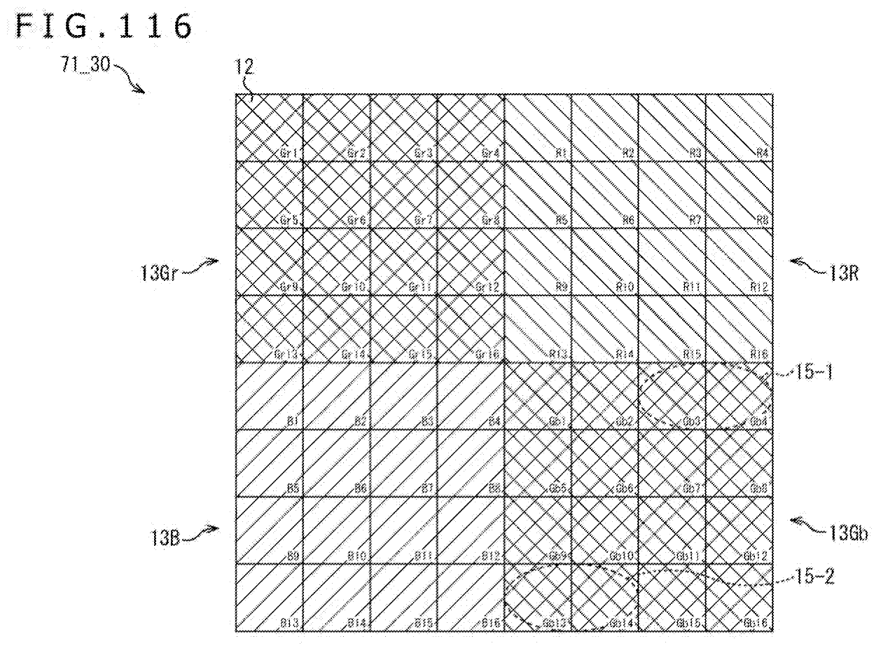

FIG. 116 is a figure depicting an example of a thirtieth 2×1-OCL arrangement pattern 71_30.

As depicted in FIG. 116, in the thirtieth 2×1-OCL arrangement pattern 71_30, the 2×1-OCL 15-1 is arranged for the pixels 12-Gb3 and 12-Gb4, and the 2×1-OCL 15-2 is arranged for the pixels 12-Gb13 and 12-Gb14.

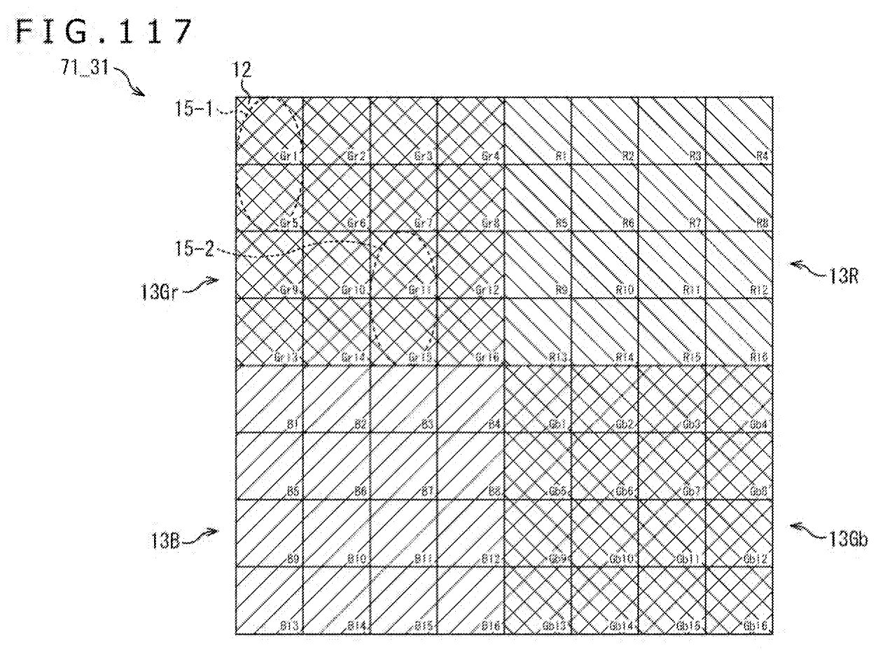

FIG. 117 is a figure depicting an example of a thirty-first 2×1-OCL arrangement pattern 71_31.

As depicted in FIG. 117, in the thirty-first 2×1-OCL arrangement pattern 71_31, the 2×1-OCL 15-1 is arranged for the pixels 12-Gr1 and 12-Gr5, and the 2×1-OCL 15-2 is arranged for the pixels 12-Gr11 and 12-Gr15.

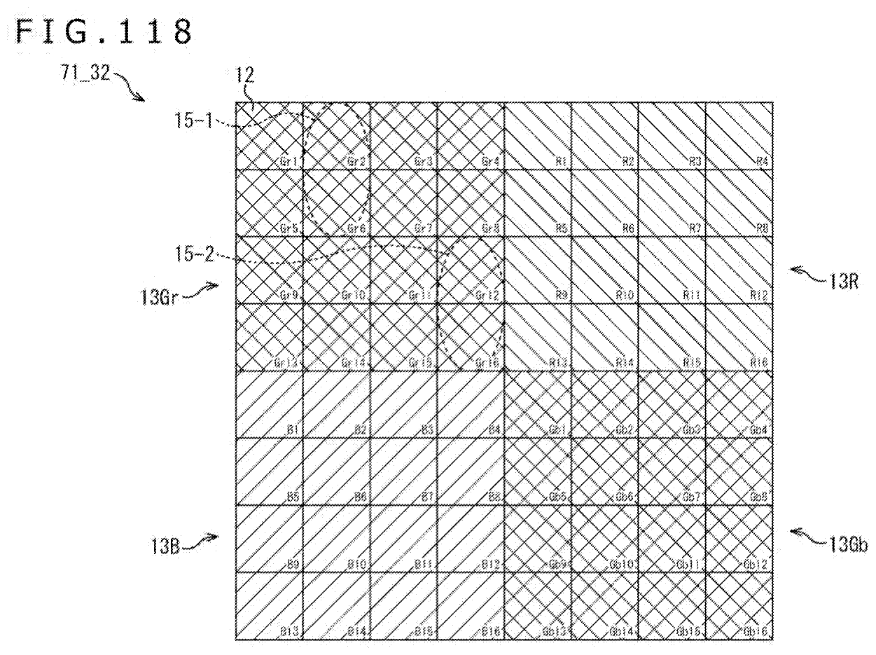

FIG. 118 is a figure depicting an example of a thirty-second 2×1-OCL arrangement pattern 71_32.

As depicted in FIG. 118, in the thirty-second 2×1-OCL arrangement pattern 71_32, the 2×1-OCL 15-1 is arranged for the pixels 12-Gr2 and 12-Gr6, and the 2×1-OCL 15-2 is arranged for the pixels 12-Gr12 and 12-Gr16.

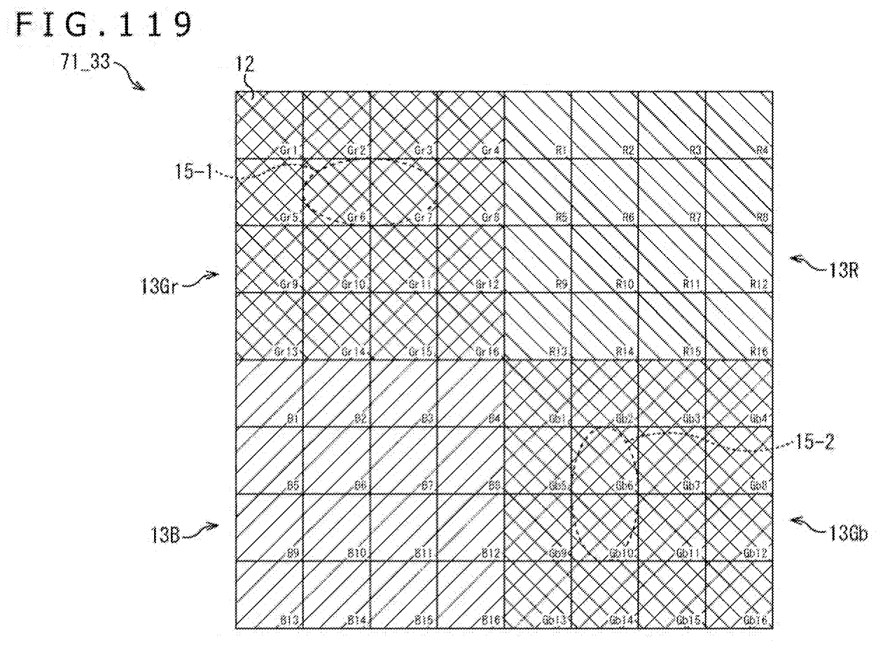

FIG. 119 is a figure depicting an example of a thirty-third 2×1-OCL arrangement pattern 71_33.

As depicted in FIG. 119, in the thirty-third 2×1-OCL arrangement pattern 71_33, the 2×1-OCL 15-1 is arranged for the pixels 12-Gr6 and 12-Gr7, and the 2×1-OCL 15-2 is arranged for the pixels 12-Gb6 and 12-Gb10.

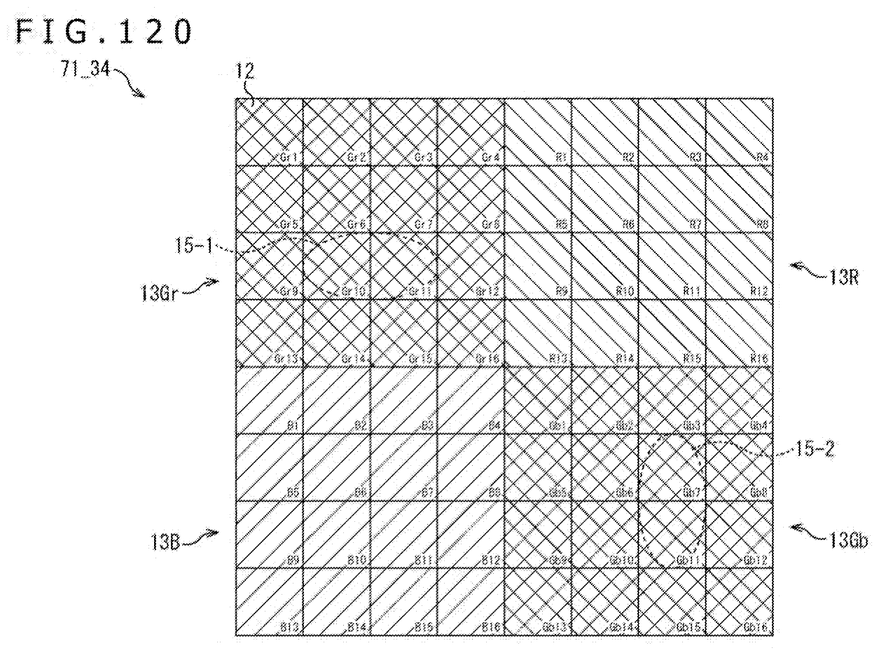

FIG. 120 is a figure depicting an example of a thirty-fourth 2×1-OCL arrangement pattern 71_34.

As depicted in FIG. 120, in the thirty-fourth 2×1-OCL arrangement pattern 71_34, the 2×1-OCL 15-1 is arranged for the pixels 12-Gr10 and 12-Gr11, and the 2×1-OCL 15-2 is arranged for the pixels 12-Gb7 and 12-Gb11.

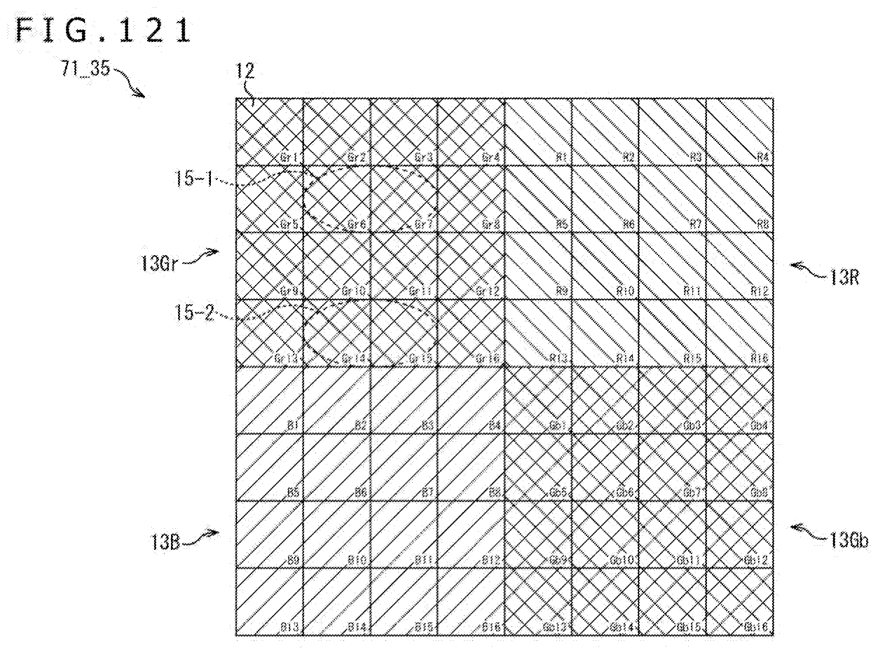

FIG. 121 is a figure depicting an example of a thirty-fifth 2×1-OCL arrangement pattern 71_35.

As depicted in FIG. 121, in the thirty-fifth 2×1-OCL arrangement pattern 71_35, the 2×1-OCL 15-1 is arranged for the pixels 12-Gr6 and 12-Gr7, and the 2×1-OCL 15-2 is arranged for the pixels 12-Gr14 and 12-Gr15.

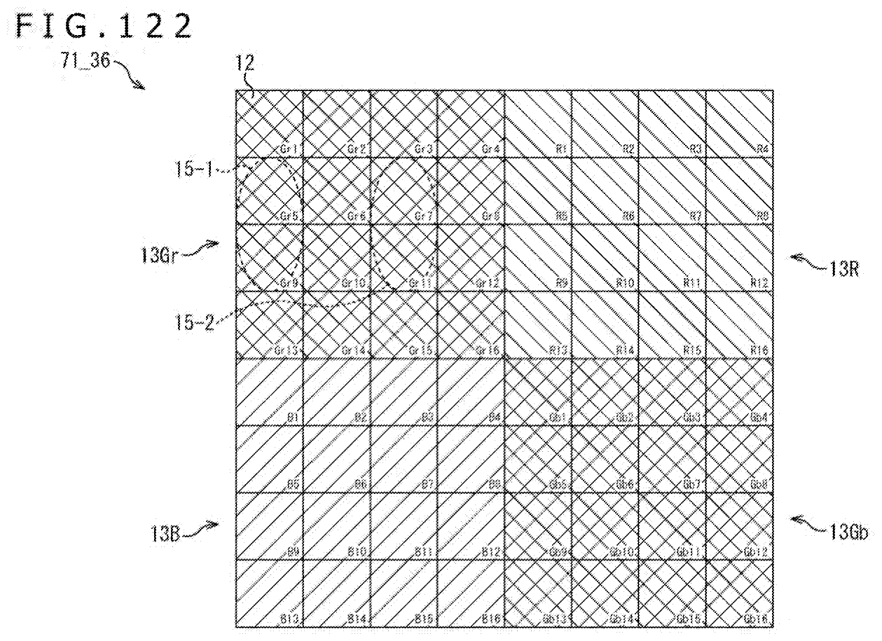

FIG. 122 is a figure depicting an example of a thirty-sixth 2×1-OCL arrangement pattern 71_36.

As depicted in FIG. 122, in the thirty-sixth 2×1-OCL arrangement pattern 71_36, the 2×1-OCL 15-1 is arranged for the pixels 12-Gr5 and 12-Gr9, and the 2×1-OCL 15-2 is arranged for the pixels 12-Gr7 and 12-Gr11.

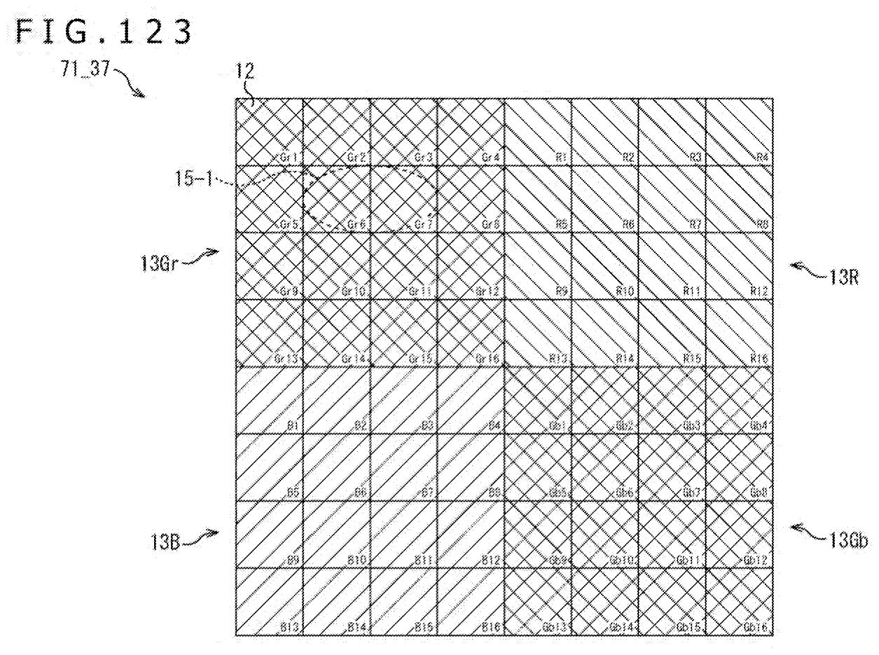

FIG. 123 is a figure depicting an example of a thirty-seventh 2×1-OCL arrangement pattern 71_37.

As depicted in FIG. 123, in the thirty-seventh 2×1-OCL arrangement pattern 71_37, the 2×1-OCL 15-1 is arranged for the pixels 12-Gr6 and 12-Gr7.

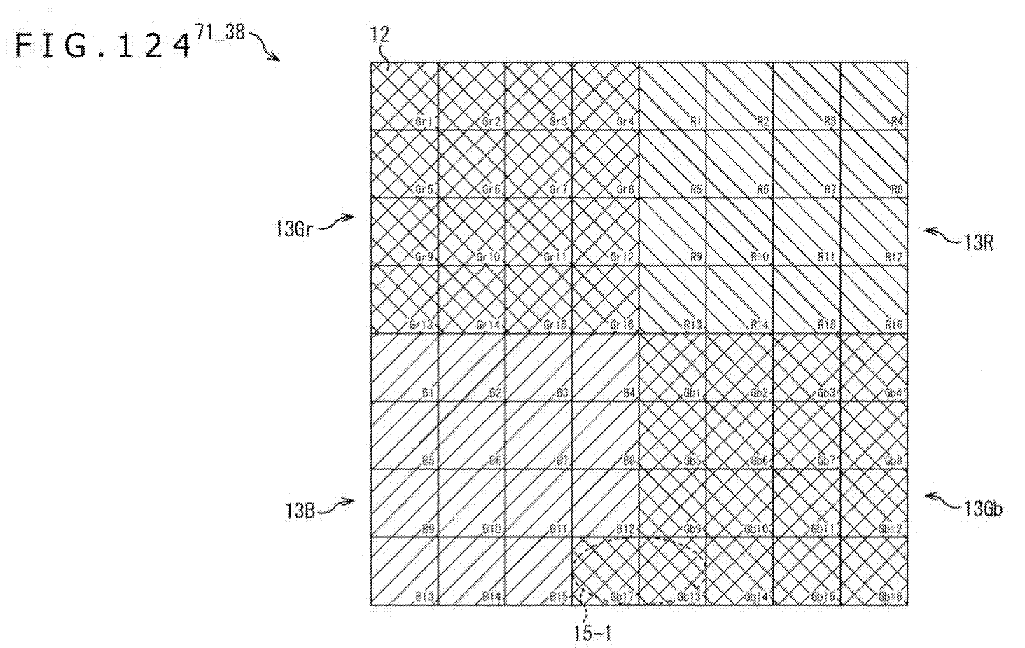

FIG. 124 is a figure depicting an example of a thirty-eighth 2×1-OCL arrangement pattern 71_38.

Here, in the thirty-eighth 2×1-OCL arrangement pattern 71_38, the blue pixel 12-B16 is replaced with the green pixel 12-Gb17. That is, in this arrangement of the color filters 43, the green same-color pixel group 13Gb partially protrudes into the blue same-color pixel group 13B.

Further, in the thirty-eighth 2×1-OCL arrangement pattern 71_38, the 2×1-OCL 15-1 is arranged for the pixels 12-Gb13 and 12-Gb17.

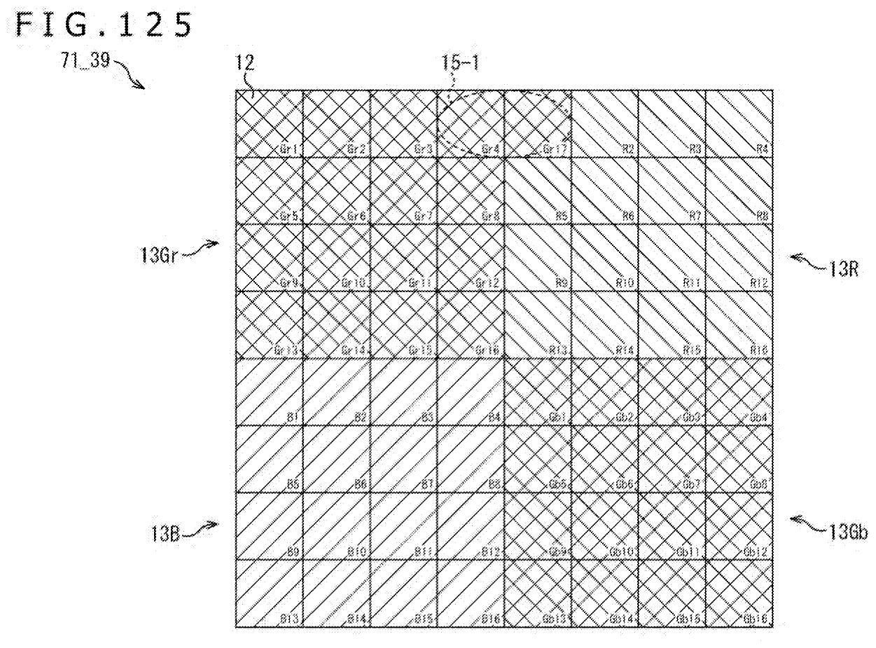

FIG. 125 is a figure depicting an example of a thirty-ninth 2×1-OCL arrangement pattern 71_39.

Here, in the thirty-ninth 2×1-OCL arrangement pattern 71_39, the red pixel 12-R1 is replaced with the green pixel 12-Gr17. That is, in this arrangement of the color filters 43, the green same-color pixel group 13Gr partially protrudes into the red same-color pixel group 13R.

Further, in the thirty-ninth 2×1-OCL arrangement pattern 71_39, the 2×1-OCL 15-1 is arranged for the pixels 12-Gr4 and 12-Gr17.

Note that the arrangement examples of the 2×1-OCL arrangement patterns 71 as the ones described above are not the sole examples, and 2×1-OCLs 15 may be arranged in various arrangement patterns.

### Configuration Examples of 5×5-Array Sensitivity Adjustment Structures

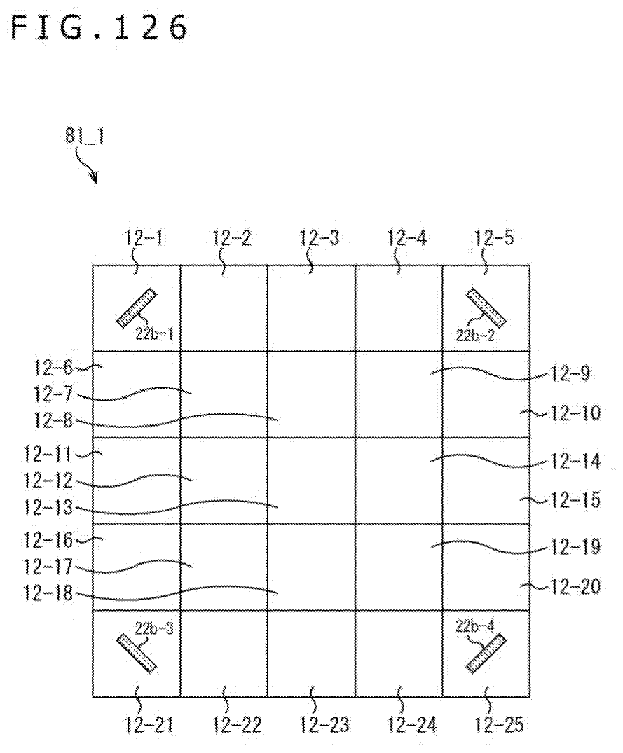

Configuration examples of 5×5-array sensitivity adjustment structures are explained with reference to FIG. 126 to FIG. 159.

Whereas sensitivity adjustment structures 21 for the same-color pixel groups 13 each including the 4×4 array of the sixteen pixels 12-1 to 12-16 are explained in the embodiment described above, sensitivity adjustment structures can be applied to same-color pixel groups 13 other than 4×4 arrays. Although sensitivity adjustment structures 81 applied to same-color pixel groups 13 each including a 5×5 array are explained hereinbelow, it goes without saying that sensitivity adjustment structures may be applied to same-color pixel groups 13 each including an array larger than a 5×5 array.

FIG. 126 is a figure depicting a configuration example of a first 5×5-array sensitivity adjustment structure 81_1.

As depicted in FIG. 126, the first 5×5-array sensitivity adjustment structure 81_1 uses the intra-pixel grooves 22b with the diagonal line shape extending in a diagonal direction of a pixel 12.

The first 5×5-array sensitivity adjustment structure 81_1 includes an arrangement pattern in which, in a 5×5 array of twenty-five pixels 12-1 to 12-25, the intra-pixel grooves 22b with the diagonal line shape are provided to pixels 12 arranged at the four corner locations. The intra-pixel grooves 22b with the diagonal line shape are formed such that side surfaces of the intra-pixel grooves 22b along the longitudinal directions face the middle of the 5×5 array, and 5×5-array sensitivity adjustment structures 81 explained below are formed similarly.

That is, in the first 5×5-array sensitivity adjustment structure 81_1, the intra-pixel groove 22b-1 with the diagonal line shape whose longitudinal direction extends from the upper right to the lower left is provided to the pixel 12-1, the intra-pixel groove 22b-2 with the diagonal line shape whose longitudinal direction extends from the upper left to the lower right is provided to the pixel 12-5, the intra-pixel groove 22b-3 with the diagonal line shape whose longitudinal direction extends from the upper left to the lower right is provided to the pixel 12-21, and the intra-pixel groove 22b-4 with the diagonal line shape whose longitudinal direction extends from the upper right to the lower left is provided to the pixel 12-25.

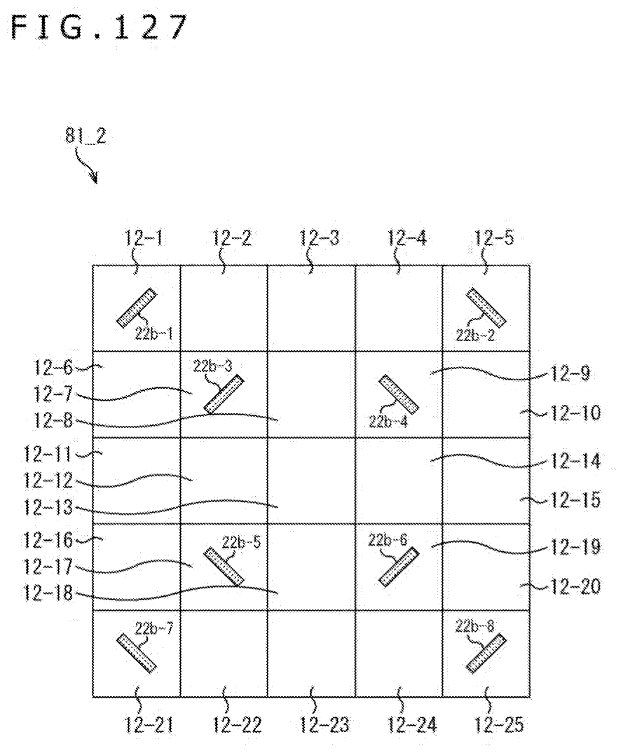

FIG. 127 is a figure depicting a configuration example of a second 5×5-array sensitivity adjustment structure 81_2.

As depicted in FIG. 127, the second 5×5-array sensitivity adjustment structure 81_2 uses the intra-pixel grooves 22b with the diagonal line shape extending in a diagonal direction of a pixel 12.

The second 5×5-array sensitivity adjustment structure 81_2 includes an arrangement pattern in which, in the 5×5 array of the twenty-five pixels 12-1 to 12-25, the intra-pixel grooves 22b with the diagonal line shape are provided to pixels 12 arranged at the four corner locations and the intra-pixel grooves 22b with the diagonal line shape are provided to pixels 12 arranged at the four corner locations in the middle 3×3 array.

That is, in the second 5×5-array sensitivity adjustment structure 81_2, the intra-pixel groove 22b-1 with the diagonal line shape whose longitudinal direction extends from the upper right to the lower left is provided to the pixel 12-1, the intra-pixel groove 22b-2 with the diagonal line shape whose longitudinal direction extends from the upper left to the lower right is provided to the pixel 12-5, the intra-pixel groove 22b-3 with the diagonal line shape whose longitudinal direction extends from the upper right to the lower left is provided to the pixel 12-7, and the intra-pixel groove 22b-4 with the diagonal line shape whose longitudinal direction extends from the upper left to the lower right is provided to the pixel 12-9. Moreover, the intra-pixel groove 22b-5 with the diagonal line shape whose longitudinal direction extends from the upper left to the lower right is provided to the pixel 12-17, the intra-pixel groove 22b-6 with the diagonal line shape whose longitudinal direction extends from the upper right to the lower left is provided to the pixel 12-19, the intra-pixel groove 22b-7 with the diagonal line shape whose longitudinal direction extends from the upper left to the lower right is provided to the pixel 12-21, and the intra-pixel groove 22b-8 with the diagonal line shape whose longitudinal direction extends from the upper right to the lower left is provided to the pixel 12-25.

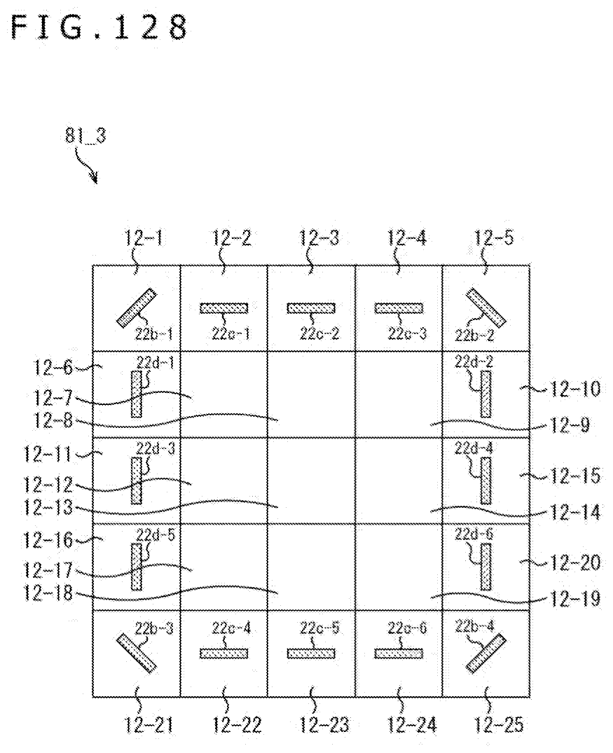

FIG. 128 is a figure depicting a configuration example of a third 5×5-array sensitivity adjustment structure 81_3.

As depicted in FIG. 128, the third 5×5-array sensitivity adjustment structure 81_3 uses the intra-pixel grooves 22b with the diagonal line shape extending in a diagonal direction of a pixel 12, the intra-pixel grooves 22c with the horizontal line shape extending in the horizontal direction of a pixel 12, and the intra-pixel grooves 22d with the vertical line shape extending in the vertical direction of a pixel 12.

The third 5×5-array sensitivity adjustment structure 81_3 includes an arrangement pattern in which, in the 5×5 array of the twenty-five pixels 12-1 to 12-25, the intra-pixel grooves 22b with the diagonal line shape are provided to pixels 12 arranged at the four corner locations, the intra-pixel grooves 22c with the horizontal line shape are provided to pixels 12 arranged at the three middle locations on the upper side and pixels 12 arranged at the three middle locations on the lower side, and the intra-pixel grooves 22d with the vertical line shape are provided to pixels 12 arranged at the three middle locations on the right side and pixels 12 arranged at the three middle locations on the left side.

That is, in the third 5×5-array sensitivity adjustment structure 81_3, the intra-pixel groove 22b-1 with the diagonal line shape whose longitudinal direction extends from the upper right to the lower left is provided to the pixel 12-1, the intra-pixel groove 22b-2 with the diagonal line shape whose longitudinal direction extends from the upper left to the lower right is provided to the pixel 12-5, the intra-pixel groove 22b-3 with the diagonal line shape whose longitudinal direction extends from the upper left to the lower right is provided to the pixel 12-21, and the intra-pixel groove 22b-4 with the diagonal line shape whose longitudinal direction extends from the upper right to the lower left is provided to the pixel 12-25. Moreover, the intra-pixel groove 22c-1 with the horizontal line shape is provided to the pixel 12-2, the intra-pixel groove 22c-2 with the horizontal line shape is provided to the pixel 12-3, the intra-pixel groove 22c-3 with the horizontal line shape is provided to the pixel 12-4, the intra-pixel groove 22c-4 with the horizontal line shape is provided to the pixel 12-22, the intra-pixel groove 22c-5 with the horizontal line shape is provided to the pixel 12-23, and the intra-pixel groove 22c-6 with the horizontal line shape is provided to the pixel 12-24. Moreover, the intra-pixel groove 22d-1 with the vertical line shape is provided to the pixel 12-6, the intra-pixel groove 22d-2 with the vertical line shape is provided to the pixel 12-10, the intra-pixel groove 22d-3 with the vertical line shape is provided to the pixel 12-11, the intra-pixel groove 22d-4 with the vertical line shape is provided to the pixel 12-15, the intra-pixel groove 22d-5 with the vertical line shape is provided to the pixel 12-16, and the intra-pixel groove 22d-6 with the vertical line shape is provided to the pixel 12-20.

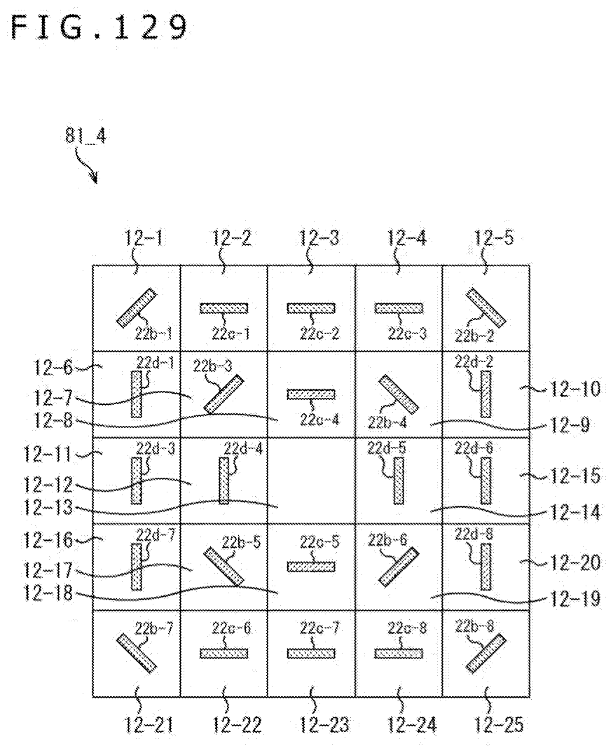

FIG. 129 is a figure depicting a configuration example of a fourth 5×5-array sensitivity adjustment structure 81_4.

As depicted in FIG. 129, the fourth 5×5-array sensitivity adjustment structure 81_4 uses the intra-pixel grooves 22b with the diagonal line shape extending in a diagonal direction of a pixel 12, the intra-pixel grooves 22c with the horizontal line shape extending in the horizontal direction of a pixel 12, and the intra-pixel grooves 22d with the vertical line shape extending in the vertical direction of a pixel 12.

The fourth 5×5-array sensitivity adjustment structure 81_4 includes an arrangement pattern in which, in the 5×5 array of the twenty-five pixels 12-1 to 12-25, the intra-pixel grooves 22b with the diagonal line shape are provided to pixels 12 arranged at the four corner locations, the intra-pixel grooves 22c with the horizontal line shape are provided to pixels 12 arranged at the three middle locations on the upper side and pixels 12 arranged at the three middle locations on the lower side, and the intra-pixel grooves 22d with the vertical line shape are provided to pixels 12 arranged at the three middle locations on the right side and pixels 12 arranged at the three middle locations on the left side. Moreover, the fourth 5×5-array sensitivity adjustment structure 81_4 includes an arrangement pattern in which the intra-pixel grooves 22b with the diagonal line shape are provided to pixels 12 arranged at the four corner locations in the middle 3×3 array, the intra-pixel grooves 22c with the horizontal line shape are provided to a pixel 12 arranged at the one middle location on the upper side and a pixel 12 arranged at the one middle location on the lower side in the middle 3×3 array, and the intra-pixel grooves 22d with the vertical line shape are provided to a pixel 12 arranged at the one middle location on the right side and a pixel 12 arranged at the one middle location on the left side in the middle 3×3 array.

That is, in the fourth 5×5-array sensitivity adjustment structure 81_4, the intra-pixel groove 22b-1 with the diagonal line shape whose longitudinal direction extends from the upper right to the lower left is provided to the pixel 12-1, the intra-pixel groove 22b-2 with the diagonal line shape whose longitudinal direction extends from the upper left to the lower right is provided to the pixel 12-5, the intra-pixel groove 22b-3 with the diagonal line shape whose longitudinal direction extends from the upper right to the lower left is provided to the pixel 12-7, and the intra-pixel groove 22b-4 with the diagonal line shape whose longitudinal direction extends from the upper left to the lower right is provided to the pixel 12-9. Moreover, the intra-pixel groove 22b-5 with the diagonal line shape whose longitudinal direction extends from the upper left to the lower right is provided to the pixel 12-17, the intra-pixel groove 22b-6 with the diagonal line shape whose longitudinal direction extends from the upper right to the lower left is provided to the pixel 12-19, the intra-pixel groove 22b-7 with the diagonal line shape whose longitudinal direction extends from the upper left to the lower right is provided to the pixel 12-21, and the intra-pixel groove 22b-8 with the diagonal line shape whose longitudinal direction extends from the upper right to the lower left is provided to the pixel 12-25.

Moreover, the intra-pixel groove 22c-1 with the horizontal line shape is provided to the pixel 12-2, the intra-pixel groove 22c-2 with the horizontal line shape is provided to the pixel 12-3, the intra-pixel groove 22c-3 with the horizontal line shape is provided to the pixel 12-4, and the intra-pixel groove 22c-4 with the horizontal line shape is provided to the pixel 12-8. Moreover, the intra-pixel groove 22c-5 with the horizontal line shape is provided to the pixel 12-18, the intra-pixel groove 22c-6 with the horizontal line shape is provided to the pixel 12-22, the intra-pixel groove 22c-7 with the horizontal line shape is provided to the pixel 12-23, and the intra-pixel groove 22c-8 with the horizontal line shape is provided to the pixel 12-24.

Moreover, the intra-pixel groove 22d-1 with the vertical line shape is provided to the pixel 12-6, the intra-pixel groove 22d-2 with the vertical line shape is provided to the pixel 12-10, the intra-pixel groove 22d-3 with the vertical line shape is provided to the pixel 12-11, and the intra-pixel groove 22d-4 with the vertical line shape is provided to the pixel 12-12. Moreover, the intra-pixel groove 22d-5 with the vertical line shape is provided to the pixel 12-14, the intra-pixel groove 22d-6 with the vertical line shape is provided to the pixel 12-15, the intra-pixel groove 22d-7 with the vertical line shape is provided to the pixel 12-16, and the intra-pixel groove 22d-8 with the vertical line shape is provided to the pixel 12-20.

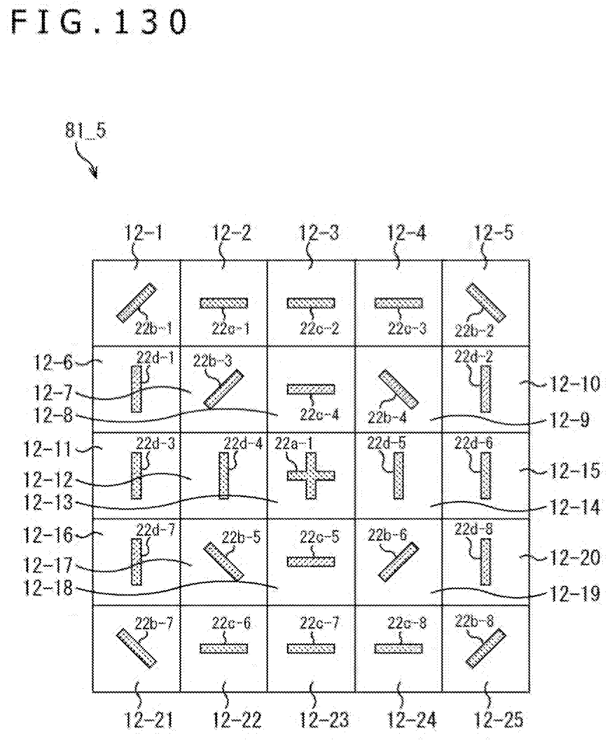

FIG. 130 is a figure depicting a configuration example of a fifth 5×5-array sensitivity adjustment structure 81_5.

As depicted in FIG. 130, the fifth 5×5-array sensitivity adjustment structure 81_5 uses the intra-pixel groove 22a with the cross shape in which lines extending in the vertical direction and the horizontal direction of a pixel 12 cross each other at the middle, the intra-pixel grooves 22b with the diagonal line shape extending in a diagonal direction of a pixel 12, the intra-pixel grooves 22c with the horizontal line shape extending in the horizontal direction of a pixel 12, and the intra-pixel grooves 22d with the vertical line shape extending in the vertical direction of a pixel 12.

The fifth 5×5-array sensitivity adjustment structure 81_5 includes an arrangement pattern in which, in the 5×5 array of the twenty-five pixels 12-1 to 12-25, the intra-pixel groove 22a with the cross shape is provided to a pixel 12 arranged at the middle. Moreover, the fifth 5×5-array sensitivity adjustment structure 81_5 includes an arrangement pattern in which the intra-pixel grooves 22b with the diagonal line shape are provided to pixels 12 arranged at the four corner locations, the intra-pixel grooves 22c with the horizontal line shape are provided to pixels 12 arranged at the three middle locations on the upper side and pixels 12 arranged at the three middle locations on the lower side, and the intra-pixel grooves 22d with the vertical line shape are provided to pixels 12 arranged at the three middle locations on the right side and pixels 12 arranged at the three middle locations on the left side. Moreover, the fifth 5×5-array sensitivity adjustment structure 81_5 includes an arrangement pattern in which the intra-pixel grooves 22b with the diagonal line shape are provided to pixels 12 arranged at the four corner locations in the middle 3×3 array, the intra-pixel grooves 22c with the horizontal line shape are provided to a pixel 12 arranged at the one middle location on the upper side and a pixel 12 arranged at the one middle location on the lower side in the middle 3×3 array, and the intra-pixel grooves 22d with the vertical line shape are provided to a pixel 12 arranged at the one middle location on the right side and a pixel 12 arranged at the one middle location on the left side in the middle 3×3 array.

That is, in the fifth 5×5-array sensitivity adjustment structure 81_5, the intra-pixel groove 22a with the cross shape is provided to the pixel 12-13. Moreover, similarly to the fourth 5×5-array sensitivity adjustment structure 81_4 in FIG. 129, the intra-pixel grooves 22b-1 to 22b-4 with the diagonal line shape, the intra-pixel grooves 22c-1 to 22c-4 with the horizontal line shape, and the intra-pixel groove 22d-1 to 22d-4 with the vertical line shape are provided.

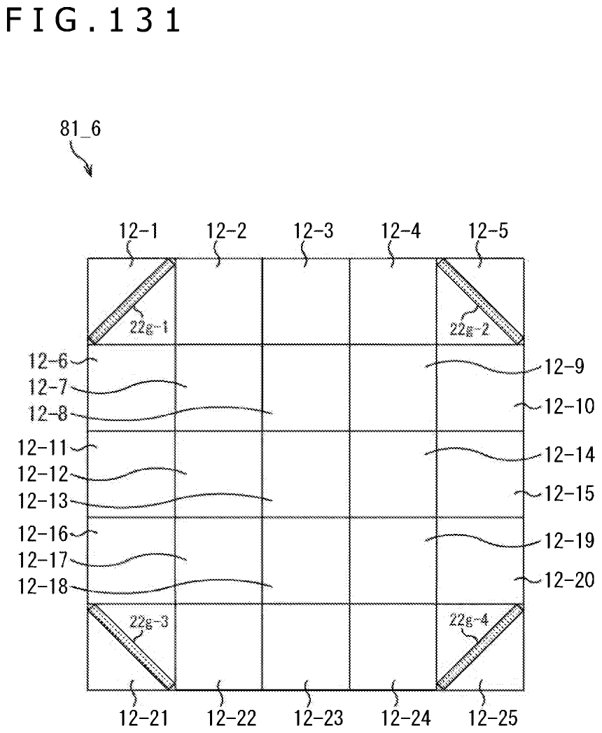

FIG. 131 is a figure depicting a configuration example of a sixth 5×5-array sensitivity adjustment structure 81_6.

As depicted in FIG. 131, the sixth 5×5-array sensitivity adjustment structure 81_6 uses the intra-pixel grooves 22g with the diagonal line shape and the enlarged structure extending in a diagonal direction of a pixel 12.

Similarly to the first 5×5-array sensitivity adjustment structure 81_1 in FIG. 126, the sixth 5×5-array sensitivity adjustment structure 81_6 includes an arrangement pattern in which, in the 5×5 array of the twenty-five pixels 12-1 to 12-25, the intra-pixel grooves 22g with the diagonal line shape and the enlarged structure are provided to pixels 12 arranged at the four corner locations.

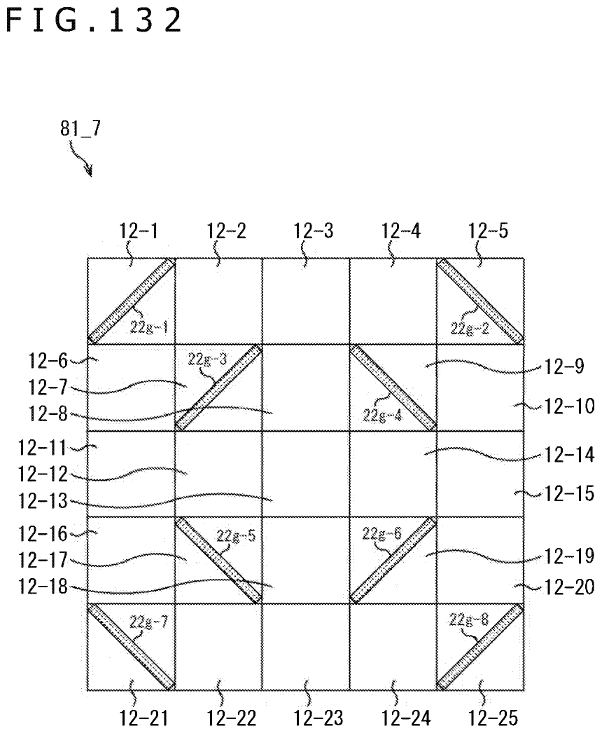

FIG. 132 is a figure depicting a configuration example of a seventh 5×5-array sensitivity adjustment structure 81_7.

As depicted in FIG. 132, the seventh 5×5-array sensitivity adjustment structure 81_7 uses the intra-pixel grooves 22g with the diagonal line shape and the enlarged structure extending in a diagonal direction of a pixel 12.

Similarly to the second 5×5-array sensitivity adjustment structure 81_2 in FIG. 127, the seventh 5×5-array sensitivity adjustment structure 81_7 includes an arrangement pattern in which, in the 5×5 array of the twenty-five pixels 12-1 to 12-25, the intra-pixel grooves 22g with the diagonal line shape and the enlarged structure are provided to pixels 12 arranged at the four corner locations and the intra-pixel grooves 22g with the diagonal line shape and the enlarged structure are provided to pixels 12 arranged at the four corner locations in the middle 3×3 array.

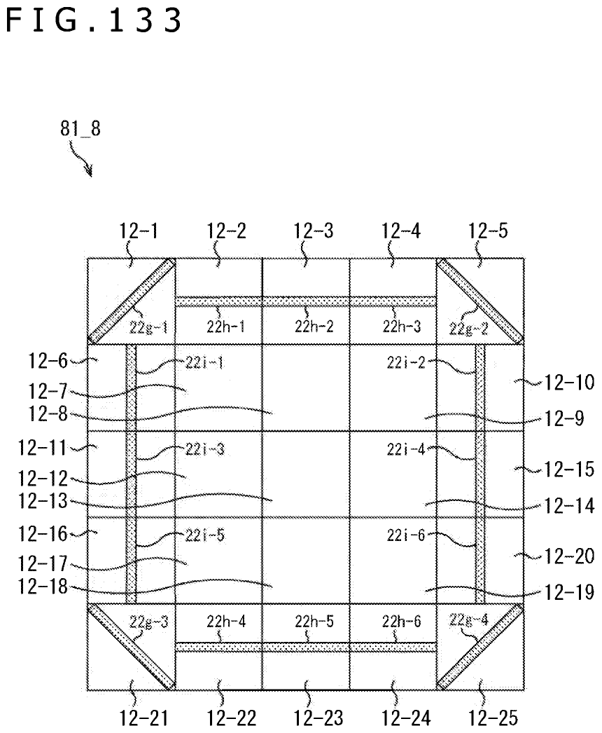

FIG. 133 is a figure depicting a configuration example of an eighth 5×5-array sensitivity adjustment structure 81_8.

As depicted in FIG. 133, the eighth 5×5-array sensitivity adjustment structure 81_8 uses the intra-pixel grooves 22g with the diagonal line shape and the enlarged structure extending in a diagonal direction of a pixel 12, the intra-pixel grooves 22h with the horizontal line shape and the enlarged structure extending in the horizontal direction of a pixel 12, and the intra-pixel grooves 22i with the vertical line shape and the enlarged structure extending in the vertical direction of a pixel 12.

Similarly to the third 5×5-array sensitivity adjustment structure 81_3 in FIG. 128, the eighth 5×5-array sensitivity adjustment structure 81_8 includes an arrangement pattern in which, in the 5×5 array of the twenty-five pixels 12-1 to 12-25, the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the three middle locations on the upper side and pixels 12 arranged at the three middle locations on the lower side, and the intra-pixel grooves 22i with the vertical line shape and the enlarged structure are provided to pixels 12 arranged at the three middle locations on the right side and pixels 12 arranged at the three middle locations on the left side.

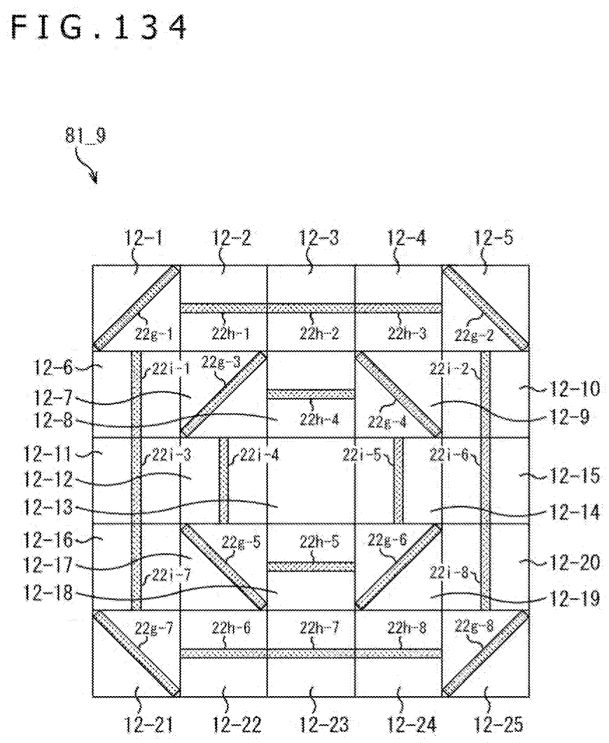

FIG. 134 is a figure depicting a configuration example of a ninth 5×5-array sensitivity adjustment structure 81_9.

As depicted in FIG. 134, the ninth 5×5-array sensitivity adjustment structure 81_9 uses the intra-pixel grooves 22g with the diagonal line shape and the enlarged structure extending in a diagonal direction of a pixel 12, the intra-pixel grooves 22h with the horizontal line shape and the enlarged structure extending in the horizontal direction of a pixel 12, and the intra-pixel grooves 22i with the vertical line shape and the enlarged structure extending in the vertical direction of a pixel 12.

Similarly to the fourth 5×5-array sensitivity adjustment structure 81_4 in FIG. 129, the ninth 5×5-array sensitivity adjustment structure 81_9 includes an arrangement pattern in which, in the 5×5 array of the twenty-five pixels 12-1 to 12-25, the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the three middle locations on the upper side and pixels 12 arranged at the three middle locations on the lower side, and the intra-pixel grooves 22i with the vertical line shape and the enlarged structure are provided to pixels 12 arranged at the three middle locations on the right side and pixels 12 arranged at the three middle locations on the left side. Moreover, the ninth 5×5-array sensitivity adjustment structure 81_9 includes an arrangement pattern in which the intra-pixel grooves 22g with the diagonal line shape and the enlarged structure are provided to pixels 12 arranged at the four corner locations in the middle 3×3 array, the intra-pixel grooves 22h with the horizontal line shape and the enlarged structure are provided to a pixel 12 arranged at the one middle location on the upper side and a pixel 12 arranged at the one middle location on the lower side in the middle 3×3 array, and the intra-pixel grooves 22i with the vertical line shape and the enlarged structure are provided to a pixel 12 arranged at the one middle location on the right side and a pixel 12 arranged at the one middle location on the left side in the middle 3×3 array.

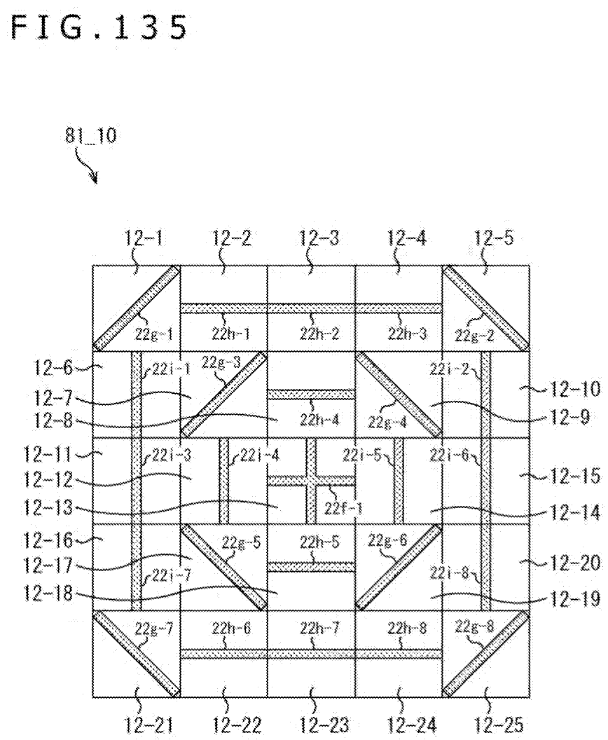

FIG. 135 is a figure depicting a configuration example of a tenth 5×5-array sensitivity adjustment structure 81_10.

As depicted in FIG. 135, the tenth 5×5-array sensitivity adjustment structure 81_10 uses the intra-pixel groove 22f with the cross shape and the enlarged structure in which lines extending in the vertical direction and the horizontal direction of a pixel 12 cross each other at the middle, the intra-pixel grooves 22g with the diagonal line shape and the enlarged structure extending in a diagonal direction of a pixel 12, the intra-pixel grooves 22h with the horizontal line shape and the enlarged structure extending in the horizontal direction of a pixel 12, and the intra-pixel grooves 22i with the vertical line shape and the enlarged structure extending in the vertical direction of a pixel 12.

Similarly to the fifth 5×5-array sensitivity adjustment structure 81_5 in FIG. 130, the tenth 5×5-array sensitivity adjustment structure 81_10 includes an arrangement pattern in which, in the 5×5 array of the twenty-five pixels 12-1 to 12-25, the intra-pixel groove 22f with the cross shape and the enlarged structure is provided to a pixel 12 arranged at the middle. Moreover, the tenth 5×5-array sensitivity adjustment structure 81_10 includes an arrangement pattern in which the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the three middle locations on the upper side and pixels 12 arranged at the three middle locations on the lower side, and the intra-pixel grooves 22i with the vertical line shape and the enlarged structure are provided to pixels 12 arranged at the three middle locations on the right side and pixels 12 arranged at the three middle locations on the left side. Moreover, the tenth 5×5-array sensitivity adjustment structure 81_10 includes an arrangement pattern in which the intra-pixel grooves 22g with the diagonal line shape and the enlarged structure are provided to pixels 12 arranged at the four corner locations in the middle 3×3 array, the intra-pixel grooves 22h with the horizontal line shape and the enlarged structure are provided to a pixel 12 arranged at the one middle location on the upper side and a pixel 12 arranged at the one middle location on the lower side in the middle 3×3 array, and the intra-pixel grooves 22i with the vertical line shape and the enlarged structure are provided to a pixel 12 arranged at the one middle location on the right side and a pixel 12 arranged at the one middle location on the left side in the middle 3×3 array.

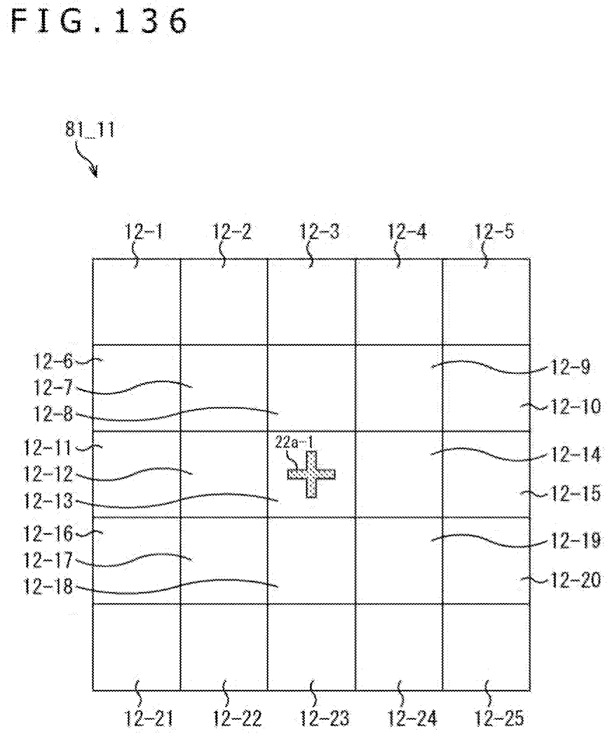

FIG. 136 is a figure depicting a configuration example of an eleventh 5×5-array sensitivity adjustment structure 81_11.

As depicted in FIG. 136, the eleventh 5×5-array sensitivity adjustment structure 81_11 uses the intra-pixel groove 22a with the cross shape in which lines extending in the vertical direction and the horizontal direction of a pixel 12 cross each other at the middle.

The eleventh 5×5-array sensitivity adjustment structure 81_11 includes an arrangement pattern in which, in the 5×5 array of the twenty-five pixels 12-1 to 12-25, the intra-pixel groove 22a with the cross shape is provided to a pixel 12 arranged at the middle. That is, in the eleventh 5×5-array sensitivity adjustment structure 81_11, the intra-pixel groove 22a-1 with the cross shape is provided to the pixel 12-13.

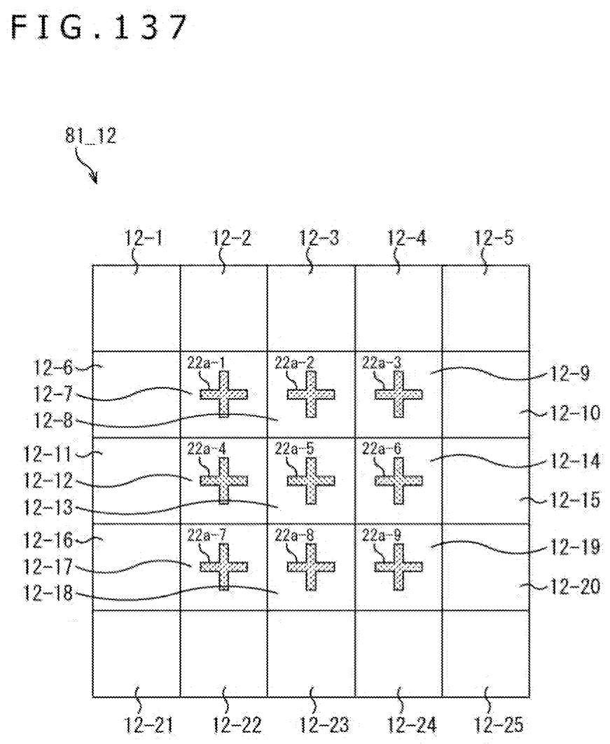

FIG. 137 is a figure depicting a configuration example of a twelfth 5×5-array sensitivity adjustment structure 81_12.

As depicted in FIG. 137, the twelfth 5×5-array sensitivity adjustment structure 81_12 uses the intra-pixel grooves 22a with the cross shape in which lines extending in the vertical direction and the horizontal direction of a pixel 12 cross each other at the middle.

The twelfth 5×5-array sensitivity adjustment structure 81_12 includes an arrangement pattern in which, in the 5×5 array of the twenty-five pixels 12-1 to 12-25, the intra-pixel grooves 22a with the cross shape are provided to pixels 12 arranged at the nine locations in the middle 3×3 array.

That is, in the twelfth 5×5-array sensitivity adjustment structure 81_12, the intra-pixel grooves 22a-1 to 22a-3 with the cross shape are provided to the pixels 12-7 to 12-9, the intra-pixel grooves 22a-4 to 22a-6 with the cross shape are provided to the pixels 12-12 to 12-14, and the intra-pixel grooves 22a-7 to 22a-9 with the cross shape are provided to the pixels 12-17 to 12-19.

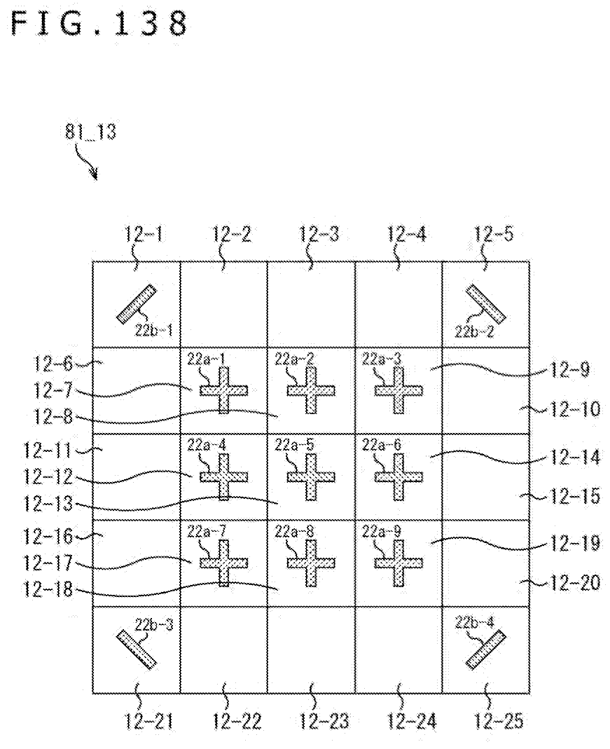

FIG. 138 is a figure depicting a configuration example of a thirteenth 5×5-array sensitivity adjustment structure 81_13.

As depicted in FIG. 138, the thirteenth 5×5-array sensitivity adjustment structure 81_13 uses the intra-pixel grooves 22a with the cross shape in which lines extending in the vertical direction and the horizontal direction of a pixel 12 cross each other at the middle and the intra-pixel grooves 22b with the diagonal line shape extending in a diagonal direction of a pixel 12.

Similarly to the first 5×5-array sensitivity adjustment structure 81_1 in FIG. 126, in the thirteenth 5×5-array sensitivity adjustment structure 81_13, the intra-pixel grooves 22b with the diagonal line shape are provided to pixels 12 arranged at the four corner locations in the 5×5 array of the twenty-five pixels 12-1 to 12-25. Moreover, similarly to the twelfth 5×5-array sensitivity adjustment structure 81_12 in FIG. 137, the thirteenth 5×5-array sensitivity adjustment structure 81_13 includes an arrangement pattern in which the intra-pixel grooves 22a with the cross shape are provided to pixels 12 arranged at the nine locations in the middle 3×3 array.

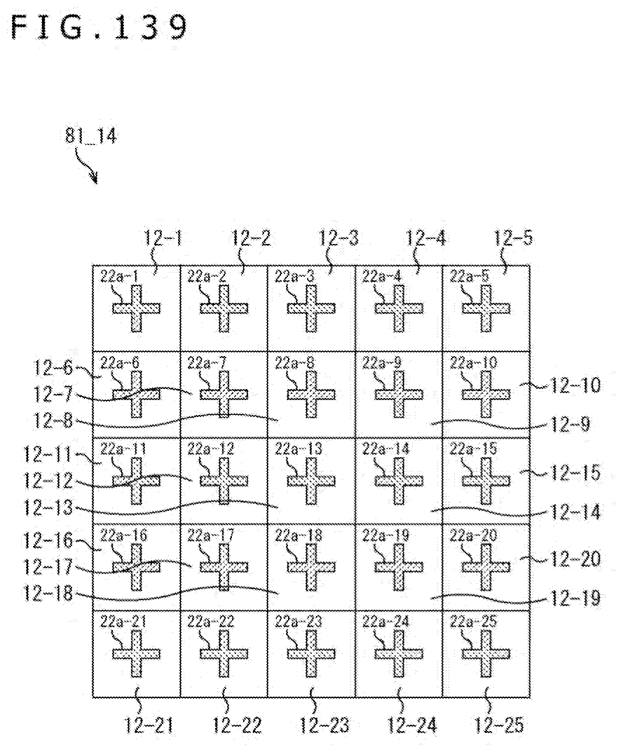

FIG. 139 is a figure depicting a configuration example of a fourteenth 5×5-array sensitivity adjustment structure 81_14.

As depicted in FIG. 139, the fourteenth 5×5-array sensitivity adjustment structure 81_14 uses the intra-pixel grooves 22a with the cross shape in which lines extending in the vertical direction and the horizontal direction of a pixel 12 cross each other at the middle.

The fourteenth 5×5-array sensitivity adjustment structure 81_14 includes an arrangement pattern in which the intra-pixel grooves 22a with the cross shape are provided to all the twenty-five pixels 12-1 to 12-25 in the 5×5 array. That is, in the fourteenth 5×5-array sensitivity adjustment structure 81_14, the intra-pixel grooves 22a-1 to 22a-25 with the cross shape are provided to the pixels 12-1 to 12-25, respectively.

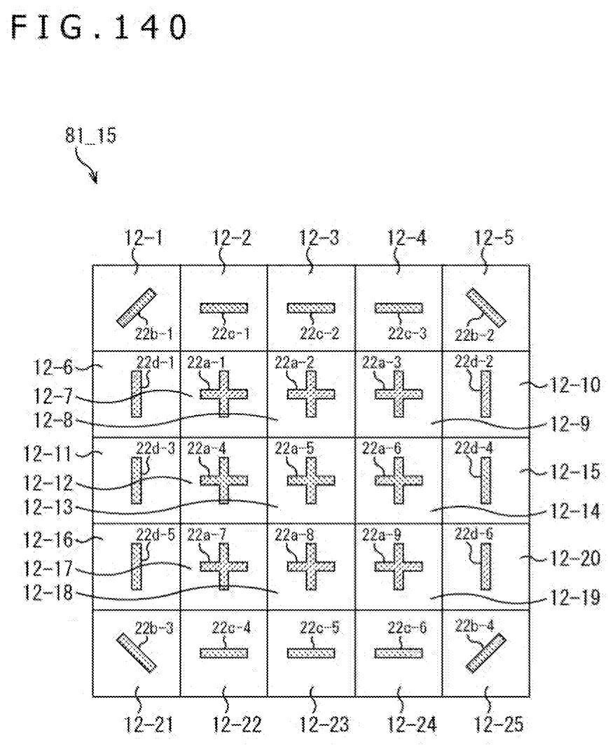

FIG. 140 is a figure depicting a configuration example of a fifteenth 5×5-array sensitivity adjustment structure 81_15.

As depicted in FIG. 140, the fifteenth 5×5-array sensitivity adjustment structure 81_15 uses the intra-pixel grooves 22a with the cross shape in which lines extending in the vertical direction and the horizontal direction of a pixel 12 cross each other at the middle, the intra-pixel grooves 22b with the diagonal line shape extending in a diagonal direction of a pixel 12, the intra-pixel grooves 22c with the horizontal line shape extending in the horizontal direction of a pixel 12, and the intra-pixel grooves 22d with the vertical line shape extending in the vertical direction of a pixel 12.

Similarly to the third 5×5-array sensitivity adjustment structure 81_3 in FIG. 128, the fifteenth 5×5-array sensitivity adjustment structure 81_15 includes an arrangement pattern in which, in the 5×5 array of the twenty-five pixels 12-1 to 12-25, the intra-pixel grooves 22b with the diagonal line shape are provided to pixels 12 arranged at the four corner locations, the intra-pixel grooves 22c with the horizontal line shape are provided to pixels 12 arranged at the three middle locations on the upper side and pixels 12 arranged at the three middle locations on the lower side, and the intra-pixel grooves 22d with the vertical line shape are provided to pixels 12 arranged at the three middle locations on the right side and pixels 12 arranged at the three middle locations on the left side. Moreover, similarly to the twelfth 5×5-array sensitivity adjustment structure 81_12 in FIG. 137, the fifteenth 5×5-array sensitivity adjustment structure 81_15 includes an arrangement pattern in which the intra-pixel grooves 22a with the cross shape are provided to pixels 12 arranged at the nine locations in the middle 3×3 array.

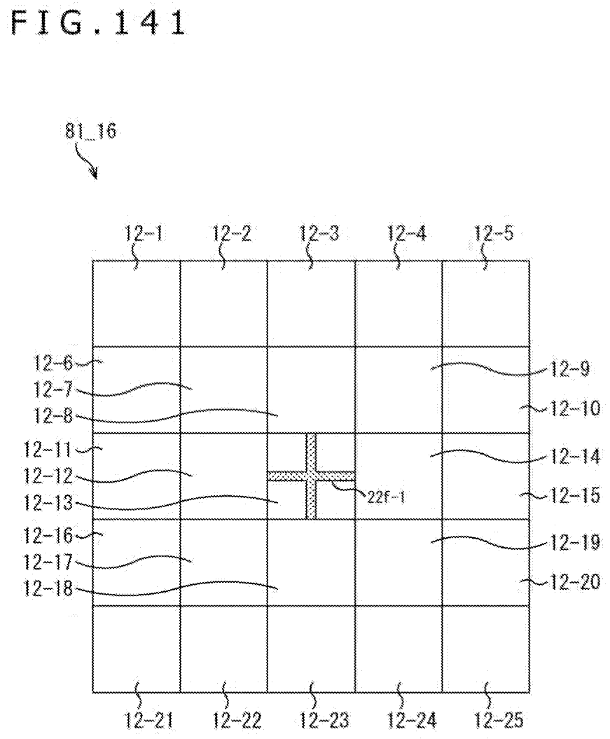

FIG. 141 is a figure depicting a configuration example of a sixteenth 5×5-array sensitivity adjustment structure 81_16.

As depicted in FIG. 141, the sixteenth 5×5-array sensitivity adjustment structure 81_16 uses the intra-pixel groove 22f with the cross shape and the enlarged structure in which lines extending in the vertical direction and the horizontal direction of a pixel 12 cross each other at the middle.

Similarly to the eleventh 5×5-array sensitivity adjustment structure 81_11 in FIG. 136, the sixteenth 5×5-array sensitivity adjustment structure 81_16 includes an arrangement pattern in which, in the 5×5 array of the twenty-five pixels 12-1 to 12-25, the intra-pixel groove 22f with the cross shape and the enlarged structure is provided to a pixel 12 arranged at the middle.

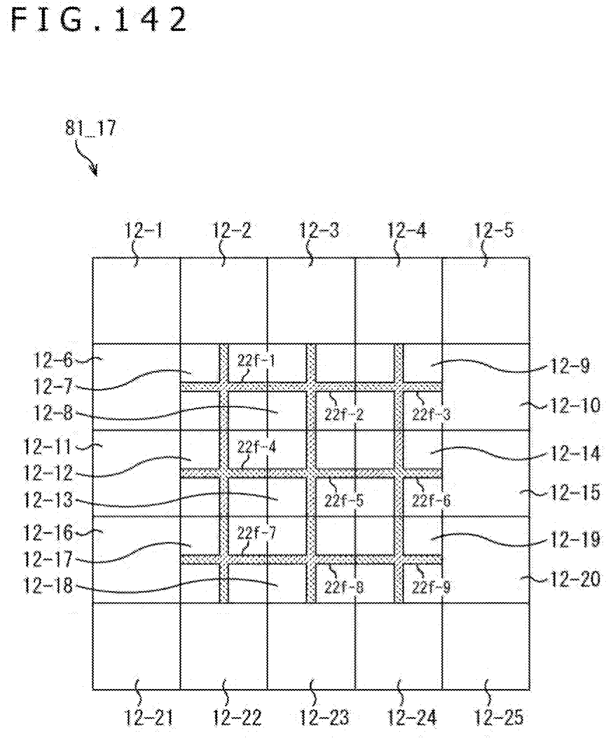

FIG. 142 is a figure depicting a configuration example of a seventeenth 5×5-array sensitivity adjustment structure 81_17.

As depicted in FIG. 142, the seventeenth 5×5-array sensitivity adjustment structure 81_17 uses the intra-pixel grooves 22f with the cross shape and the enlarged structure in which lines extending in the vertical direction and the horizontal direction of a pixel 12 cross each other at the middle.

Similarly to the twelfth 5×5-array sensitivity adjustment structure 81_12 in FIG. 137, the seventeenth 5×5-array sensitivity adjustment structure 81_17 includes an arrangement pattern in which, in the 5×5 array of the twenty-five pixels 12-1 to 12-25, the intra-pixel grooves 22f with the cross shape and the enlarged structure are provided to pixels 12 arranged at the nine locations in the middle 3×3 array.

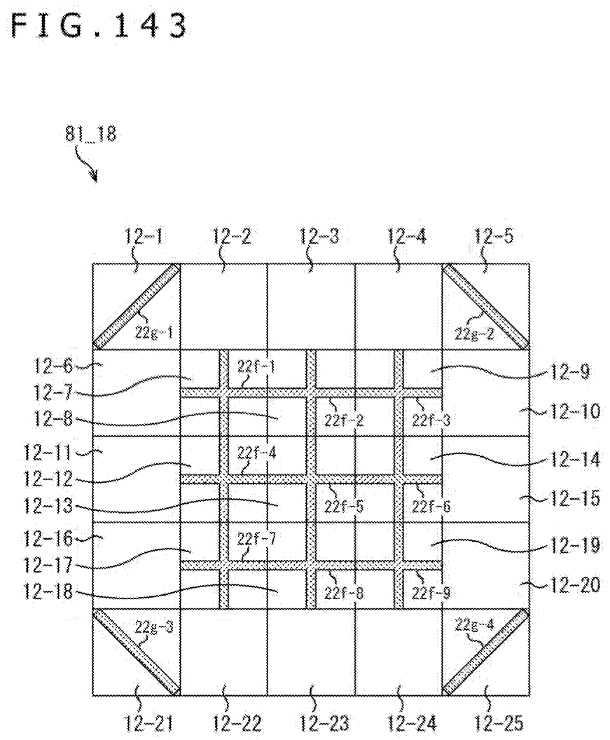

FIG. 143 is a figure depicting a configuration example of an eighteenth 5×5-array sensitivity adjustment structure 81_18.

As depicted in FIG. 143, the eighteenth 5×5-array sensitivity adjustment structure 81_18 uses the intra-pixel grooves 22f with the cross shape and the enlarged structure in which lines extending in the vertical direction and the horizontal direction of a pixel 12 cross each other at the middle and the intra-pixel grooves 22g with the diagonal line shape and the enlarged structure extending in a diagonal direction of a pixel 12.

Similarly to the thirteenth 5×5-array sensitivity adjustment structure 81_13 in FIG. 138, the eighteenth 5×5-array sensitivity adjustment structure 81_18 includes an arrangement pattern in which, in the 5×5 array of the twenty-five pixels 12-1 to 12-25 the intra-pixel grooves 22f with the cross shape and the enlarged structure are provided to pixels 12 arranged at the nine locations in the middle 3×3 array, and the intra-pixel grooves 22g with the diagonal line shape and the enlarged structure are provided to pixels 12 arranged at the four corner locations.

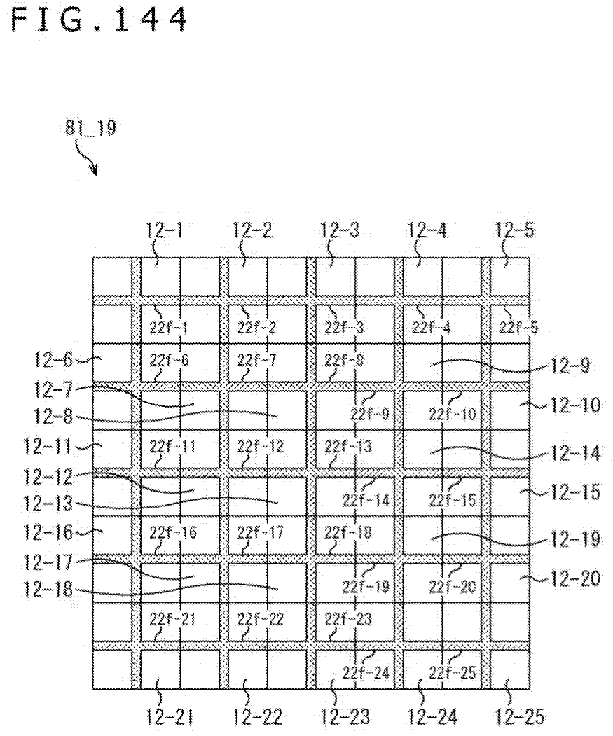

FIG. 144 is a figure depicting a configuration example of a nineteenth 5×5-array sensitivity adjustment structure 81_19.

As depicted in FIG. 144, the nineteenth 5×5-array sensitivity adjustment structure 81_19 uses the intra-pixel grooves 22f with the cross shape and the enlarged structure in which lines extending in the vertical direction and the horizontal direction of a pixel 12 cross each other at the middle.

Similarly to the fourteenth 5×5-array sensitivity adjustment structure 81_14 in FIG. 139, the nineteenth 5×5-array sensitivity adjustment structure 81_19 includes an arrangement pattern in which the intra-pixel grooves 22f with the cross shape and the enlarged structure are provided to all the twenty-five pixels 12-1 to 12-25 in the 5×5 array.

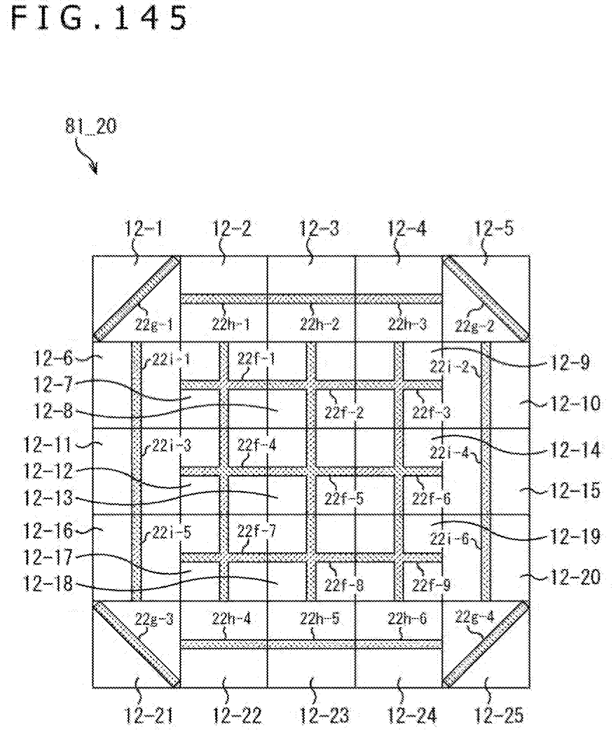

FIG. 145 is a figure depicting a configuration example of a twentieth 5×5-array sensitivity adjustment structure 81_20.

As depicted in FIG. 145, the twentieth 5×5-array sensitivity adjustment structure 81_20 uses the intra-pixel grooves 22f with the cross shape and the enlarged structure in which lines extending in the vertical direction and the horizontal direction of a pixel 12 cross each other at the middle, the intra-pixel grooves 22g with the diagonal line shape and the enlarged structure extending in a diagonal direction of a pixel 12, the intra-pixel grooves 22h with the horizontal line shape and the enlarged structure extending in the horizontal direction of a pixel 12, and the intra-pixel grooves 22i with the vertical line shape and the enlarged structure extending in the vertical direction of a pixel 12.

Similarly to the fifteenth 5×5-array sensitivity adjustment structure 81_15 in FIG. 140, the twentieth 5×5-array sensitivity adjustment structure 81_20 includes an arrangement pattern in which, in the 5×5 array of the twenty-five pixels 12-1 to 12-25, the intra-pixel grooves 22f with the cross shape and the enlarged structure are provided to pixels 12 arranged at the nine locations in the middle 3×3 array, the intra-pixel grooves 22g with the diagonal line shape and the enlarged structure are provided to pixels 12 arranged at the four corner locations, the intra-pixel grooves 22h with the horizontal line shape and the enlarged structure are provided to pixels 12 arranged at the three middle locations on the upper side and pixels 12 arranged at the three middle locations on the lower side, and the intra-pixel grooves 22i with the vertical line shape and the enlarged structure are provided to pixels 12 arranged at the three middle locations on the right side and pixels 12 arranged at the three middle locations on the left side.

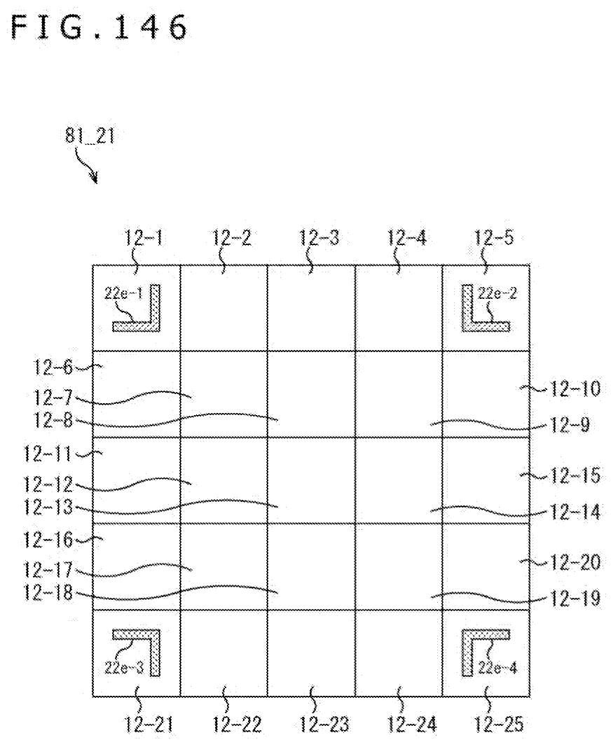

FIG. 146 is a figure depicting a configuration example of a twenty-first 5×5-array sensitivity adjustment structure 81_21.

As depicted in FIG. 146, the twenty-first 5×5-array sensitivity adjustment structure 81_21 uses the intra-pixel grooves 22e with the L-shape in which lines extending in the vertical direction and the horizontal direction of a pixel 12 are joined with each other at ends thereof.

The twenty-first 5×5-array sensitivity adjustment structure 81_21 includes an arrangement pattern in which, in the 5×5 array of twenty-five pixels 12-1 to 12-25, the intra-pixel grooves 22e with the L-shape are provided to pixels 12 arranged at the four corner locations. The intra-pixel grooves 22e with the L-shape are formed such that the joined portions of the lines extending in the vertical directions and the horizontal directions are arranged on the middle side of the 5×5 array, and 5×5-array sensitivity adjustment structures 81 explained below are formed similarly.

That is, in the twenty-first 5×5-array sensitivity adjustment structure 81_21, the intra-pixel groove 22e-1 with the L-shape having a vertical line that is arranged near the right side and a horizontal line that is arranged near the lower side is provided to the pixel 12-1, and the intra-pixel groove 22e-2 with the L-shape having a vertical line that is arranged near the left side and a horizontal line that is arranged near the lower side is provided to the pixel 12-5. Moreover, the intra-pixel groove 22e-3 with the L-shape having a vertical line that is arranged near the right side and a horizontal line that is arranged near the upper side is provided to the pixel 12-21, and the intra-pixel groove 22e-4 with the L-shape having a vertical line that is arranged near the left side and a horizontal line that is arranged near the upper side is provided to the pixel 12-25.

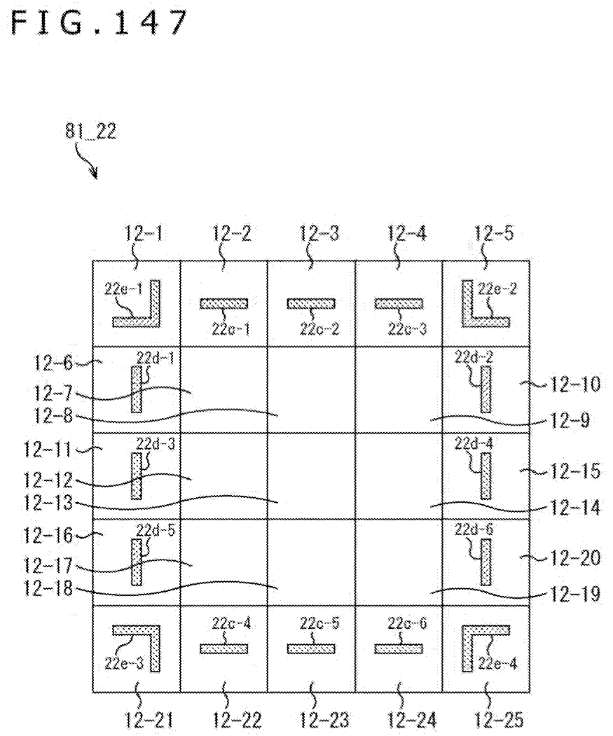

FIG. 147 is a figure depicting a configuration example of a twenty-second 5×5-array sensitivity adjustment structure 81_22.

As depicted in FIG. 147, the twenty-second 5×5-array sensitivity adjustment structure 81_22 uses the intra-pixel grooves 22c with the horizontal line shape extending in the horizontal direction of a pixel 12, the intra-pixel grooves 22d with the vertical line shape extending in the vertical direction of a pixel 12, and the intra-pixel grooves 22e with the L-shape in which lines extending in the vertical direction and the horizontal direction of a pixel 12 are joined with each other at ends thereof.

The twenty-second 5×5-array sensitivity adjustment structure 81_22 includes an arrangement pattern in which, in the 5×5 array of the twenty-five pixels 12-1 to 12-25, the intra-pixel grooves 22c with the horizontal line shape are provided to pixels 12 arranged at the three middle locations on the upper side and pixels 12 arranged at the three middle locations on the lower side, the intra-pixel grooves 22d with the vertical line shape are provided to pixels 12 arranged at the three middle locations on the right side and pixels 12 arranged at the three middle locations on the left side, and the intra-pixel grooves 22e with the L-shape are provided to pixels 12 arranged at the four corner locations.

That is, in the twenty-second 5×5-array sensitivity adjustment structure 81_22, the intra-pixel groove 22c-1 with the horizontal line shape is provided to the pixel 12-2, the intra-pixel groove 22c-2 with the horizontal line shape is provided to the pixel 12-3, the intra-pixel groove 22c-3 with the horizontal line shape is provided to the pixel 12-4, the intra-pixel groove 22c-4 with the horizontal line shape is provided to the pixel 12-22, the intra-pixel groove 22c-5 with the horizontal line shape is provided to the pixel 12-23, and the intra-pixel groove 22c-6 with the horizontal line shape is provided to the pixel 12-24. Moreover, the intra-pixel groove 22d-1 with the vertical line shape is provided to the pixel 12-6, the intra-pixel groove 22d-2 with the vertical line shape is provided to the pixel 12-10, the intra-pixel groove 22d-3 with the vertical line shape is provided to the pixel 12-11, the intra-pixel groove 22d-4 with the vertical line shape is provided to the pixel 12-15, the intra-pixel groove 22d-5 with the vertical line shape is provided to the pixel 12-16, and the intra-pixel groove 22d-6 with the vertical line shape is provided to the pixel 12-20.

Moreover, the intra-pixel groove 22e-1 with the L-shape having a vertical line that is arranged near the right side and a horizontal line that is arranged near the lower side is provided to the pixel 12-1, and the intra-pixel groove 22e-2 with the L-shape having a vertical line that is arranged near the left side and a horizontal line that is arranged near the lower side is provided to the pixel 12-5. Moreover, the intra-pixel groove 22e-3 with the L-shape having a vertical line that is arranged near the right side and a horizontal line that is arranged near the upper side is provided to the pixel 12-21, and the intra-pixel groove 22e-4 with the L-shape having a vertical line that is arranged near the left side and a horizontal line that is arranged near the upper side is provided to the pixel 12-25.

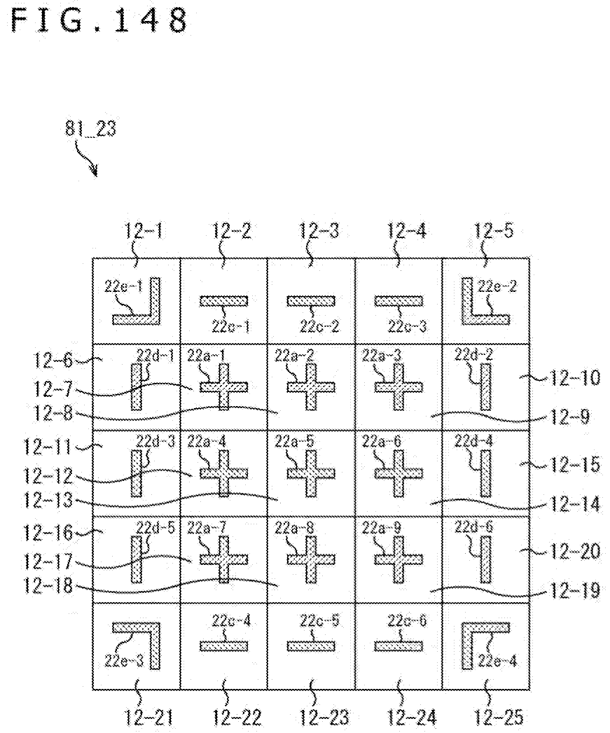

FIG. 148 is a figure depicting a configuration example of a twenty-third 5×5-array sensitivity adjustment structure 81_23.

As depicted in FIG. 148, the twenty-third 5×5-array sensitivity adjustment structure 81_23 uses the intra-pixel grooves 22a with the cross shape in which lines extending in the vertical direction and the horizontal direction of a pixel 12 cross each other at the middle, the intra-pixel grooves 22c with the horizontal line shape extending in the horizontal direction of a pixel 12, the intra-pixel grooves 22d with the vertical line shape extending in the vertical direction of a pixel 12, and the intra-pixel grooves 22e with the L-shape in which lines extending in the vertical direction and the horizontal direction of a pixel 12 are joined with each other at ends thereof.

Similarly to the twenty-second 5×5-array sensitivity adjustment structure 81_22 in FIG. 147, the twenty-third 5×5-array sensitivity adjustment structure 81_23 includes an arrangement pattern in which, in the 5×5 array of the twenty-five pixels 12-1 to 12-25, the intra-pixel grooves 22e with the L-shape are provided to pixels 12 arranged at the four corner locations, the intra-pixel grooves 22c with the horizontal line shape are provided to pixels 12 arranged at the three middle locations on the upper side and pixels 12 arranged at the three middle locations on the lower side, and the intra-pixel grooves 22d with the vertical line shape are provided to pixels 12 arranged at the three middle locations on the right side and pixels 12 arranged at the three middle locations on the left side. Moreover, similarly to the twelfth 5×5-array sensitivity adjustment structure 81_12 in FIG. 137, the twenty-third 5×5-array sensitivity adjustment structure 81_23 includes an arrangement pattern in which the intra-pixel grooves 22a with the cross shape are provided to pixels 12 arranged at the nine locations in the middle 3×3 array.

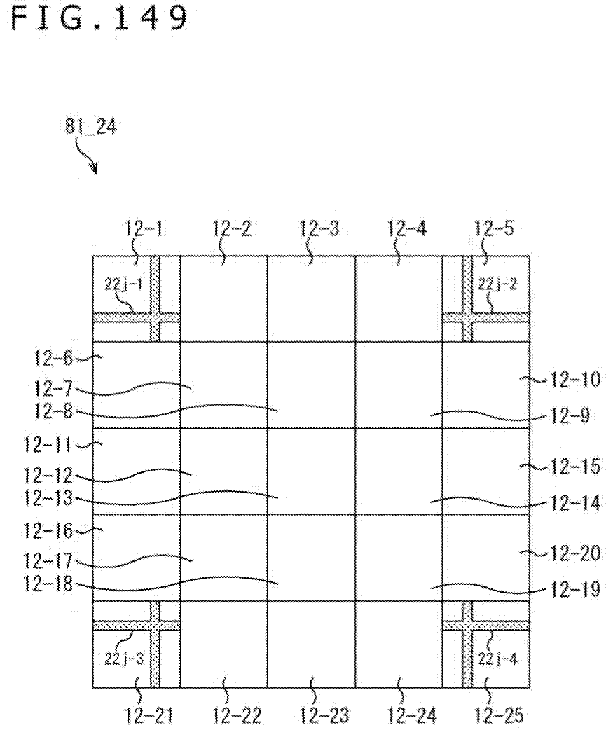

FIG. 149 is a figure depicting a configuration example of a twenty-fourth 5×5-array sensitivity adjustment structure 81_24.

As depicted in FIG. 149, the twenty-fourth 5×5-array sensitivity adjustment structure 81_24 uses the intra-pixel grooves 22j with the L-shape and the enlarged structure in which lines extending in the vertical directions and the horizontal directions of the intra-pixel grooves 22e with the L-shape are enlarged to pixel ends.

Similarly to the twenty-first 5×5-array sensitivity adjustment structure 81_21 in FIG. 146, the twenty-fourth 5×5-array sensitivity adjustment structure 81_24 includes an arrangement pattern in which, in the 5×5 array of the twenty-five pixels 12-1 to 12-25, the intra-pixel grooves 22j with the L-shape and the enlarged structure are provided to pixels 12 arranged at the four corner locations.

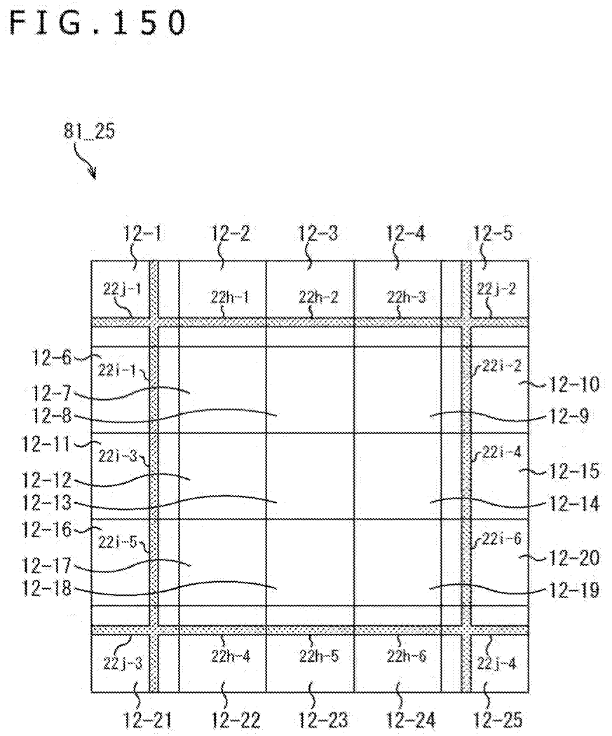

FIG. 150 is a figure depicting a configuration example of a twenty-fifth 5×5-array sensitivity adjustment structure 81_25.

As depicted in FIG. 150, the twenty-fifth 5×5-array sensitivity adjustment structure 81_25 uses the intra-pixel grooves 22h with the horizontal line shape and the enlarged structure extending in the horizontal direction of a pixel 12, the intra-pixel grooves 22i with the vertical line shape and the enlarged structure extending in the vertical direction of a pixel 12, and the intra-pixel grooves 22j with the L-shape and the enlarged structure in which lines extending in the vertical directions and the horizontal directions of the intra-pixel grooves 22e with the L-shape are enlarged to pixel ends.

Similarly to the twenty-second 5×5-array sensitivity adjustment structure 81_22 in FIG. 147, the twenty-fifth 5×5-array sensitivity adjustment structure 81_25 includes an arrangement pattern in which, in the 5×5 array of the twenty-five pixels 12-1 to 12-25, the intra-pixel grooves 22h with the horizontal line shape and the enlarged structure are provided to pixels 12 arranged at the three middle locations on the upper side and pixels 12 arranged at the three middle locations on the lower side, the intra-pixel grooves 22i with the vertical line shape and the enlarged structure are provided to pixels 12 arranged at the three middle locations on the right side and pixels 12 arranged at the three middle locations on the left side, and the intra-pixel grooves 22j with the L-shape and the enlarged structure are provided to pixels 12 arranged at the four corner locations.

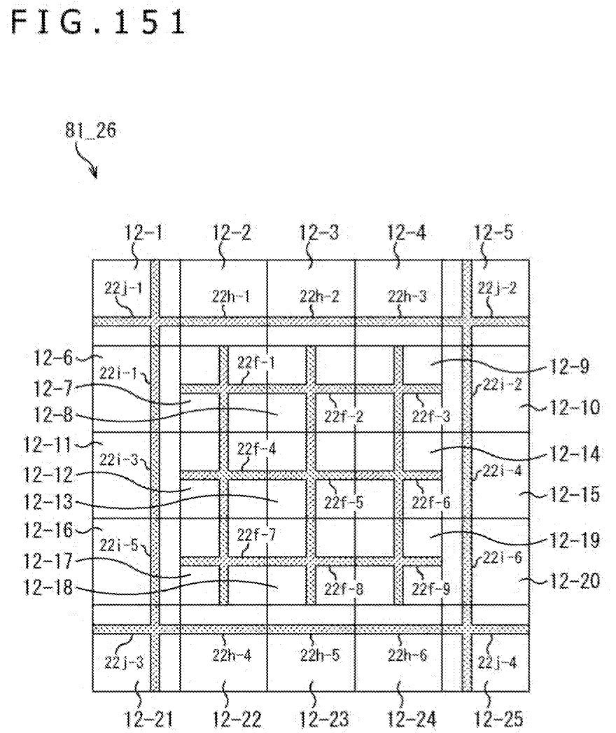

FIG. 151 is a figure depicting a configuration example of a twenty-sixth 5×5-array sensitivity adjustment structure 81_26.

As depicted in FIG. 151, the twenty-sixth 5×5-array sensitivity adjustment structure 81_26 uses the intra-pixel grooves 22f with the cross shape and the enlarged structure in which lines extending in the vertical direction and the horizontal direction of a pixel 12 cross each other at the middle, the intra-pixel grooves 22h with the horizontal line shape and the enlarged structure extending in the horizontal direction of a pixel 12, the intra-pixel grooves 22i with the vertical line shape and the enlarged structure extending in the vertical direction of a pixel 12, and the intra-pixel grooves 22j with the L-shape and the enlarged structure in which lines extending in the vertical directions and the horizontal directions of the intra-pixel grooves 22e with the L-shape are enlarged to pixel ends.

Similarly to the twenty-third 5×5-array sensitivity adjustment structure 81_23 in FIG. 148, the twenty-sixth 5×5-array sensitivity adjustment structure 81_26 includes an arrangement pattern in which, in the 5×5 array of the twenty-five pixels 12-1 to 12-25, the intra-pixel grooves 22f with the cross shape and the enlarged structure are provided to pixels 12 arranged at the nine locations in the middle 3×3 array, the intra-pixel grooves 22h with the horizontal line shape and the enlarged structure are provided to pixels 12 arranged at the three middle locations on the upper side and pixels 12 arranged at the three middle locations on the lower side, the intra-pixel grooves 22i with the vertical line shape and the enlarged structure are provided to pixels 12 arranged at the three middle locations on the right side and pixels 12 arranged at the three middle locations on the left side, and the intra-pixel grooves 22j with the L-shape and the enlarged structure are provided to pixels 12 arranged at the four corner locations.

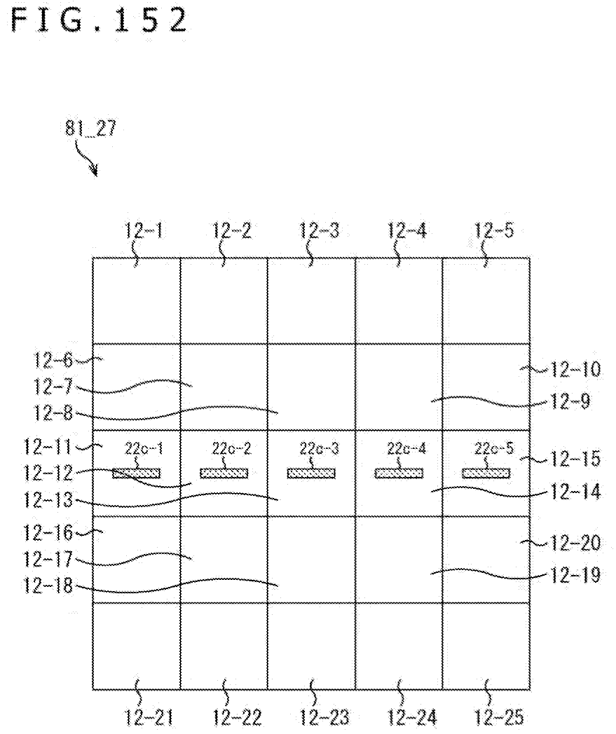

FIG. 152 is a figure depicting a configuration example of a twenty-seventh 5×5-array sensitivity adjustment structure 81_27.

As depicted in FIG. 152, the twenty-seventh 5×5-array sensitivity adjustment structure 81_27 uses the intra-pixel grooves 22c with the horizontal line shape extending in the horizontal direction of a pixel 12.

The twenty-seventh 5×5-array sensitivity adjustment structure 81_27 includes an arrangement pattern in which, in the 5×5 array of the twenty-five pixels 12-1 to 12-25, the intra-pixel grooves 22c with the horizontal line shape are provided to pixels 12 arranged at the five locations in the one middle row. That is, in the twenty-seventh 5×5-array sensitivity adjustment structure 81_27, the intra-pixel grooves 22c-1 to 22c-5 with the horizontal line shape are provided to the pixels 12-11 to 12-15, respectively.

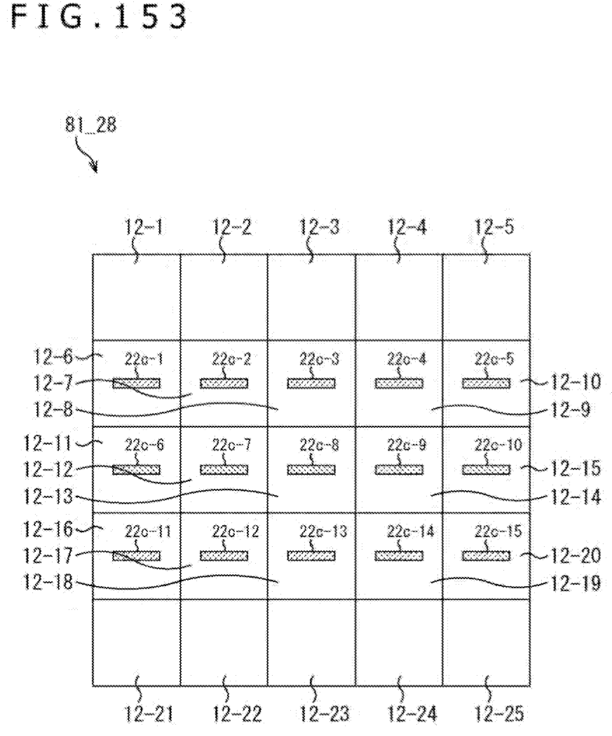

FIG. 153 is a figure depicting a configuration example of a twenty-eighth 5×5-array sensitivity adjustment structure 81_28.

As depicted in FIG. 153, the twenty-eighth 5×5-array sensitivity adjustment structure 81_28 uses the intra-pixel grooves 22c with the horizontal line shape extending in the horizontal direction of a pixel 12.

The twenty-eighth 5×5-array sensitivity adjustment structure 81_28 includes an arrangement pattern in which, in the 5×5 array of the twenty-five pixels 12-1 to 12-25, the intra-pixel grooves 22c with the horizontal line shape are provided to pixels 12 arranged at the fifteen locations in the three middle rows. That is, in the twenty-eighth 5×5-array sensitivity adjustment structure 81_28, the intra-pixel grooves 22c-1 to 22c-15 with the horizontal line shape are provided to the pixels 12-6 to 12-20, respectively.

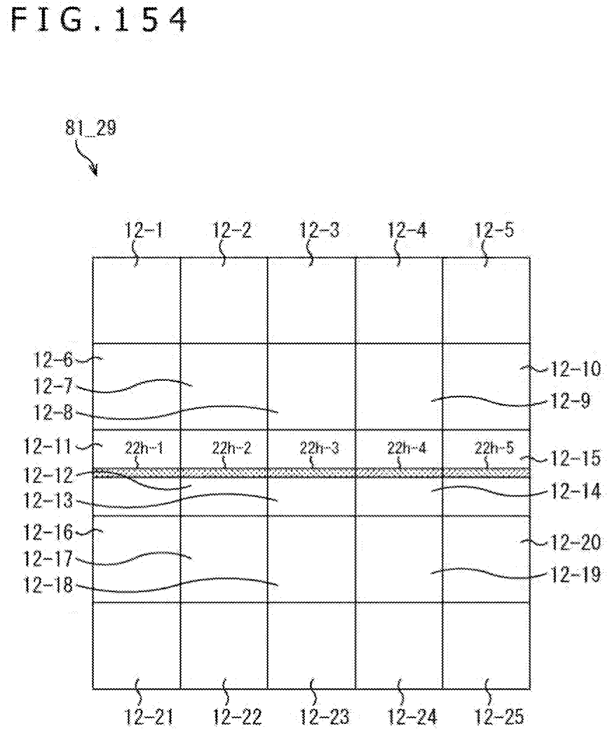

FIG. 154 is a figure depicting a configuration example of a twenty-ninth 5×5-array sensitivity adjustment structure 81_29.

As depicted in FIG. 154, the twenty-ninth 5×5-array sensitivity adjustment structure 81_29 uses the intra-pixel grooves 22h with the horizontal line shape and the enlarged structure extending in the horizontal direction of a pixel 12.

Similarly to the twenty-seventh 5×5-array sensitivity adjustment structure 81_27 in FIG. 152, the twenty-ninth 5×5-array sensitivity adjustment structure 81_29 includes an arrangement pattern in which, in the 5×5 array of the twenty-five pixels 12-1 to 12-25, the intra-pixel grooves 22h with the horizontal line shape and the enlarged structure are provided to pixels 12 arranged at the five locations in the one middle row.

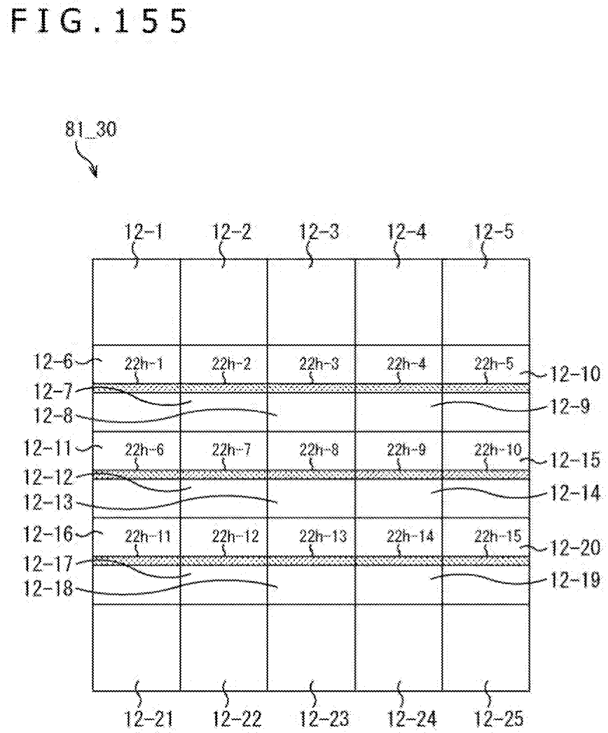

FIG. 155 is a figure depicting a configuration example of a thirtieth 5×5-array sensitivity adjustment structure 81_30.

As depicted in FIG. 155, the thirtieth 5×5-array sensitivity adjustment structure 81_30 uses the intra-pixel grooves 22h with the horizontal line shape and the enlarged structure extending in the horizontal direction of a pixel 12.

Similarly to the twenty-eighth 5×5-array sensitivity adjustment structure 81_28 in FIG. 153, the thirtieth 5×5-array sensitivity adjustment structure 81_30 includes an arrangement pattern in which, in the 5×5 array of the twenty-five pixels 12-1 to 12-25, the intra-pixel grooves 22h with the horizontal line shape and the enlarged structure are provided to pixels 12 arranged at the fifteen locations in the three middle rows.

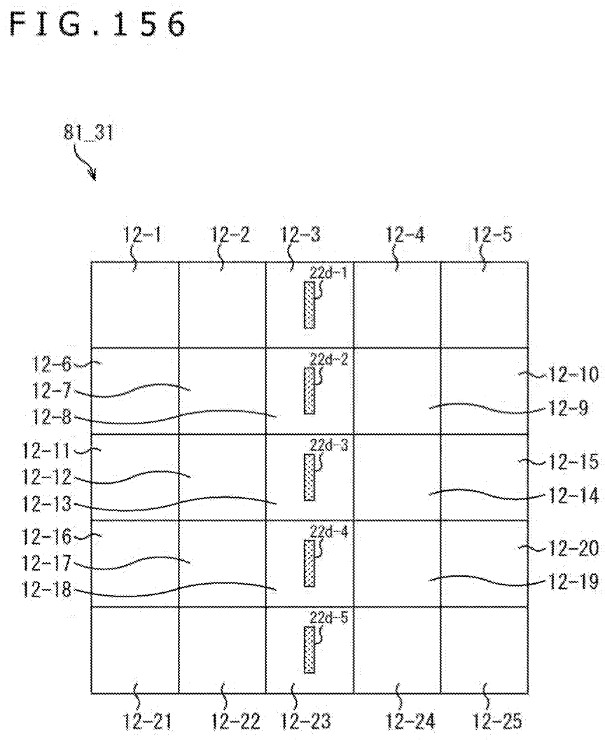

FIG. 156 is a figure depicting a configuration example of a thirty-first 5×5-array sensitivity adjustment structure 81_31.

As depicted in FIG. 156, the thirty-first 5×5-array sensitivity adjustment structure 81_31 uses the intra-pixel grooves 22d with the vertical line shape extending in the vertical direction of a pixel 12.

The thirty-first 5×5-array sensitivity adjustment structure 81_31 includes an arrangement pattern in which, in the 5×5 array of the twenty-five pixels 12-1 to 12-25, the intra-pixel grooves 22d with the vertical line shape are provided to pixels 12 arranged at the five locations in the one middle column. That is, in the thirty-first 5×5-array sensitivity adjustment structure 81_31, the intra-pixel groove 22d-1 with the vertical line shape is provided to the pixel 12-3, the intra-pixel groove 22d-2 with the vertical line shape is provided to the pixel 12-8, the intra-pixel groove 22d-3 with the vertical line shape is provided to the pixel 12-13, the intra-pixel groove 22d-4 with the vertical line shape is provided to the pixel 12-18, and the intra-pixel groove 22d-5 with the vertical line shape is provided to the pixel 12-23.

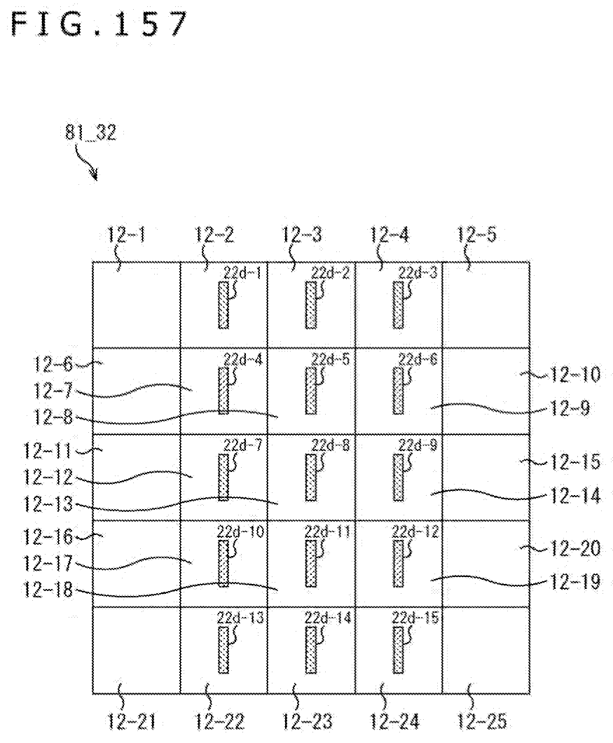

FIG. 157 is a figure depicting a configuration example of a thirty-second 5×5-array sensitivity adjustment structure 81_32.

As depicted in FIG. 157, the thirty-second 5×5-array sensitivity adjustment structure 81_32 uses the intra-pixel grooves 22d with the vertical line shape extending in the vertical direction of a pixel 12.

The thirty-second 5×5-array sensitivity adjustment structure 81_32 includes an arrangement pattern in which, in the 5×5 array of the twenty-five pixels 12-1 to 12-25, the intra-pixel grooves 22d with the vertical line shape are provided to pixels 12 arranged at the fifteen locations in the three middle columns. That is, in the thirty-second 5×5-array sensitivity adjustment structure 81_32, the intra-pixel grooves 22d-1 to 22d-3 with the vertical line shape are provided to the pixels 12-2 to 12-4, the intra-pixel grooves 22d-4 to 22d-6 with the vertical line shape are provided to the pixels 12-7 to 12-9, the intra-pixel grooves 22d-7 to 22d-9 with the vertical line shape are provided to the pixels 12-12 to 12-14, the intra-pixel grooves 22d-10 to 22d-12 with the vertical line shape are provided to the pixels 12-17 to 12-19, and the intra-pixel grooves 22d-13 to 22d-15 with the vertical line shape are provided to the pixels 12-22 to 12-24.

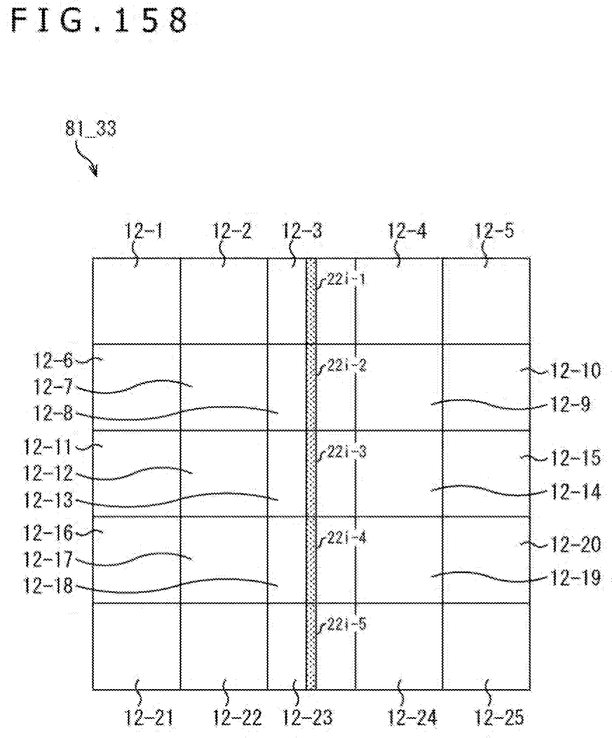

FIG. 158 is a figure depicting a configuration example of a thirty-third 5×5-array sensitivity adjustment structure 81_33.

As depicted in FIG. 158, the thirty-third 5×5-array sensitivity adjustment structure 81_33 uses the intra-pixel grooves 22i with the vertical line shape and the enlarged structure extending in the vertical direction of a pixel 12.

Similarly to the thirty-first 5×5-array sensitivity adjustment structure 81_31 in FIG. 156, the thirty-third 5×5-array sensitivity adjustment structure 81_33 includes an arrangement pattern in which, in the 5×5 array of the twenty-five pixels 12-1 to 12-25, the intra-pixel grooves 22i with the vertical line shape and the enlarged structure are provided to pixels 12 arranged at the five locations in the one middle column.

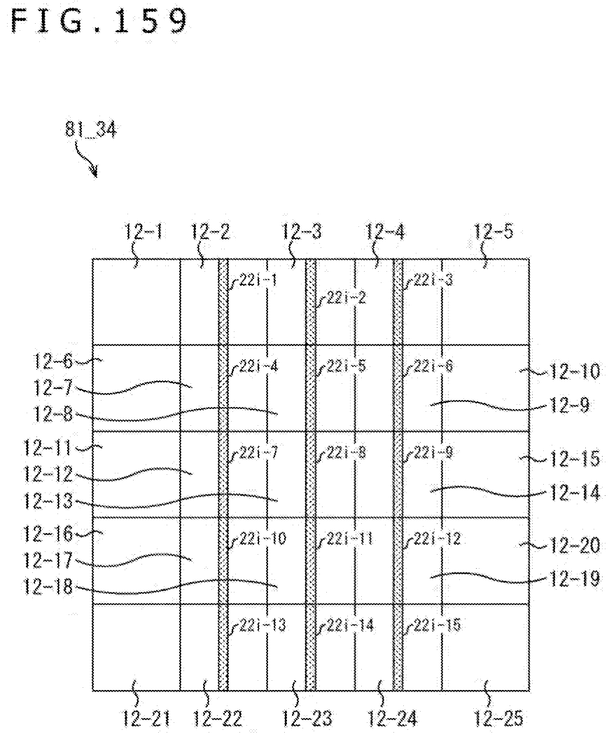

FIG. 159 is a figure depicting a configuration example of a thirty-fourth 5×5-array sensitivity adjustment structure 81_34.

As depicted in FIG. 159, the thirty-fourth 5×5-array sensitivity adjustment structure 81_34 uses the intra-pixel grooves 22i with the vertical line shape and the enlarged structure extending in the vertical direction of a pixel 12.

Similarly to the thirty-second 5×5-array sensitivity adjustment structure 81_32 in FIG. 157, the thirty-fourth 5×5-array sensitivity adjustment structure 81_34 includes an arrangement pattern in which, in the 5×5 array of the twenty-five pixels 12-1 to 12-25, the intra-pixel grooves 22i with the vertical line shape and the enlarged structure are provided to pixels 12 arranged at the fifteen locations in the three middle columns.

Similarly to the 4×4 arrays described above, by applying the 5×5-array sensitivity adjustment structures 81 as the ones above to same-color pixel groups 13, it is possible to suppress inter-pixel-12 sensitivity differences in the same-color pixel groups 13, and attain more uniform sensitivity characteristics.

Note that the configuration examples of the sensitivity adjustment structures 81 adopting the arrangement patterns of the intra-pixel grooves 22 as the ones described above are not the sole examples, and various arrangement patterns of intra-pixel grooves 22 may be adopted as long as those sensitivity adjustment structures 81 can contribute to suppression of inter-pixel-12 sensitivity differences in same-color pixel groups 13.

### Configuration Example of Electronic Equipment

For example, the image-capturing element 11 as the one described above can be applied to various types of electronic equipment such as image-capturing systems such as digital still cameras or digital video cameras, mobile phones having image-capturing functions, or other equipment having image-capturing functions.

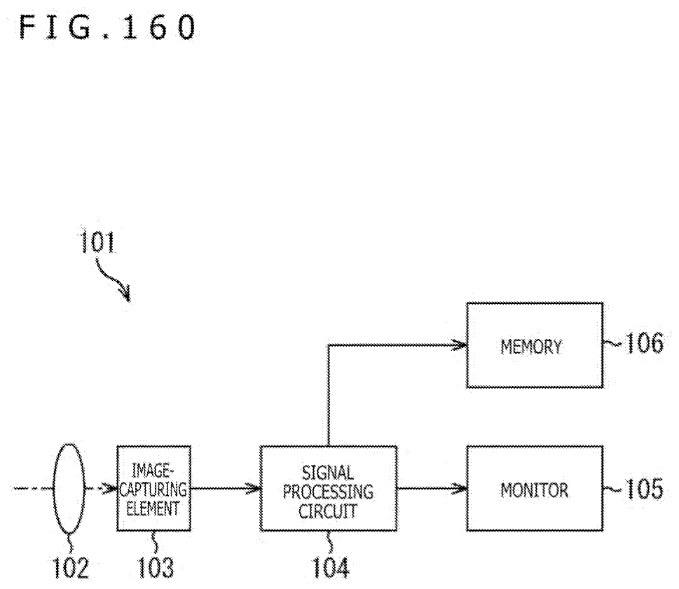

FIG. 160 is a block diagram depicting a configuration example of an image-capturing device mounted on electronic equipment.

As depicted in FIG. 160, an image-capturing device 101 includes an optical system 102, an image-capturing element 103, a signal processing circuit 104, a monitor 105, and a memory 106, and is capable of capturing still images and moving images.

The optical system 102 has one lens or multiple lenses, guides image light (incident light) from a subject to the image-capturing element 103, and causes an image to be formed on the light reception surface (sensor section) of the image-capturing element 103.

The image-capturing element 11 described above is applied as the image-capturing element 103. In the image-capturing element 103, electrons are accumulated for a predetermined period according to the image formed on the light reception surface via the optical system 102. Then, a signal according to the electrons accumulated in the image-capturing element 103 is supplied to the signal processing circuit 104.

The signal processing circuit 104 implements various types of signal processing on the pixel signal output from the image-capturing element 103. An image (image data) obtained by the implementation of the signal processing by the signal processing circuit 104 is supplied to and displayed on the monitor 105, is supplied to and stored (recorded) on the memory 106, and so on.

For example, the image-capturing device 101 configured as described above can capture images with higher image quality by applying the image-capturing element 11 described above.

### Use Examples of Image Sensor

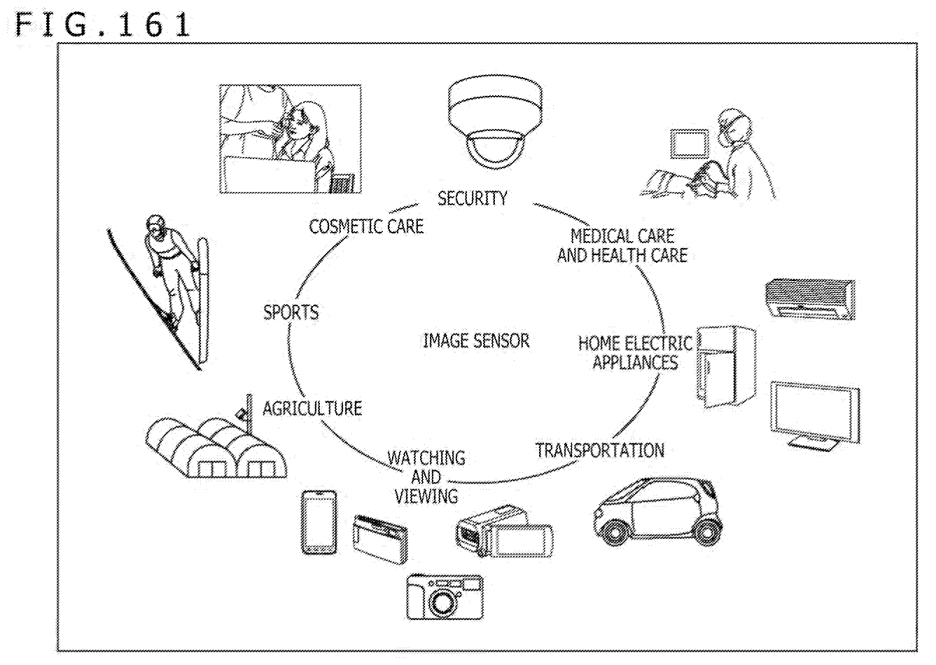

FIG. 161 is a figure depicting use examples in which the image sensor (image-capturing element) described above is used.

For example, the image sensor described above can be used in various cases in which light such as visible light, infrared light, ultraviolet light, or X-rays is sensed in the following manner.
Devices that capture images aimed for watching and viewing, such as digital cameras or mobile equipment having camera functions
Devices aimed for transportation, such as vehicle-mounted sensors that capture images of a space in front of an automobile, a space behind the automobile, spaces around the automobile, the interior of the automobile, or the like, monitoring cameras that monitor travelling vehicles and roads, or distance measurement sensors that perform measurement of distances between vehicles and the like, each for safe driving by automatic stops or the like, recognition of the state of the driver, and the like
Devices aimed for home electric appliances such as TVs, refrigerators, or air conditioners for performing equipment operation according to gestures of a user, images of which were captured by the devices
Devices aimed for medical care and health care, such as endoscopes and devices that perform image-capturing of blood vessels by receiving infrared light
Devices aimed for security, such as monitoring cameras for crime prevention uses or cameras for person authentication uses
Devices aimed for cosmetic care, such as skin measurement devices that capture images of skin or microscopes that capture images of scalps
Devices aimed for sports, such as action cameras or wearable cameras targeted at sports uses or the like
Devices aimed for agriculture, such as cameras for monitoring the states of fields and crops

Note that the present technology can also adopt the following configurations.

(1)

A solid-state image-capturing element including:

a same-color pixel group including pixels that receive light of the same color and that are arranged in an n×n array (n is an integer which is equal to or greater than two);

an on-chip lens provided for each m×m array (m is an integer which is equal to or smaller than n) of pixels in the same-color pixel group; and

a sensitivity adjustment structure with a configuration in which a dug portion shallower than an element separating portion for separating a photoelectric converting section in units of the pixels is provided on a light-incidence surface side of a semiconductor substrate at a predetermined pixel in the same-color pixel group.

(2)

The solid-state image-capturing element according to (1) above, in which

the same-color pixel group includes a 4×4 array of pixels, and

the on-chip lens is provided for each 2×2 array of pixels.

(3)

The solid-state image-capturing element according to (1) or (2) above, in which, when the pixel is seen in a plan view, the dug portion has a cross shape in which lines extending in a vertical direction and a horizontal direction of the pixel cross each other at a middle, a diagonal line shape in which a line extends in a diagonal direction of the pixel, a horizontal line shape in which a line extends in the horizontal direction of the pixel, a vertical line shape in which a line extends in the vertical direction of the pixel, or an L-shape in which lines extending in the vertical direction and the horizontal direction of the pixel are joined with each other at ends thereof.

(4)

The solid-state image-capturing element according to (3) above, in which, when the pixel is seen in a plan view, the dug portion has a structure in which the line(s) is/are provided at a middle portion of the pixel or a structure in which both ends of the line(s) are provided to be linked with the element separating portion.

(5)

The solid-state image-capturing element according to any one of (1) to (4) above, in which the dug portions with the cross shape are provided to pixels arranged at four locations in a middle 2×2 array in a 4×4 array of sixteen pixels.

(6)

The solid-state image-capturing element according to any one of (1) to (5) above, in which

the dug portions with the diagonal line shape are provided to pixels arranged at four corner locations in a 4×4 array of sixteen pixels, and

the dug portions with the diagonal line shape have side surfaces along longitudinal directions thereof that face a middle of the 4×4 array.

(7)

The solid-state image-capturing element according to any one of (1) to (5) above, in which

the dug portions with the L-shape are provided to pixels arranged at four corner locations in a 4×4 array of sixteen pixels, and

joined portions of the lines extending in the vertical directions and the horizontal directions of the dug portions with the L-shape are arranged on a middle side of the 4×4 array.

(8)

The solid-state image-capturing element according to any one of (1) to (4) above, in which the dug portions with the cross shape are provided to pixels arranged at four locations on an upper side and pixels arranged at four locations on a lower side in a 4×4 array of sixteen pixels.

(9)

The solid-state image-capturing element according to any one of (1) to (4) or (8) above, in which the dug portions with the horizontal line shape are provided to pixels arranged at eight locations in two middle rows in a 4×4 array of sixteen pixels.

(10)

The solid-state image-capturing element according to any one of (1) to (4) above, in which the dug portions with the cross shape are provided to pixels arranged at four locations on a left side and pixels arranged at four locations on a right side in a 4×4 array of sixteen pixels.

(11)

The solid-state image-capturing element according to any one of (1) to (4) or (10) above, in which the dug portions with the vertical line shape are provided to pixels arranged at eight locations in two middle columns in a 4×4 array of sixteen pixels.

(12)

The solid-state image-capturing element according to (1) or (2) above, in which, when the pixel is seen in a plan view, the dug portion has an approximately circular dot shape, a lattice shape in which multiple lines extending in a vertical direction and a horizontal direction of the pixel are provided at a predetermined pitch, horizontal stripes in which multiple lines extending in the horizontal direction of the pixel are provided, vertical stripes in which multiple lines extending in the vertical direction of the pixel are provided, or a multi-recess shape in which multiple recesses are provided at a predetermined pitch.

(13)

The solid-state image-capturing element according to (12) above, in which the dug portions with the dot shape or with the multi-recess shape are provided to pixels arranged at four locations in a middle 2×2 array in a 4×4 array of sixteen pixels.

(14)

The solid-state image-capturing element according to (12) above, in which the dug portions with the lattice shape or with the multi-recess shape are provided to pixels arranged at four locations on an upper side and pixels arranged at four locations on a lower side in a 4×4 array of sixteen pixels.

(15)

The solid-state image-capturing element according to (12) or (14) above, in which the dug portions with the horizontal stripes are provided to pixels arranged at eight locations in two middle rows in a 4×4 array of sixteen pixels.

(16)

The solid-state image-capturing element according to (12) above, in which the dug portions with the lattice shape or with the multi-recess shape are provided to pixels arranged at four locations on a left side and pixels arranged at four locations on a right side in a 4×4 array of sixteen pixels.

(17)

The solid-state image-capturing element according to (12) or (16) above, in which the dug portions with the vertical stripes are provided to pixels arranged at eight locations in two middle columns in a 4×4 array of sixteen pixels.

(18)

The solid-state image-capturing element according to any one of (1) to (17) above, further including:

a second on-chip-on-chip lens arranged for a pair of horizontally or vertically adjacent pixels, in which

the dug portions are provided to pixels other than the pixels for which the second on-chip-on-chip lens is arranged.

(19)

The solid-state image-capturing element according to (1) above, in which the same-color pixel group includes a 5×5 array of pixels.

(20)

Electronic equipment including:

a solid-state image-capturing element having
a same-color pixel group including pixels that receive light of the same color and that are arranged in an n×n array (n is an integer which is equal to or greater than two),
an on-chip lens provided for each m×m array (m is an integer which is equal to or smaller than n) of pixels in the same-color pixel group, and
a sensitivity adjustment structure with a configuration in which a dug portion shallower than an element separating portion for separating a photoelectric converting section in units of the pixels is provided on a light-incidence surface side of a semiconductor substrate at a predetermined pixel in the same-color pixel group.

Note that the present embodiment is not limited to the embodiment described above, and can be changed in various manners within the scope not deviating from the gist of the present disclosure. In addition, advantages described in the present specification are illustrated merely as examples and are not the sole examples, and there may be other advantages.

### REFERENCE SIGNS LIST

11: Image-capturing element
12: Pixel
13: Same-color pixel group 13
14: On-chip lens
15: 2×1-OCL 15
21: Sensitivity adjustment structure
22: Intra-pixel groove
31: Semiconductor layer
32: Filter layer
33: On-chip lens layer
41: Photoelectric converting section
42: Element separating portion
43: Color filter
44: Light-blocking portion
51: Sensor surface
61: Combination layout
71: 2×1-OCL arrangement pattern
81: 5×5-array sensitivity adjustment structure

1. A solid-state image-capturing element, comprising:
a same-color pixel group including pixels configured to receive light of a same color, wherein
the pixels are in an n×n array, and
n is an integer which is equal to or greater than two;
an on-chip lens for each m×m array of the pixels in the same-color pixel group, wherein
m is an integer which is equal to or smaller than n; and
a sensitivity adjustment structure with a configuration in which a dug portion shallower than an element separating portion for separating a photoelectric converting section in units of the pixels is on a light-incidence surface side of a semiconductor substrate at a specific pixel of the pixels in the same-color pixel group, wherein
when the specific pixel is seen in a plan view, the dug portion has a cross shape in which a line extending in a vertical direction of the specific pixel crosses a line extending in a horizontal direction of the specific pixel at a middle, a diagonal line shape in which a line extends in a diagonal direction of the specific pixel, a horizontal line shape in which the line extends in the horizontal direction of the specific pixel, a vertical line shape in which the line extends in the vertical direction of the specific pixel, or an L-shape in which an end of the line extending in the vertical direction of the specific pixel is joined with an end of the line extending in the horizontal direction of the specific pixel.

2. The solid-state image-capturing element according to claim 1, wherein
the same-color pixel group includes a 4×4 array of the pixels, and
the on-chip lens is for each 2×2 array of the pixels.

3. (canceled)

4. The solid-state image-capturing element according to claim 1, wherein, when the specific pixel is seen in the plan view, the dug portion has a structure in which the line extending in the horizontal direction, the line extending in the vertical direction, and the line extending in the diagonal direction are at a middle portion of the specific pixel or a structure in which both ends of each of the line extending in the horizontal direction, the line extending in the vertical direction, and the line extending in the diagonal direction linked with the element separating portion.

5. The solid-state image-capturing element according to claim 4, wherein the dug portion with the cross shape is at four locations in a middle 2×2 array in a 4×4 array of sixteen pixels of the pixels.

6. The solid-state image-capturing element according to claim 4, wherein
the dug portion with the diagonal line shape is at four corner locations in a 4×4 array of sixteen pixels of the pixels, and
the dug portion with the diagonal line shape has side surfaces along a longitudinal direction thereof that face a middle of the 4×4 array of the sixteen pixels.

7. The solid-state image-capturing element according to claim 4, wherein
the dug portion with the L-shape is at four corner locations in a 4×4 array of sixteen pixels of the pixels, and
joined portions of the line extending in the vertical direction and the line extending in the horizontal direction of the dug portion with the L-shape are on a middle side of the 4×4 array of the sixteen pixels.

8. The solid-state image-capturing element according to claim 4, wherein the dug portion with the cross shape is at four locations on an upper side in a 4×4 array of sixteen pixels of the pixels and at four locations on a lower side in the 4×4 array of the sixteen pixels.

9. The solid-state image-capturing element according to claim 4, wherein the dug portion with the horizontal line shape is at eight locations in two middle rows in a 4×4 array of sixteen pixels of the pixels.

10. The solid-state image-capturing element according to claim 4, wherein the dug portion with the cross shape is at four locations on a left side in a 4×4 array of sixteen pixels of the pixels and at four locations on a right side in the 4×4 array of the sixteen pixels.

11. The solid-state image-capturing element according to claim 4, wherein the dug portion with the vertical line shape is at eight locations in two middle columns in a 4×4 array of sixteen pixels of the pixels.

12. The solid-state image-capturing element according to claim 2, wherein, when the specific pixel is seen in the plan view, the dug portion has an approximately circular dot shape, a lattice shape in which multiple lines extending in the vertical direction and the horizontal direction of the specific pixel are at a specific pitch, horizontal stripes in which the multiple lines extend in the horizontal direction of the specific pixel, vertical stripes in which the multiple lines extend in the vertical direction of the specific pixel, or a multi-recess shape in which multiple recesses are at the specific pitch.

13. The solid-state image-capturing element according to claim 12, wherein the dug portion with the circular dot shape or the multi-recess shape is at four locations in a middle of the 2×2 array in the 4×4 array of sixteen pixels of the pixels.

14. The solid-state image-capturing element according to claim 12, wherein the dug portion with the lattice shape or the multi-recess shape is at four locations on an upper side in the 4×4 array of sixteen pixels of the pixels and at four locations on a lower side in the 4×4 array of the sixteen pixels.

15. The solid-state image-capturing element according to claim 12, wherein the dug portion with the horizontal stripes is at eight locations in two middle rows in the 4×4 array of sixteen pixels of the pixels.

16. The solid-state image-capturing element according to claim 12, wherein the dug portion with the lattice shape or the multi-recess shape is at four locations on a left side in the 4×4 array of sixteen pixels of the pixels and at four locations on a right side in the 4×4 array of the sixteen pixels.

17. The solid-state image-capturing element according to claim 12, wherein the dug portion with the vertical stripes is at eight locations in two middle columns in the 4×4 array of sixteen pixels of the pixels.

18. The solid-state image-capturing element according to claim 1, further comprising a second on-chip-on-chip lens for a pair of horizontally adjacent pixels of the pixels or vertically adjacent pixels of the pixels, wherein
the dug portion is for remaining pixels of the pixels that do not include the second on-chip-on-chip lens.

19. The solid-state image-capturing element according to claim 1, wherein the same-color pixel group includes a 5×5 array of the pixels.

20. An electronic equipment, comprising:
a solid-state image-capturing element that includes:
a same-color pixel group that includes pixels configured to receive light of a same color, wherein
the pixels are arranged in an n×n array, and
n is an integer which is equal to or greater than two;
an on-chip lens for each m×m array of the pixels in the same-color pixel group, wherein
m is an integer which is equal to or smaller than n; and
a sensitivity adjustment structure with a configuration in which a dug portion shallower than an element separating portion for separating a photoelectric converting section in units of the pixels is on a light-incidence surface side of a semiconductor substrate at a specific pixel of the pixels in the same-color pixel group, wherein
when the specific pixel is seen in a plan view, the dug portion has a cross shape in which a line extending in a vertical direction of the specific pixel crosses a line extending in a horizontal direction of the specific pixel at a middle, a diagonal line shape in which a line extends in a diagonal direction of the specific pixel, a horizontal line shape in which the line extends in the horizontal direction of the specific pixel, a vertical line shape in which the line extends in the vertical direction of the specific pixel, or an L-shape in which an end of the line extending in the vertical direction of the specific pixel is joined with an end of the line extending in the horizontal direction of the specific pixel.
